(19) United States
(12) Patent Application Publication
(10) Pub. No.: US 2024/0381685 A1
(43) Pub. Date: Nov. 14, 2024

(54) ELECTRONIC DEVICE

(71) Applicant: Merck Patent GmbH, Darmstadt (DE)

(72) Inventors: Elvira MONTENEGRO, Darmstadt (DE); Jens ENGELHART, Darmstadt (DE); You-Hyun KIM, Darmstadt (DE)

(21) Appl. No.: 18/689,448

(22) PCT Filed: Sep. 6, 2022
(86) PCT No.: PCT/EP2022/074662

§ 371 Date: Mar. 6, 2024

(30) Foreign Application Priority Data
Sep. 8, 2021 (EP) 21195441.7

(51) Int. Cl. H10K 50/15; H10K 50/125; H10K 50/16; H10K 71/16; H10K 85/60; H10K 101/10; H10K 101/30

(52) U.S. Cl. CPC H10K 50/156; H10K 50/125; H10K 50/16; H10K 71/16; H10K 85/657; H10K 2101/10; H10K 2101/30

(57) ABSTRACT

The present application relates to an electronic device comprising, in this sequence, an anode, a layer HTL1, a layer HTL2, directly adjoined by an emitting layer, and a cathode.

The present application relates to an electronic device comprising, in this sequence, an anode, a layer HTL1, a layer HTL2, directly adjoined by an emitting layer, and a cathode.

Electronic devices in the context of this application are understood to mean what are called organic electronic devices, which comprise organic semiconductor materials as functional materials. More particularly, these are understood to mean OLEDs (organic light-emitting diodes, organic electroluminescent devices). These are electronic devices which have one or more layers comprising organic compounds and emit light on application of electrical voltage. The construction and general principle of function of OLEDs are known to those skilled in the art.

In electronic devices, especially OLEDs, there is great interest in an improvement in the performance data, especially lifetime, efficiency, operating voltage and colour purity. In these aspects, it has not yet been possible to find any entirely satisfactory solution.

Hole-transporting layers such as layers HTL1 and HTL2 of the device according to the application have a great influence on the abovementioned performance data of electronic devices. The hole-transporting layers may, as well as their hole-transporting function, also have an electron-blocking function, meaning that they block the passage of electrons from the emitting layer to the anode. In addition, the hole-transporting layers of the OLED preferably have suitable HOMO levels to efficiently enable the transport of the holes from the anode to the emitting layer.

Materials for hole-transporting layers that are known in the prior art are primarily amine compounds, especially triarylamine compounds. Examples of such triarylamine compounds are spirobifluoreneamines, fluoreneamines, indenofluoreneamines, phenanthreneamines, carbazoleamines, xantheneamines, spirodihydroacridineamines, biphenylamines and combinations of these structural elements having one or more amino groups, and the person skilled in the art is aware of further structure classes.

It has now been found that, surprisingly, the combination of an undoped hole-transporting layer HTL1 containing a spirobifluorenyl or fluorenyl compound as defined below with a hole-transporting layer HTL2 that adjoins the emitting layer and contains a spirobifluorenyl or fluorenyl compound as defined below leads to very good properties of the OLED, especially to very good efficiency and very good lifetime.

The present application thus provides an electronic device comprising
an anode,
a cathode,
an emitting layer disposed between anode and cathode,
an undoped layer HTL1 which is disposed between anode and emitting layer and contains a compound of a formula (I)

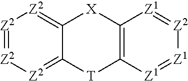

Formula (I), for which:
X is selected from C(R¹)₂ and a group

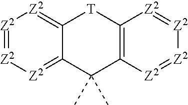

where the dotted lines represent the bonds of the group to the rest of the formula (I);
T is the same or different at each instance and is selected from single bond, O, S, NR², and C(R²)₂;
Z¹ is the same or different at each instance and is CR³ or N; where at least one Z¹ group is CR³ with

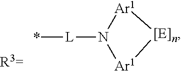

where the bond marked * is the bond to the carbon atom of this CR³ group;
Z² is CR⁴ or N;
L is selected from single bond, aromatic ring systems which have 6 to 40 aromatic ring atoms and are substituted by R⁵ radicals and heteroaromatic ring systems which have 5 to 40 aromatic ring atoms and are substituted by R⁵ radicals;
Ar¹ is the same or different at each instance and is selected from aromatic ring systems which have 6 to 40 aromatic ring atoms and are substituted by R⁶ radicals, and heteroaromatic ring systems which have 5 to 40 aromatic ring atoms and are substituted by R⁶ radicals;
E is selected from single bond, C(R⁷)₂, —C(R⁷)₂—C(R⁷)₂—, —CR⁷=CR⁷—, Si(R⁷)₂, O, S, S═O, SO₂ and NR⁷;
R¹ is the same or different at each instance and is selected from H, D, F, Cl, Br, I, C(═O)R⁸, CN, Si(R⁸)₃, N(R⁸)₂, P(═O)(R⁸)₂, OR⁸, S(═O)R⁸, S(═O)₂R⁸, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two R¹ radicals may be joined to one another to form a cycloalkyl ring; where the alkyl, alkoxy, alkenyl and alkynyl groups mentioned and the aromatic ring systems and heteroaromatic ring systems mentioned are each substituted by R⁸ radicals; and where one or more CH₂ groups in the alkyl, alkoxy, alkenyl and alkynyl groups mentioned may be replaced by —R⁸C=CR⁸—, —C≡C—, Si(R⁸)₂, C═O, C=NR⁸, —C(═O)O—, —C(═O)NR⁸—, NR⁸, P(═O)(R⁸), —O—, —S—, SO or SO₂;
R² is the same or different at each instance and is selected from H, D, F, Cl, Br, I, C(═O)R⁸, CN, Si(R⁸)₃, N(R⁸)₂, P(═O)(R⁸)₂, OR⁸, S(═O)R⁸, S(═O)₂R⁸, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two R² radicals may be joined to one another and may form a ring; where the alkyl, alkoxy, alkenyl and alkynyl groups mentioned and the aromatic ring systems and heteroaromatic ring systems mentioned are each substituted by R⁸ radicals; and where one or more CH₂ groups in the alkyl, alkoxy, alkenyl and alkynyl groups mentioned may be replaced by —R⁸C=CR⁸—, —C═C—, Si(R⁸)₂, C═O, C=NR⁸, —C(═O)O—, —C(═O)NR⁸—, NR⁸, P(═O)(R⁸), —O—, —S—, SO or SO₂;
R³ is the same or different at each instance and is selected from a group

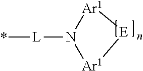

bonded via the bond marked * to the carbon atom of the Z¹ group,
H, D, F, Cl, Br, I, C(═O)R⁸, CN, Si(R⁸)₃, N(R⁸)₂, P(═O)(R⁸)₂, OR⁸, S(═O)R⁸, S(═O)₂R⁸, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R³ radicals may be joined to one another and may form a ring; where the alkyl, alkoxy, alkenyl and alkynyl groups mentioned and the aromatic ring systems and heteroaromatic ring systems mentioned are each substituted by R⁸ radicals; and where one or more CH₂ groups in the alkyl, alkoxy, alkenyl and alkynyl groups mentioned may be replaced by —R⁸C=CR⁸—, —C═C—, Si(R⁸)₂, C═O, C=NR⁸, —C(═O)O—, —C(═O)NR⁸—, NR⁸, P(═O)(R⁸), —O—, —S—, SO or SO₂;
R⁴ is the same or different at each instance and is selected from a group

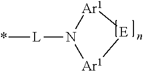

bonded via the bond marked * to the carbon atom of the Z² group,
H, D, F, Cl, Br, I, C(═O)R⁸, CN, Si(R⁸)₃, N(R⁸)₂, P(═O)(R⁸)₂, OR⁸, S(═O)R⁸, S(═O)₂R⁸, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R⁴ radicals may be joined to one another and may form a ring; where the alkyl, alkoxy, alkenyl and alkynyl groups mentioned and the aromatic ring systems and heteroaromatic ring systems mentioned are each substituted by R⁸ radicals; and where one or more CH₂ groups in the alkyl, alkoxy, alkenyl and alkynyl groups mentioned may be replaced by —R⁸C=CR⁸—, —C═C—, Si(R⁸)₂, C═O, C=NR⁸, —C(═O)O—, —C(═O)NR⁸—, NR⁸, P(═O)(R⁸), —O—, —S—, SO or SO₂;
R⁵ is the same or different at each instance and is selected from H, D, F, Cl, Br, I, C(═O)R⁸, CN, Si(R⁸)₃, N(R⁸)₂, P(═O)(R⁸)₂, OR⁸, S(═O)R⁸, S(═O)₂R⁸, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R⁵ radicals may be joined to one another and may form a ring; where the alkyl, alkoxy, alkenyl and alkynyl groups mentioned and the aromatic ring systems and heteroaromatic ring systems mentioned are each substituted by R⁸ radicals; and where one or more CH₂ groups in the alkyl, alkoxy, alkenyl and alkynyl groups mentioned may be replaced by —R⁸C=CR⁸—, —C═C—, Si(R⁸)₂, C═O, C=NR⁸, —C(═O)O—, —C(═O)NR⁸—, NR⁸, P(═O)(R⁸), —O—, —S—, SO or SO₂;
R⁶ is the same or different at each instance and is selected from H, D, F, Cl, Br, I, C(═O)R⁸, CN, Si(R⁸)₃, N(R⁸)₂, P(═O)(R⁸)₂, OR⁸, S(═O)R⁸, S(═O)₂R⁸, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R⁶ radicals may be joined to one another and may form a ring; where the alkyl, alkoxy, alkenyl and alkynyl groups mentioned and the aromatic ring systems and heteroaromatic ring systems mentioned are each substituted by R⁸ radicals; and where one or more CH₂ groups in the alkyl, alkoxy, alkenyl and alkynyl groups mentioned may be replaced by —R⁸C=CR⁸—, —C═C—, Si(R⁸)₂, C═O, C=NR⁸, —C(═O)O—, —C(═O)NR⁸—, NR⁸, P(═O)(R⁸), —O—, —S—, SO or SO₂;
R⁷ is the same or different at each instance and is selected from H, D, F, Cl, Br, I, C(═O)R⁸, CN, Si(R⁸)₃, N(R⁸)₂, P(═O)(R⁸)₂, OR⁸, S(═O)R⁸, S(═O)₂R⁸, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R⁷ radicals may be joined to one another and may form a ring; where the alkyl, alkoxy, alkenyl and alkynyl groups mentioned and the aromatic ring systems and heteroaromatic ring systems mentioned are each substituted by R⁸ radicals; and where one or more CH₂ groups in the alkyl, alkoxy, alkenyl and alkynyl groups mentioned may be replaced by —R⁸C=CR⁸—, —C≡C—, Si(R⁸)₂, C═O, C=NR⁸, —C(═O)O—, —C(═O)NR⁸—, NR⁸, P(═O)(R⁸), —O—, —S—, SO or SO₂;
R⁸ is the same or different at each instance and is selected from H, D, F, Cl, Br, I, C(═O)R⁹, CN, Si(R⁹)₃, N(R⁹)₂, P(═O)(R⁹)₂, OR⁹, S(═O)R⁹, S(═O)₂R⁹, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more Ra radicals may be joined to one another and may form a ring; where the alkyl, alkoxy, alkenyl and alkynyl groups mentioned and the aromatic ring systems and heteroaromatic ring systems mentioned are each substituted by R⁹ radicals; and where one or more CH₂ groups in the alkyl, alkoxy, alkenyl and alkynyl groups mentioned may be replaced by —R⁹C=CR⁹—, —C≡C—, Si(R⁹)₂, C=O, C=NR⁹, —C(═O)O—, —C(═O)NR⁹—, NR⁹, P(═O)(R⁹), —O—, —S—, SO or SO₂;
R⁹ is the same or different at each instance and is selected from H, D, F, Cl, Br, I, CN, alkyl or alkoxy groups having 1 to 20 carbon atoms, alkenyl or alkynyl groups having 2 to 20 carbon atoms, aromatic ring systems having 6 to 40 aromatic ring atoms and heteroaromatic ring systems having 5 to 40 aromatic ring atoms; where two or more R⁹ radicals may be joined to one another and may form a ring; and where the alkyl, alkoxy, alkenyl and alkynyl groups, aromatic ring systems and heteroaromatic ring systems mentioned may be substituted by one or more radicals selected from F and CN;
n is 0 or 1, where, when n=0, the E group is absent, and the two Ar¹ groups are not bonded to one another;
and
a layer HTL2 which is disposed between the anode and emitting layer and directly adjoining the emitting layer, and which contains a compound of the formula (II) or (III)

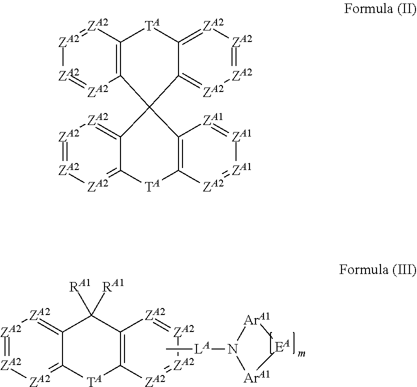

for which:
T^{A} is the same or different at each instance and is selected from single bond, O, S, NR^{A2} and C(R^{A2})₂.
Z^{A1} is the same or different at each instance and is CR^{A3} or N; where at least one Z^{A1} group in formula (II) is CR^{A3} with

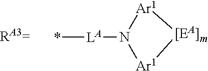

where the bond marked * is the bond to the carbon atom of this CR^{A3} group;
Z^{A2} is the same or different at each instance and is CR^{A4} or N, or is C in formula (III) when the

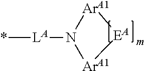

group is bonded thereto;
L^{A} is selected from single bond, aromatic ring systems which have 6 to 40 aromatic ring atoms and are substituted by R^{A5} radicals and heteroaromatic ring systems which have 5 to 40 aromatic ring atoms and are substituted by R^{A5} radicals;
Ar^{A1} is the same or different at each instance and is selected from aromatic ring systems which have 6 to 40 aromatic ring atoms and are substituted by R^{A6} radicals, and heteroaromatic ring systems which have 5 to 40 aromatic ring atoms and are substituted by R^{A6} radicals;
E^{A} is selected from single bond, C(R^{A7})₂, —C(R^{A7})₂—C(R^{A7})₂—, —CR^{A7}=R^{A7}—, Si(R^{A7})₂, O, S, S=O, SO₂ and NRA⁷;
R^{A1} is the same or different at each instance and is selected from H, D, F, Cl, Br, I, C(═O)R^{A8}, CN, Si(R^{A8})₃, N(R^{A8})₂, P(═O)(R^{A8})₂, OR^{A8}, S(═O)R^{A8}, S(═O)₂R^{A8}, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two A¹ radicals may be joined to one another to form a cycloalkyl ring; where the alkyl, alkoxy, alkenyl and alkynyl groups mentioned and the aromatic ring systems and heteroaromatic ring systems mentioned are each substituted by R^{A8} radicals; and where one or more CH₂ groups in the alkyl, alkoxy, alkenyl and alkynyl groups mentioned may be replaced by —R^{A8}C=CR^{A8}—, —C≡C—, —Si(R^{A8})₂, C=O, C=NR^{A8}, —C(=)O—, —C(═O)NR^{A8}—, NR^{A8}, P(═O)(R^{A8}) —O—, —S—, SO or SO₂;
R^{A2} is the same or different at each instance and is selected from H, D, F, Cl, Br, I, C(═O)R^{A8}, CN, Si(R^{A8})₃, N(R^{A8})₂, P(═O)(R^{A8})₂, OR^{A8}, S(═O)R^{A8}, S(═O)₂R^{A8}, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R^{A2} radicals may be joined to one another and may form a ring; where the alkyl, alkoxy, alkenyl and alkynyl groups mentioned and the aromatic ring systems and heteroaromatic ring systems mentioned are each substituted by R^{A8} radicals; and where one or more CH₂ groups in the alkyl, alkoxy, alkenyl and alkynyl groups mentioned may be replaced by —R^{A8}C=CR^{A8}—, —C=C—, Si(R^{A8})₂, C=O, C=NR^{A8}, —C(═O)O—, —C(═O)NR^{A8}—, NR^{A8}, P(═O)(R^{A8}) —O—, —S—, SO or SO₂;
R^{A3} is the same or different at each instance and is selected from a group

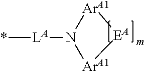

bonded via the bond marked * to the carbon atom of the Z¹ group,
H, D, F, Cl, Br, I, C(═O)R^{A8}, CN, Si(R^{A8})₃, N(R^{A8})₂, P(═O)(R^{A8})₂, OR^{A8} S(═O)R^{A8}, S(═O)₂R^{A8}, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R^{A3} radicals may be joined to one another and may form a ring; where the alkyl, alkoxy, alkenyl and alkynyl groups mentioned and the aromatic ring systems and heteroaromatic ring systems mentioned are each substituted by R^{A8} radicals; and where one or more CH₂ groups in the alkyl, alkoxy, alkenyl and alkynyl groups mentioned may be replaced by —R^{A8}C=CR^{A8}—, —C≡C—, Si(R^{A8})₂, C=O, C=NR^{A8}, —C(═O)O—, —C(═O)NR^{A8}—, NR^{A8}, P(═O)(R^{A8}), —O—, —S—, SO or SO₂; R^{A4} is the same or different at each instance and is selected from H, D, F, Cl, Br, I, C(═O)R^{A8}, CN, Si(R^{A8})₃, N(R^{A8})₂, P(═O)(R^{A8})₂, OR^{A8}, S(═O)R^{A8}, S(═O)₂R^{A8}, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R^{A4} radicals may be joined to one another and may form a ring; where the alkyl, alkoxy, alkenyl and alkynyl groups mentioned and the aromatic ring systems and heteroaromatic ring systems mentioned are each substituted by R^{A8} radicals; and where one or more CH₂ groups in the alkyl, alkoxy, alkenyl and alkynyl groups mentioned may be replaced by —R^{A8}C=CR^{A8}—, —C≡C—, Si(R^{A8})₂, C=O, C=NR^{A8}, —C(═O)O—, —C(═O)NR^{A8}—, NR^{A8}, P(═O)(R^{A8}), —O—, —S—, SO or SO₂;
R^{A5} is the same or different at each instance and is selected from H, D, F, Cl, Br, I, C(═O)R^{A8}, CN, Si(R^{A8})₃, N(R^{A8})₂, P(═O)(R^{A8})₂, OR^{A8}, S(═O)R^{A8}, S(═O)₂R^{A8}, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R^{A5} radicals may be joined to one another and may form a ring; where the alkyl, alkoxy, alkenyl and alkynyl groups mentioned and the aromatic ring systems and heteroaromatic ring systems mentioned are each substituted by R^{A8} radicals; and where one or more CH₂ groups in the alkyl, alkoxy, alkenyl and alkynyl groups mentioned may be replaced by —R^{A8}C=CR^{A8}—, —C=C—, Si(R^{A8})₂, C=O, C=NR^{A8}, —C(═O)O —C(═O)NR^{A8}—, NR^{A8}, P(═O)(R^{A8}) —O—, —S—, SO or SO₂;
R^{A6} is the same or different at each instance and is selected from H, D, F, Cl, Br, I, C(═O)R^{A8}, CN, Si(R^{A8})₃, N(R^{A8})₂, P(═O)(R^{A8})₂, OR^{A8}, S(═O)R^{A8}, S(═O)₂R^{A8}, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R^{A6} radicals may be joined to one another and may form a ring; where the alkyl, alkoxy, alkenyl and alkynyl groups mentioned and the aromatic ring systems and heteroaromatic ring systems mentioned are each substituted by R^{A8} radicals; and where one or more CH₂ groups in the alkyl, alkoxy, alkenyl and alkynyl groups mentioned may be replaced by —R^{A8}C=CR^{A8}—, —C≡C—, Si(R^{A8})₂, C=O, C=NR^{A8}, —C(═O)O—, —C(═O)NR^{A8}—, NR^{A8}, P(═O)(R^{A8}) —O—, —S—, SO or SO₂;
R^{A7} is the same or different at each instance and is selected from H, D, F, Cl, Br, I, C(═O)R^{A8}, CN, Si(R^{A8})₃, N(R^{A8})₂, P(═O)(R^{A8})₂, OR^{A8}, S(═O)R^{A8}, S(═O)₂R^{A8}, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R^{A7} radicals may be joined to one another and may form a ring; where the alkyl, alkoxy, alkenyl and alkynyl groups mentioned and the aromatic ring systems and heteroaromatic ring systems mentioned are each substituted by R^{A8} radicals; and where one or more CH₂ groups in the alkyl, alkoxy, alkenyl and alkynyl groups mentioned may be replaced by —R^{A8}C=CR^{A8}—, —C=C—, Si(R^{A8})₂, C=O, C=NR^{A8}, —C(═O)O—, —C(═O)NR^{A8}—, NR^{A8}, P(═O)(R^{A8}) —O—, —S—, SO or SO₂;
R^{A8} is the same or different at each instance and is selected from H, D, F, Cl, Br, I, C(═O)R^{A9}, CN, Si(R^{A9})₃, N(R^{A9})₂, P(═O)(R^{A9})₂, OR^{A9}, S(═O)R^{A9}, S(═O)₂R^{A9}, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R^{A8} radicals may be joined to one another and may form a ring; where the alkyl, alkoxy, alkenyl and alkynyl groups mentioned and the aromatic ring systems and heteroaromatic ring systems mentioned are each substituted by R^{A9} radicals; and where one or more CH₂ groups in the alkyl, alkoxy, alkenyl and alkynyl groups mentioned may be replaced by —R^{A9}C=CR^{A9}—, —C=C—, Si(R^{A9})₂, C=O, C=NR^{A9}, —C(═O)O—, —C(═O)NR^{A9}—, NR^{A9}, P(═O)(R^{A9}), —O—, —S—, SO or SO₂;
R^{A9} is the same or different at each instance and is selected from H, D, F, Cl, Br, I, CN, alkyl or alkoxy groups having 1 to 20 carbon atoms, alkenyl or alkynyl groups having 2 to 20 carbon atoms, aromatic ring systems having 6 to 40 aromatic ring atoms and heteroaromatic ring systems having 5 to 40 aromatic ring atoms; where two or more R^{A9} radicals may be joined to one another and may form a ring; and where the alkyl, alkoxy, alkenyl and alkynyl groups, aromatic ring systems and heteroaromatic ring systems mentioned may be substituted by one or more radicals selected from F and CN;
m is 0 or 1, where, when m=0, the E^{A} group is absent, and the two Ar^{A1} groups are not bonded to one another.

The definitions which follow are applicable to the chemical groups that are used in the present application. They are applicable unless any more specific definitions are given.

An aryl group in the context of this invention is understood to mean either a single aromatic cycle, i.e. benzene, or a fused aromatic polycycle, for example naphthalene, phenanthrene or anthracene. A fused aromatic polycycle in the context of the present application consists of two or more single aromatic cycles fused to one another. Fusion between cycles is understood here to mean that the cycles share at least one edge with one another. An aryl group in the context of this invention contains 6 to 40 aromatic ring atoms. In addition, an aryl group does not contain any heteroatom as aromatic ring atom, but only carbon atoms.

A heteroaryl group in the context of this invention is understood to mean either a single heteroaromatic cycle, for example pyridine, pyrimidine or thiophene, or a fused heteroaromatic polycycle, for example quinoline or carbazole. A fused heteroaromatic polycycle in the context of the present application consists of two or more single aromatic or heteroaromatic cycles that are fused to one another, where at least one of the aromatic and heteroaromatic cycles is a heteroaromatic cycle. Fusion between cycles is understood here to mean that the cycles share at least one edge with one another. A heteroaryl group in the context of this invention contains 5 to 40 aromatic ring atoms of which at least one is a heteroatom. The heteroatoms of the heteroaryl group are preferably selected from N, O and S.

An aryl or heteroaryl group, each of which may be substituted by the abovementioned radicals, is especially understood to mean groups derived from benzene, naphthalene, anthracene, phenanthrene, pyrene, dihydropyrene, chrysene, perylene, triphenylene, fluoranthene, benzanthracene, benzophenanthrene, tetracene, pentacene, benzopyrene, furan, benzofuran, isobenzofuran, dibenzofuran, thiophene, benzothiophene, isobenzothiophene, dibenzothiophene, pyrrole, indole, isoindole, carbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, benzimidazolo[1,2-a]benzimidazole, naphthimidazole, phenanthrimidazole, pyridimidazole, pyrazinimidazole, quinoxalinimidazole, oxazole, benzoxazole, naphthoxazole, anthroxazole, phenanthroxazole, isoxazole, 1,2-thiazole, 1,3-thiazole, benzothiazole, pyridazine, benzopyridazine, pyrimidine, benzopyrimidine, quinoxaline, pyrazine, phenazine, naphthyridine, azacarbazole, benzocarboline, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole, 1,2,4,5-tetrazine, 1,2,3,4-tetrazine, 1,2,3,5-tetrazine, purine, pteridine, indolizine and benzothiadiazole.

An aromatic ring system in the context of this invention is a system which does not necessarily contain solely aryl groups, but which may additionally contain one or more nonaromatic rings fused to at least one aryl group. These nonaromatic rings contain exclusively carbon atoms as ring atoms. Examples of groups covered by this definition are tetrahydronaphthalene, fluorene and spirobifluorene. In addition, the term “aromatic ring system” includes systems that consist of two or more aromatic ring systems joined to one another via single bonds, for example biphenyl, terphenyl, 7-phenyl-2-fluorenyl, quaterphenyl and 3,5-diphenyl-1-phenyl. An aromatic ring system in the context of this invention contains 6 to 40 carbon atoms and no heteroatoms in the ring system. The definition of “aromatic ring system” does not include heteroaryl groups.

A heteroaromatic ring system conforms to the abovementioned definition of an aromatic ring system, except that it must contain at least one heteroatom as ring atom. As is the case for the aromatic ring system, the heteroaromatic ring system need not contain exclusively aryl groups and heteroaryl groups, but may additionally contain one or more nonaromatic rings fused to at least one aryl or heteroaryl group. The nonaromatic rings may contain exclusively carbon atoms as ring atoms, or they may additionally contain one or more heteroatoms, where the heteroatoms are preferably selected from N, O and S. One example of such a heteroaromatic ring system is benzopyranyl. In addition, the term “heteroaromatic ring system” is understood to mean systems that consist of two or more aromatic or heteroaromatic ring systems that are bonded to one another via single bonds, for example 4,6-diphenyl-2-triazinyl. A heteroaromatic ring system in the context of this invention contains 5 to 40 ring atoms selected from carbon and heteroatoms, where at least one of the ring atoms is a heteroatom. The heteroatoms of the heteroaromatic ring system are preferably selected from N, O and S.

The terms “heteroaromatic ring system” and “aromatic ring system” as defined in the present application thus differ from one another in that an aromatic ring system cannot have a heteroatom as ring atom, whereas a heteroaromatic ring system must have at least one heteroatom as ring atom. This heteroatom may be present as a ring atom of a nonaromatic heterocyclic ring or as a ring atom of an aromatic heterocyclic ring.

In accordance with the above definitions, any aryl group is covered by the term “aromatic ring system”, and any heteroaryl group is covered by the term “heteroaromatic ring system”.

An aromatic ring system having 6 to 40 aromatic ring atoms or a heteroaromatic ring system having 5 to 40 aromatic ring atoms is especially understood to mean groups derived from the groups mentioned above under aryl groups and heteroaryl groups, and from biphenyl, terphenyl, quaterphenyl, fluorene, spirobifluorene, dihydrophenanthrene, dihydropyrene, tetrahydropyrene, indenofluorene, truxene, isotruxene, spirotruxene, spiroisotruxene, indenocarbazole, or from combinations of these groups.

In the context of the present invention, a straight-chain alkyl group having 1 to 20 carbon atoms and a branched or cyclic alkyl group having 3 to 20 carbon atoms and an alkenyl or alkynyl group having 2 to 40 carbon atoms in which individual hydrogen atoms or CH₂ groups may also be substituted by the groups mentioned above in the definition of the radicals are preferably understood to mean the methyl, ethyl, n-propyl, i-propyl, n-butyl, i-butyl, s-butyl, t-butyl, 2-methylbutyl, n-pentyl, s-pentyl, cyclopentyl, neopentyl, n-hexyl, cyclohexyl, neohexyl, n-heptyl, cycloheptyl, n-octyl, cyclooctyl, 2-ethylhexyl, trifluoromethyl, pentafluoroethyl, 2,2,2-trifluoroethyl, ethenyl, propenyl, butenyl, pentenyl, cyclopentenyl, hexenyl, cyclohexenyl, heptenyl, cycloheptenyl, octenyl, cyclooctenyl, ethynyl, propynyl, butynyl, pentynyl, hexynyl or octynyl radicals.

An alkoxy or thioalkyl group having 1 to 20 carbon atoms in which individual hydrogen atoms or CH₂ groups may also be substituted by the groups mentioned above in the definition of the radicals is preferably understood to mean methoxy, trifluoromethoxy, ethoxy, n-propoxy, i-propoxy, n-butoxy, i-butoxy, s-butoxy, t-butoxy, n-pentoxy, s-pentoxy, 2-methylbutoxy, n-hexoxy, cyclohexyloxy, n-heptoxy, cycloheptyloxy, n-octyloxy, cyclooctyloxy, 2-ethylhexyloxy, pentafluoroethoxy, 2,2,2-trifluoroethoxy, methylthio, ethylthio, n-propylthio, i-propylthio, n-butylthio, i-butylthio, s-butylthio, t-butylthio, n-pentylthio, s-pentylthio, n-hexylthio, cyclohexylthio, n-heptylthio, cycloheptylthio, n-octylthio, cyclooctylthio, 2-ethylhexylthio, trifluoromethylthio, pentafluoroethylthio, 2,2,2-trifluoroethylthio, ethenylthio, propenylthio, butenylthio, pentenylthio, cyclopentenylthio, hexenylthio, cyclohexenylthio, heptenylthio, cycloheptenylthio, octenylthio, cyclooctenylthio, ethynylthio, propynylthio, butynylthio, pentynylthio, hexynylthio, heptynylthio or octynylthio.

The wording that two or more radicals together may form a ring, in the context of the present application, shall be understood to mean, inter alia, that the two radicals are joined to one another by a chemical bond. In addition, however, the abovementioned wording shall also be understood to mean that, if one of the two radicals is hydrogen, the second radical binds to the position to which the hydrogen atom was bonded, forming a ring.

An undoped layer HTL1 is understood in the context of the present application to mean that the layer is not p-doped, i.e. the material of the layer is not doped with p-dopants.

In formula (I), X is preferably selected from a group

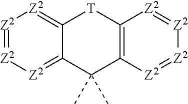

where the dotted lines represent the bonds of the group to the rest of the formula (I).

In addition, T is preferably a single bond.

In addition, Z¹ is preferably CR³; with at least one Z¹ group is CR³ with

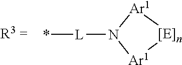

where the bond marked * is the bond to the carbon atom of this CR³ group.

In a further preferred embodiment, 0, 1 or 2, more preferably 0 or 1 of the Z¹ groups, are N, and the remaining Z¹ groups are CR³.

Preferably, exactly one Z¹ group in formula (I) is CR³ with

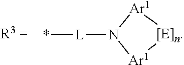

In addition, Z² is preferably CR⁴.

In a further preferred embodiment, 0, 1, 2 or 3, more preferably 0, 1 or 2, most preferably 0 or 1, of the Z² groups, are N, and the remaining Z² groups are CR⁴.

In a preferred embodiment, L is a single bond.

If L is selected from aromatic and heteroaromatic ring systems, L is preferably selected from the following groups:

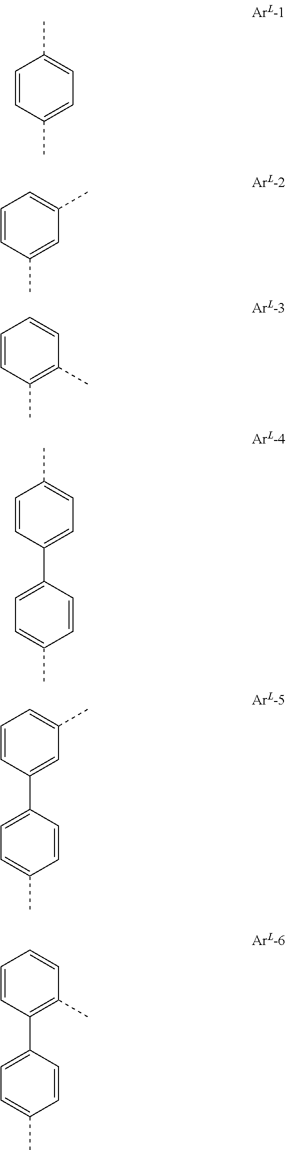

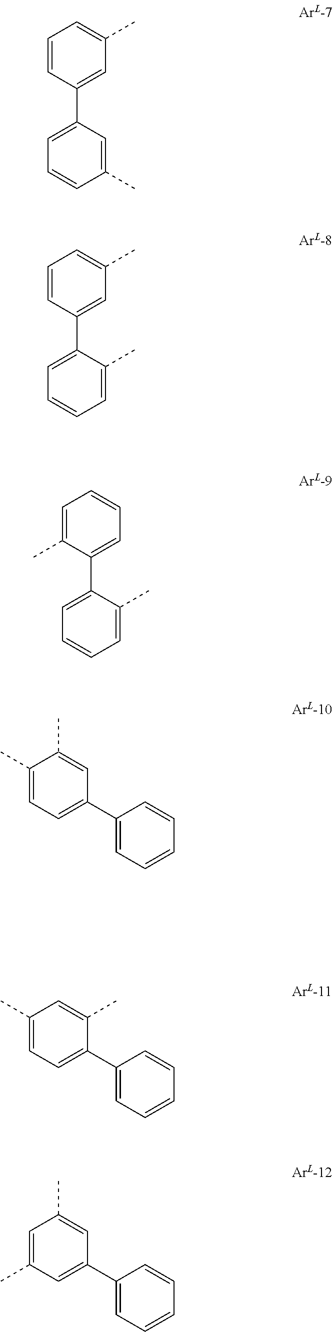

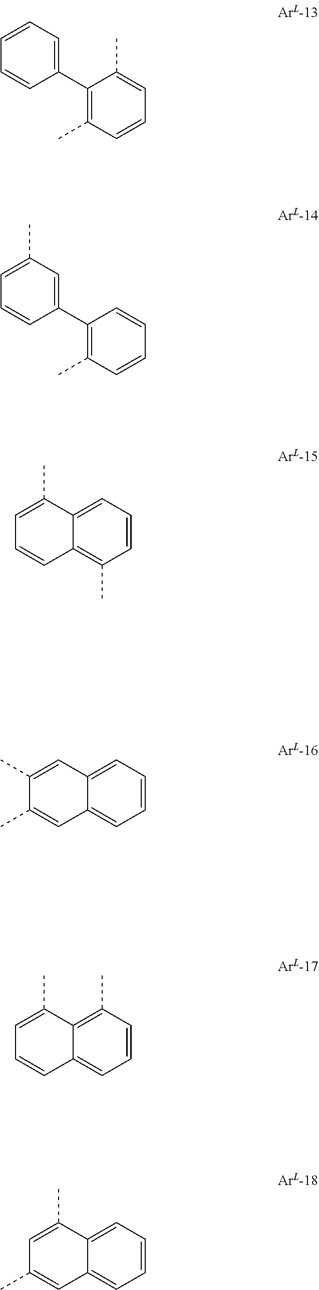

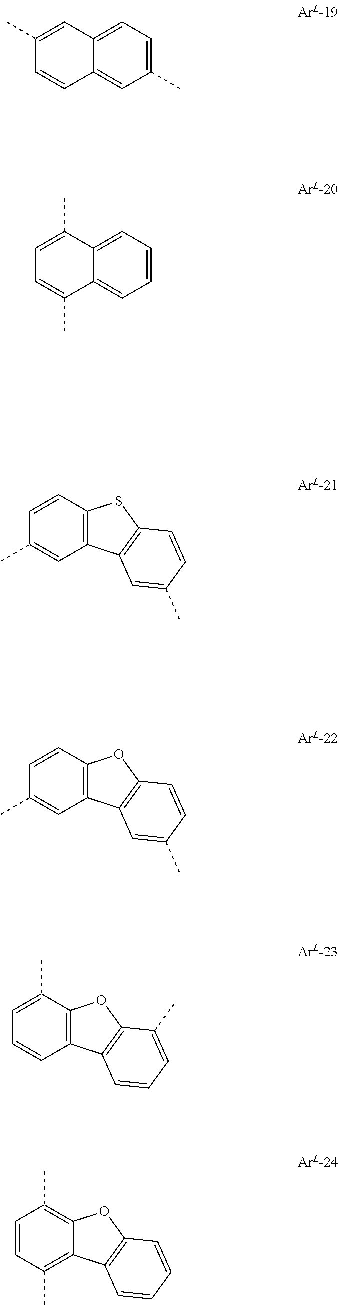

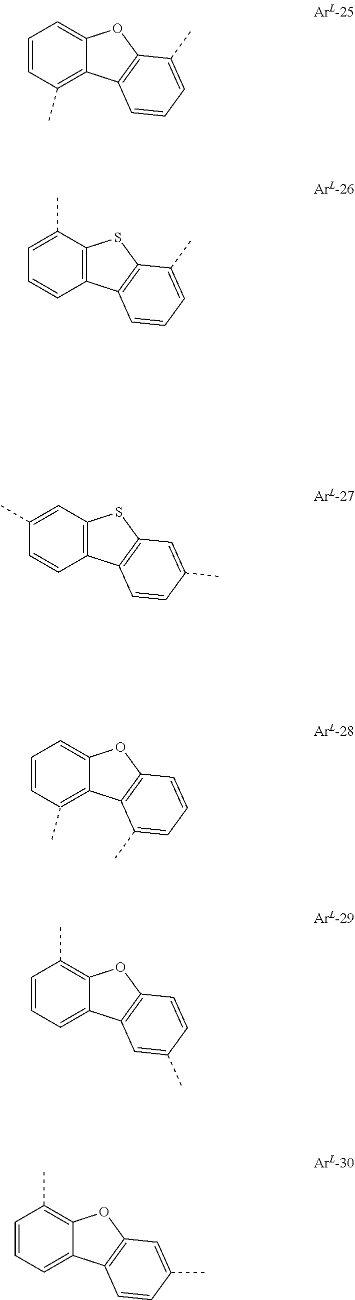

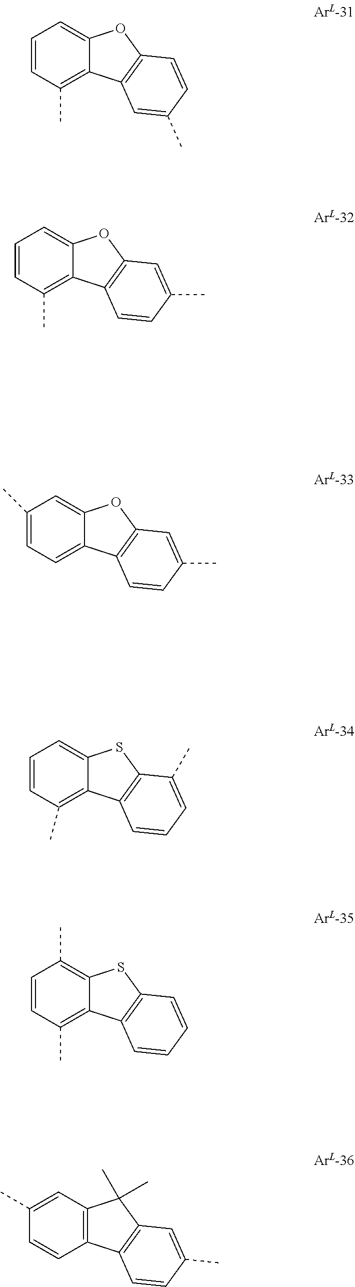

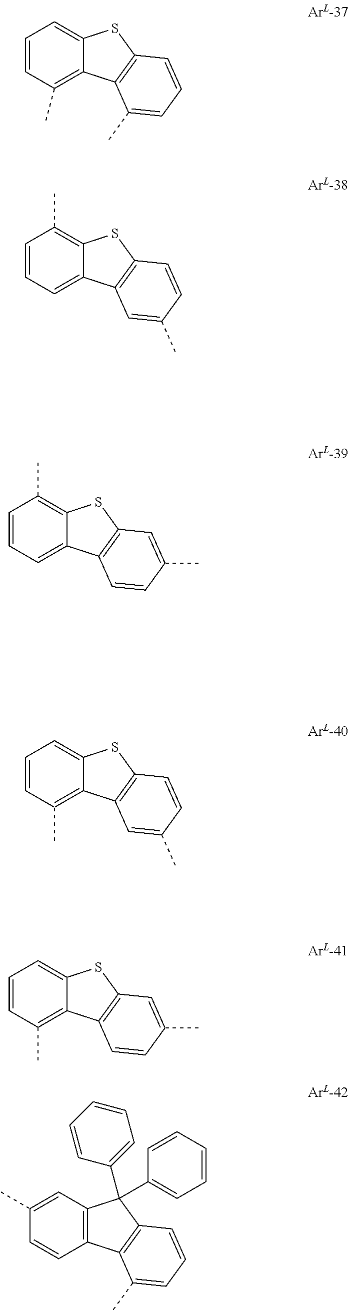

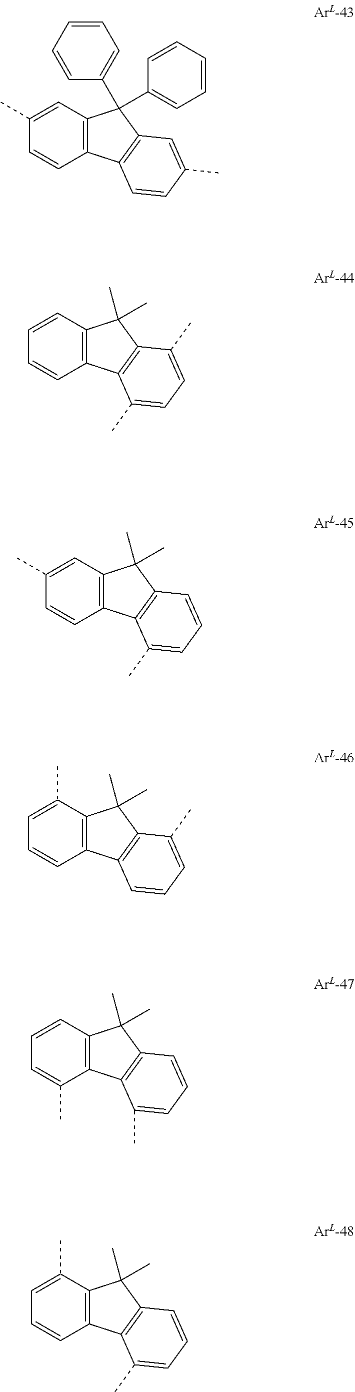

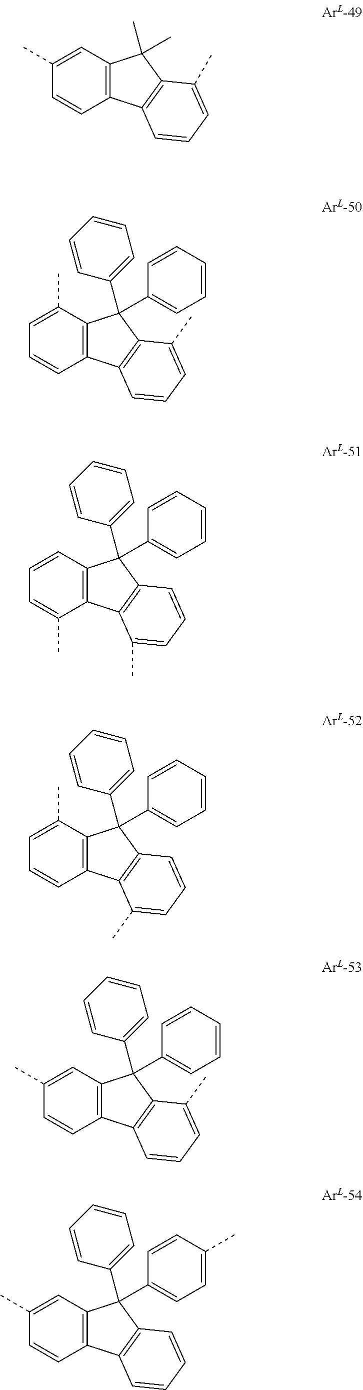

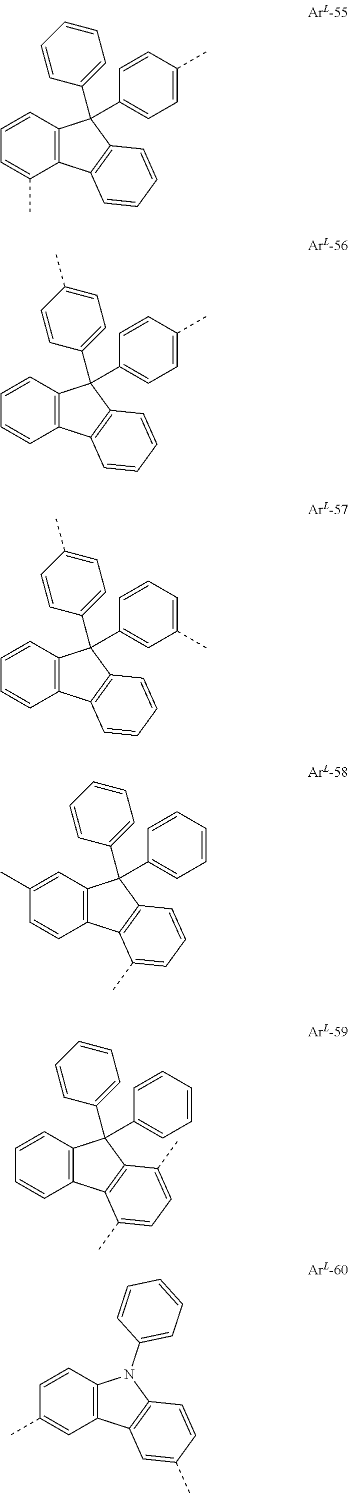

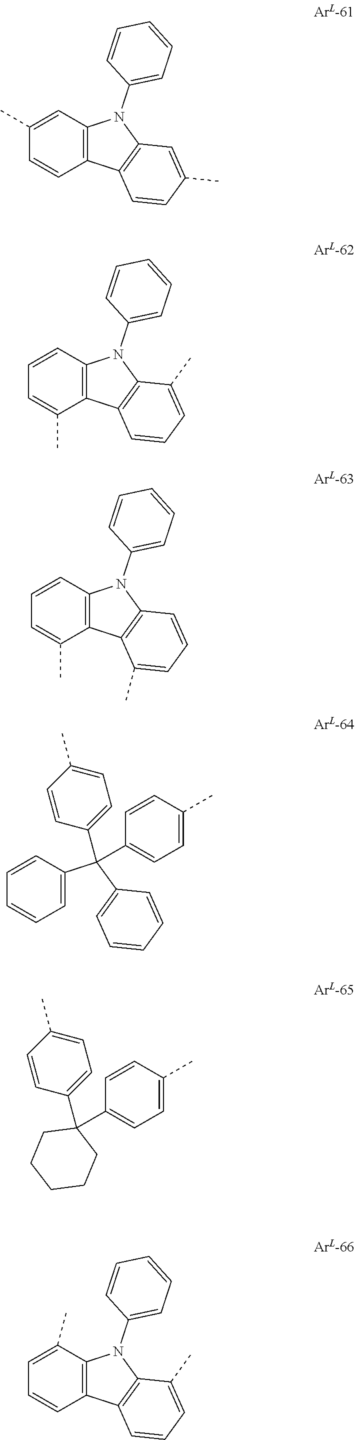

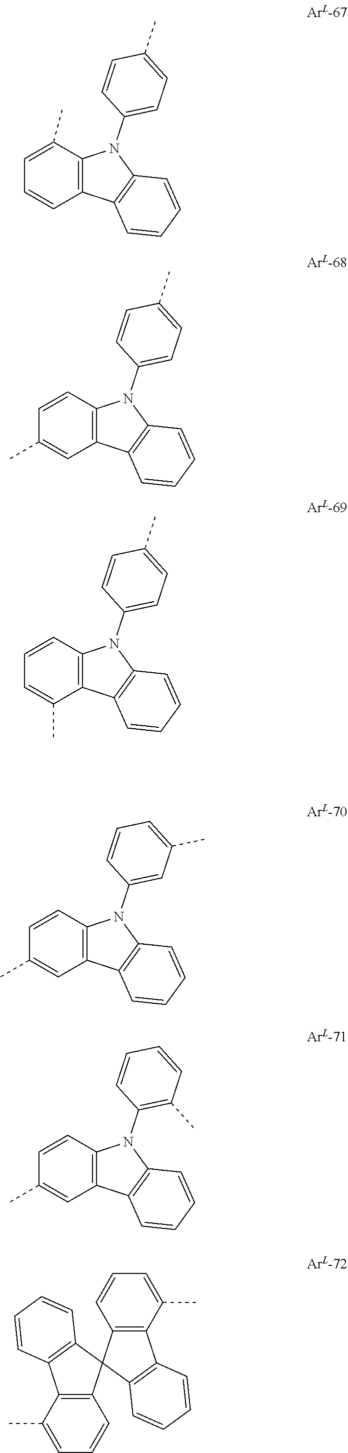

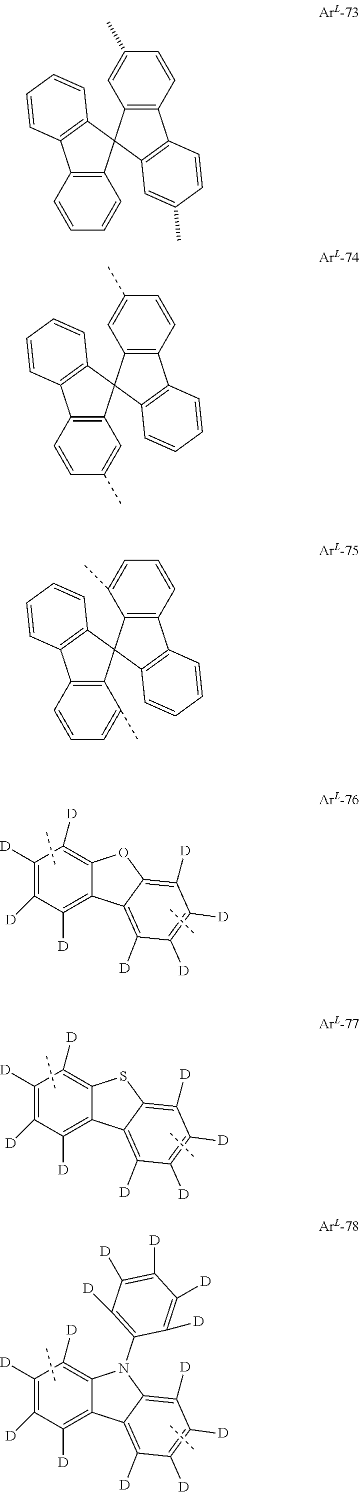

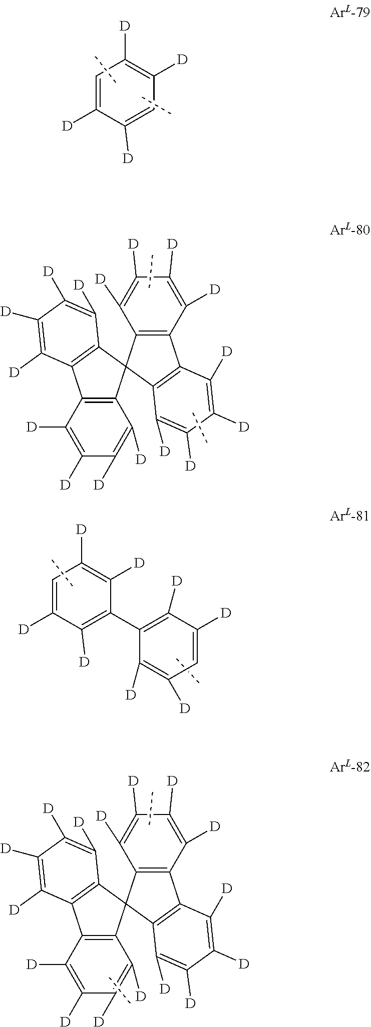

where the dotted lines represent the bonds to the rest of the formula, and where the groups may bear one or more substituents R⁵ other than H at the positions shown as being unsubstituted, and preferably bear H at the positions shown as being unsubstituted.

Preferably, index n in formula (I) is 0, i.e. the E group is absent, and the Ar¹ groups are not bonded to one another.

In a preferred embodiment, at least one R⁴ group in formula (I) is

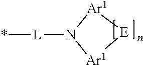

bonded via the bond marked * to the carbon atom of the Z² group, more preferably exactly one R⁴ group in formula (I) is

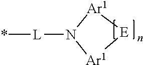

bonded via the bond marked * to the carbon atom of the Z² group. In these cases, preferably exactly one R³ group is

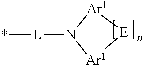

bonded via the bond marked * to the carbon atom of the Z¹ group.

Ar¹ is preferably the same or different at each instance and is selected from groups of the following formulae:

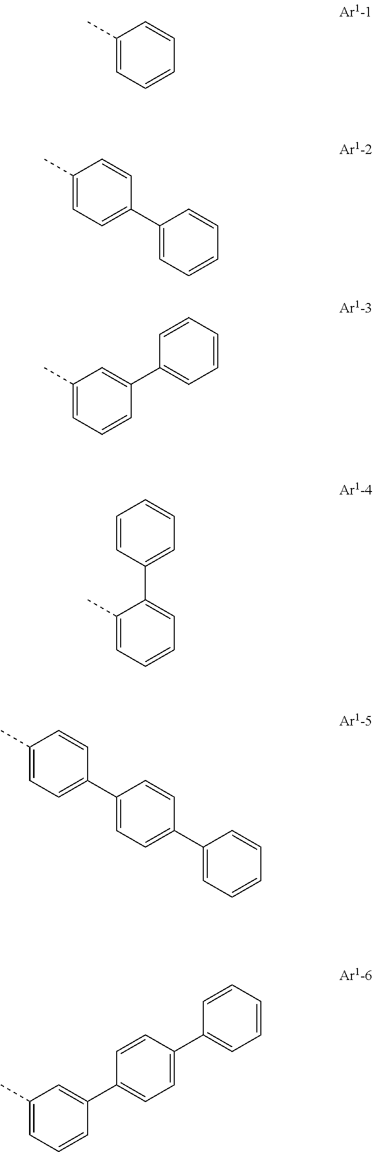

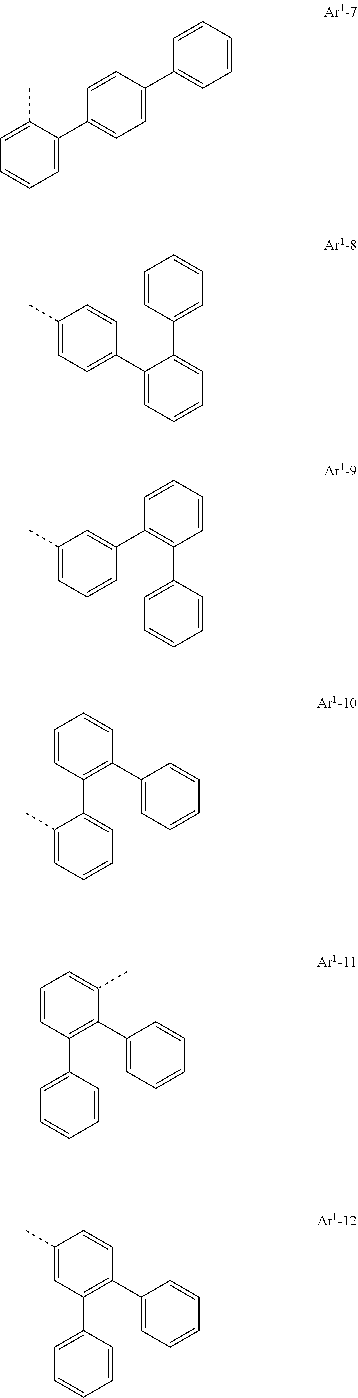

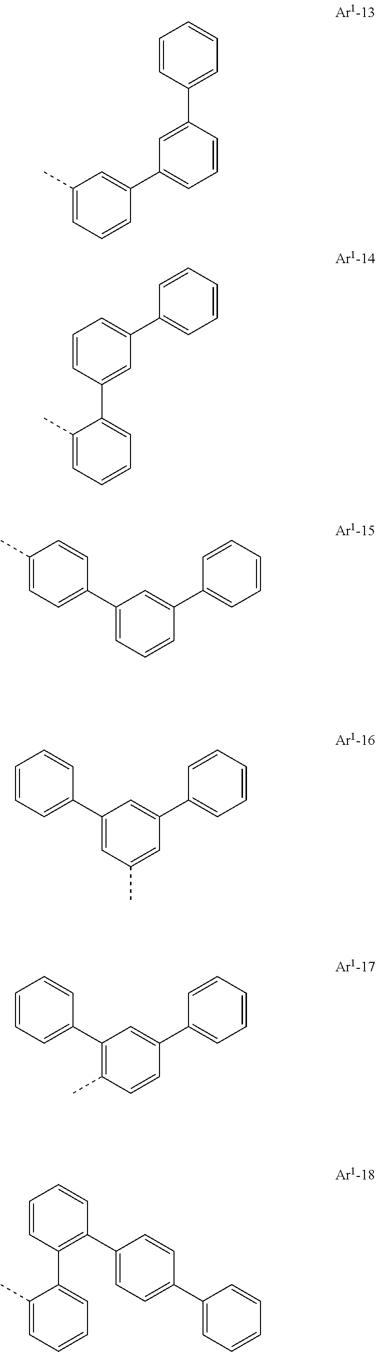

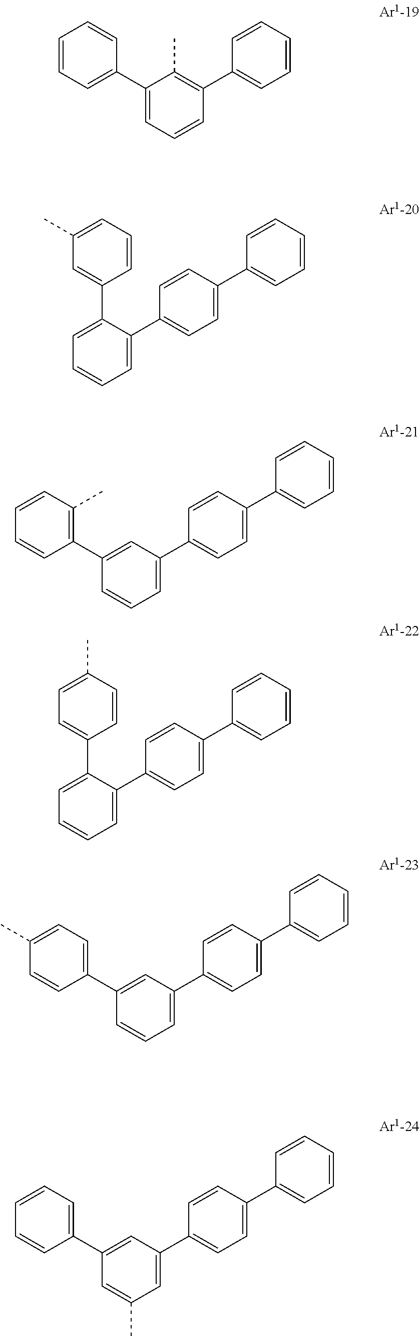

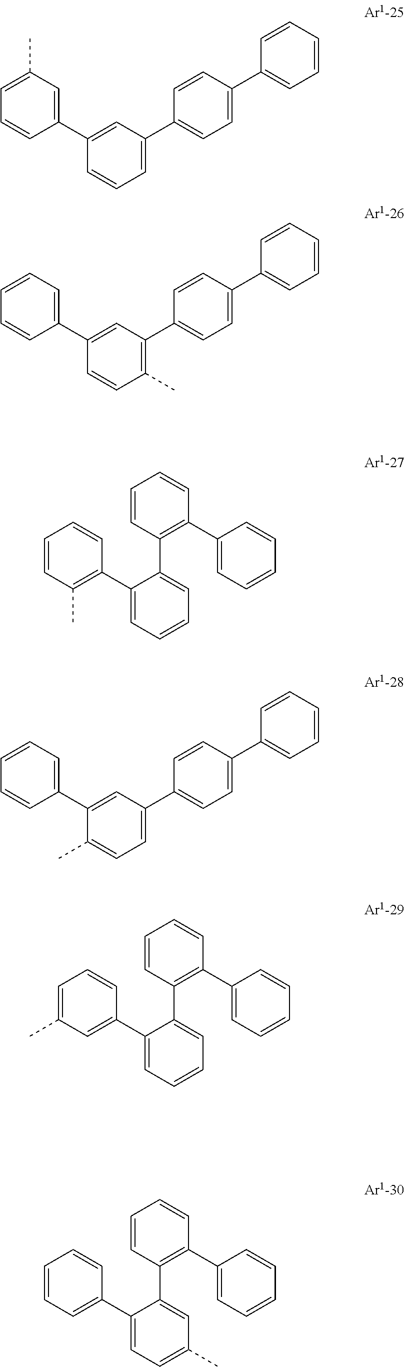

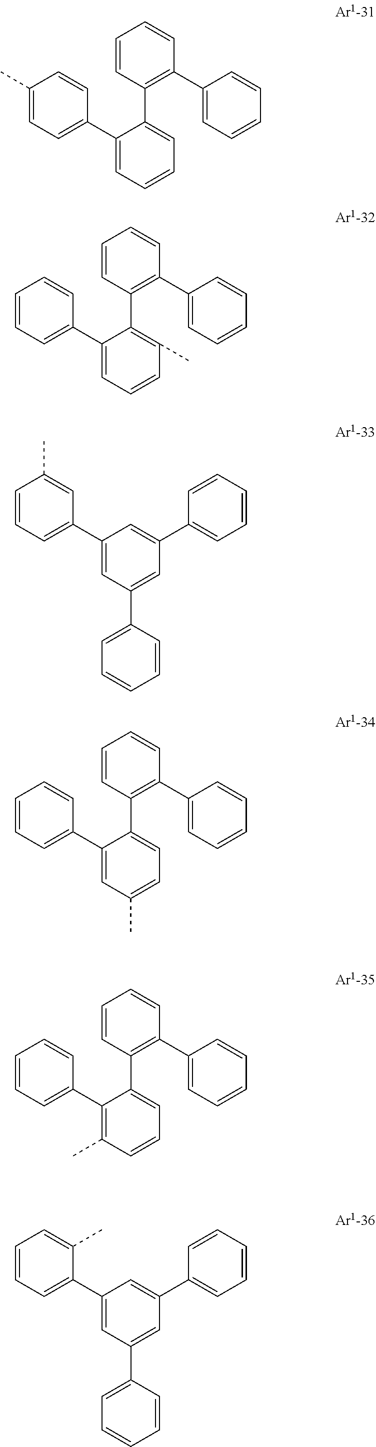

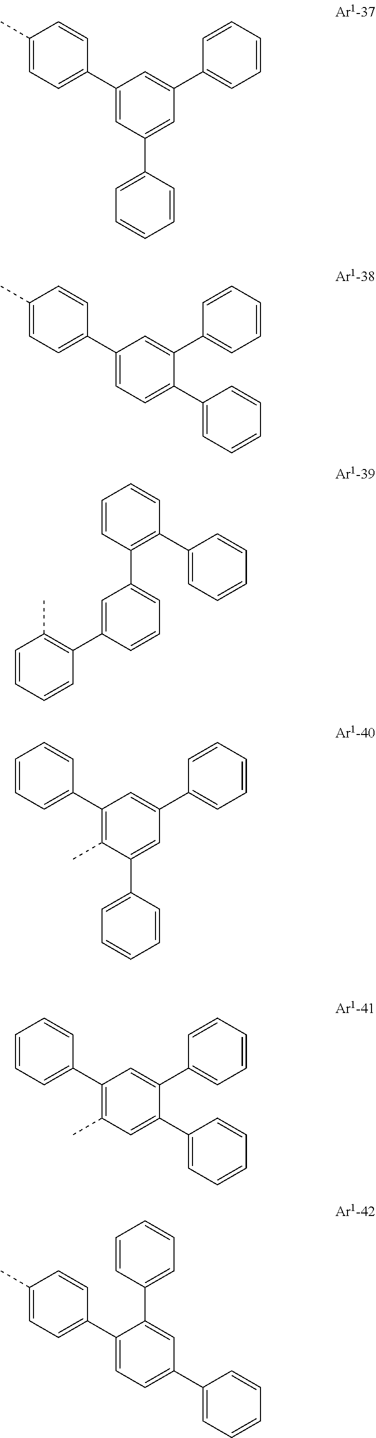

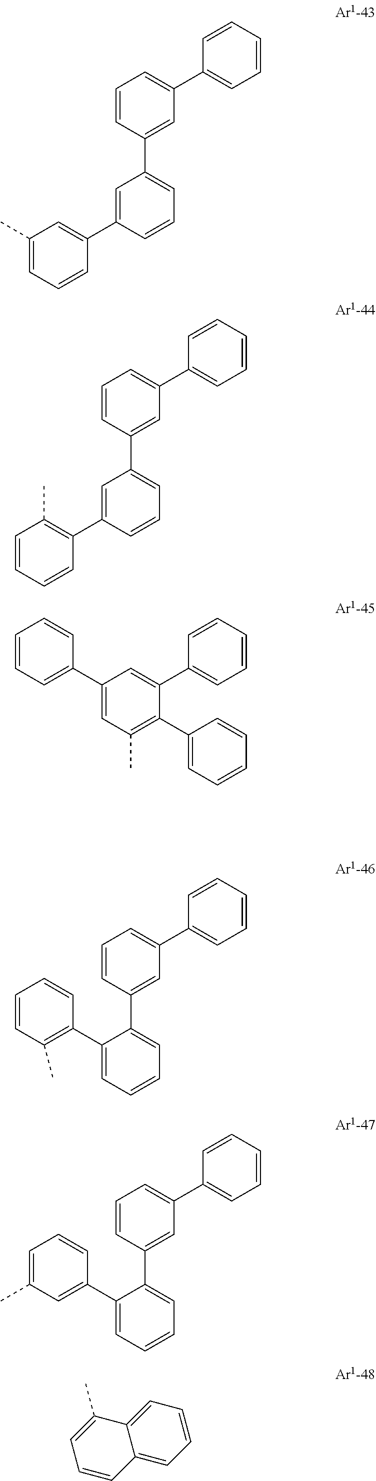

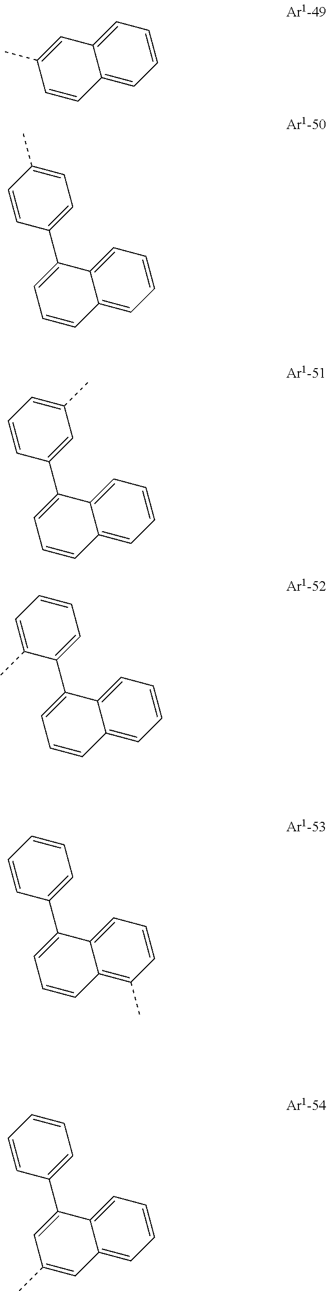

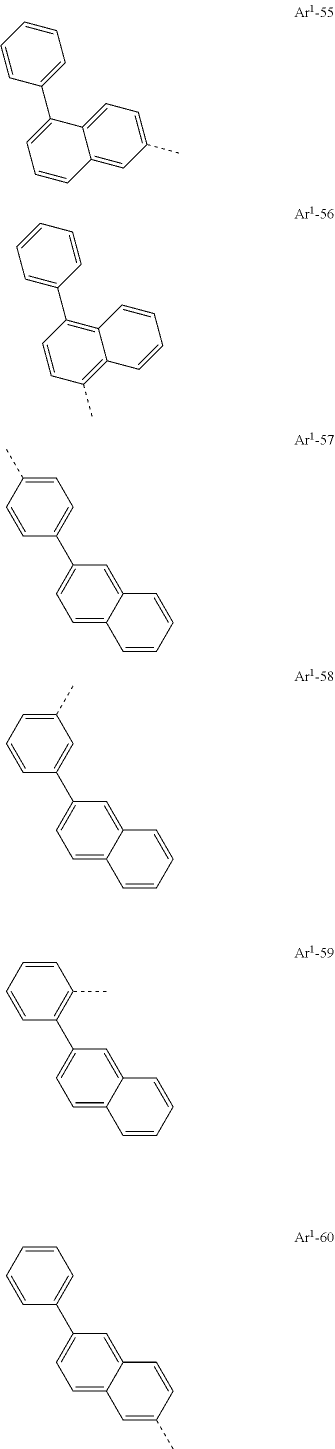

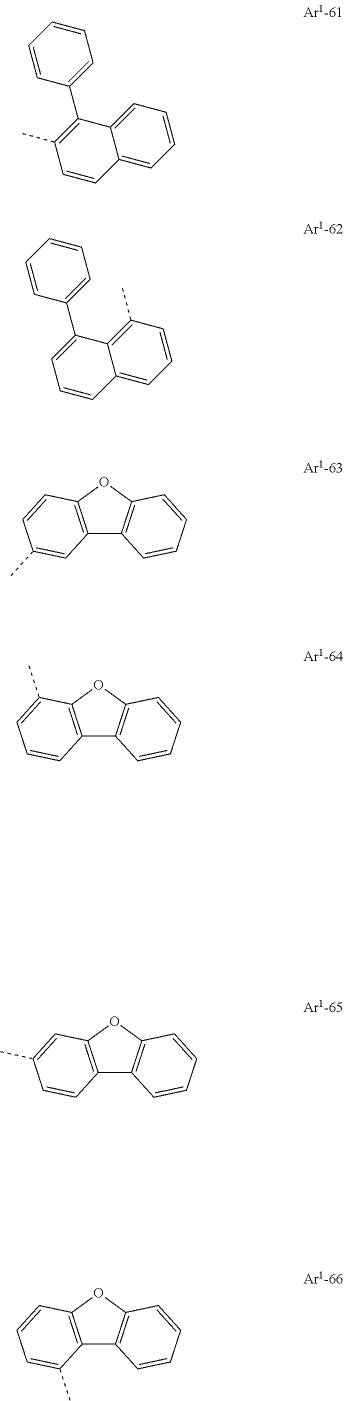

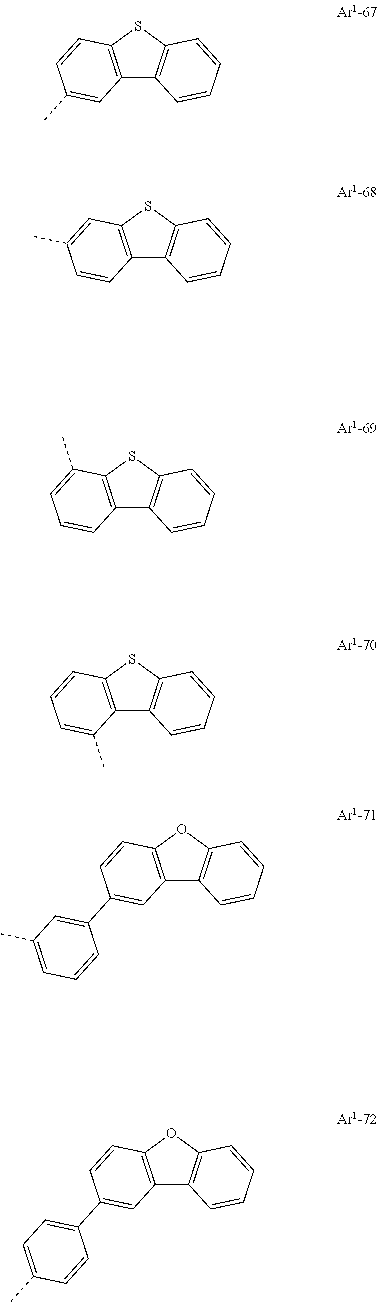

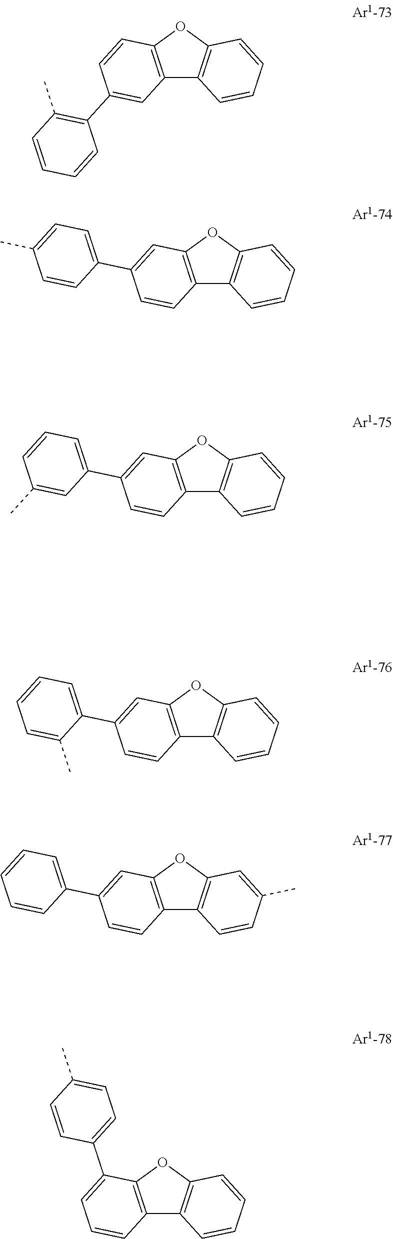

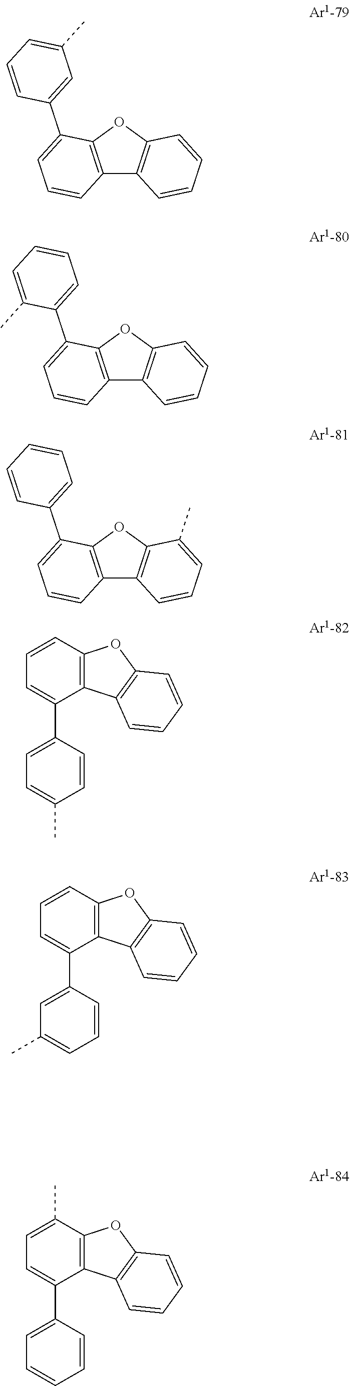

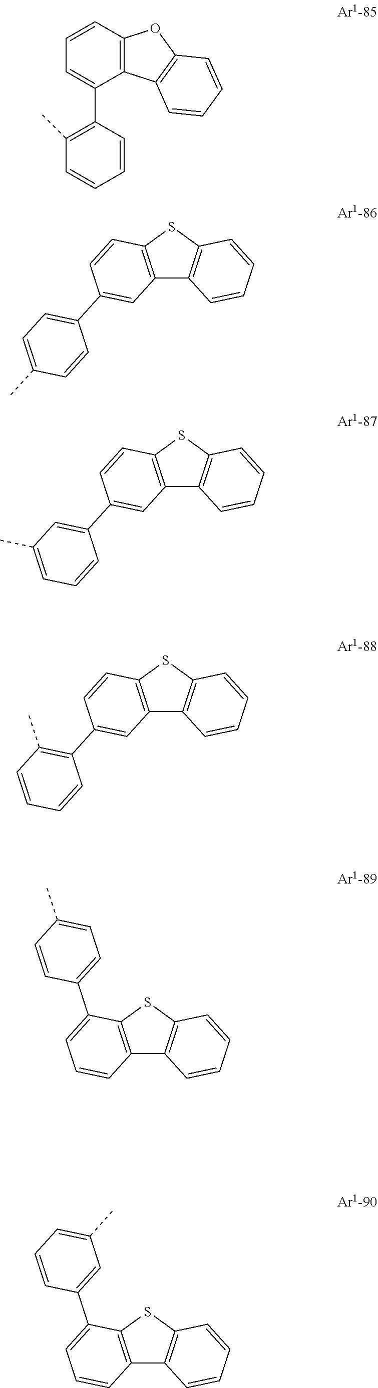

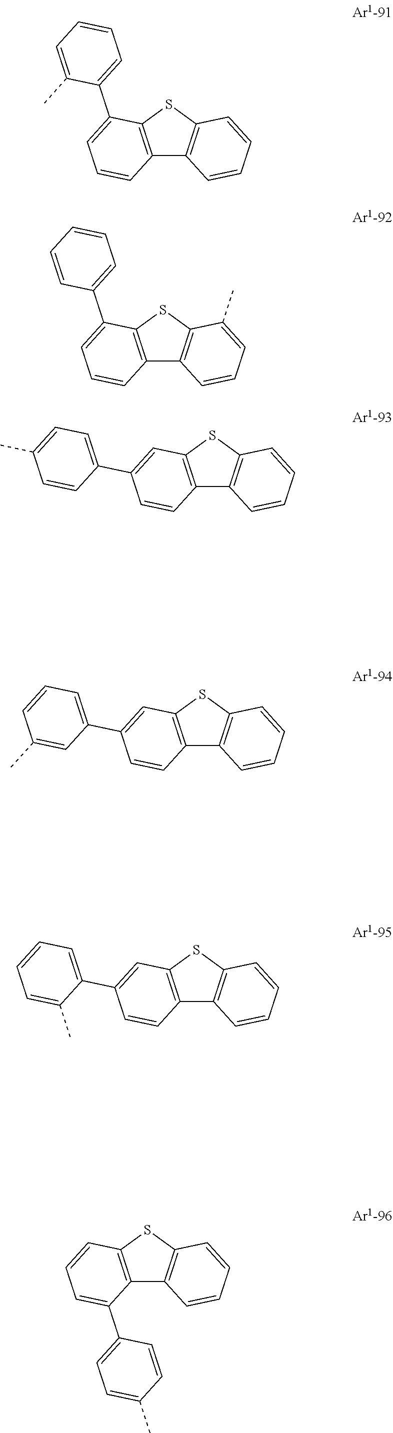

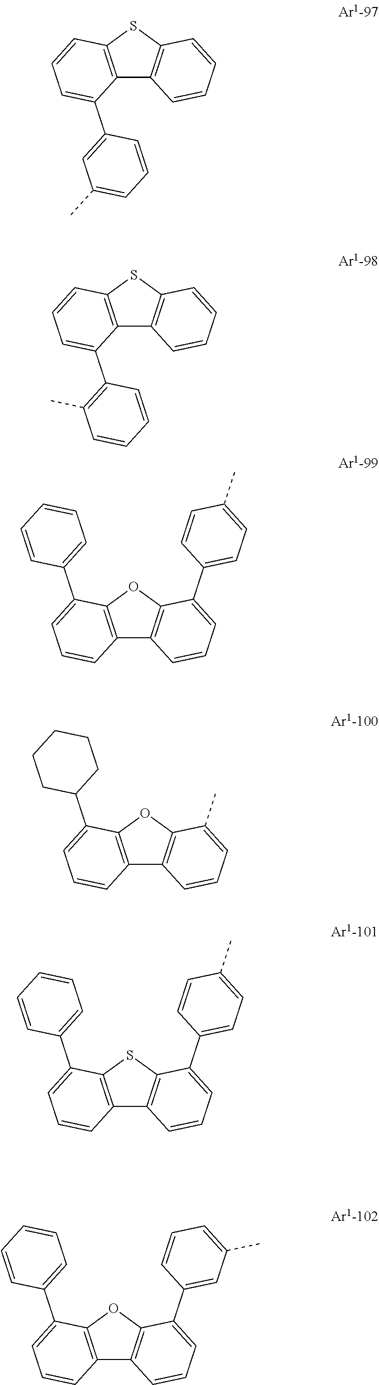

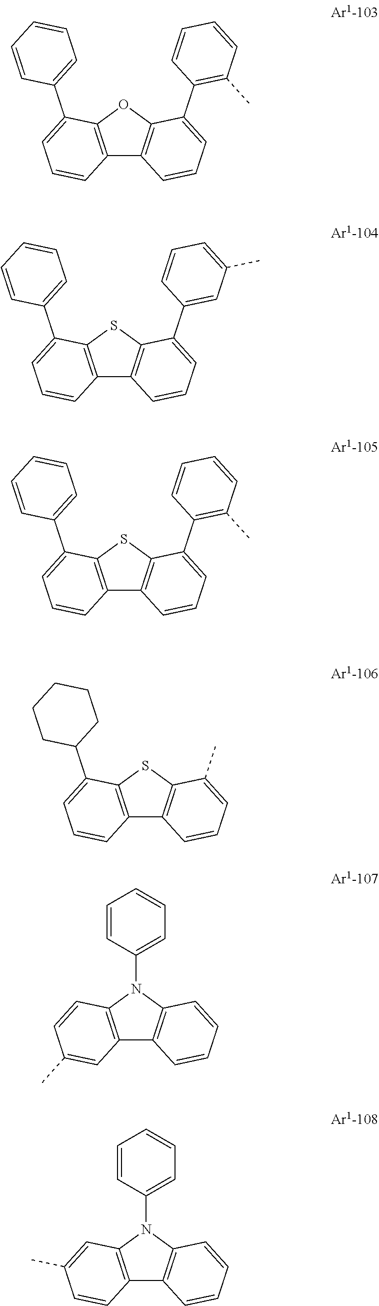

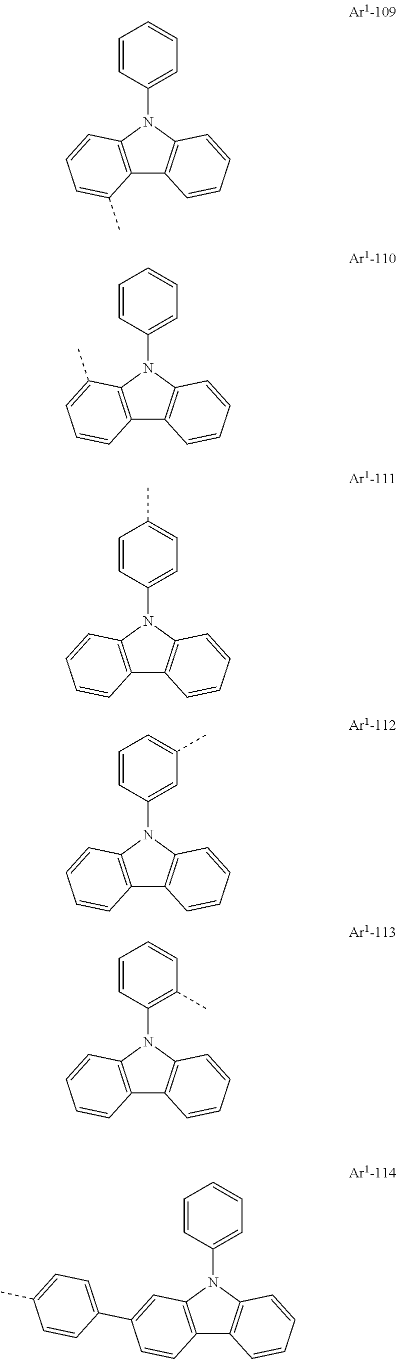

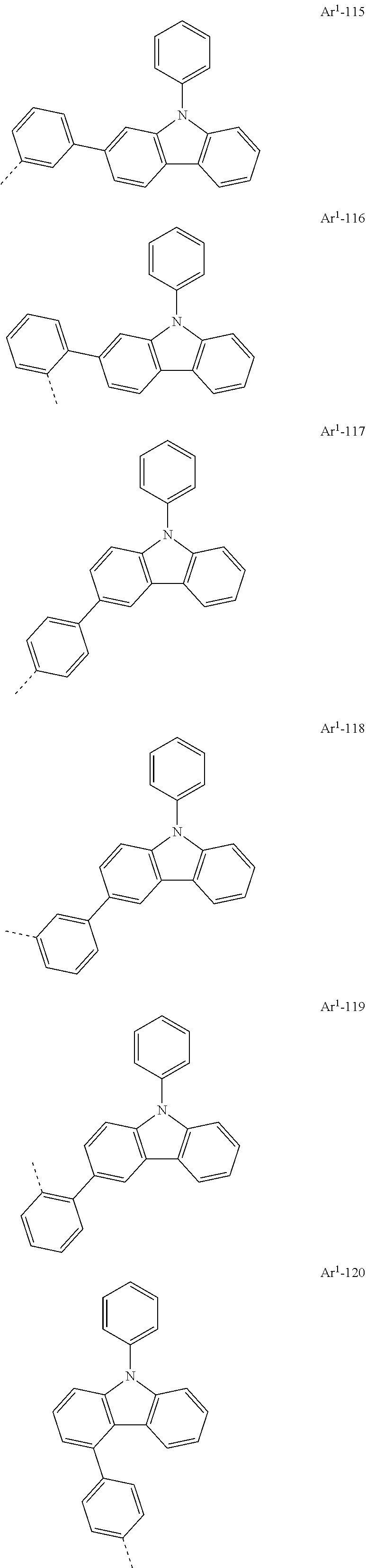

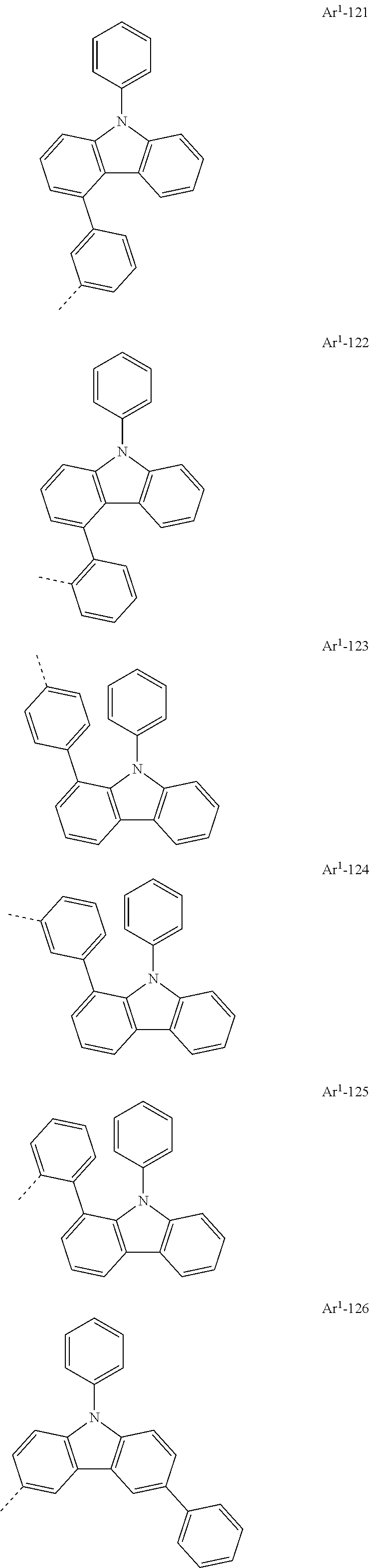

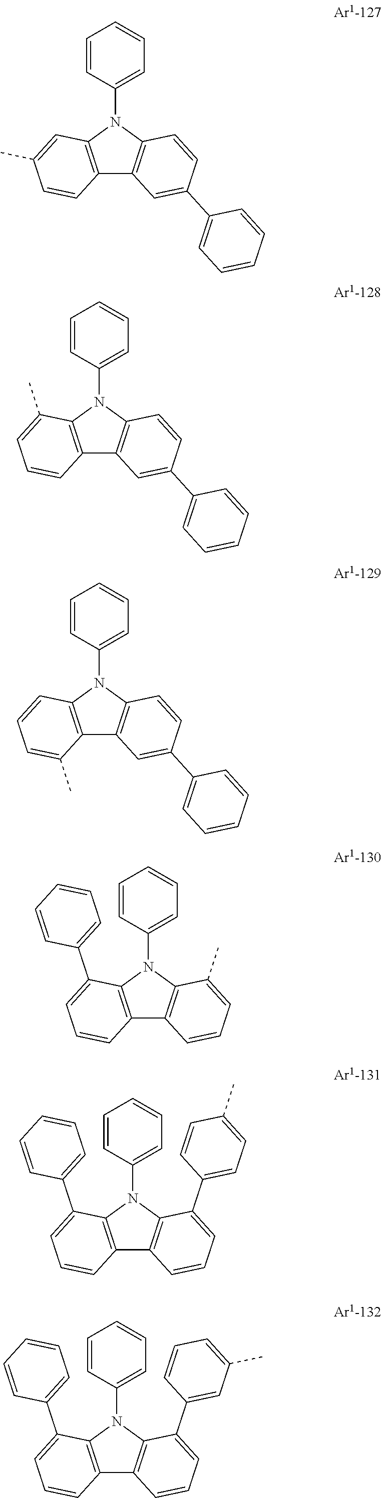

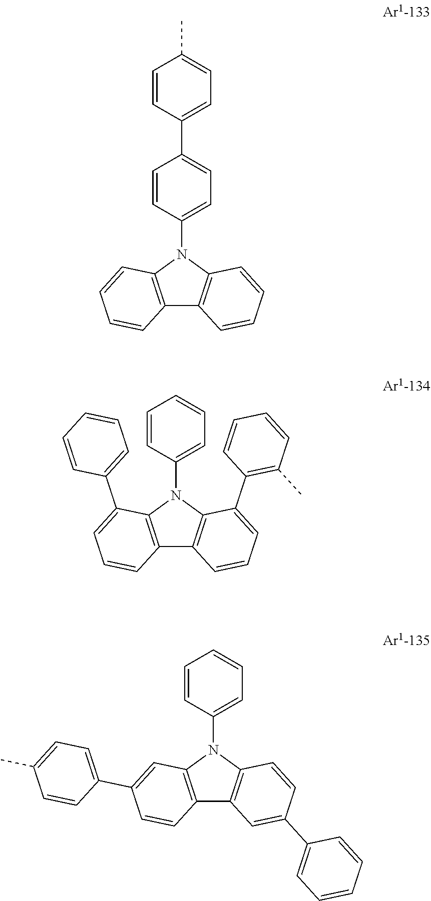

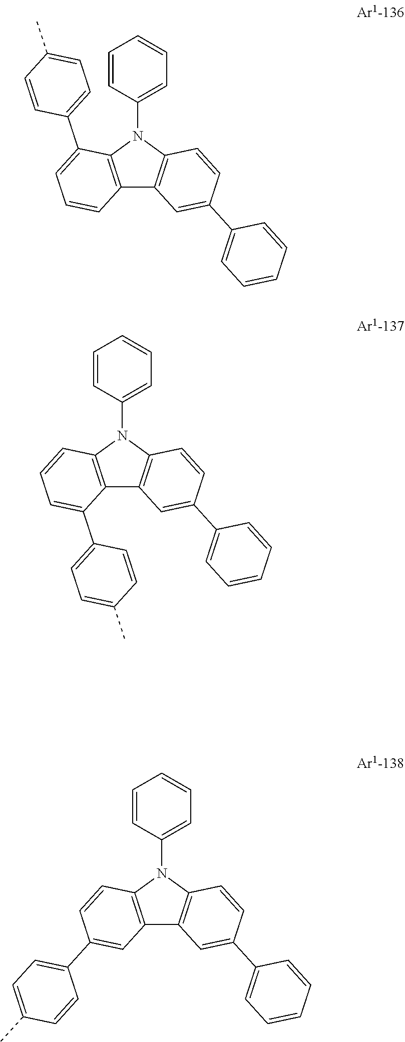

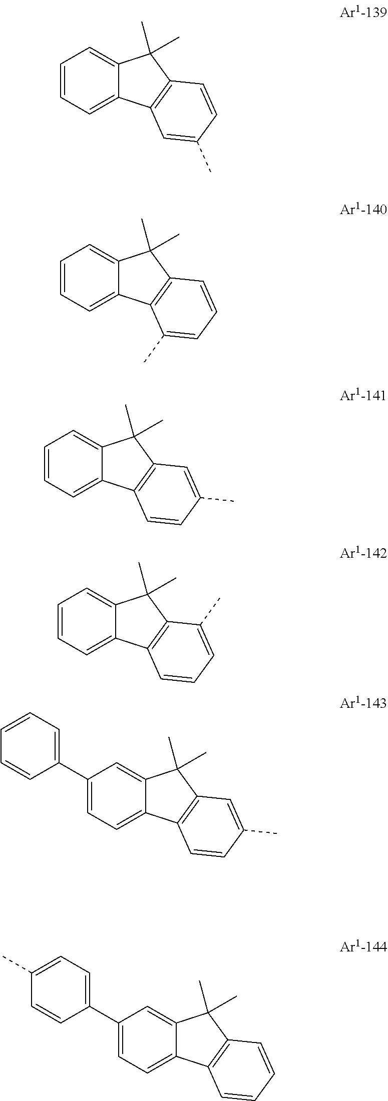

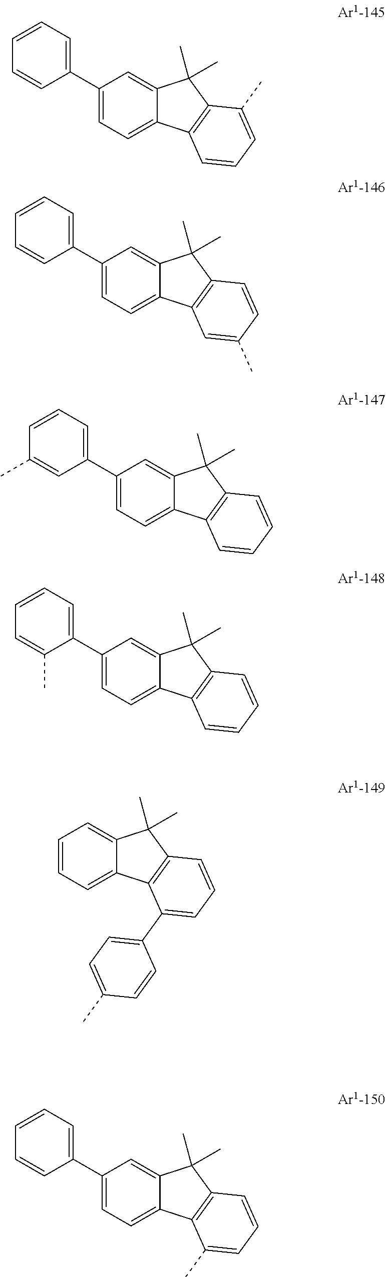

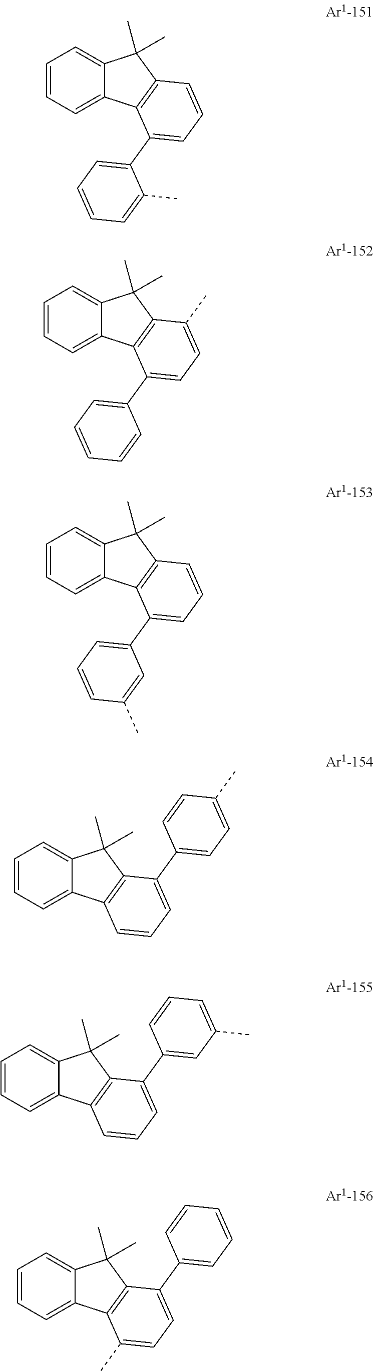

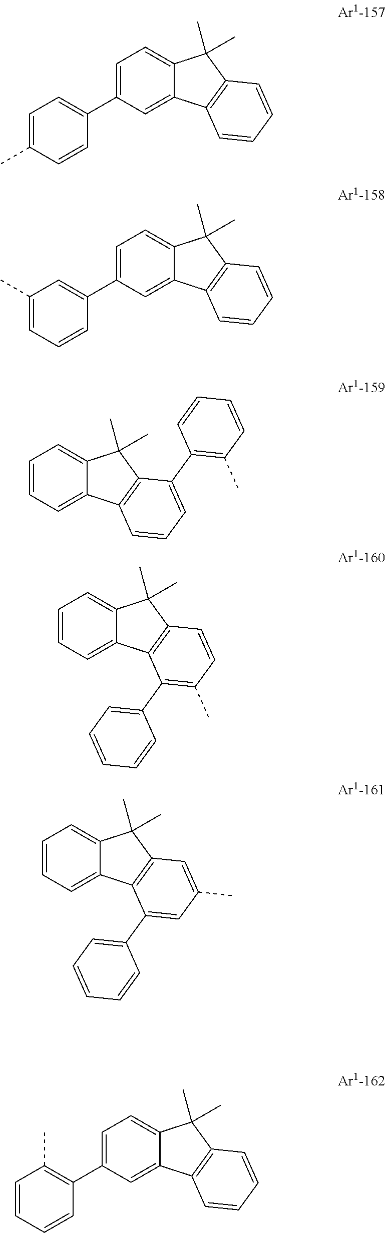

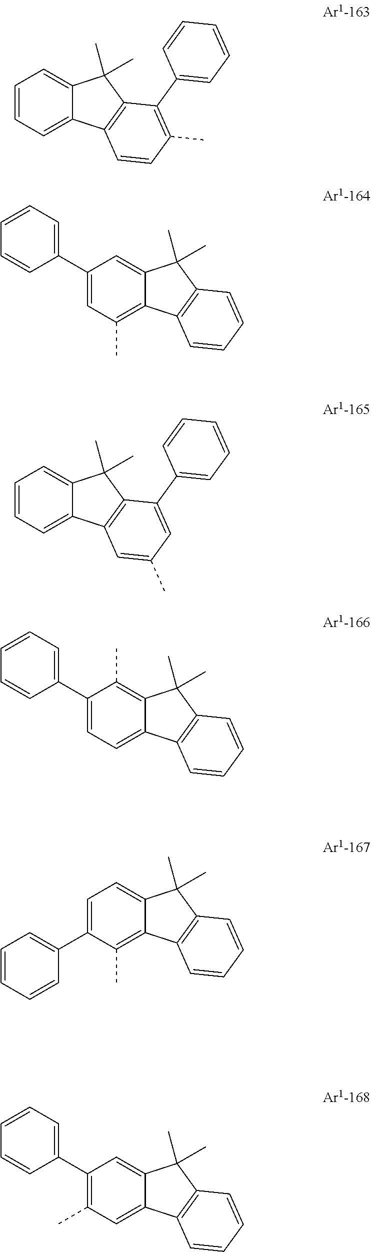

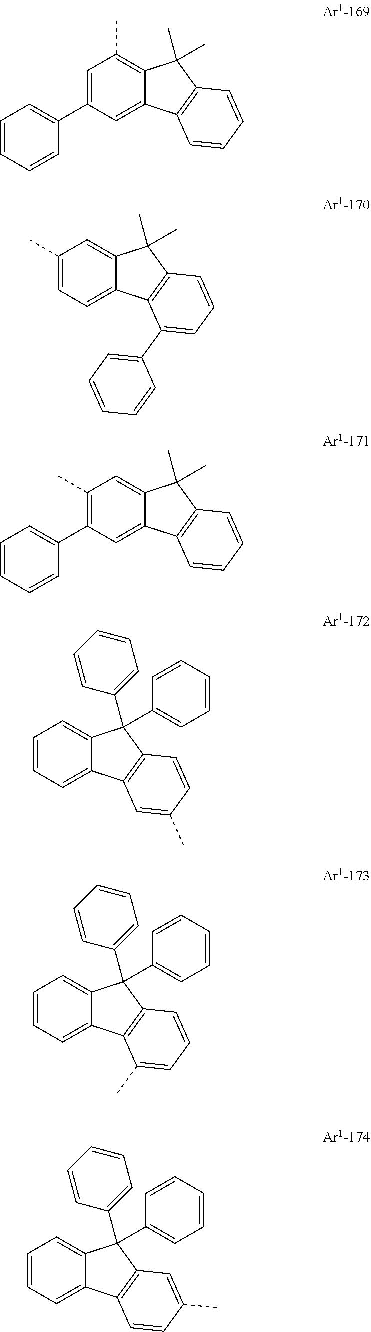

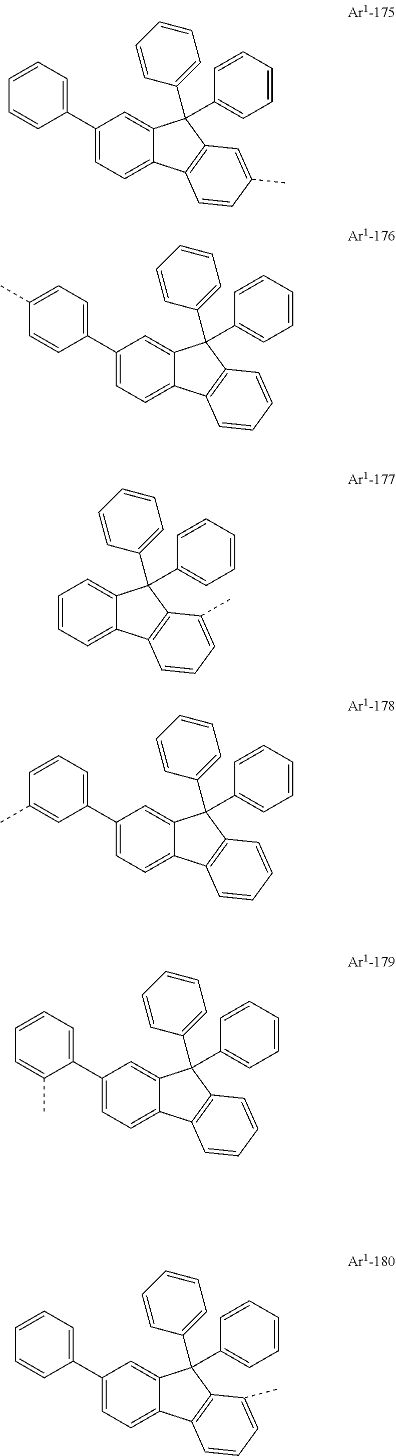

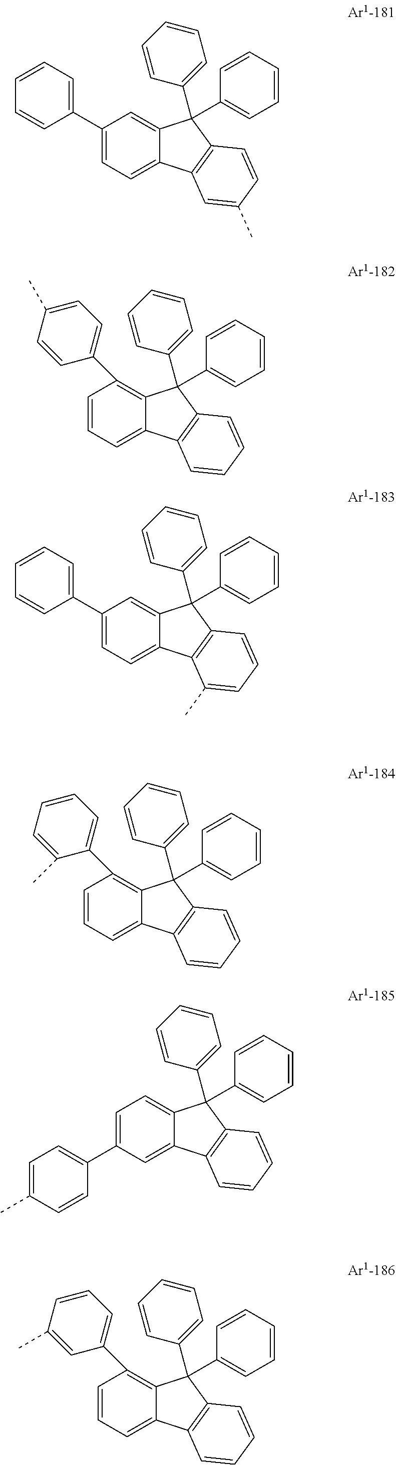

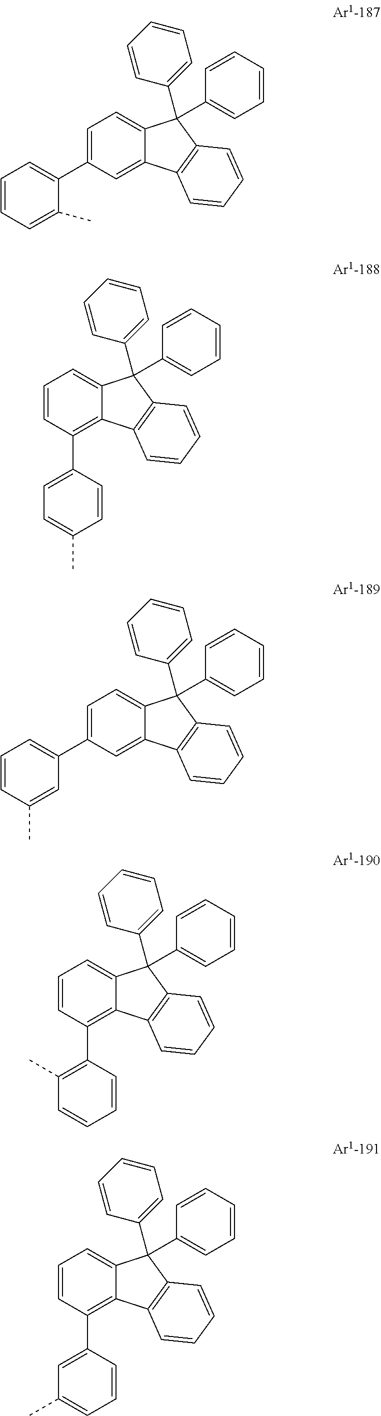

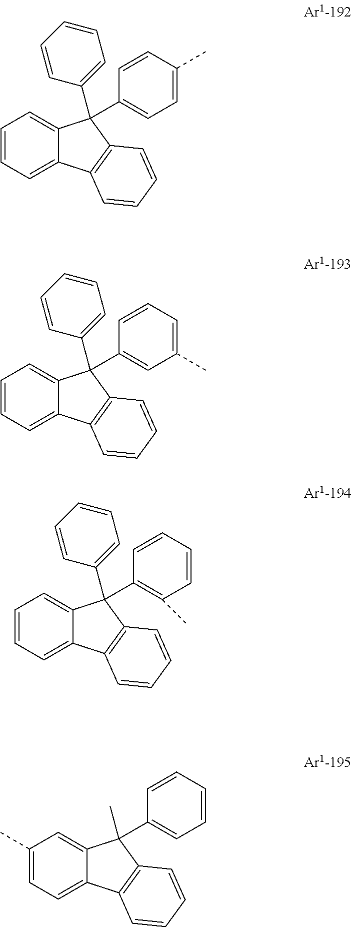

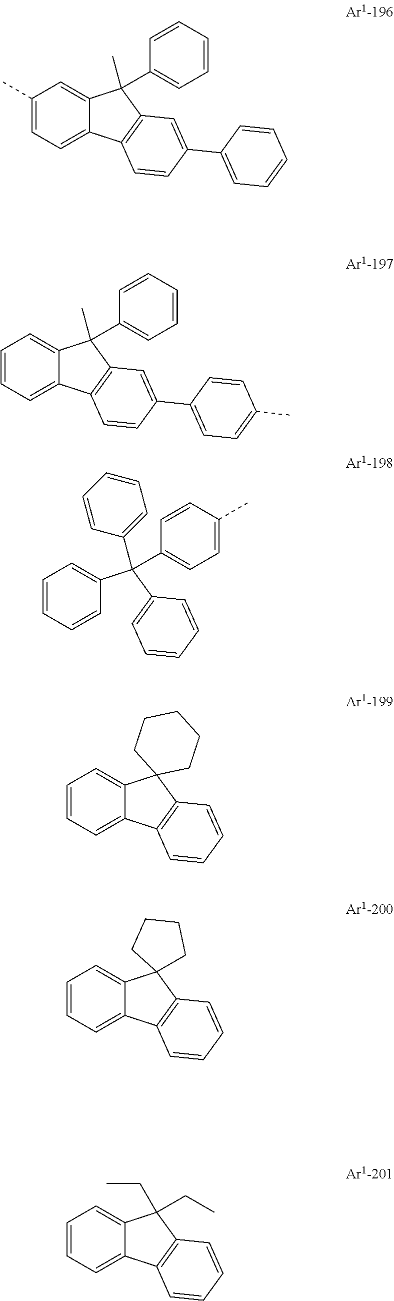

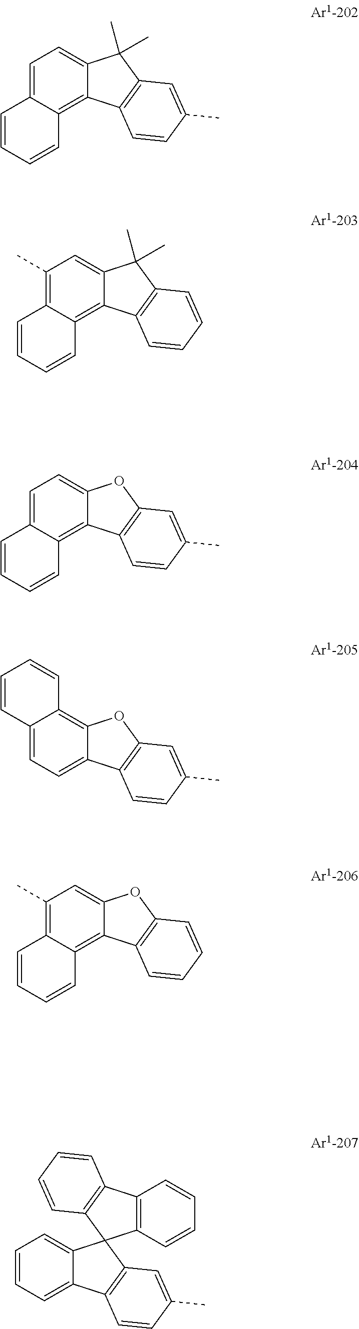

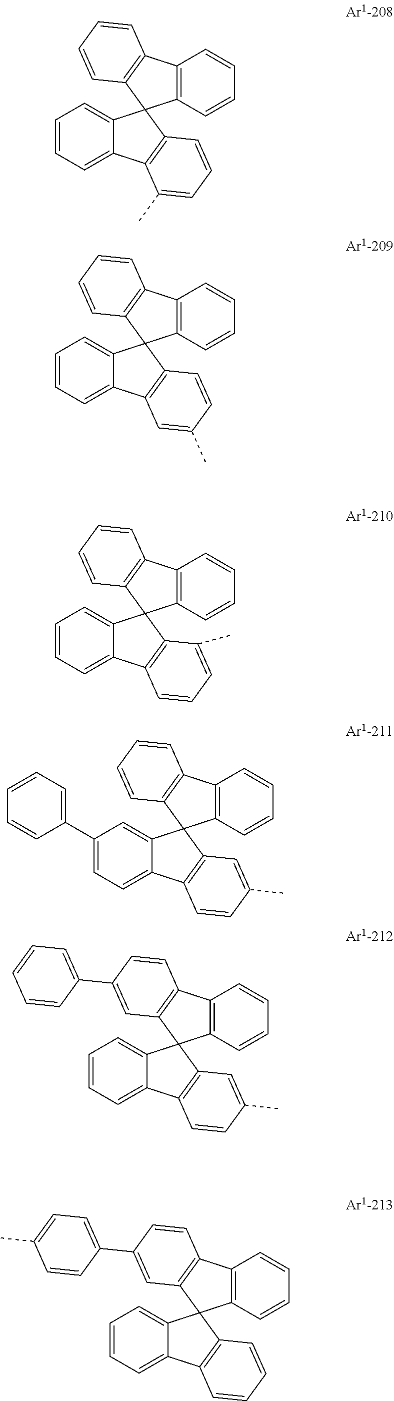

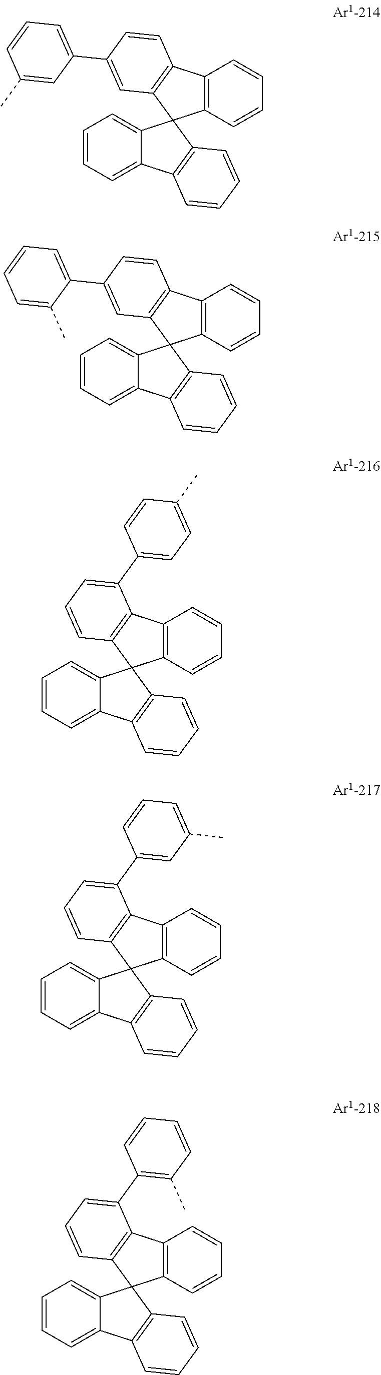

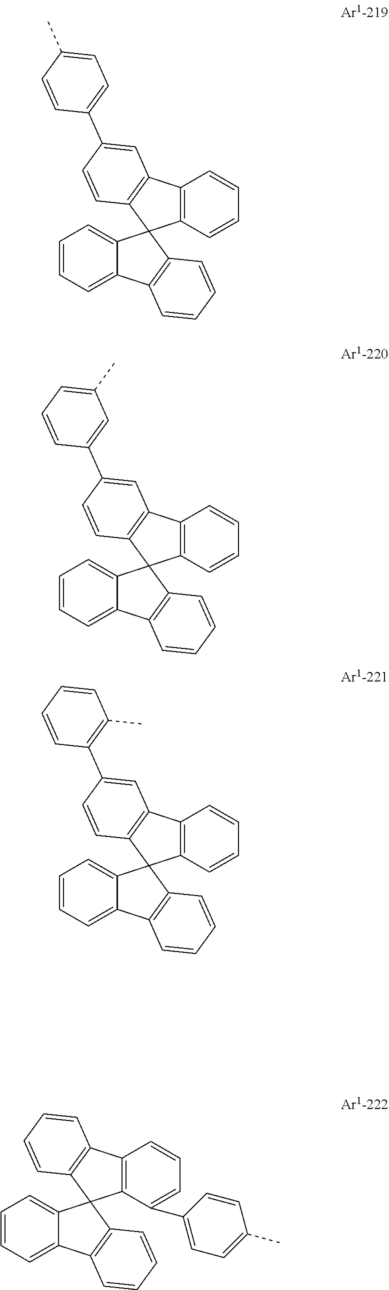

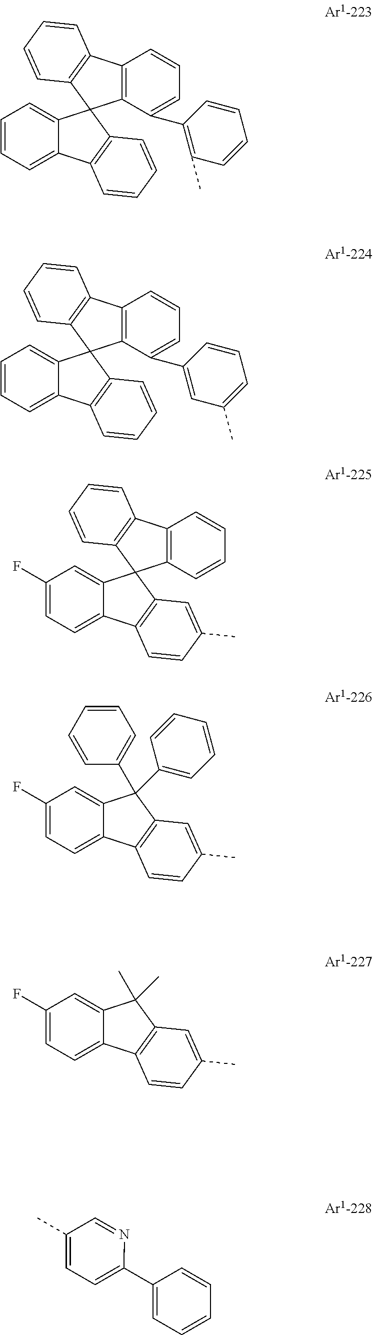

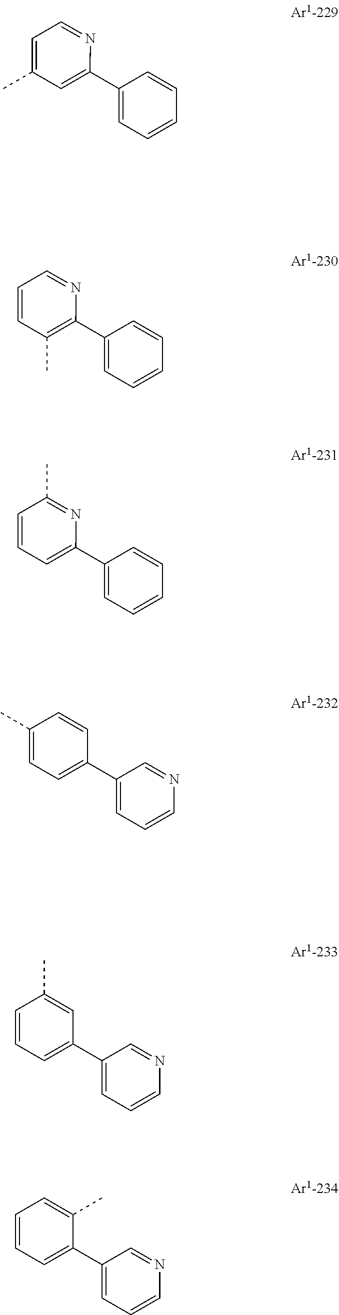

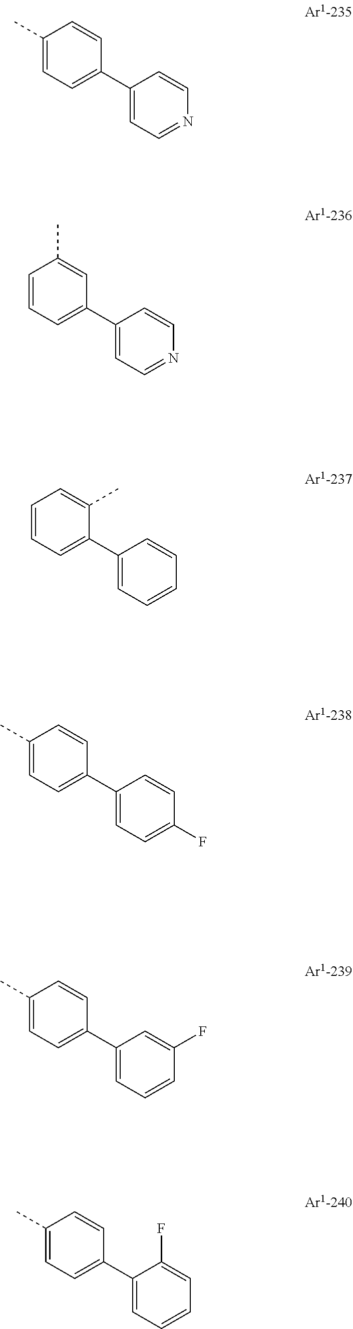

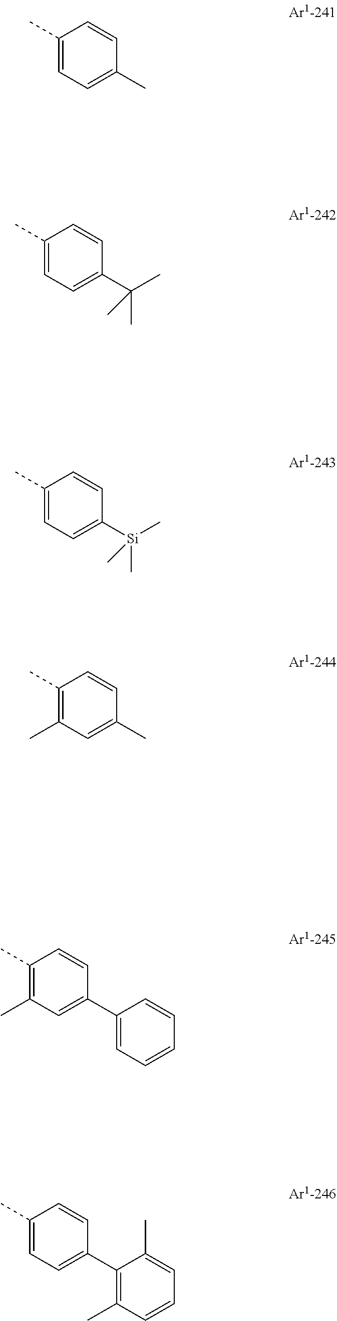

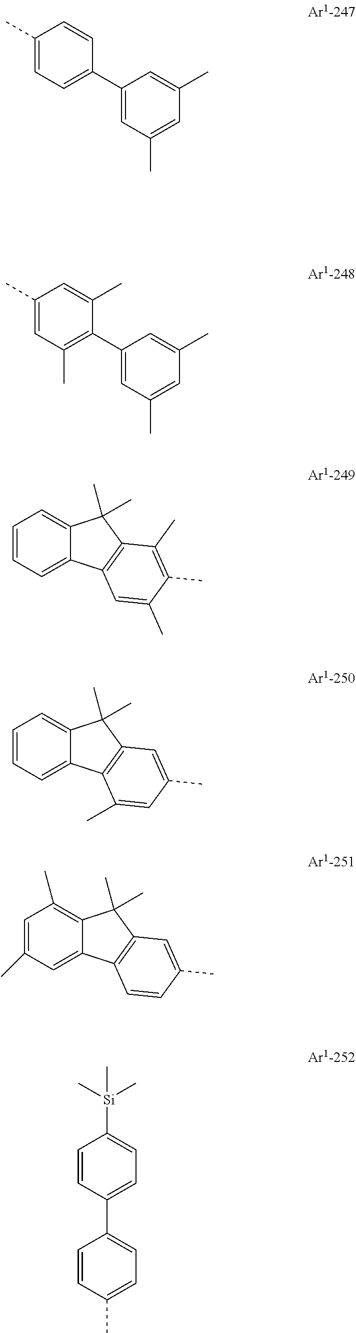

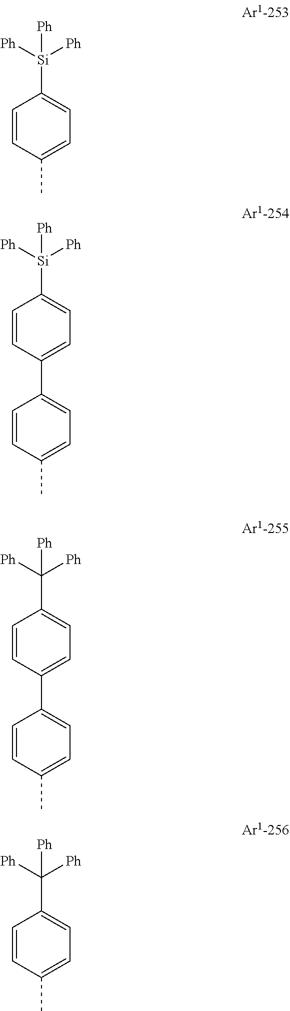

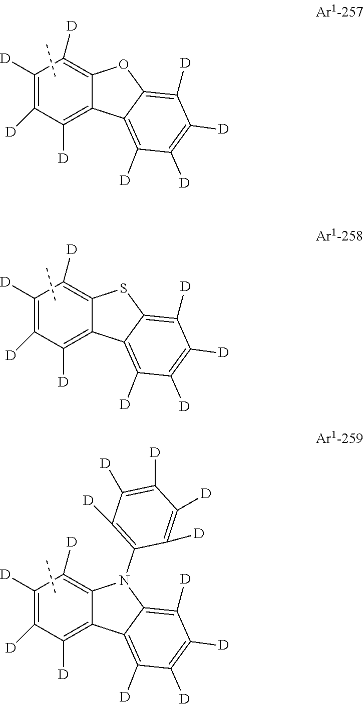

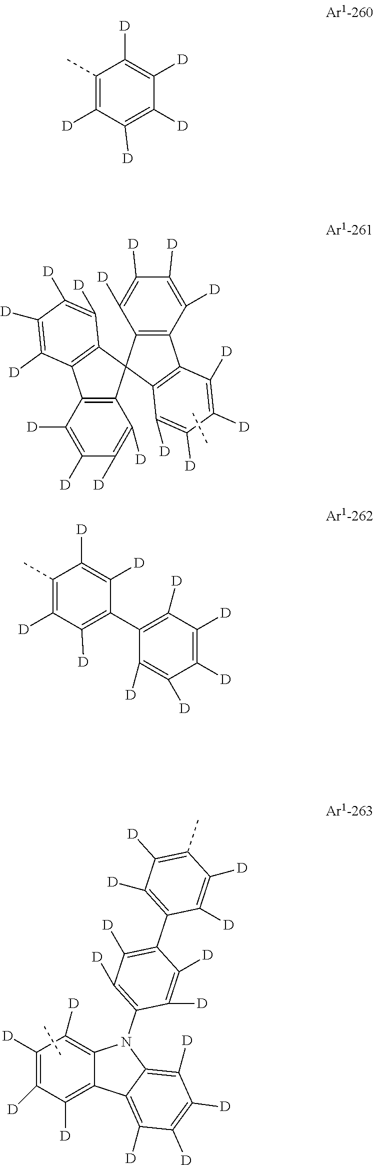

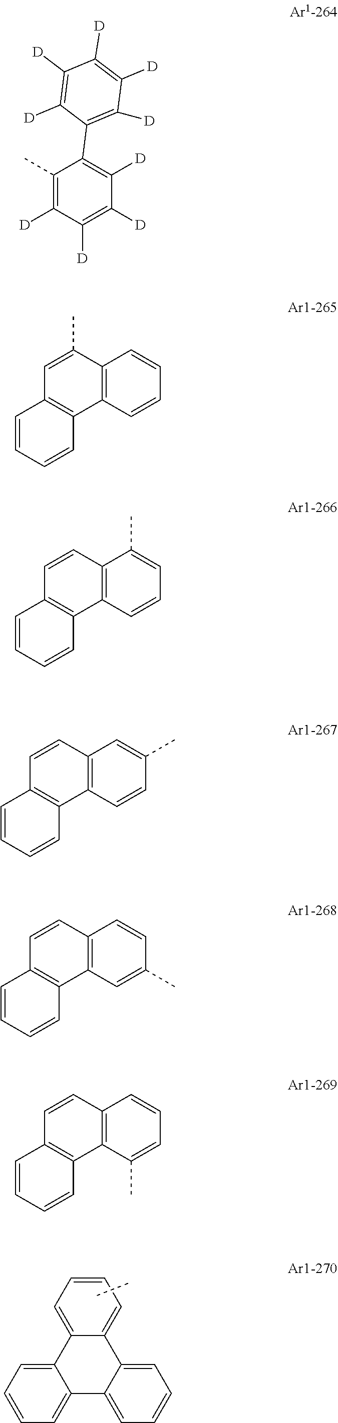

where the dotted line represents the bond to the nitrogen atom, and where the groups may bear one or more substituents R⁶ other than H at the positions shown as being unsubstituted, and preferably bear H at the positions shown as being unsubstituted. Particularly preferred among the groups of the formulae Ar¹-1 to Ar¹-270 specified above are the groups of the formulae Ar¹-11 to Ar¹-7, Ar¹-48 to Ar¹-52, Ar¹-63 to Ar¹-84, Ar¹-107 to Ar¹-129, Ar¹-139 to Ar¹-158, Ar¹-172 to Ar¹-194, Ar¹-207 to Ar¹-218, and Ar¹-254 to Ar¹-261.

In a preferred embodiment, Ar¹ is not optionally substituted 2-fluorenyl or optionally substituted 2-spirobifluorenyl. In a particularly preferred embodiment, Ar¹ does not contain optionally substituted 2-fluorenyl or optionally substituted 2-spirobifluorenyl.

In an alternative preferred embodiment, at least one Ar¹, preferably both Ar¹, are the same or different at each instance and are selected from the following formulae:

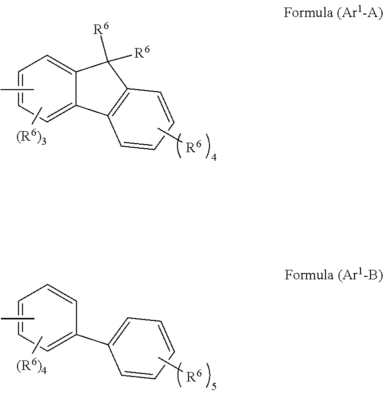

wherein the groups that occur are as defined above.

Formula (Ar¹-A) here preferably corresponds to the following formula (Ar¹-A-1):

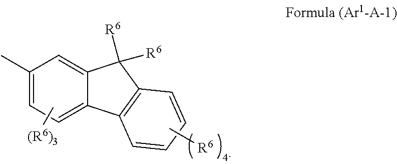

Formula (Ar¹—B) here preferably corresponds to the following formula (Ar¹—B-1)

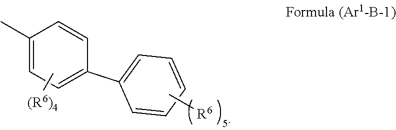

R¹ is preferably the same or different at each instance and is selected from H, D, F, CN, Si(R⁸)₃, N(R⁸)₂, straight-chain alkyl or alkoxy groups having 1 to 20 carbon atoms, branched or cyclic alkyl or alkoxy groups having 3 to 20 carbon atoms, aromatic ring systems having 6 to 40 aromatic ring atoms and heteroaromatic ring systems having 5 to 40 aromatic ring atoms; where the alkyl and alkoxy groups mentioned, the aromatic ring systems mentioned and the heteroaromatic ring systems mentioned are each substituted by R⁸ radicals; and where one or more CH₂ groups in the alkyl or alkoxy groups mentioned may be replaced by —C═C—, —R⁸C=CR⁸—, Si(R⁸)₂, C=O, C=NR⁸, —NR⁸—, —O—, —S—, —C(═O)O— or —C(═O)NR⁸—. More preferably, R¹ is the same or different at each instance and is selected from straight-chain alkyl groups having 1 to 20 carbon atoms, from branched or cyclic alkyl groups having 3 to 20 carbon atoms, and from aromatic ring systems having 6 to 40 aromatic ring atoms; most preferably, R¹ is the same or different at each instance and is selected from methyl and phenyl.

R³ is preferably the same or different at each instance and is selected from a group

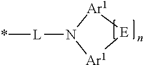

bonded via the bond marked * to the carbon atom of the Z¹ group, H, D, F, CN, Si(R⁸)₃, straight-chain alkyl or alkoxy groups having 1 to 20 carbon atoms, branched or cyclic alkyl or alkoxy groups having 3 to 20 carbon atoms, aromatic ring systems having 6 to 40 aromatic ring atoms and heteroaromatic ring systems having 5 to 40 aromatic ring atoms; where the alkyl and alkoxy groups mentioned, the aromatic ring systems mentioned and the heteroaromatic ring systems mentioned are each substituted by R⁸ radicals; and where one or more CH₂ groups in the alkyl or alkoxy groups mentioned may be replaced by —C═C—, —R⁸C=CR⁸—, Si(R⁸)₂, C═O, C=NR⁸, —NR⁸—, —O—, —S—, —C(═O)O— or —C(═O)NR⁸—. More preferably, R³ is the same or different at each instance and is selected from a group

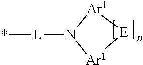

bonded via the bond marked * to the carbon atom of the Z¹ group, H, D, and aromatic ring systems which have 6 to 40 aromatic ring atoms and are each substituted by R⁸ radicals. Most preferably, R³ is the same or different at each instance and is selected from a group

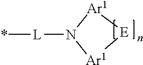

bonded via the bond marked * to the carbon atom of the Z¹ group, H and D, especially H.

In a preferred embodiment of the invention, the compound of the formula (I) contains at least one group selected from R³ and R⁴ groups which is an aromatic ring system which has 6 to 40 aromatic ring atoms and is substituted by R⁸ radicals, or a heteroaromatic ring system which has 5 to 40 aromatic ring atoms and is substituted by R⁸ radicals. In a particularly preferred embodiment of the invention, the compound of the formula (I) contains at least one group selected from R³ and R⁴ groups which is an aromatic ring system which has 6 to 40 aromatic ring atoms and is substituted by R⁸ radicals.

R⁴ is preferably the same or different at each instance and is selected from a group

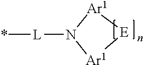

bonded via the bond marked * to the carbon atom of the Z² group, H, D, F, CN, Si(R⁸)₃, straight-chain alkyl or alkoxy groups having 1 to 20 carbon atoms, branched or cyclic alkyl or alkoxy groups having 3 to 20 carbon atoms, aromatic ring systems having 6 to 40 aromatic ring atoms and heteroaromatic ring systems having 5 to 40 aromatic ring atoms; where the alkyl and alkoxy groups mentioned, the aromatic ring systems mentioned and the heteroaromatic ring systems mentioned are each substituted by R⁸ radicals; and where one or more CH₂ groups in the alkyl or alkoxy groups mentioned may be replaced by —C≡C—, —R⁸C=CR⁸—, Si(R⁸)₂, C=O, C=NR⁸, —NR^{B}—, —O—, —S—, —C(═O)O— or —C(═O)NR⁸—. More preferably, R⁴ is the same or different at each instance and is selected from a group

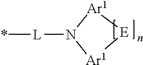

bonded via the bond marked * to the carbon atom of the Z² group, H, D, and aromatic ring systems which have 6 to 40 aromatic ring atoms and are each substituted by R⁸ radicals. Most preferably, R⁴ is H or D, especially H.

R⁵, R⁶ are preferably the same or different at each instance and are selected from H, D, F, CN, Si(R⁸)₃, N(R⁸)₂, straight-chain alkyl or alkoxy groups having 1 to 20 carbon atoms, branched or cyclic alkyl or alkoxy groups having 3 to 20 carbon atoms, aromatic ring systems having 6 to 40 aromatic ring atoms and heteroaromatic ring systems having 5 to 40 aromatic ring atoms; where the alkyl and alkoxy groups mentioned, the aromatic ring systems mentioned and the heteroaromatic ring systems mentioned are each substituted by R⁸ radicals; and where one or more CH₂ groups in the alkyl or alkoxy groups mentioned may be replaced by —C═C—, —R⁸C=CR^{B}—, Si(R⁸)₂, C=O, C=NR⁸, —NR⁸—, —O—, —S—, —C(═O)O— or —C(═O)NR⁸—. More preferably, R⁵, R⁶ are the same or different at each instance and are selected from H, D, straight-chain alkyl groups having 1 to 20 carbon atoms, branched or cyclic alkyl groups having 3 to 20 carbon atoms and aromatic ring systems having 6 to 40 aromatic ring atoms.

Preferably, R⁸ is the same or different at each instance and is selected from H, D, F, CN, Si(R⁹)₃, N(R⁹)₂, straight-chain alkyl or alkoxy groups having 1 to 20 carbon atoms, branched or cyclic alkyl or alkoxy groups having 3 to 20 carbon atoms, aromatic ring systems having 6 to 40 aromatic ring atoms and heteroaromatic ring systems having 5 to 40 aromatic ring atoms; where the alkyl and alkoxy groups mentioned, the aromatic ring systems mentioned and the heteroaromatic ring systems mentioned are each substituted by R⁹ radicals; and where one or more CH₂ groups in the alkyl or alkoxy groups mentioned may be replaced by —C═C—, —R⁹C=CR⁹—, Si(R⁹)₂, C=O, C=NR⁹, —NR⁹—, —O—, —S—, —C(═O)O— or —C(═O)NR⁹—. More preferably, R⁸ is H or D, especially H.

Formula (I) preferably corresponds to a formula selected from the formulae (1-1) and (1-2)

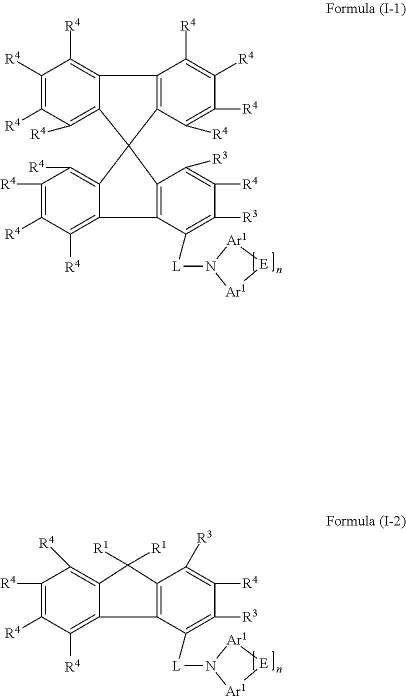

where the symbols that occur are as defined above, and preferably correspond to their preferred embodiments. Among the formulae (1-1) and (1-2), the formula (1-1) is particularly preferred.

More preferably, the compound of the formula (I) corresponds to a formula selected from formulae (1-1) and (1-2), especially (1-1), where the variable groups that occur are as follows:
L is a single bond;
n is 0;
Ar¹ is the same or different at each instance and is selected from aromatic ring systems which have 6 to 40 aromatic ring atoms and are substituted by R⁶ radicals, and heteroaromatic ring systems which have 5 to 40 aromatic ring atoms and are substituted by R⁶ radicals;
R³ is the same or different at each instance and is selected from H, D and aromatic ring systems which have 6 to 40 aromatic ring atoms and are each substituted by R⁸ radicals;
R⁴ is the same or different at each instance and is selected from H, D and aromatic ring systems which have 6 to 40 aromatic ring atoms and are each substituted by R⁸ radicals;
R⁶ is the same or different at each instance and is selected from H, D, F, CN, Si(R⁸)₃, N(R⁸)₂, straight-chain alkyl or alkoxy groups having 1 to 20 carbon atoms, branched or cyclic alkyl or alkoxy groups having 3 to 20 carbon atoms, aromatic ring systems having 6 to 40 aromatic ring atoms and heteroaromatic ring systems having 5 to 40 aromatic ring atoms; where the alkyl and alkoxy groups mentioned, the aromatic ring systems mentioned and the heteroaromatic ring systems mentioned are each substituted by R⁸ radicals; and where one or more CH₂ groups in the alkyl or alkoxy groups mentioned may be replaced by —C═C—, —R⁸C=CR⁸—, Si(R⁸)₂, C=O, C=NR⁸, —NR⁸—, —O—, —S—, —C(═O)O— or —C(═O)NR⁸—;
R⁸ is the same or different at each instance and is selected from H, D, F, CN, Si(R⁹)₃, N(R⁹)₂, straight-chain alkyl or alkoxy groups having 1 to 20 carbon atoms, branched or cyclic alkyl or alkoxy groups having 3 to 20 carbon atoms, aromatic ring systems having 6 to 40 aromatic ring atoms and heteroaromatic ring systems having 5 to 40 aromatic ring atoms; where the alkyl and alkoxy groups mentioned, the aromatic ring systems mentioned and the heteroaromatic ring systems mentioned are each substituted by R⁹ radicals; and where one or more CH₂ groups in the alkyl or alkoxy groups mentioned may be replaced by —C═C—, —R⁹C=CR⁹—, Si(R⁹)₂, C=O, C=NR⁹, —NR⁹—, —O—, —S—, —C(═O)O— or —C(═O)NR⁹—;
R⁹ is the same or different at each instance and is selected from H, D, F, Cl, Br, I, CN, alkyl or alkoxy groups having 1 to 20 carbon atoms, alkenyl or alkynyl groups having 2 to 20 carbon atoms, aromatic ring systems having 6 to 40 aromatic ring atoms and heteroaromatic ring systems having 5 to 40 aromatic ring atoms; where two or more R⁹ radicals may be joined to one another and may form a ring and where the alkyl, alkoxy, alkenyl and alkynyl groups, aromatic ring systems and heteroaromatic ring systems mentioned may be substituted by one or more radicals selected from F and CN.

In a preferred embodiment, the R³ group that corresponds to the following group:

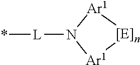

contains at least one Ar¹ group containing at least one group selected from fluorenyl, spirobifluorenyl and carbazolyl. Fluorenyl here is preferably 2-fluorenyl. Spirobifluorenyl here is preferably 2-spirobifluorenyl. Carbazolyl here is preferably 3-carbazolyl.

Preferably, the R³ group that corresponds to the following group:

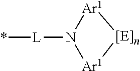

contains at least one Ar¹ group selected from fluorenyl, spirobifluorenyl and carbazolyl, each substituted by R⁶ radicals. Fluorenyl here is preferably 2-fluorenyl. Spirobifluorenyl here is preferably 2-spirobifluorenyl. Carbazolyl here is preferably 3-carbazolyl.

The compound of the formula (I) preferably has a HOMO of higher than −5.25 eV, more preferably of higher than −5.20 eV, where the HOMO is determined as specified in example 1) of the working examples of WO2021/028513.

What is meant by the expression “higher” HOMO in the context of the present application is that the value is less negative, for example, a HOMO of −5.2 eV is higher than a HOMO of −5.3 eV.

Particular preference is given to the compounds shown in the table below:

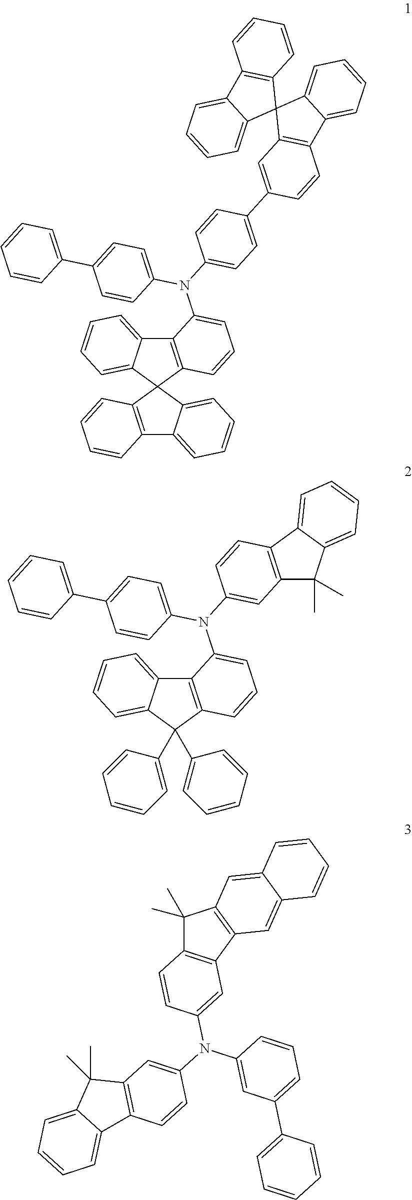 [SMILES: c1ccc(-c2ccc(N(c3ccc(-c4ccc5c(c4)C4(c6ccccc6-c6ccccc64)c4ccccc4-5)cc3)c3cccc4c3-c3ccccc3C43c4ccccc4-c4ccccc43)cc2)cc1 ; CC1(C)c2ccccc2-c2ccc(N(c3ccc(-c4ccccc4)cc3)c3cccc4c3-c3ccccc3C4(c3ccccc3)c3ccccc3)cc21 ; CC1(C)c2ccccc2-c2ccc(N(c3cccc(-c4ccccc4)c3)c3ccc4c(c3)-c3cc5ccccc5cc3C4(C)C)cc21]

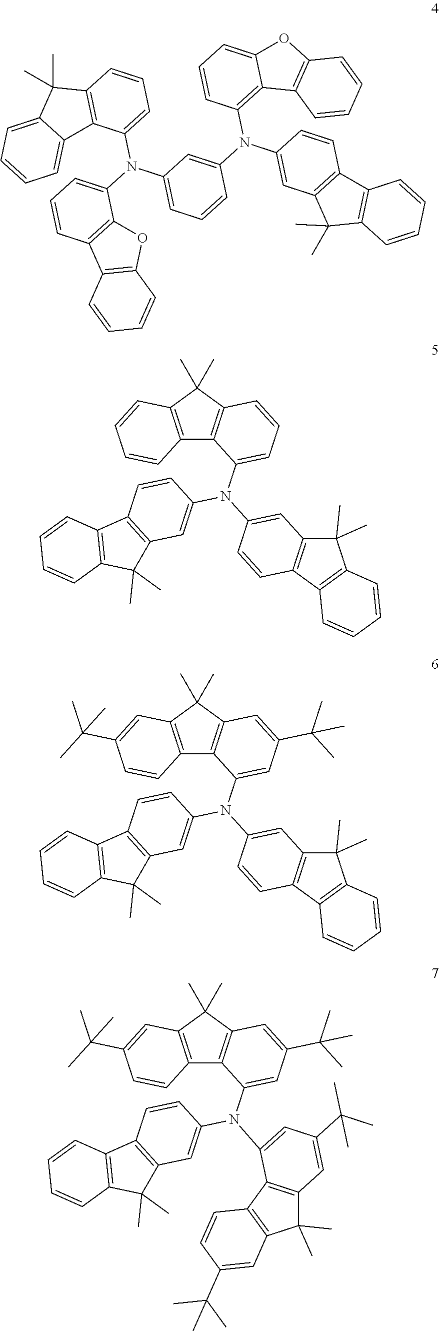 [SMILES: CC1(C)c2ccccc2-c2ccc(N(c3cccc(N(c4cccc5c4-c4ccccc4C5(C)C)c4cccc5c4oc4ccccc45)c3)c3cccc4oc5ccccc5c34)cc21 ; CC1(C)c2ccccc2-c2ccc(N(c3ccc4c(c3)C(C)(C)c3ccccc3-4)c3cccc4c3-c3ccccc3C4(C)C)cc21 ; CC(C)(C)c1ccc2c(c1)C(C)(C)c1cc(C(C)(C)C)cc(N(c3ccc4c(c3)C(C)(C)c3ccccc3-4)c3ccc4c(c3)C(C)(C)c3ccccc3-4)c1-2 ; CC(C)(C)c1ccc2c(c1)C(C)(C)c1cc(C(C)(C)C)cc(N(c3ccc4c(c3)C(C)(C)c3ccccc3-4)c3cc(C(C)(C)C)cc4c3-c3ccc(C(C)(C)C)cc3C4(C)C)c1-2]

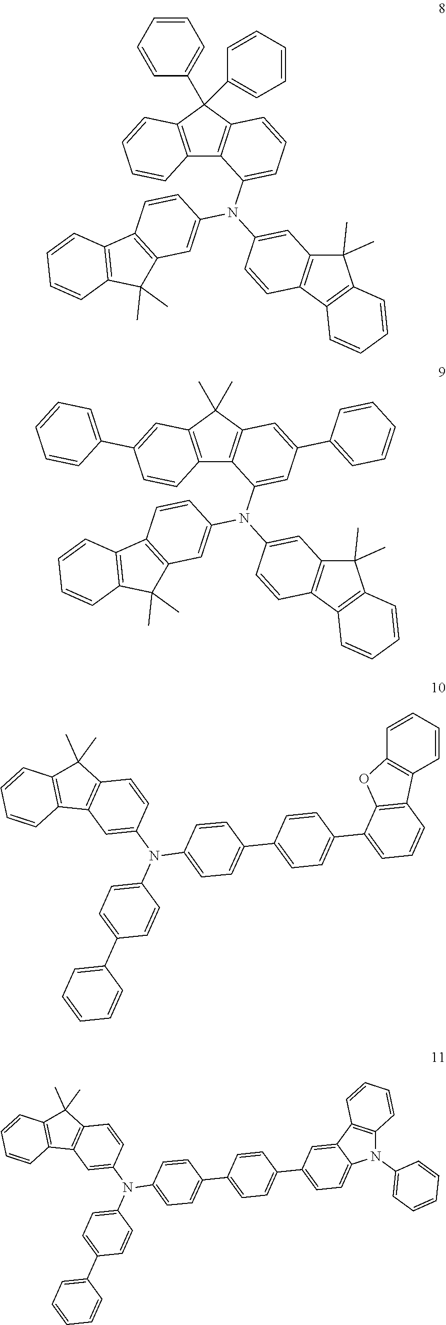 [SMILES: CC1(C)c2ccccc2-c2ccc(N(c3ccc4c(c3)C(C)(C)c3ccccc3-4)c3cccc4c3-c3ccccc3C4(c3ccccc3)c3ccccc3)cc21 ; CC1(C)c2ccccc2-c2ccc(N(c3ccc4c(c3)C(C)(C)c3ccccc3-4)c3cc(-c4ccccc4)cc4c3-c3ccc(-c5ccccc5)cc3C4(C)C)cc21 ; CC1(C)c2ccccc2-c2cc(N(c3ccc(-c4ccccc4)cc3)c3ccc(-c4ccc(-c5cccc6c5oc5ccccc56)cc4)cc3)ccc21 ; CC1(C)c2ccccc2-c2cc(N(c3ccc(-c4ccccc4)cc3)c3ccc(-c4ccc(-c5ccc6c(c5)c5ccccc5n6-c5ccccc5)cc4)cc3)ccc21]

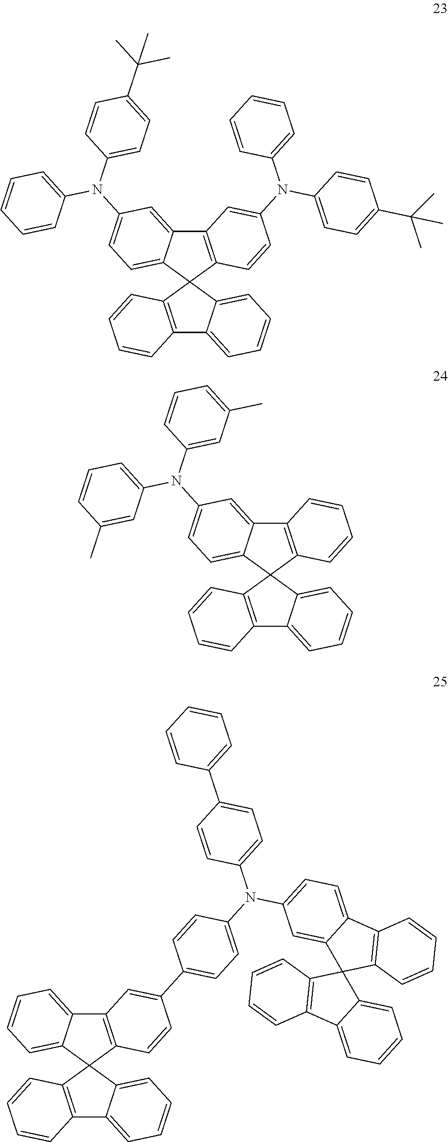

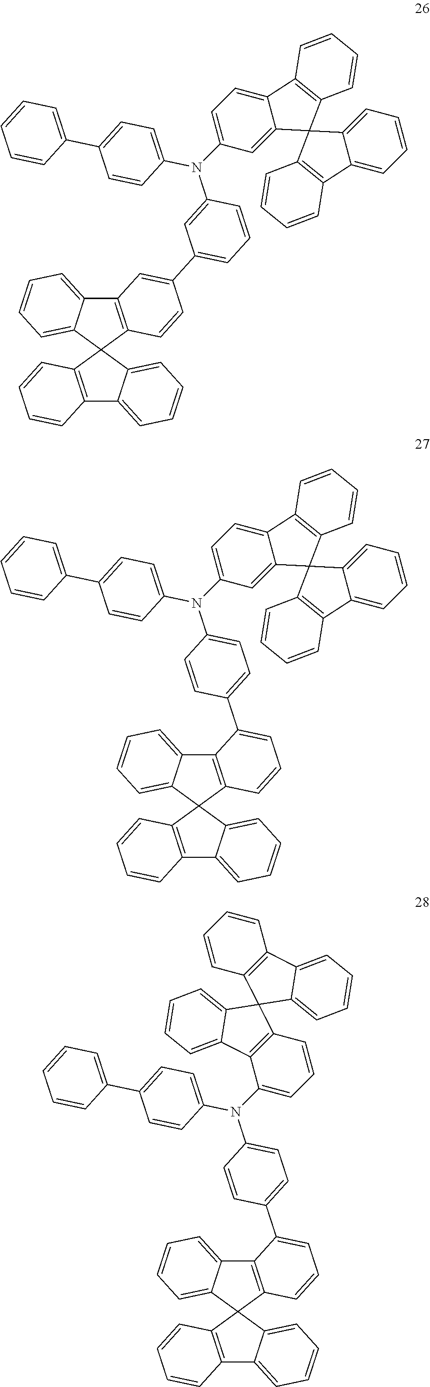

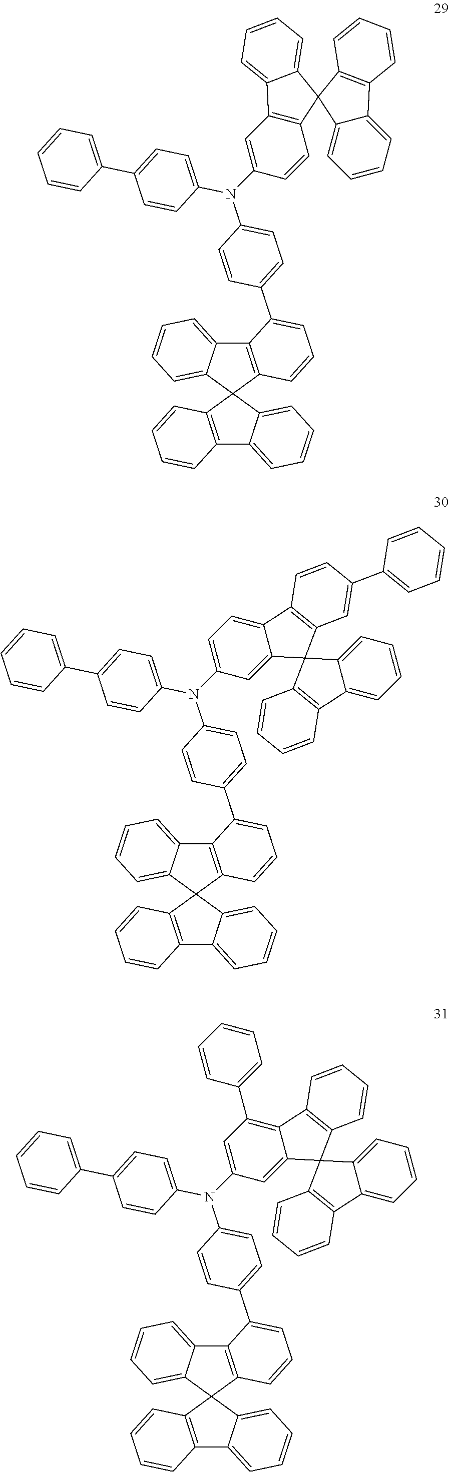 [SMILES: c1ccc(-c2ccc(N(c3ccc(-c4cccc5c4-c4ccccc4C54c5ccccc5-c5ccccc54)cc3)c3ccc4c(c3)-c3ccccc3C43c4ccccc4-c4ccccc43)cc2)cc1 ; c1ccc(-c2ccc(N(c3ccc(-c4cccc5c4-c4ccccc4C54c5ccccc5-c5ccccc54)cc3)c3ccc4c(c3)C3(c5ccccc5-c5ccccc53)c3cc(-c5ccccc5)ccc3-4)cc2)cc1 ; c1ccc(-c2ccc(N(c3ccc(-c4cccc5c4-c4ccccc4C54c5ccccc5-c5ccccc54)cc3)c3cc(-c4ccccc4)c4c(c3)C3(c5ccccc5-c5ccccc53)c3ccccc3-4)cc2)cc1]

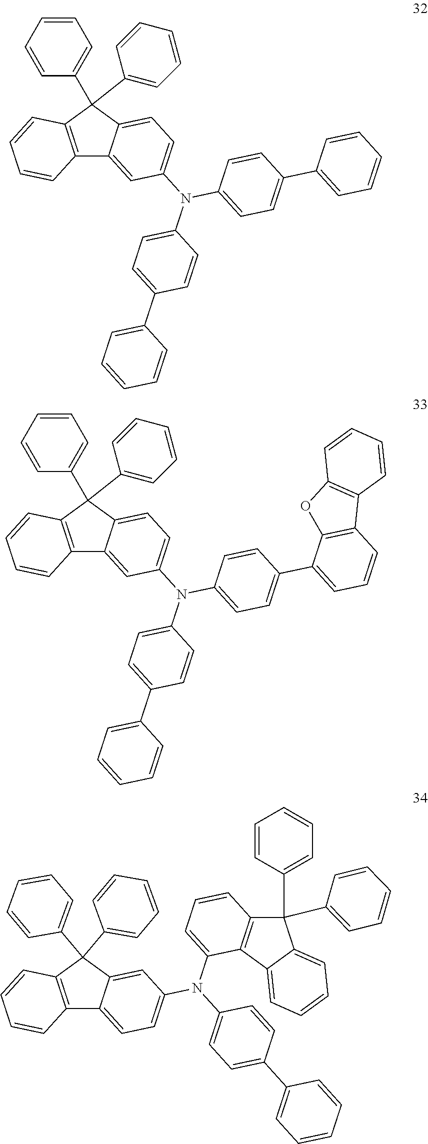

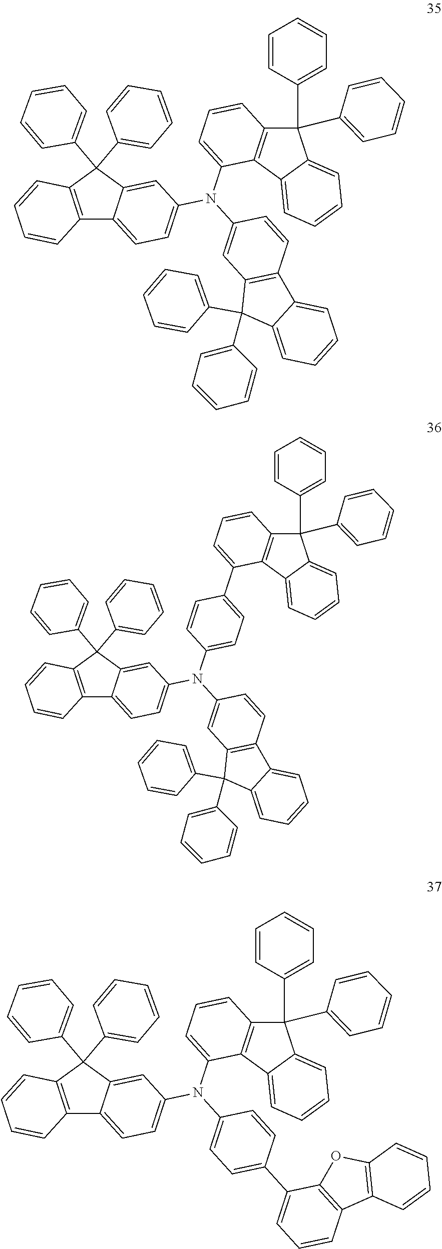 [SMILES: c1ccc(C2(c3ccccc3)c3ccccc3-c3ccc(N(c4ccc5c(c4)C(c4ccccc4)(c4ccccc4)c4ccccc4-5)c4cccc5c4-c4ccccc4C5(c4ccccc4)c4ccccc4)cc32)cc1 ; c1ccc(C2(c3ccccc3)c3ccccc3-c3ccc(N(c4ccc(-c5cccc6c5-c5ccccc5C6(c5ccccc5)c5ccccc5)cc4)c4ccc5c(c4)C(c4ccccc4)(c4ccccc4)c4ccccc4-5)cc32)cc1 ; c1ccc(C2(c3ccccc3)c3ccccc3-c3ccc(N(c4ccc(-c5cccc6c5oc5ccccc56)cc4)c4cccc5c4-c4ccccc4C5(c4ccccc4)c4ccccc4)cc32)cc1]

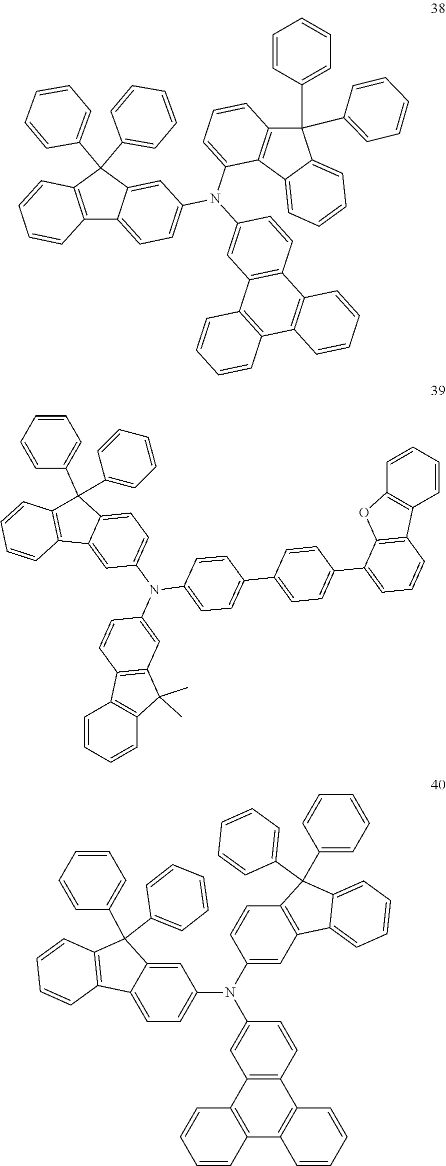 [SMILES: c1ccc(C2(c3ccccc3)c3ccccc3-c3ccc(N(c4ccc5c6ccccc6c6ccccc6c5c4)c4cccc5c4-c4ccccc4C5(c4ccccc4)c4ccccc4)cc32)cc1 ; CC1(C)c2ccccc2-c2ccc(N(c3ccc(-c4ccc(-c5cccc6c5oc5ccccc56)cc4)cc3)c3ccc4c(c3)-c3ccccc3C4(c3ccccc3)c3ccccc3)cc21 ; c1ccc(C2(c3ccccc3)c3ccccc3-c3cc(N(c4ccc5c(c4)C(c4ccccc4)(c4ccccc4)c4ccccc4-5)c4ccc5c6ccccc6c6ccccc6c5c4)ccc32)cc1]

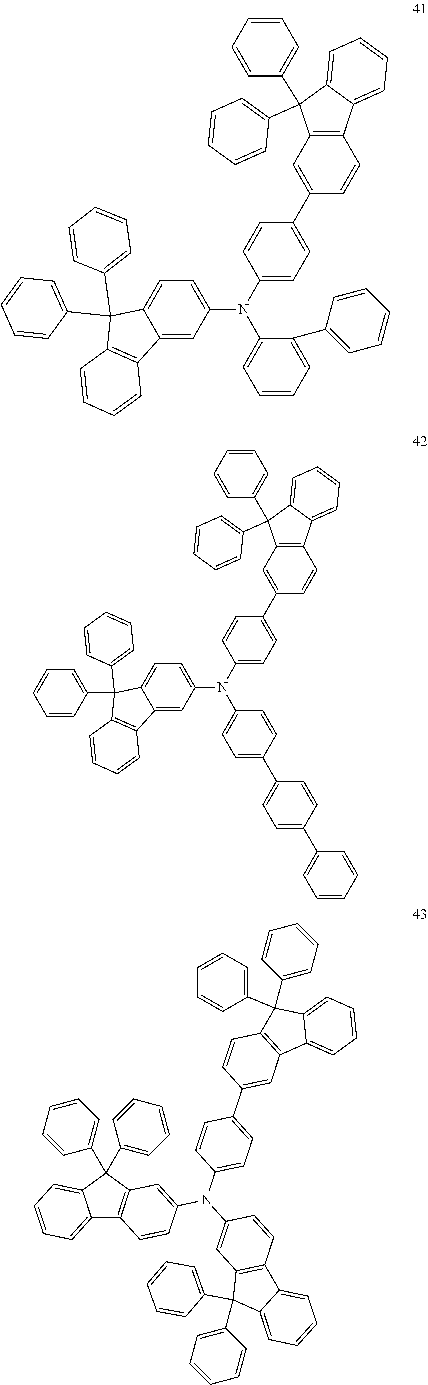

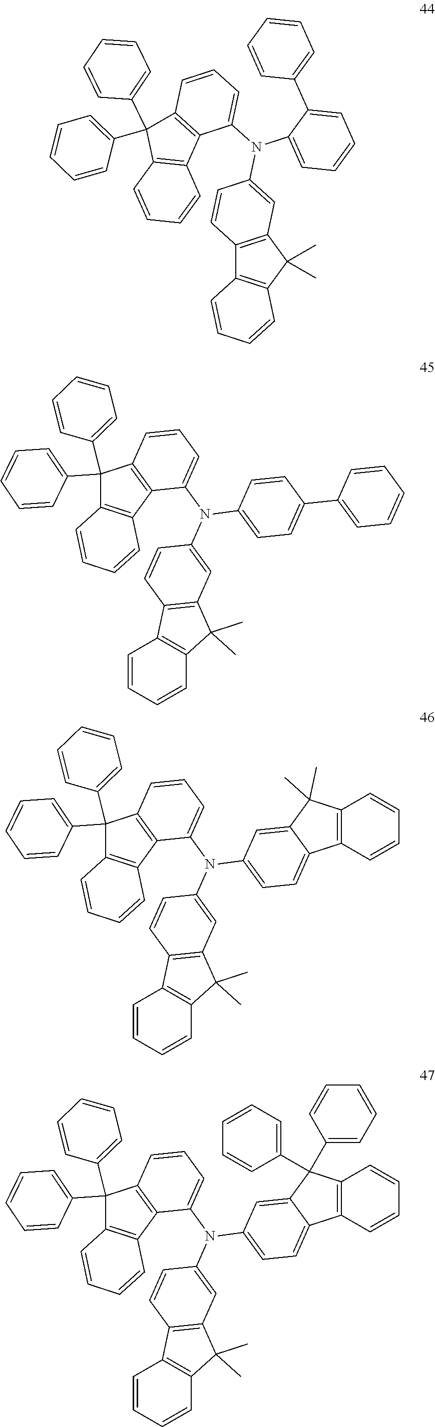 [SMILES: CC1(C)c2ccccc2-c2ccc(N(c3ccccc3-c3ccccc3)c3cccc4c3-c3ccccc3C4(c3ccccc3)c3ccccc3)cc21 ; CC1(C)c2ccccc2-c2ccc(N(c3ccc(-c4ccccc4)cc3)c3cccc4c3-c3ccccc3C4(c3ccccc3)c3ccccc3)cc21 ; CC1(C)c2ccccc2-c2ccc(N(c3ccc4c(c3)C(C)(C)c3ccccc3-4)c3cccc4c3-c3ccccc3C4(c3ccccc3)c3ccccc3)cc21 ; CC1(C)c2ccccc2-c2ccc(N(c3ccc4c(c3)C(c3ccccc3)(c3ccccc3)c3ccccc3-4)c3cccc4c3-c3ccccc3C4(c3ccccc3)c3ccccc3)cc21]

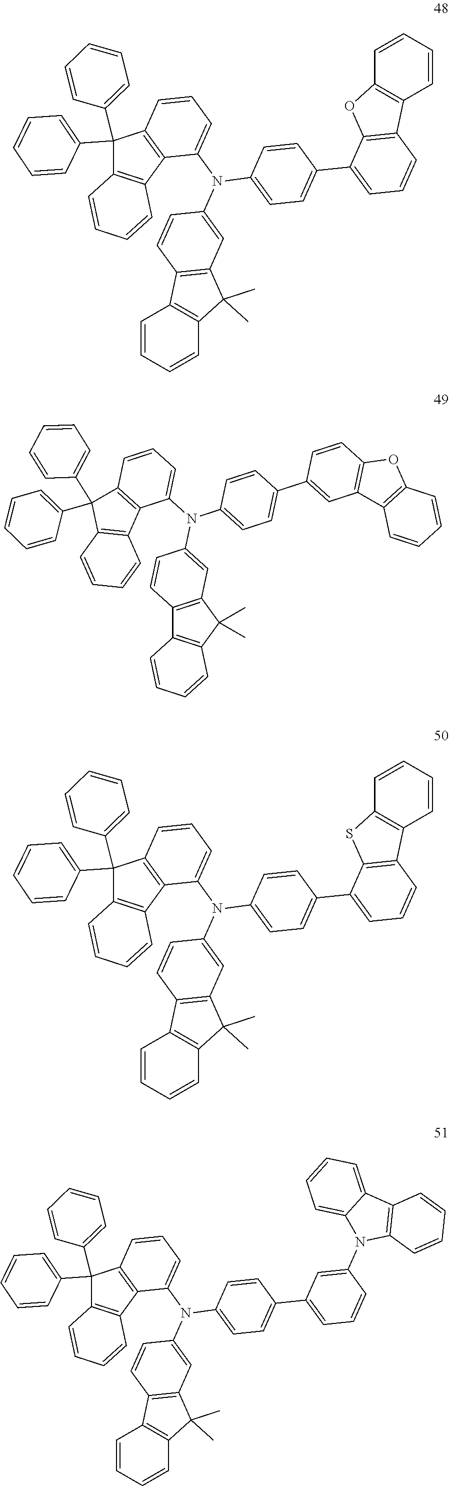 [SMILES: CC1(C)c2ccccc2-c2ccc(N(c3ccc(-c4cccc5c4oc4ccccc45)cc3)c3cccc4c3-c3ccccc3C4(c3ccccc3)c3ccccc3)cc21 ; CC1(C)c2ccccc2-c2ccc(N(c3ccc(-c4ccc5oc6ccccc6c5c4)cc3)c3cccc4c3-c3ccccc3C4(c3ccccc3)c3ccccc3)cc21 ; CC1(C)c2ccccc2-c2ccc(N(c3ccc(-c4cccc5c4sc4ccccc45)cc3)c3cccc4c3-c3ccccc3C4(c3ccccc3)c3ccccc3)cc21 ; CC1(C)c2ccccc2-c2ccc(N(c3ccc(-c4cccc(-n5c6ccccc6c6ccccc65)c4)cc3)c3cccc4c3-c3ccccc3C4(c3ccccc3)c3ccccc3)cc21]

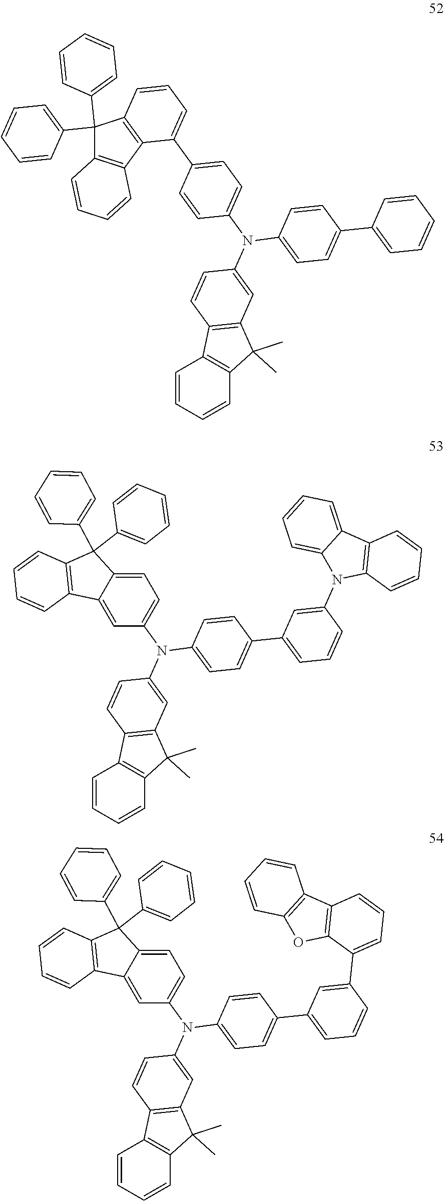

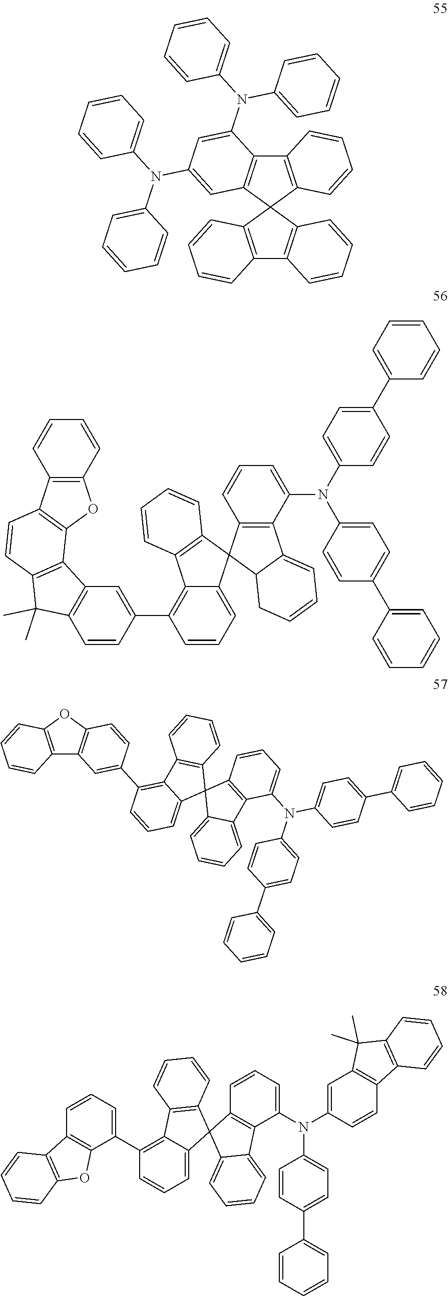 [SMILES: c1ccc(N(c2ccccc2)c2cc(N(c3ccccc3)c3ccccc3)c3c(c2)C2(c4ccccc4-c4ccccc42)c2ccccc2-3)cc1 ; CC1(C)c2ccc(-c3cccc4c3-c3ccccc3C43c4cccc(N(c5ccc(-c6ccccc6)cc5)c5ccc(-c6ccccc6)cc5)c4C4=CC=CCC43)cc2-c2c1ccc1c2oc2ccccc21 ; c1ccc(-c2ccc(N(c3ccc(-c4ccccc4)cc3)c3cccc4c3-c3ccccc3C43c4ccccc4-c4c(-c5ccc6oc7ccccc7c6c5)cccc43)cc2)cc1 ; CC1(C)c2ccccc2-c2ccc(N(c3ccc(-c4ccccc4)cc3)c3cccc4c3-c3ccccc3C43c4ccccc4-c4c(-c5cccc6c5oc5ccccc56)cccc43)cc21]

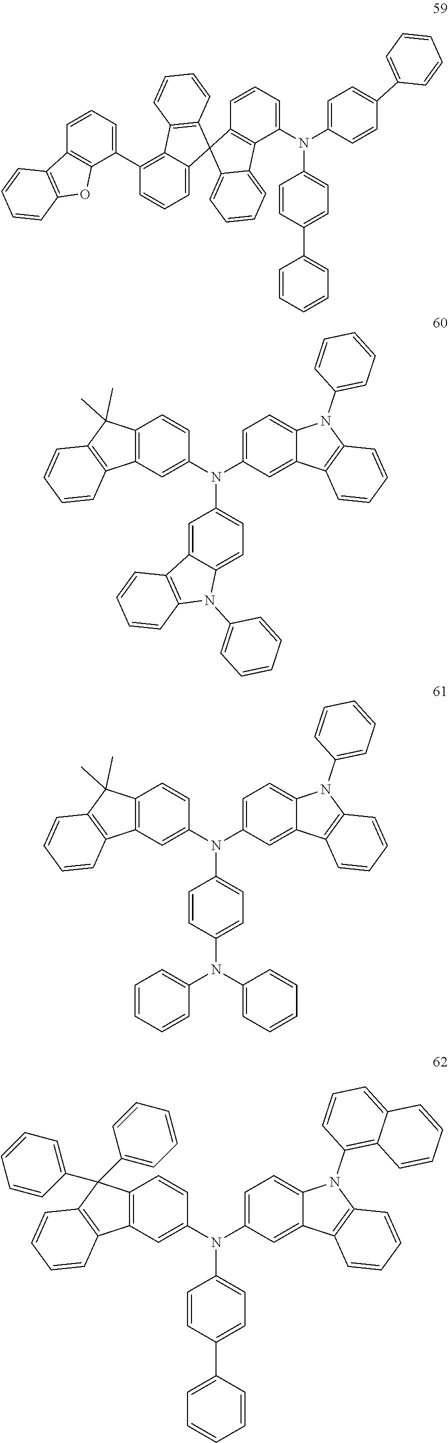

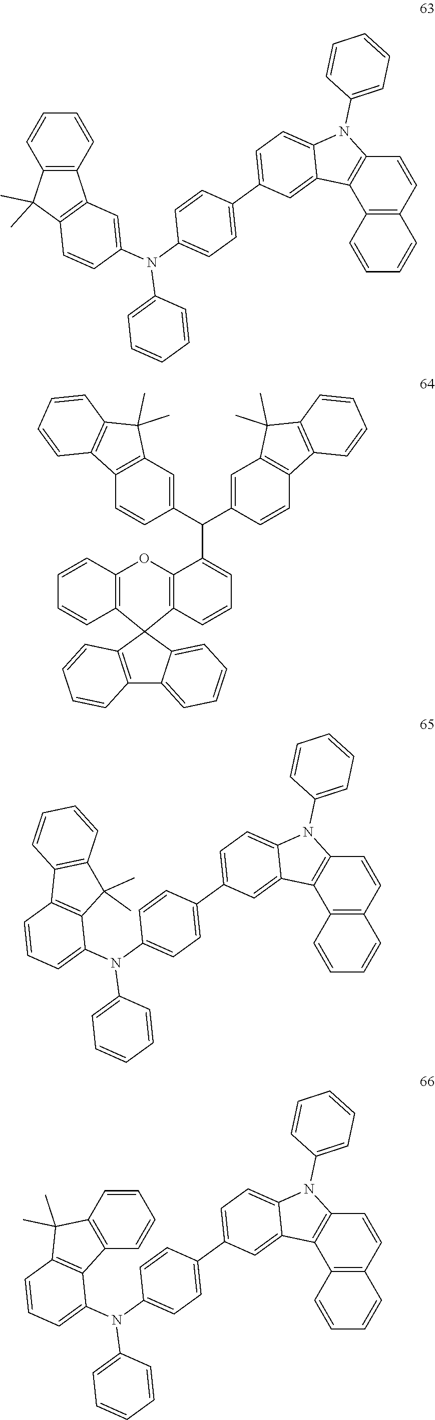

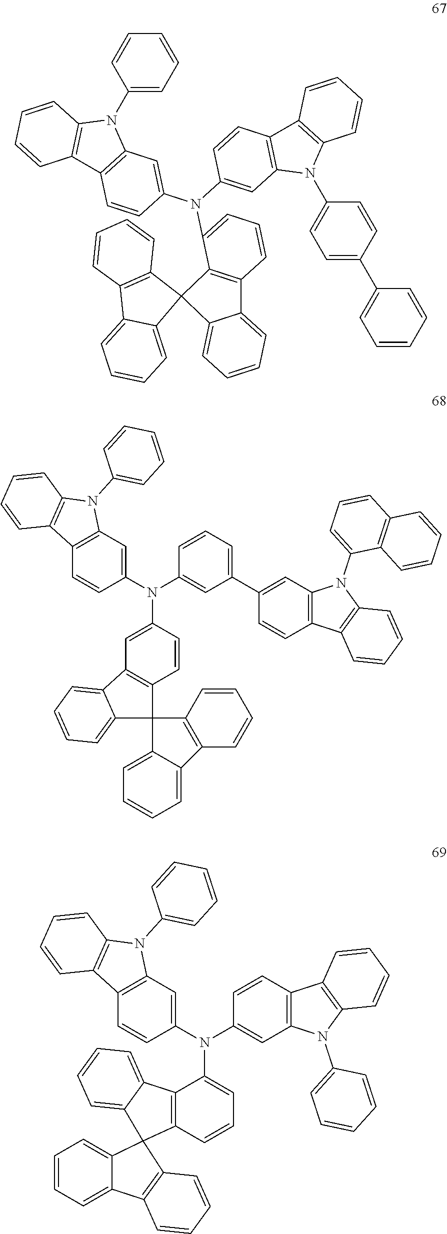 [SMILES: c1ccc(-c2ccc(-n3c4ccccc4c4ccc(N(c5ccc6c7ccccc7n(-c7ccccc7)c6c5)c5cccc6c5C5(c7ccccc7-c7ccccc75)c5ccccc5-6)cc43)cc2)cc1 ; c1ccc(-n2c3ccccc3c3ccc(N(c4cccc(-c5ccc6c7ccccc7n(-c7cccc8ccccc78)c6c5)c4)c4ccc5c(c4)-c4ccccc4C54c5ccccc5-c5ccccc54)cc32)cc1 ; c1ccc(-n2c3ccccc3c3ccc(N(c4ccc5c6ccccc6n(-c6ccccc6)c5c4)c4cccc5c4-c4ccccc4C54c5ccccc5-c5ccccc54)cc32)cc1]

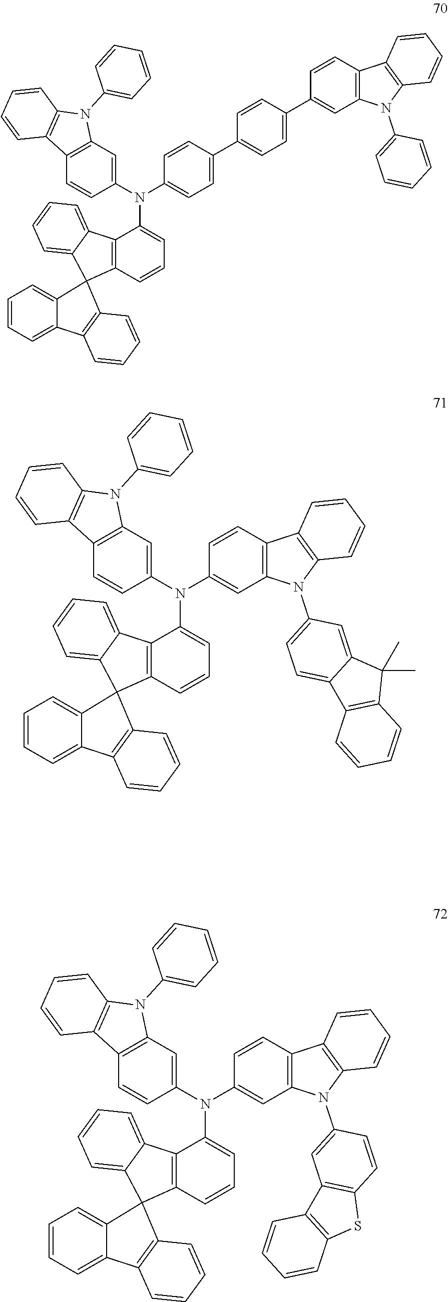 [SMILES: c1ccc(-n2c3ccccc3c3ccc(-c4ccc(-c5ccc(N(c6ccc7c8ccccc8n(-c8ccccc8)c7c6)c6cccc7c6-c6ccccc6C76c7ccccc7-c7ccccc76)cc5)cc4)cc32)cc1 ; CC1(C)c2ccccc2-c2ccc(-n3c4ccccc4c4ccc(N(c5ccc6c7ccccc7n(-c7ccccc7)c6c5)c5cccc6c5-c5ccccc5C65c6ccccc6-c6ccccc65)cc43)cc21 ; c1ccc(-n2c3ccccc3c3ccc(N(c4ccc5c6ccccc6n(-c6ccc7sc8ccccc8c7c6)c5c4)c4cccc5c4-c4ccccc4C54c5ccccc5-c5ccccc54)cc32)cc1]

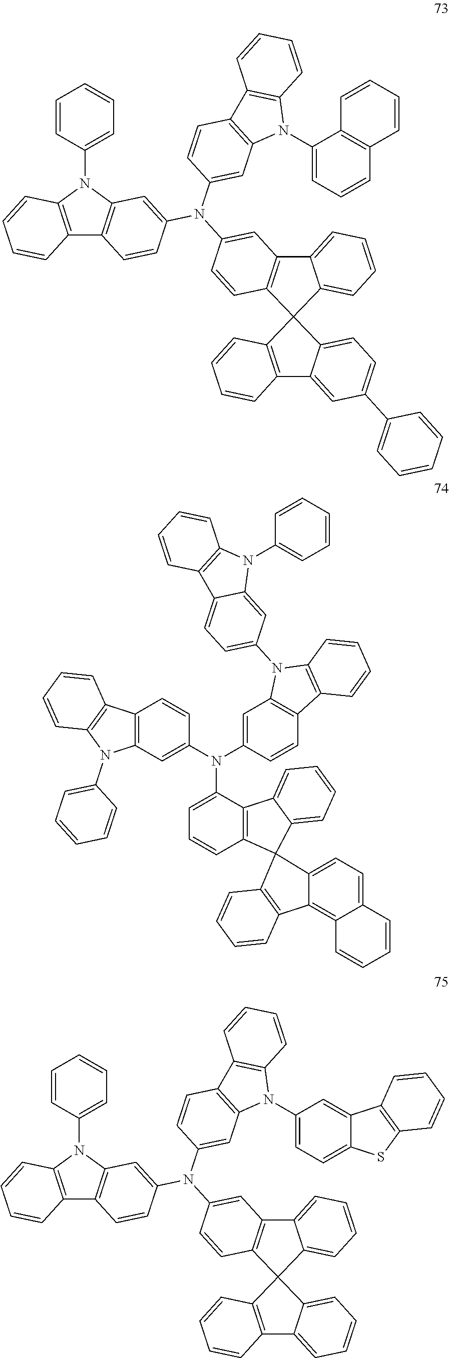 [SMILES: c1ccc(-c2ccc3c(c2)-c2ccccc2C32c3ccccc3-c3cc(N(c4ccc5c6ccccc6n(-c6ccccc6)c5c4)c4ccc5c6ccccc6n(-c6cccc7ccccc67)c5c4)ccc32)cc1 ; c1ccc(-n2c3ccccc3c3ccc(N(c4ccc5c6ccccc6n(-c6ccc7c8ccccc8n(-c8ccccc8)c7c6)c5c4)c4cccc5c4-c4ccccc4C54c5ccccc5-c5c4ccc4ccccc54)cc32)cc1 ; c1ccc(-n2c3ccccc3c3ccc(N(c4ccc5c(c4)-c4ccccc4C54c5ccccc5-c5ccccc54)c4ccc5c6ccccc6n(-c6ccc7sc8ccccc8c7c6)c5c4)cc32)cc1]

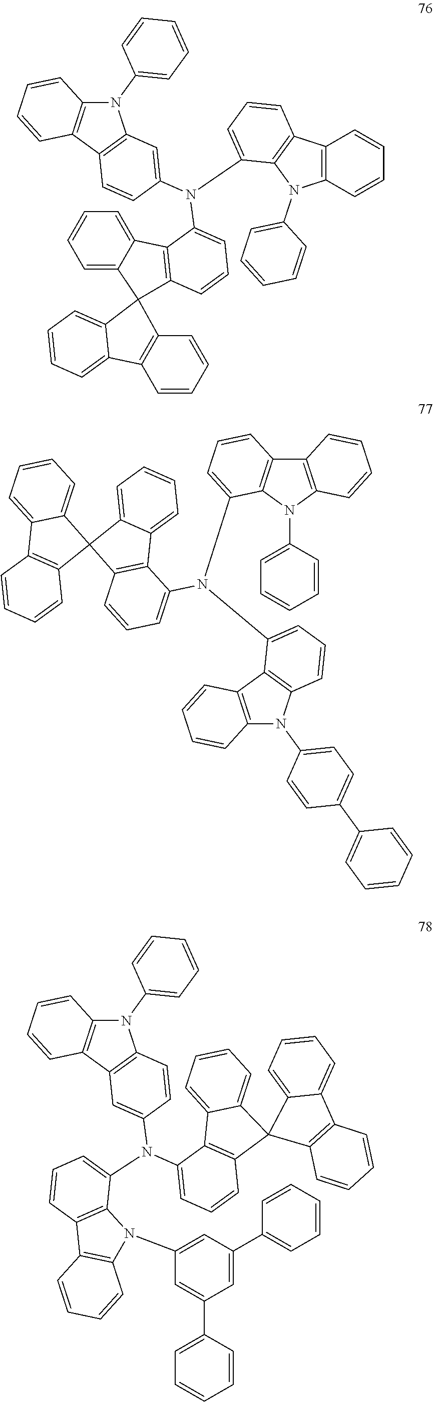 [SMILES: c1ccc(-n2c3ccccc3c3ccc(N(c4cccc5c4-c4ccccc4C54c5ccccc5-c5ccccc54)c4cccc5c6ccccc6n(-c6ccccc6)c45)cc32)cc1 ; c1ccc(-c2ccc(-n3c4ccccc4c4c(N(c5cccc6c5-c5ccccc5C65c6ccccc6-c6ccccc65)c5cccc6c7ccccc7n(-c7ccccc7)c56)cccc43)cc2)cc1 ; c1ccc(-c2cc(-c3ccccc3)cc(-n3c4ccccc4c4cccc(N(c5ccc6c(c5)c5ccccc5n6-c5ccccc5)c5cccc6c5-c5ccccc5C65c6ccccc6-c6ccccc65)c43)c2)cc1]

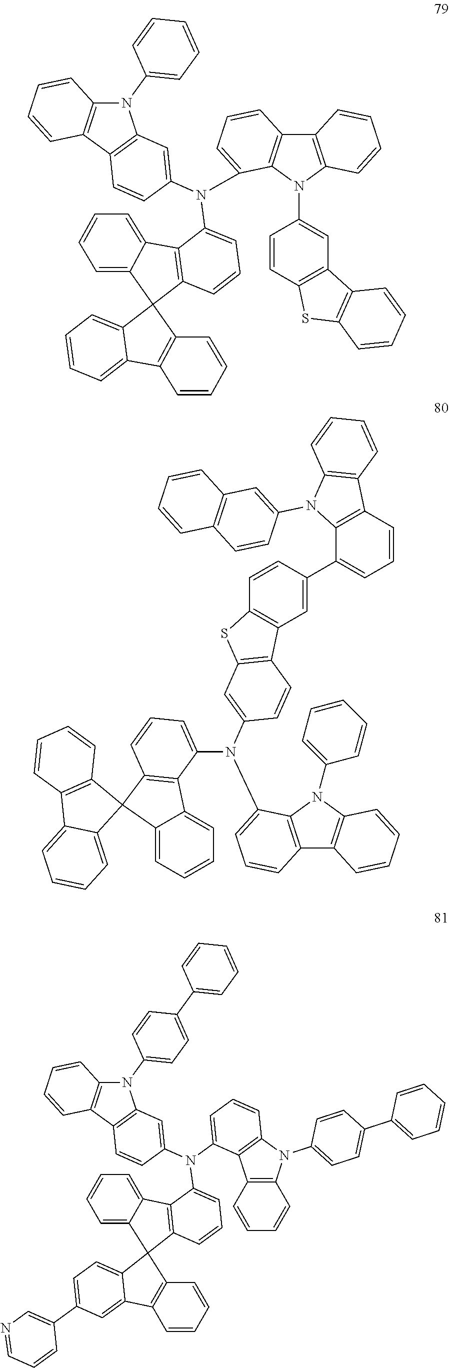 [SMILES: c1ccc(-n2c3ccccc3c3ccc(N(c4cccc5c4-c4ccccc4C54c5ccccc5-c5ccccc54)c4cccc5c6ccccc6n(-c6ccc7sc8ccccc8c7c6)c45)cc32)cc1 ; c1ccc(-n2c3ccccc3c3cccc(N(c4ccc5c(c4)sc4ccc(-c6cccc7c8ccccc8n(-c8ccc9ccccc9c8)c67)cc45)c4cccc5c4-c4ccccc4C54c5ccccc5-c5ccccc54)c32)cc1 ; c1ccc(-c2ccc(-n3c4ccccc4c4ccc(N(c5cccc6c5-c5ccccc5C65c6ccccc6-c6cc(-c7cccnc7)ccc65)c5cccc6c5c5ccccc5n6-c5ccc(-c6ccccc6)cc5)cc43)cc2)cc1]

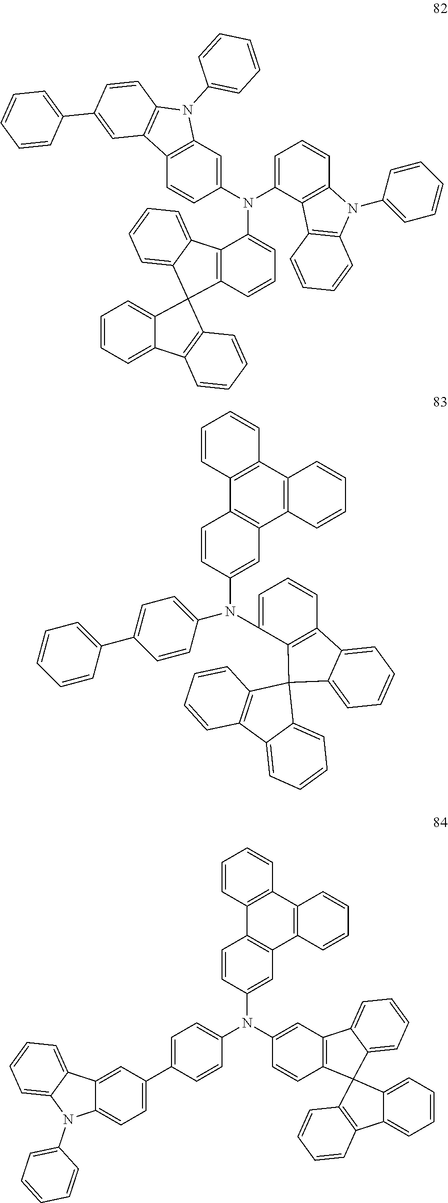

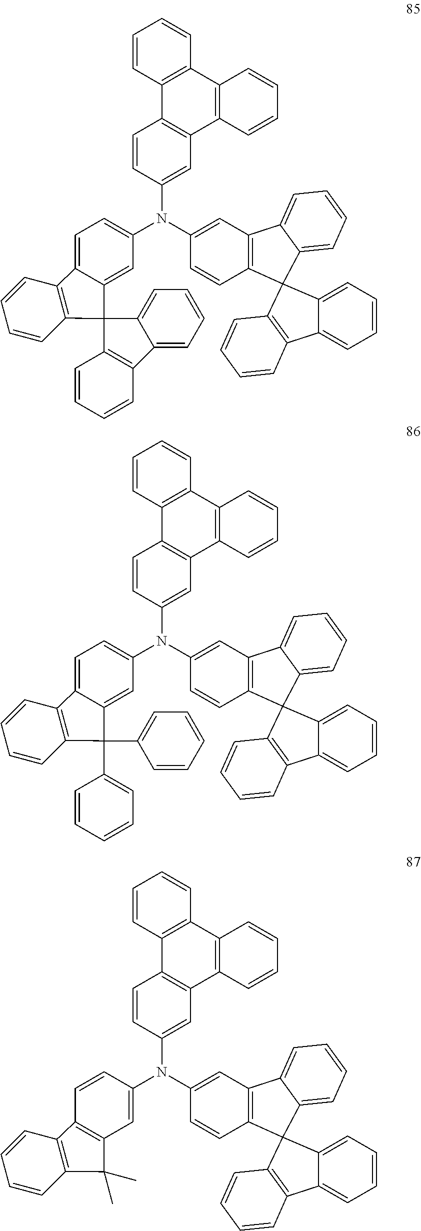 [SMILES: c1ccc2c(c1)-c1ccccc1C21c2ccccc2-c2cc(N(c3ccc4c(c3)C3(c5ccccc5-c5ccccc53)c3ccccc3-4)c3ccc4c5ccccc5c5ccccc5c4c3)ccc21 ; c1ccc(C2(c3ccccc3)c3ccccc3-c3ccc(N(c4ccc5c(c4)-c4ccccc4C54c5ccccc5-c5ccccc54)c4ccc5c6ccccc6c6ccccc6c5c4)cc32)cc1 ; CC1(C)c2ccccc2-c2ccc(N(c3ccc4c(c3)-c3ccccc3C43c4ccccc4-c4ccccc43)c3ccc4c5ccccc5c5ccccc5c4c3)cc21]

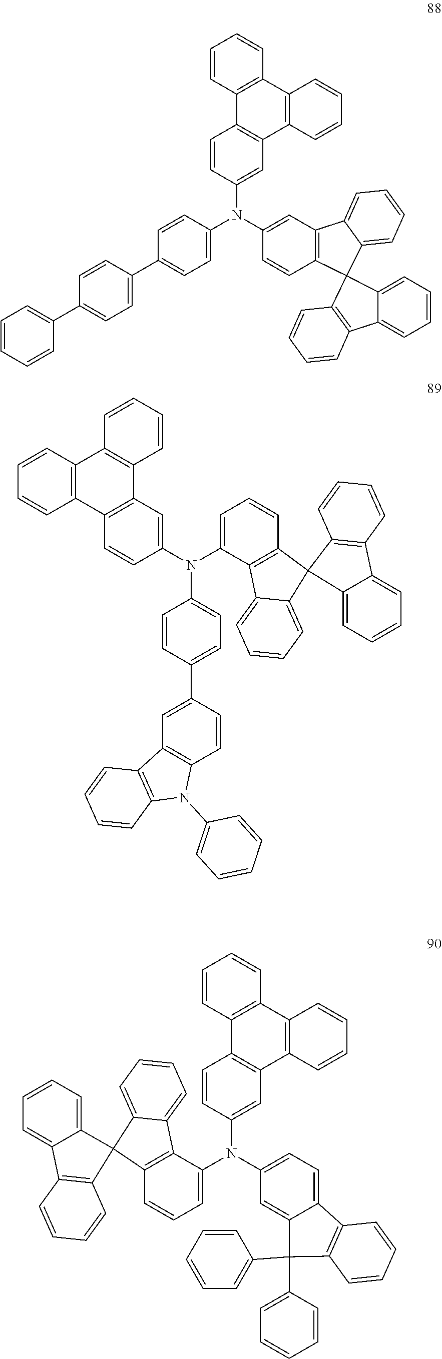 [SMILES: c1ccc(-c2ccc(-c3ccc(N(c4ccc5c(c4)-c4ccccc4C54c5ccccc5-c5ccccc54)c4ccc5c6ccccc6c6ccccc6c5c4)cc3)cc2)cc1 ; c1ccc(-n2c3ccccc3c3cc(-c4ccc(N(c5ccc6c7ccccc7c7ccccc7c6c5)c5cccc6c5-c5ccccc5C65c6ccccc6-c6ccccc65)cc4)ccc32)cc1 ; c1ccc(C2(c3ccccc3)c3ccccc3-c3ccc(N(c4ccc5c6ccccc6c6ccccc6c5c4)c4cccc5c4-c4ccccc4C54c5ccccc5-c5ccccc54)cc32)cc1]

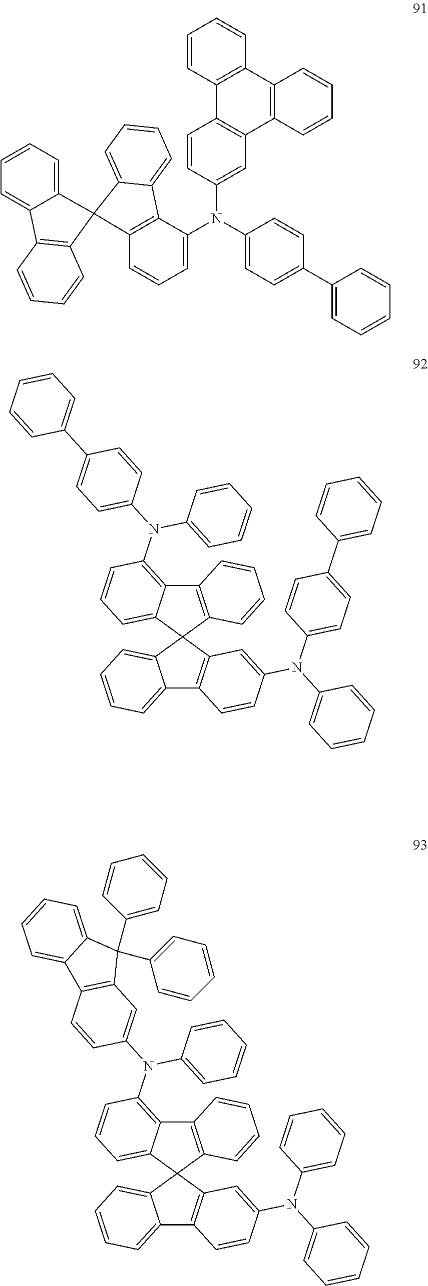 [SMILES: c1ccc(-c2ccc(N(c3ccc4c5ccccc5c5ccccc5c4c3)c3cccc4c3-c3ccccc3C43c4ccccc4-c4ccccc43)cc2)cc1 ; c1ccc(-c2ccc(N(c3ccccc3)c3ccc4c(c3)C3(c5ccccc5-4)c4ccccc4-c4c(N(c5ccccc5)c5ccc(-c6ccccc6)cc5)cccc43)cc2)cc1 ; c1ccc(N(c2ccccc2)c2ccc3c(c2)C2(c4ccccc4-3)c3ccccc3-c3c(N(c4ccccc4)c4ccc5c(c4)C(c4ccccc4)(c4ccccc4)c4ccccc4-5)cccc32)cc1]

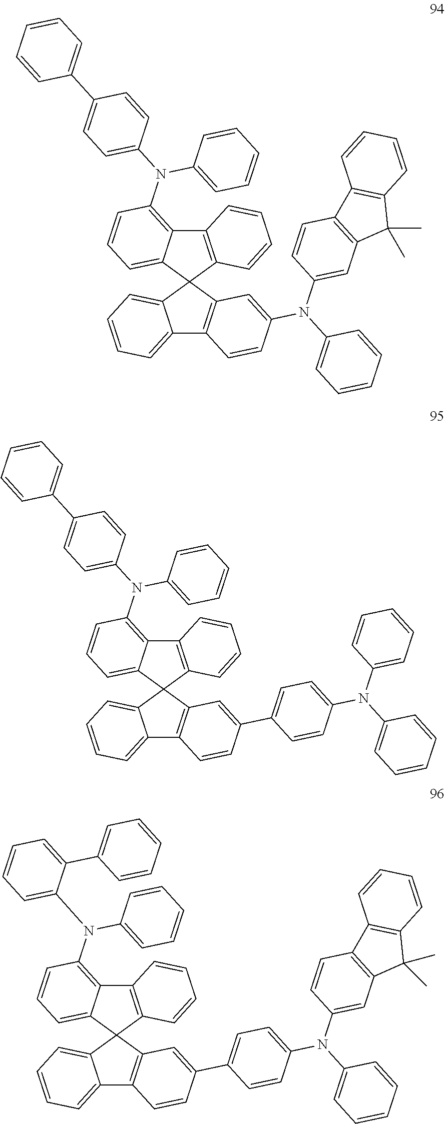 [SMILES: CC1(C)c2ccccc2-c2ccc(N(c3ccccc3)c3ccc4c(c3)C3(c5ccccc5-4)c4ccccc4-c4c(N(c5ccccc5)c5ccc(-c6ccccc6)cc5)cccc43)cc21 ; c1ccc(-c2ccc(N(c3ccccc3)c3cccc4c3-c3ccccc3C43c4ccccc4-c4ccc(-c5ccc(N(c6ccccc6)c6ccccc6)cc5)cc43)cc2)cc1 ; CC1(C)c2ccccc2-c2ccc(N(c3ccccc3)c3ccc(-c4ccc5c(c4)C4(c6ccccc6-5)c5ccccc5-c5c(N(c6ccccc6)c6ccccc6-c6ccccc6)cccc54)cc3)cc21]

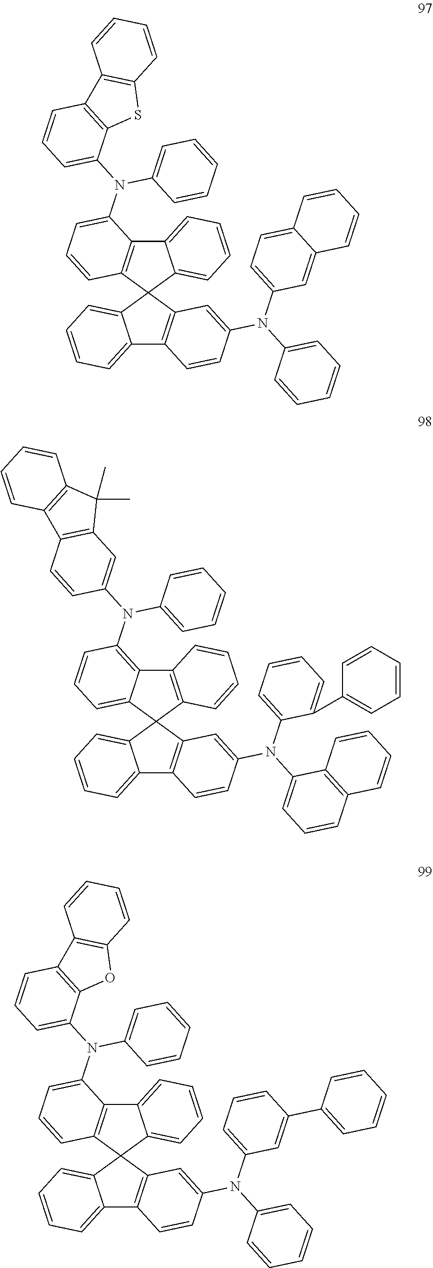 [SMILES: c1ccc(N(c2ccc3c(c2)C2(c4ccccc4-3)c3ccccc3-c3c(N(c4ccccc4)c4cccc5c4sc4ccccc45)cccc32)c2ccc3ccccc3c2)cc1 ; CC1(C)c2ccccc2-c2ccc(N(c3ccccc3)c3cccc4c3-c3ccccc3C43c4ccccc4-c4ccc(N(c5ccccc5-c5ccccc5)c5cccc6ccccc56)cc43)cc21 ; c1ccc(-c2cccc(N(c3ccccc3)c3ccc4c(c3)C3(c5ccccc5-4)c4ccccc4-c4c(N(c5ccccc5)c5cccc6c5oc5ccccc56)cccc43)c2)cc1]

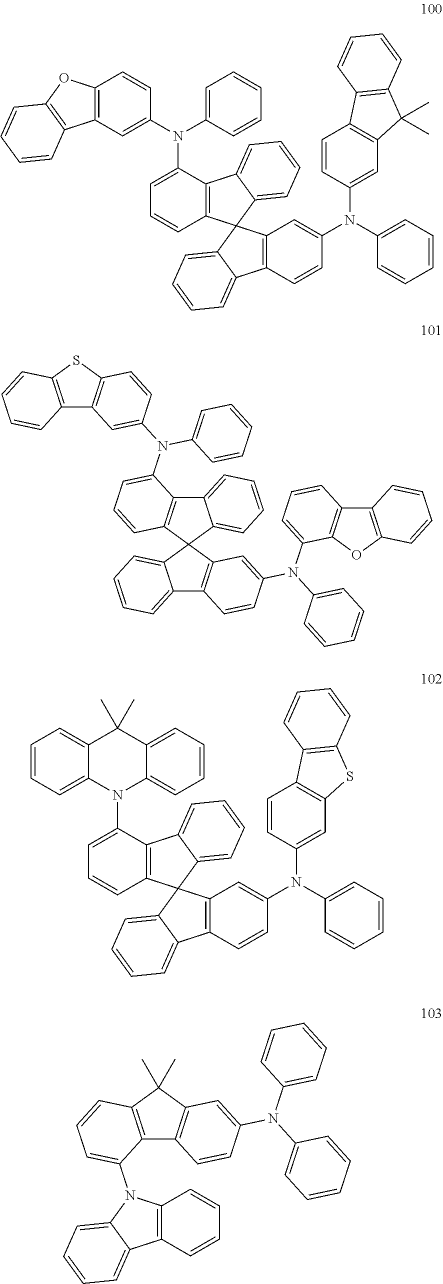

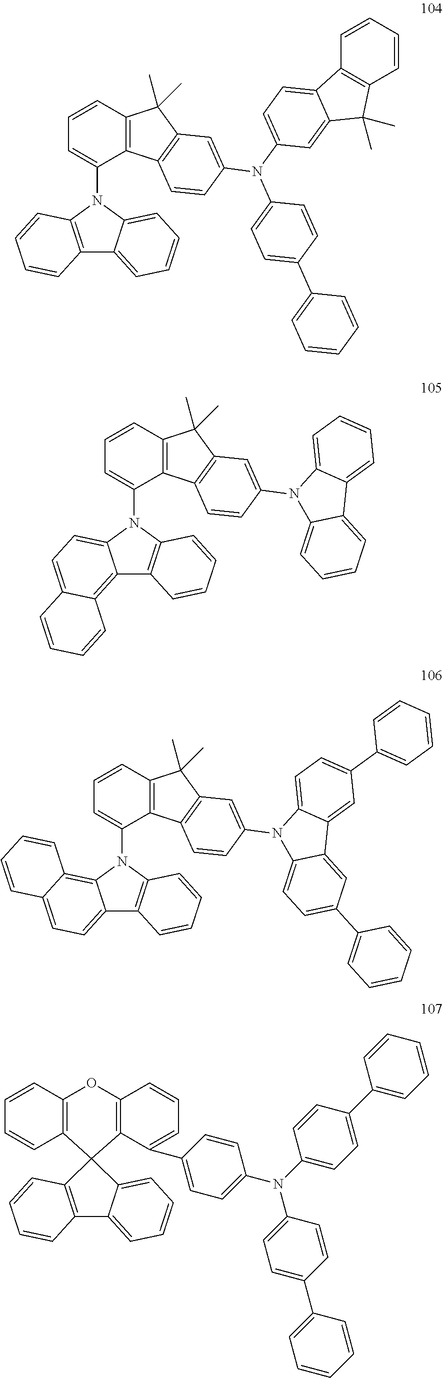 [SMILES: CC1(C)c2ccccc2-c2ccc(N(c3ccc(-c4ccccc4)cc3)c3ccc4c(c3)C(C)(C)c3cccc(-n5c6ccccc6c6ccccc65)c3-4)cc21 ; CC1(C)c2cc(-n3c4ccccc4c4ccccc43)ccc2-c2c(-n3c4ccccc4c4c5ccccc5ccc43)cccc21 ; CC1(C)c2cc(-n3c4ccc(-c5ccccc5)cc4c4cc(-c5ccccc5)ccc43)ccc2-c2c(-n3c4ccccc4c4ccc5ccccc5c43)cccc21 ; c1ccc(-c2ccc(N(c3ccc(-c4ccccc4)cc3)c3ccc(-c4cccc5c4C4(c6ccccc6O5)c5ccccc5-c5ccccc54)cc3)cc2)cc1]

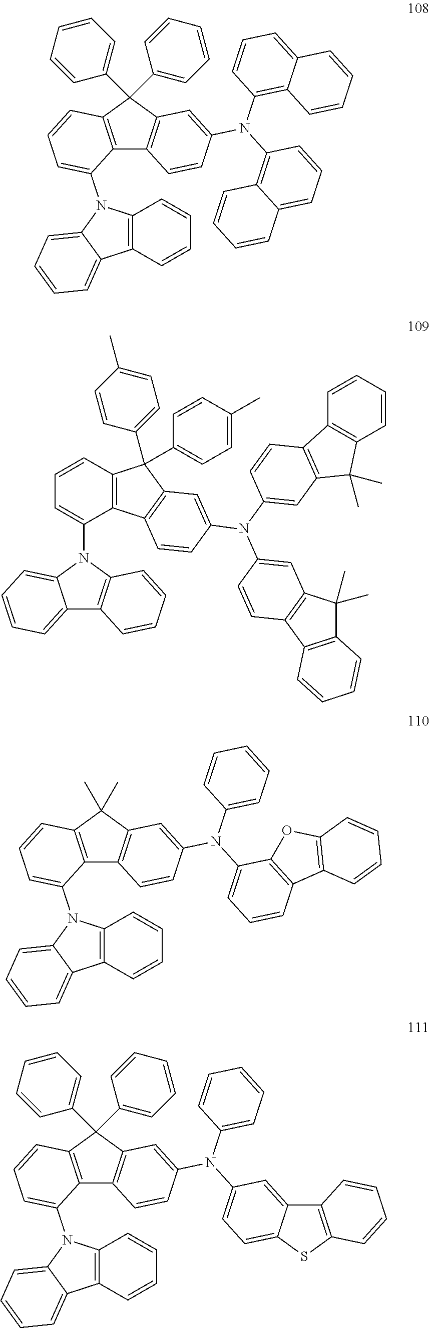 [SMILES: c1ccc(C2(c3ccccc3)c3cc(N(c4cccc5ccccc45)c4cccc5ccccc45)ccc3-c3c(-n4c5ccccc5c5ccccc54)cccc32)cc1 ; Cc1ccc(C2(c3ccc(C)cc3)c3cc(N(c4ccc5c(c4)C(C)(C)c4ccccc4-5)c4ccc5c(c4)C(C)(C)c4ccccc4-5)ccc3-c3c(-n4c5ccccc5c5ccccc54)cccc32)cc1 ; CC1(C)c2cc(N(c3ccccc3)c3cccc4c3oc3ccccc34)ccc2-c2c(-n3c4ccccc4c4ccccc43)cccc21 ; c1ccc(N(c2ccc3c(c2)C(c2ccccc2)(c2ccccc2)c2cccc(-n4c5ccccc5c5ccccc54)c2-3)c2ccc3sc4ccccc4c3c2)cc1]

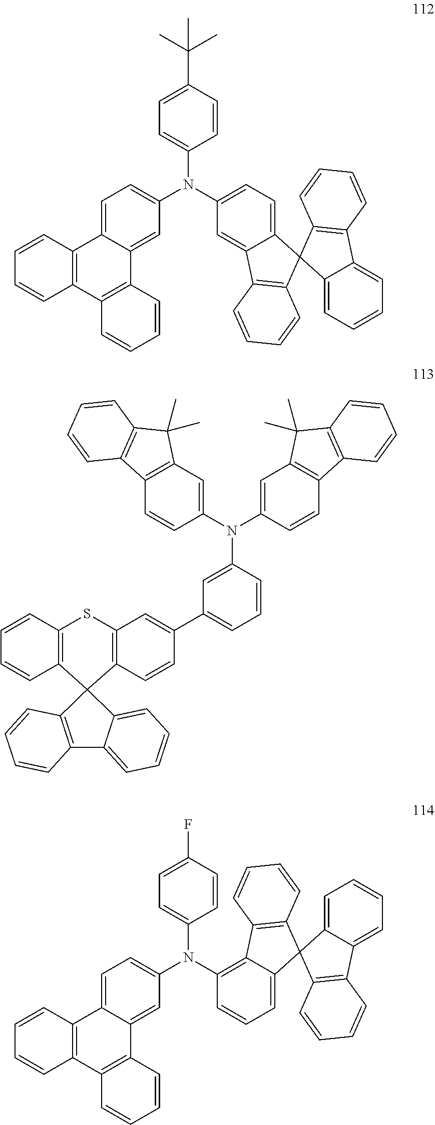 [SMILES: CC(C)(C)c1ccc(N(c2ccc3c(c2)-c2ccccc2C32c3ccccc3-c3ccccc32)c2ccc3c4ccccc4c4ccccc4c3c2)cc1 ; CC1(C)c2ccccc2-c2ccc(N(c3cccc(-c4ccc5c(c4)Sc4ccccc4C54c5ccccc5-c5ccccc54)c3)c3ccc4c(c3)C(C)(C)c3ccccc3-4)cc21 ; Fc1ccc(N(c2ccc3c4ccccc4c4ccccc4c3c2)c2cccc3c2-c2ccccc2C32c3ccccc3-c3ccccc32)cc1]

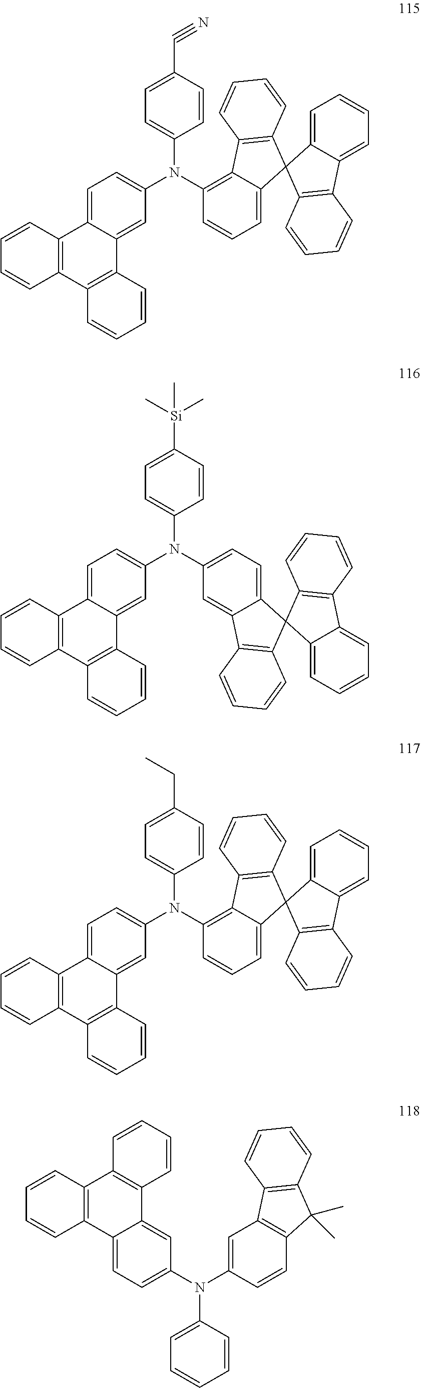 [SMILES: N#Cc1ccc(N(c2ccc3c4ccccc4c4ccccc4c3c2)c2cccc3c2-c2ccccc2C32c3ccccc3-c3ccccc32)cc1 ; C[Si](C)(C)c1ccc(N(c2ccc3c(c2)-c2ccccc2C32c3ccccc3-c3ccccc32)c2ccc3c4ccccc4c4ccccc4c3c2)cc1 ; CCc1ccc(N(c2ccc3c4ccccc4c4ccccc4c3c2)c2cccc3c2-c2ccccc2C32c3ccccc3-c3ccccc32)cc1 ; CC1(C)c2ccccc2-c2cc(N(c3ccccc3)c3ccc4c5ccccc5c5ccccc5c4c3)ccc21]

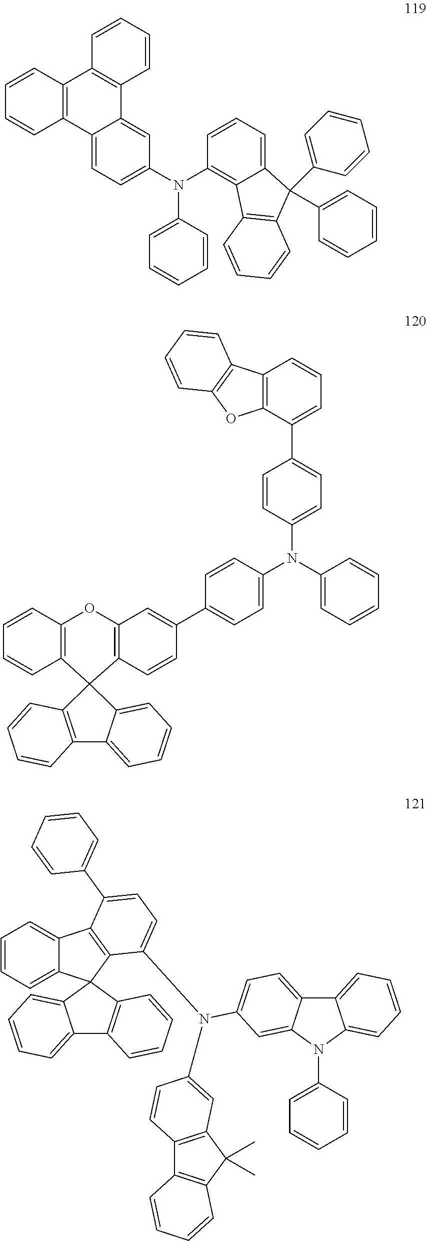

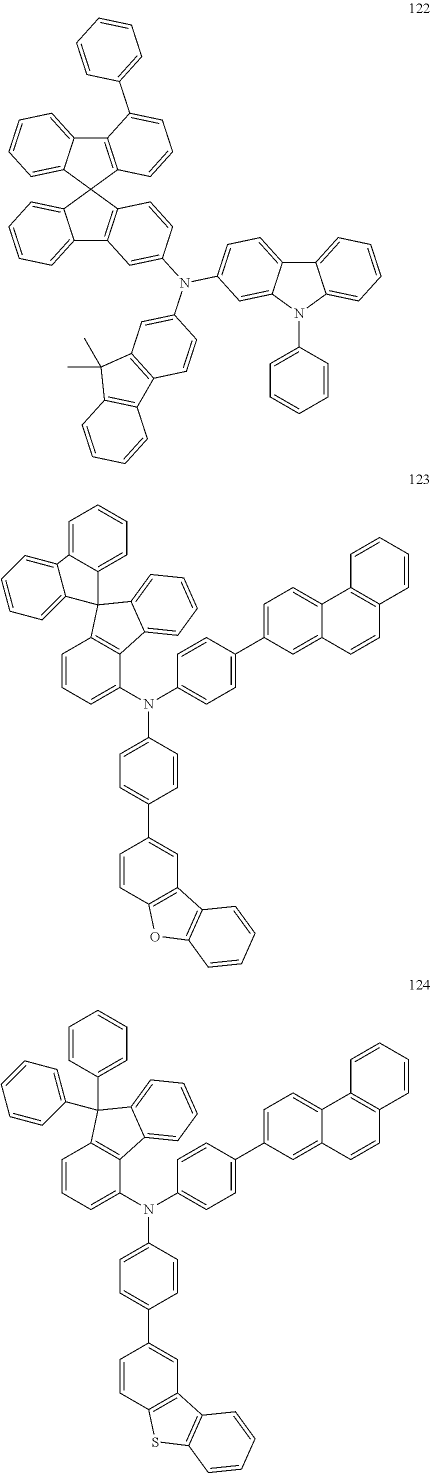 [SMILES: CC1(C)c2ccccc2-c2ccc(N(c3ccc4c(c3)-c3ccccc3C43c4ccccc4-c4c(-c5ccccc5)cccc43)c3ccc4c5ccccc5n(-c5ccccc5)c4c3)cc21 ; c1ccc2c(c1)-c1ccccc1C21c2ccccc2-c2c(N(c3ccc(-c4ccc5c(ccc6ccccc65)c4)cc3)c3ccc(-c4ccc5oc6ccccc6c5c4)cc3)cccc21 ; c1ccc(C2(c3ccccc3)c3ccccc3-c3c(N(c4ccc(-c5ccc6c(ccc7ccccc76)c5)cc4)c4ccc(-c5ccc6sc7ccccc7c6c5)cc4)cccc32)cc1]

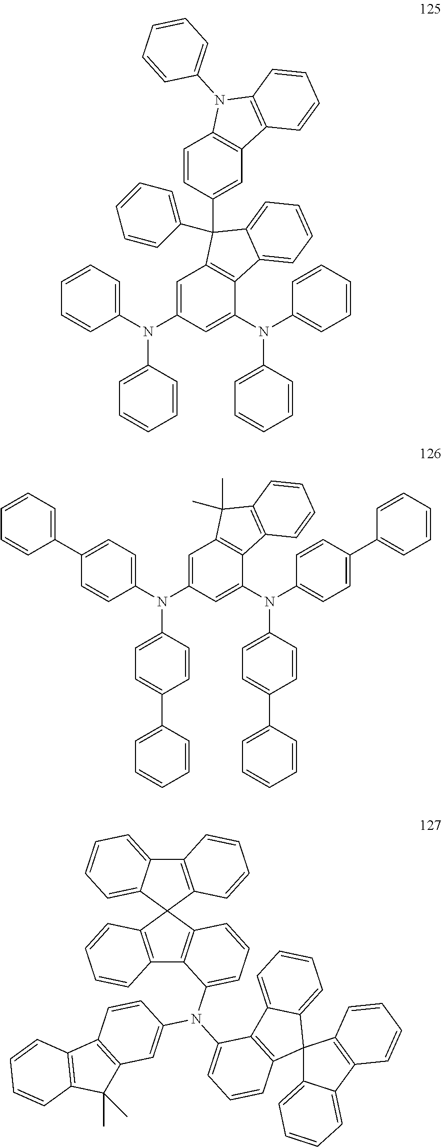 [SMILES: c1ccc(N(c2ccccc2)c2cc(N(c3ccccc3)c3ccccc3)c3c(c2)C(c2ccccc2)(c2ccc4c(c2)c2ccccc2n4-c2ccccc2)c2ccccc2-3)cc1 ; CC1(C)c2ccccc2-c2c(N(c3ccc(-c4ccccc4)cc3)c3ccc(-c4ccccc4)cc3)cc(N(c3ccc(-c4ccccc4)cc3)c3ccc(-c4ccccc4)cc3)cc21 ; CC1(C)c2ccccc2-c2ccc(N(c3cccc4c3-c3ccccc3C43c4ccccc4-c4ccccc43)c3cccc4c3-c3ccccc3C43c4ccccc4-c4ccccc43)cc21]

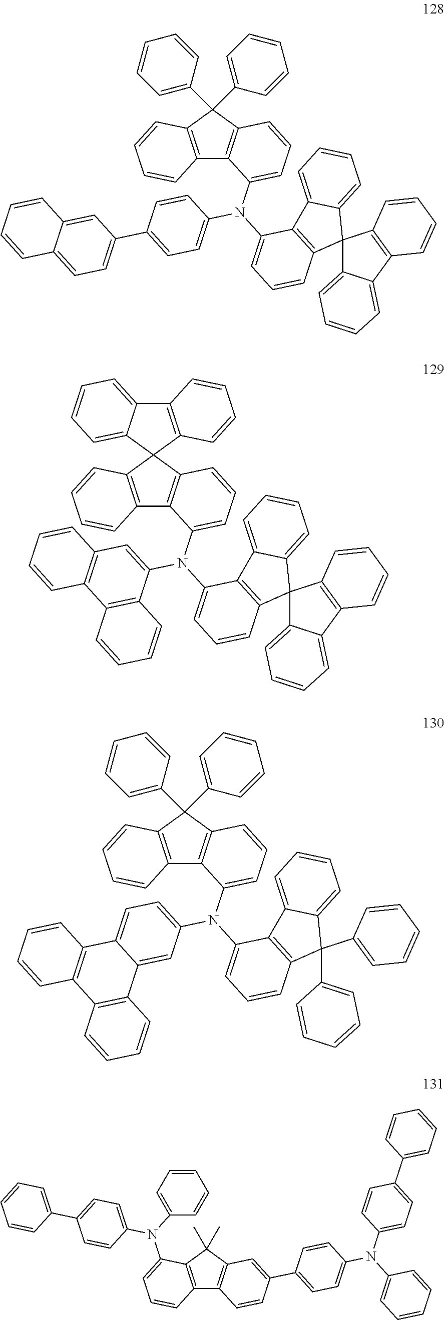 [SMILES: c1ccc(C2(c3ccccc3)c3ccccc3-c3c(N(c4ccc(-c5ccc6ccccc6c5)cc4)c4cccc5c4-c4ccccc4C54c5ccccc5-c5ccccc54)cccc32)cc1 ; c1ccc2c(c1)-c1ccccc1C21c2ccccc2-c2c(N(c3cccc4c3-c3ccccc3C43c4ccccc4-c4ccccc43)c3cc4ccccc4c4ccccc34)cccc21 ; c1ccc(C2(c3ccccc3)c3ccccc3-c3c(N(c4ccc5c6ccccc6c6ccccc6c5c4)c4cccc5c4-c4ccccc4C5(c4ccccc4)c4ccccc4)cccc32)cc1 ; CC1(C)c2cc(-c3ccc(N(c4ccccc4)c4ccc(-c5ccccc5)cc4)cc3)ccc2-c2cccc(N(c3ccccc3)c3ccc(-c4ccccc4)cc3)c21]

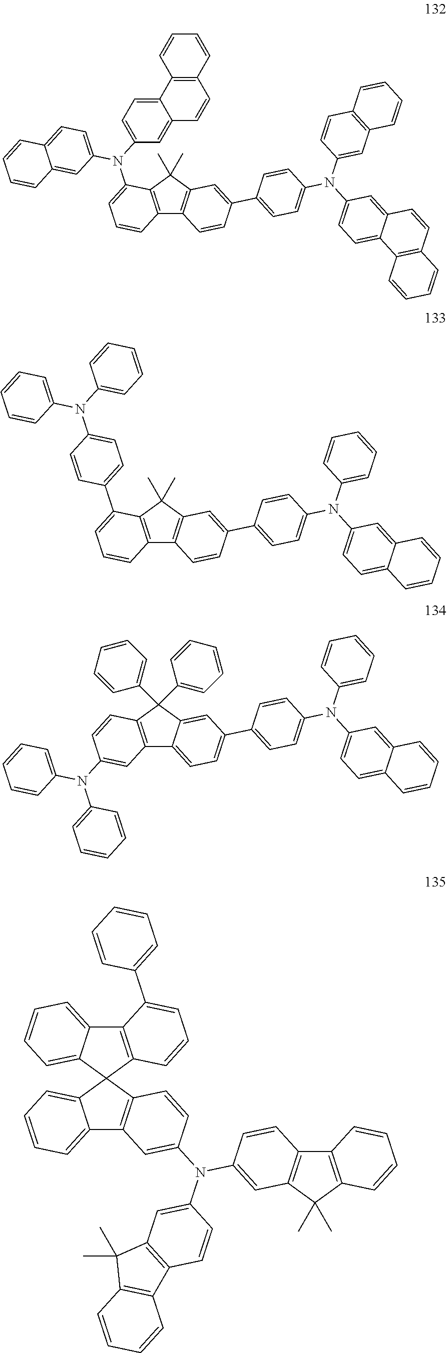 [SMILES: CC1(C)c2cc(-c3ccc(N(c4ccc5ccccc5c4)c4ccc5c(ccc6ccccc65)c4)cc3)ccc2-c2cccc(N(c3ccc4ccccc4c3)c3ccc4c(ccc5ccccc54)c3)c21 ; CC1(C)c2cc(-c3ccc(N(c4ccccc4)c4ccc5ccccc5c4)cc3)ccc2-c2cccc(-c3ccc(N(c4ccccc4)c4ccccc4)cc3)c21 ; c1ccc(N(c2ccccc2)c2ccc3c(c2)-c2ccc(-c4ccc(N(c5ccccc5)c5ccc6ccccc6c5)cc4)cc2C3(c2ccccc2)c2ccccc2)cc1 ; CC1(C)c2ccccc2-c2ccc(N(c3ccc4c(c3)-c3ccccc3C43c4ccccc4-c4c(-c5ccccc5)cccc43)c3ccc4c(c3)C(C)(C)c3ccccc3-4)cc21]

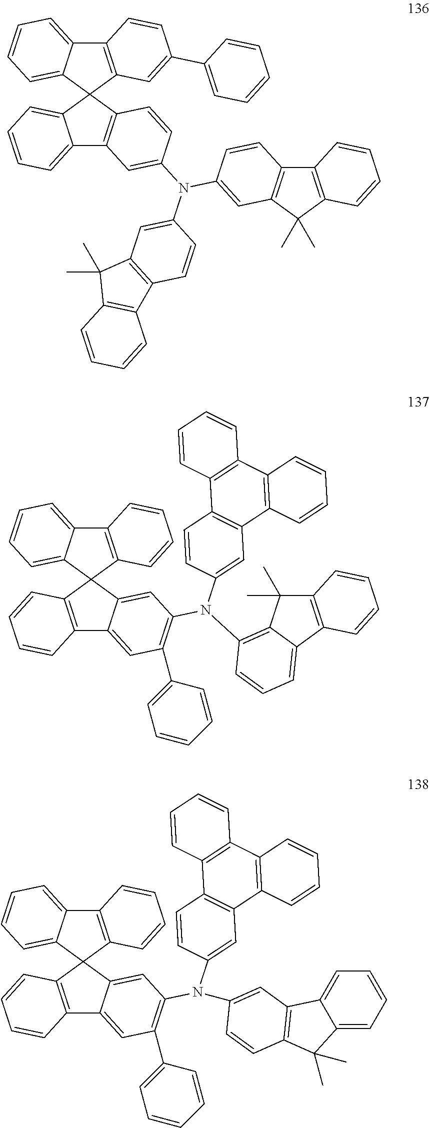 [SMILES: CC1(C)c2ccccc2-c2ccc(N(c3ccc4c(c3)-c3ccccc3C43c4ccccc4-c4ccc(-c5ccccc5)cc43)c3ccc4c(c3)C(C)(C)c3ccccc3-4)cc21 ; CC1(C)c2ccccc2-c2cccc(N(c3ccc4c5ccccc5c5ccccc5c4c3)c3cc4c(cc3-c3ccccc3)-c3ccccc3C43c4ccccc4-c4ccccc43)c21 ; CC1(C)c2ccccc2-c2cc(N(c3ccc4c5ccccc5c5ccccc5c4c3)c3cc4c(cc3-c3ccccc3)-c3ccccc3C43c4ccccc4-c4ccccc43)ccc21]

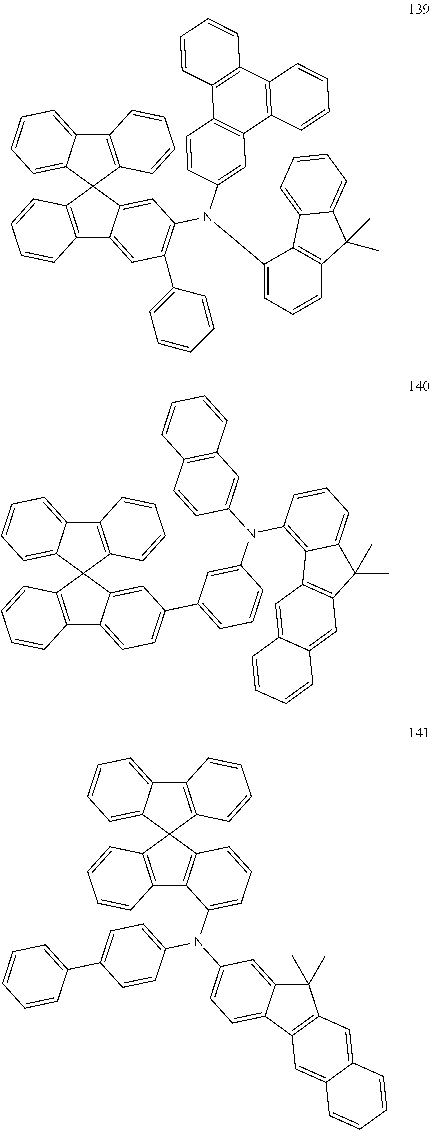

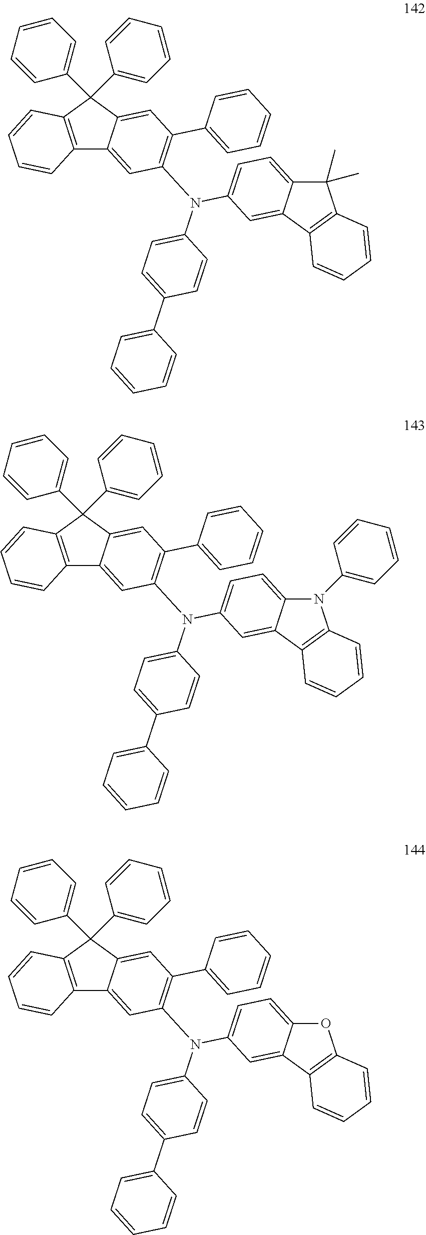

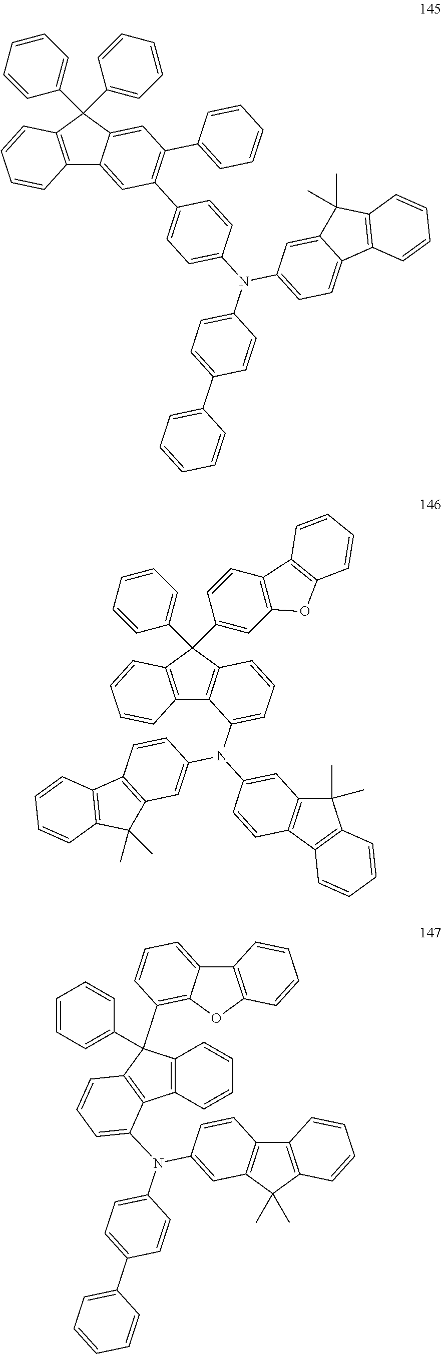 [SMILES: CC1(C)c2ccccc2-c2ccc(N(c3ccc(-c4ccccc4)cc3)c3ccc(-c4cc5c(cc4-c4ccccc4)C(c4ccccc4)(c4ccccc4)c4ccccc4-5)cc3)cc21 ; CC1(C)c2ccccc2-c2ccc(N(c3ccc4c(c3)C(C)(C)c3ccccc3-4)c3cccc4c3-c3ccccc3C4(c3ccccc3)c3ccc4c(c3)oc3ccccc34)cc21 ; CC1(C)c2ccccc2-c2ccc(N(c3ccc(-c4ccccc4)cc3)c3cccc4c3-c3ccccc3C4(c3ccccc3)c3cccc4c3oc3ccccc34)cc21]

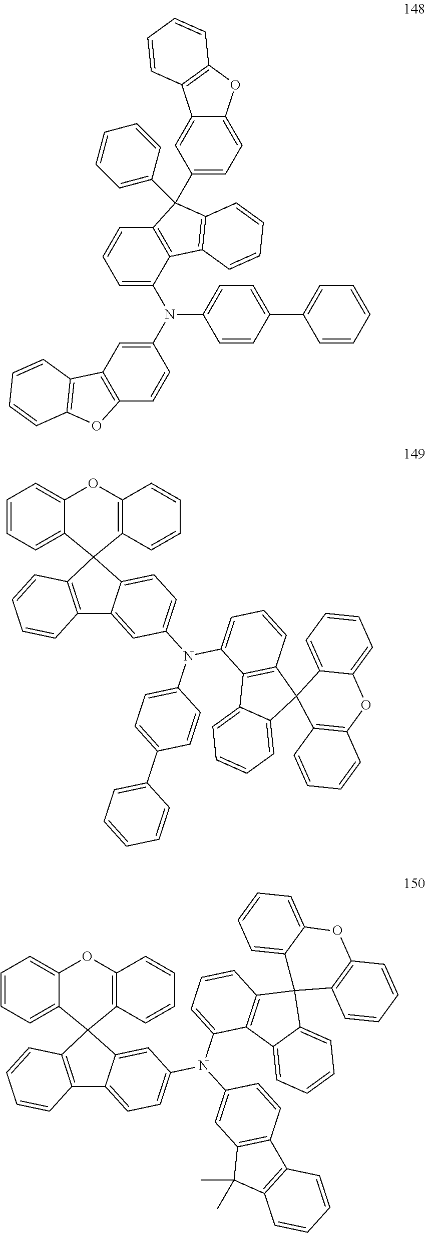 [SMILES: c1ccc(-c2ccc(N(c3ccc4oc5ccccc5c4c3)c3cccc4c3-c3ccccc3C4(c3ccccc3)c3ccc4oc5ccccc5c4c3)cc2)cc1 ; c1ccc(-c2ccc(N(c3ccc4c(c3)-c3ccccc3C43c4ccccc4Oc4ccccc43)c3cccc4c3-c3ccccc3C43c4ccccc4Oc4ccccc43)cc2)cc1 ; CC1(C)c2ccccc2-c2ccc(N(c3ccc4c(c3)C3(c5ccccc5Oc5ccccc53)c3ccccc3-4)c3cccc4c3-c3ccccc3C43c4ccccc4Oc4ccccc43)cc21]

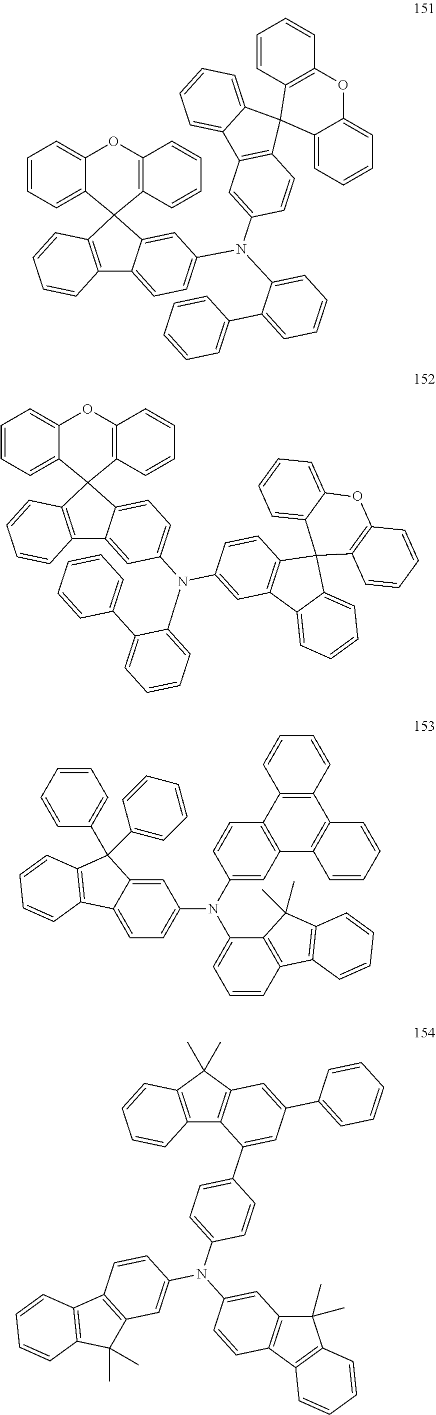 [SMILES: c1ccc(-c2ccccc2N(c2ccc3c(c2)-c2ccccc2C32c3ccccc3Oc3ccccc32)c2ccc3c(c2)C2(c4ccccc4Oc4ccccc42)c2ccccc2-3)cc1 ; c1ccc(-c2ccccc2N(c2ccc3c(c2)-c2ccccc2C32c3ccccc3Oc3ccccc32)c2ccc3c(c2)-c2ccccc2C32c3ccccc3Oc3ccccc32)cc1 ; CC1(C)c2ccccc2-c2cccc(N(c3ccc4c(c3)C(c3ccccc3)(c3ccccc3)c3ccccc3-4)c3ccc4c5ccccc5c5ccccc5c4c3)c21 ; CC1(C)c2ccccc2-c2ccc(N(c3ccc(-c4cc(-c5ccccc5)cc5c4-c4ccccc4C5(C)C)cc3)c3ccc4c(c3)C(C)(C)c3ccccc3-4)cc21]

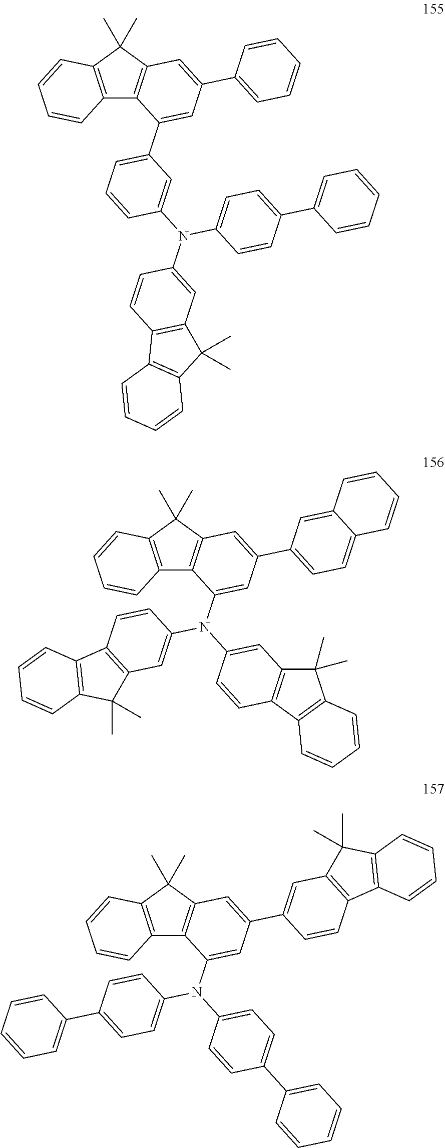 [SMILES: CC1(C)c2ccccc2-c2ccc(N(c3ccc(-c4ccccc4)cc3)c3cccc(-c4cc(-c5ccccc5)cc5c4-c4ccccc4C5(C)C)c3)cc21 ; CC1(C)c2ccccc2-c2ccc(N(c3ccc4c(c3)C(C)(C)c3ccccc3-4)c3cc(-c4ccc5ccccc5c4)cc4c3-c3ccccc3C4(C)C)cc21 ; CC1(C)c2ccccc2-c2ccc(-c3cc(N(c4ccc(-c5ccccc5)cc4)c4ccc(-c5ccccc5)cc4)c4c(c3)C(C)(C)c3ccccc3-4)cc21]

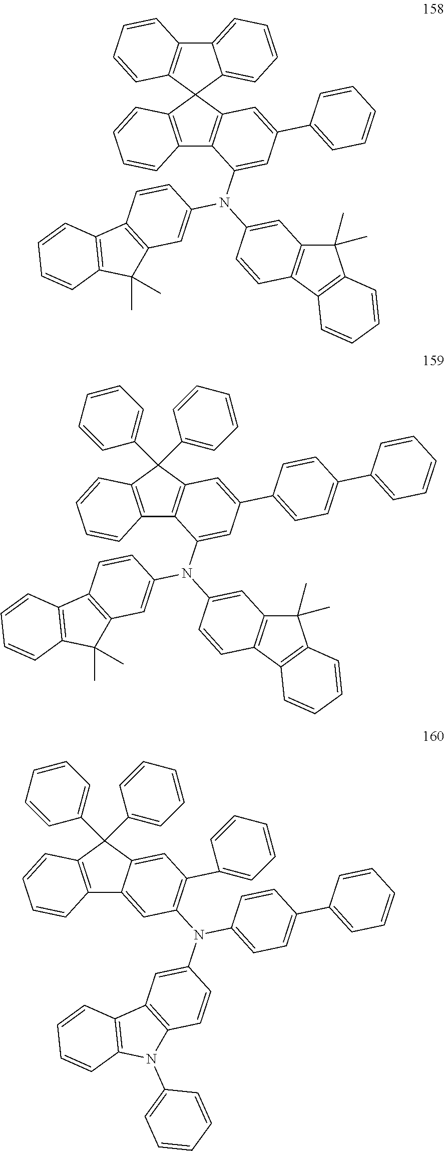 [SMILES: CC1(C)c2ccccc2-c2ccc(N(c3ccc4c(c3)C(C)(C)c3ccccc3-4)c3cc(-c4ccccc4)cc4c3-c3ccccc3C43c4ccccc4-c4ccccc43)cc21 ; CC1(C)c2ccccc2-c2ccc(N(c3ccc4c(c3)C(C)(C)c3ccccc3-4)c3cc(-c4ccc(-c5ccccc5)cc4)cc4c3-c3ccccc3C4(c3ccccc3)c3ccccc3)cc21 ; c1ccc(-c2ccc(N(c3ccc4c(c3)c3ccccc3n4-c3ccccc3)c3cc4c(cc3-c3ccccc3)C(c3ccccc3)(c3ccccc3)c3ccccc3-4)cc2)cc1]

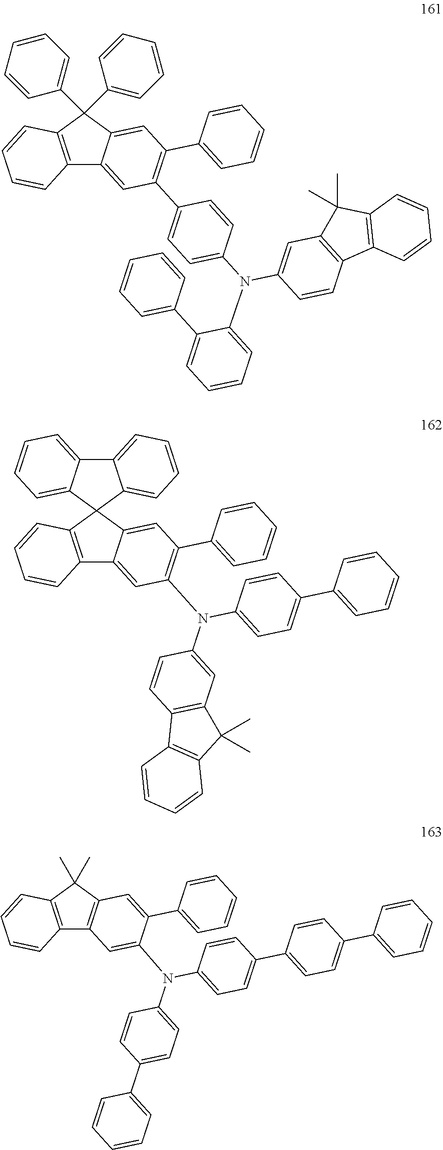 [SMILES: CC1(C)c2ccccc2-c2ccc(N(c3ccc(-c4cc5c(cc4-c4ccccc4)C(c4ccccc4)(c4ccccc4)c4ccccc4-5)cc3)c3ccccc3-c3ccccc3)cc21 ; CC1(C)c2ccccc2-c2ccc(N(c3ccc(-c4ccccc4)cc3)c3cc4c(cc3-c3ccccc3)C3(c5ccccc5-c5ccccc53)c3ccccc3-4)cc21 ; CC1(C)c2ccccc2-c2cc(N(c3ccc(-c4ccccc4)cc3)c3ccc(-c4ccc(-c5ccccc5)cc4)cc3)c(-c3ccccc3)cc21]

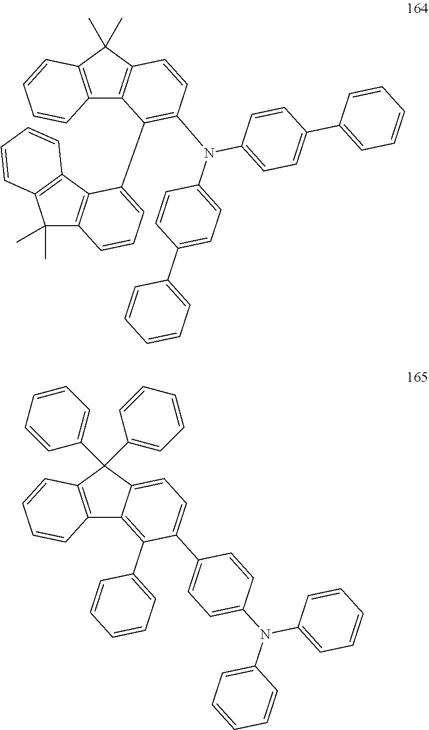

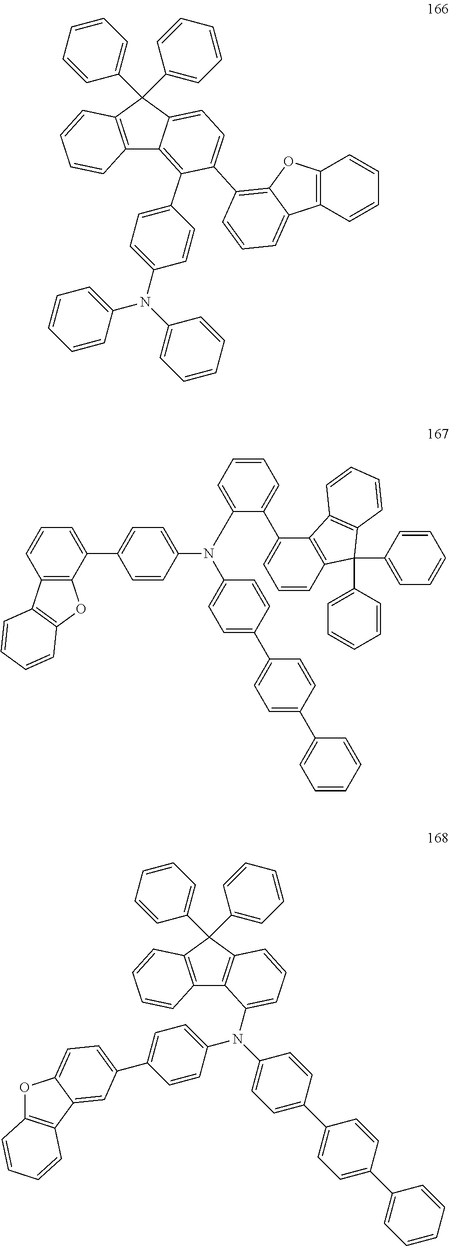 [SMILES: c1ccc(N(c2ccccc2)c2ccc(-c3c(-c4cccc5c4oc4ccccc45)ccc4c3-c3ccccc3C4(c3ccccc3)c3ccccc3)cc2)cc1 ; c1ccc(-c2ccc(-c3ccc(N(c4ccc(-c5cccc6c5oc5ccccc56)cc4)c4ccccc4-c4cccc5c4-c4ccccc4C5(c4ccccc4)c4ccccc4)cc3)cc2)cc1 ; c1ccc(-c2ccc(-c3ccc(N(c4ccc(-c5ccc6oc7ccccc7c6c5)cc4)c4cccc5c4-c4ccccc4C5(c4ccccc4)c4ccccc4)cc3)cc2)cc1]

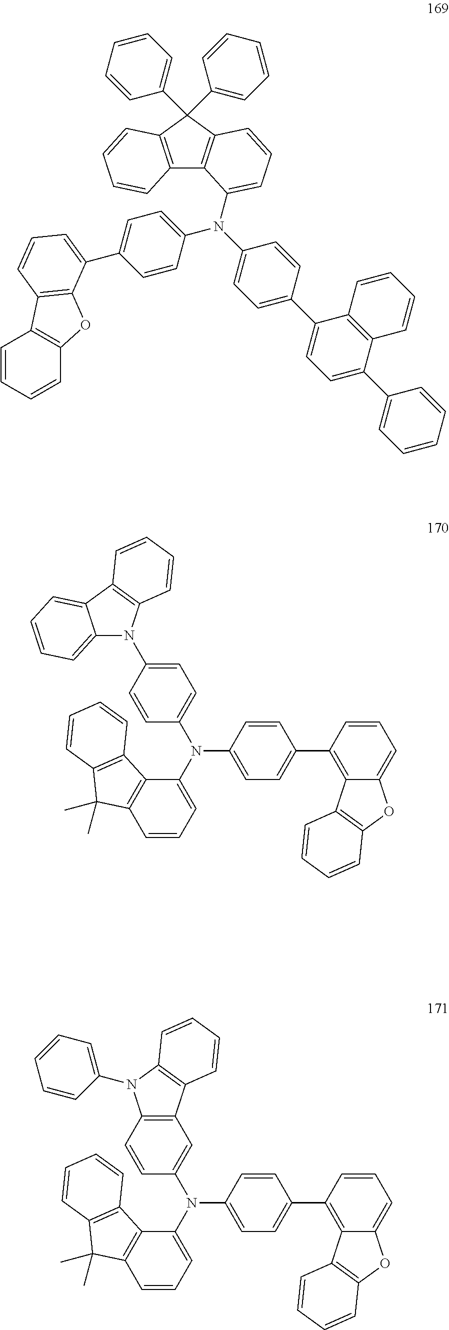 [SMILES: c1ccc(-c2ccc(-c3ccc(N(c4ccc(-c5cccc6c5oc5ccccc56)cc4)c4cccc5c4-c4ccccc4C5(c4ccccc4)c4ccccc4)cc3)c3ccccc23)cc1 ; CC1(C)c2ccccc2-c2c(N(c3ccc(-c4cccc5oc6ccccc6c45)cc3)c3ccc(-n4c5ccccc5c5ccccc54)cc3)cccc21 ; CC1(C)c2ccccc2-c2c(N(c3ccc(-c4cccc5oc6ccccc6c45)cc3)c3ccc4c(c3)c3ccccc3n4-c3ccccc3)cccc21]

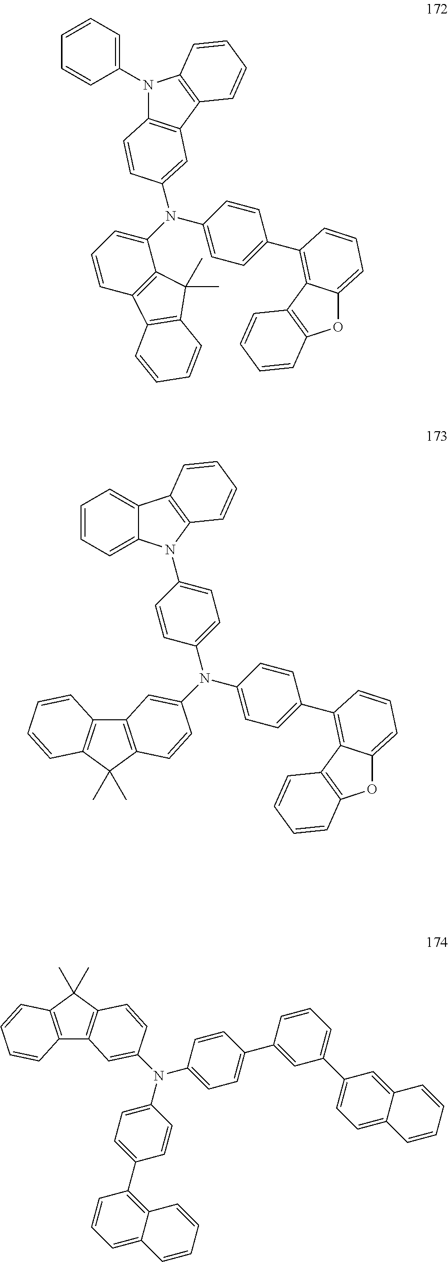 [SMILES: CC1(C)c2ccccc2-c2cccc(N(c3ccc(-c4cccc5oc6ccccc6c45)cc3)c3ccc4c(c3)c3ccccc3n4-c3ccccc3)c21 ; CC1(C)c2ccccc2-c2cc(N(c3ccc(-c4cccc5oc6ccccc6c45)cc3)c3ccc(-n4c5ccccc5c5ccccc54)cc3)ccc21 ; CC1(C)c2ccccc2-c2cc(N(c3ccc(-c4cccc(-c5ccc6ccccc6c5)c4)cc3)c3ccc(-c4cccc5ccccc45)cc3)ccc21]

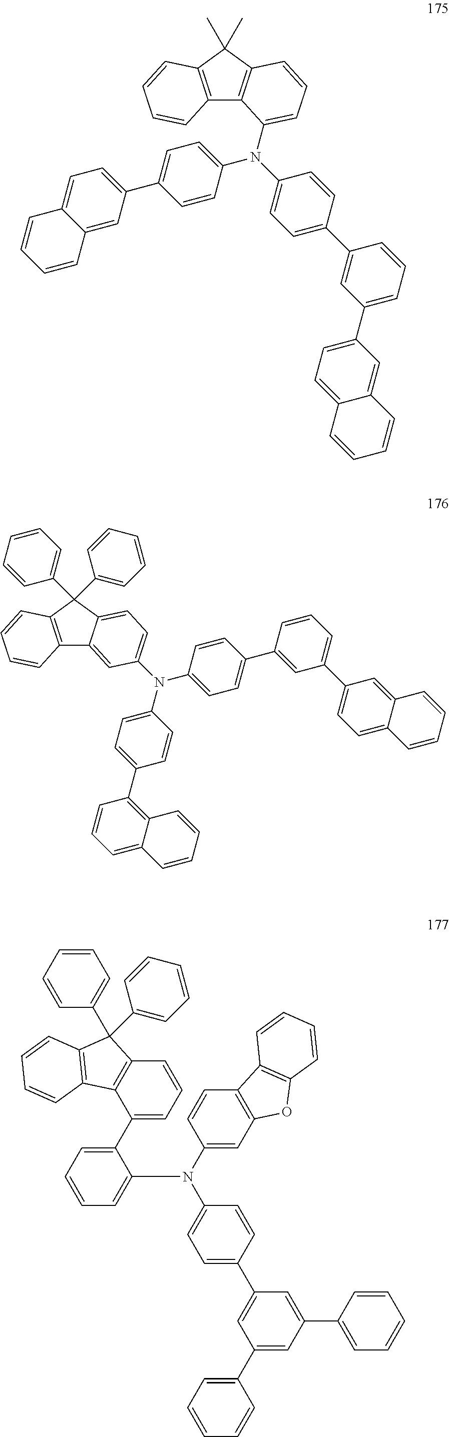 [SMILES: CC1(C)c2ccccc2-c2c(N(c3ccc(-c4cccc(-c5ccc6ccccc6c5)c4)cc3)c3ccc(-c4ccc5ccccc5c4)cc3)cccc21 ; c1ccc(C2(c3ccccc3)c3ccccc3-c3cc(N(c4ccc(-c5cccc(-c6ccc7ccccc7c6)c5)cc4)c4ccc(-c5cccc6ccccc56)cc4)ccc32)cc1 ; c1ccc(-c2cc(-c3ccccc3)cc(-c3ccc(N(c4ccc5c(c4)oc4ccccc45)c4ccccc4-c4cccc5c4-c4ccccc4C5(c4ccccc4)c4ccccc4)cc3)c2)cc1]

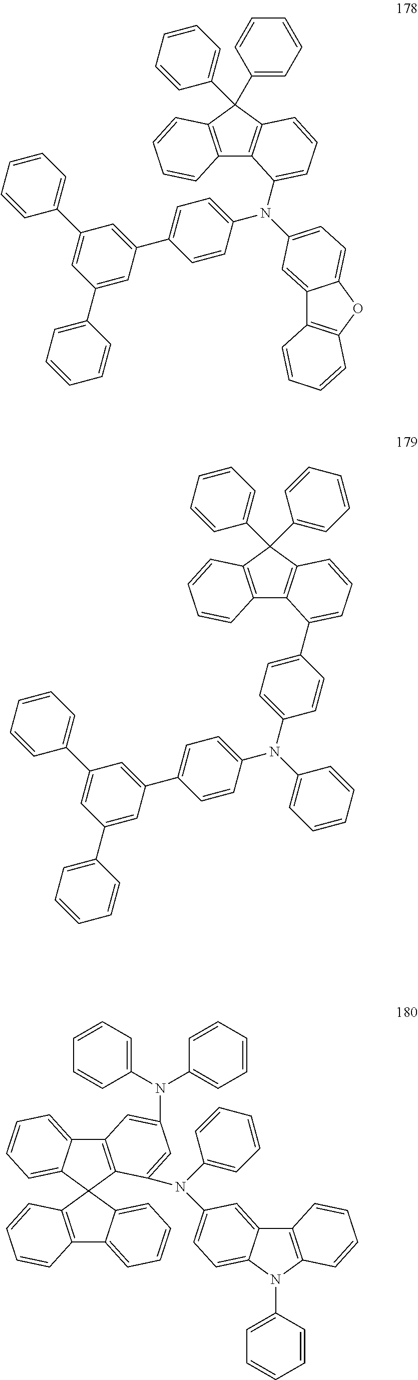 [SMILES: c1ccc(-c2cc(-c3ccccc3)cc(-c3ccc(N(c4ccc5oc6ccccc6c5c4)c4cccc5c4-c4ccccc4C5(c4ccccc4)c4ccccc4)cc3)c2)cc1 ; c1ccc(-c2cc(-c3ccccc3)cc(-c3ccc(N(c4ccccc4)c4ccc(-c5cccc6c5-c5ccccc5C6(c5ccccc5)c5ccccc5)cc4)cc3)c2)cc1 ; c1ccc(N(c2ccccc2)c2cc3c(c(N(c4ccccc4)c4ccc5c(c4)c4ccccc4n5-c4ccccc4)c2)C2(c4ccccc4-c4ccccc42)c2ccccc2-3)cc1]

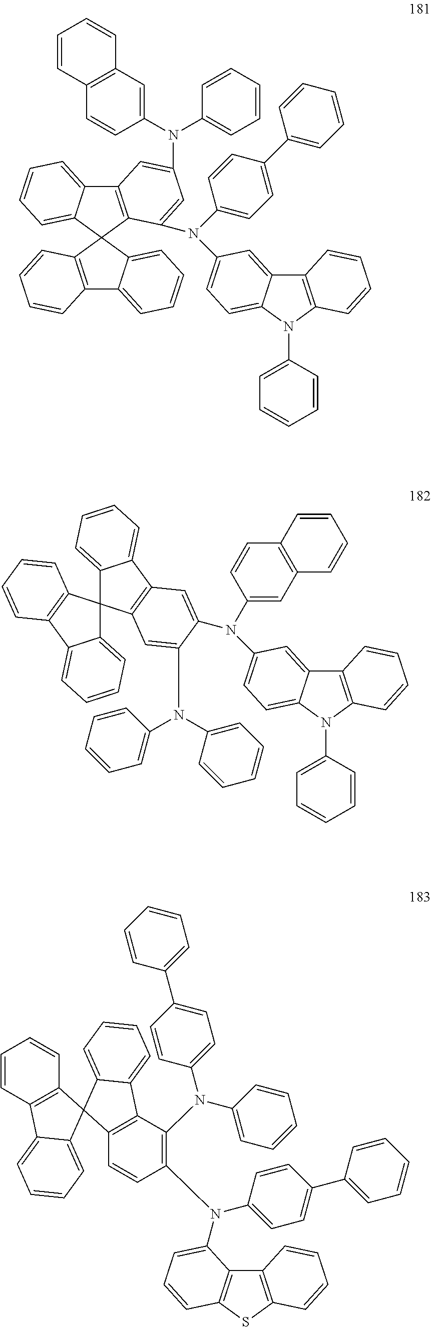 [SMILES: c1ccc(-c2ccc(N(c3ccc4c(c3)c3ccccc3n4-c3ccccc3)c3cc(N(c4ccccc4)c4ccc5ccccc5c4)cc4c3C3(c5ccccc5-c5ccccc53)c3ccccc3-4)cc2)cc1 ; c1ccc(N(c2ccccc2)c2cc3c(cc2N(c2ccc4ccccc4c2)c2ccc4c(c2)c2ccccc2n4-c2ccccc2)-c2ccccc2C32c3ccccc3-c3ccccc32)cc1 ; c1ccc(-c2ccc(N(c3ccccc3)c3c(N(c4ccc(-c5ccccc5)cc4)c4cccc5sc6ccccc6c45)ccc4c3-c3ccccc3C43c4ccccc4-c4ccccc43)cc2)cc1]

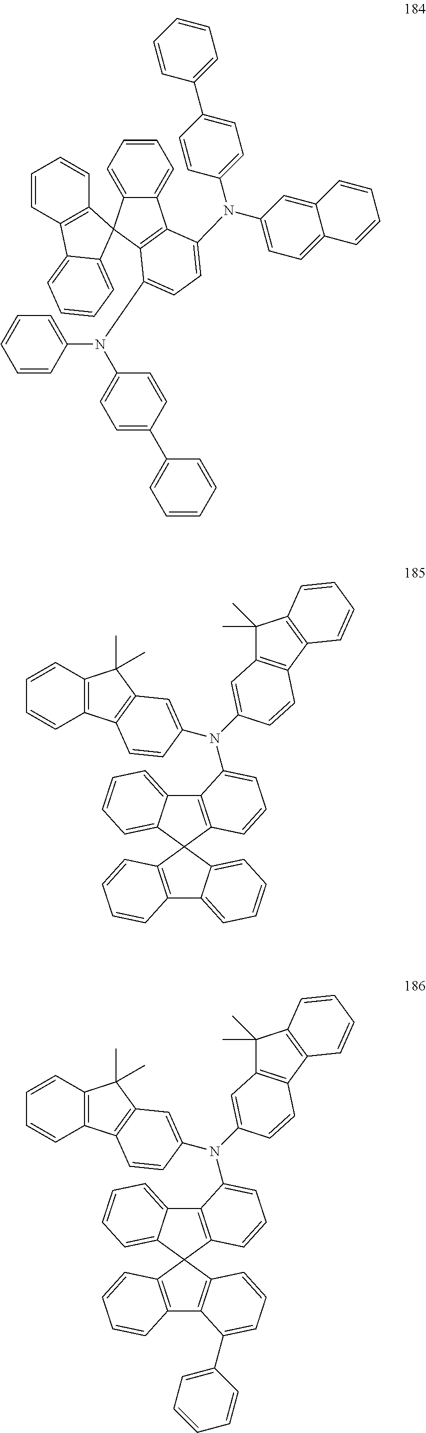 [SMILES: c1ccc(-c2ccc(N(c3ccc4ccccc4c3)c3ccc(N(c4ccccc4)c4ccc(-c5ccccc5)cc4)c4c3-c3ccccc3C43c4ccccc4-c4ccccc43)cc2)cc1 ; CC1(C)c2ccccc2-c2ccc(N(c3ccc4c(c3)C(C)(C)c3ccccc3-4)c3cccc4c3-c3ccccc3C43c4ccccc4-c4ccccc43)cc21 ; CC1(C)c2ccccc2-c2ccc(N(c3ccc4c(c3)C(C)(C)c3ccccc3-4)c3cccc4c3-c3ccccc3C43c4ccccc4-c4c(-c5ccccc5)cccc43)cc21]

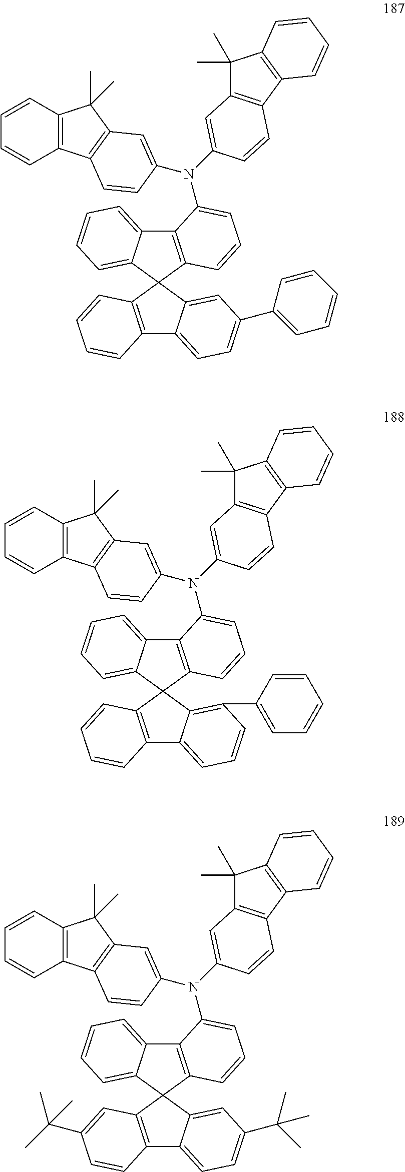 [SMILES: CC1(C)c2ccccc2-c2ccc(N(c3ccc4c(c3)C(C)(C)c3ccccc3-4)c3cccc4c3-c3ccccc3C43c4ccccc4-c4ccc(-c5ccccc5)cc43)cc21 ; CC1(C)c2ccccc2-c2ccc(N(c3ccc4c(c3)C(C)(C)c3ccccc3-4)c3cccc4c3-c3ccccc3C43c4ccccc4-c4cccc(-c5ccccc5)c43)cc21 ; CC(C)(C)c1ccc2c(c1)C1(c3cc(C(C)(C)C)ccc3-2)c2ccccc2-c2c(N(c3ccc4c(c3)C(C)(C)c3ccccc3-4)c3ccc4c(c3)C(C)(C)c3ccccc3-4)cccc21]

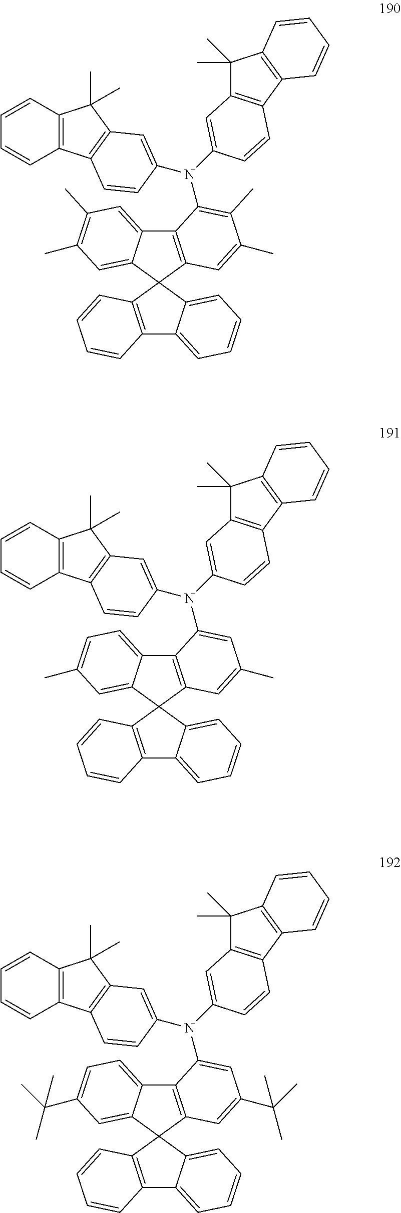 [SMILES: Cc1cc2c(cc1C)C1(c3ccccc3-c3ccccc31)c1cc(C)c(C)c(N(c3ccc4c(c3)C(C)(C)c3ccccc3-4)c3ccc4c(c3)C(C)(C)c3ccccc3-4)c1-2 ; Cc1ccc2c(c1)C1(c3ccccc3-c3ccccc31)c1cc(C)cc(N(c3ccc4c(c3)C(C)(C)c3ccccc3-4)c3ccc4c(c3)C(C)(C)c3ccccc3-4)c1-2 ; CC(C)(C)c1ccc2c(c1)C1(c3ccccc3-c3ccccc31)c1cc(C(C)(C)C)cc(N(c3ccc4c(c3)C(C)(C)c3ccccc3-4)c3ccc4c(c3)C(C)(C)c3ccccc3-4)c1-2]

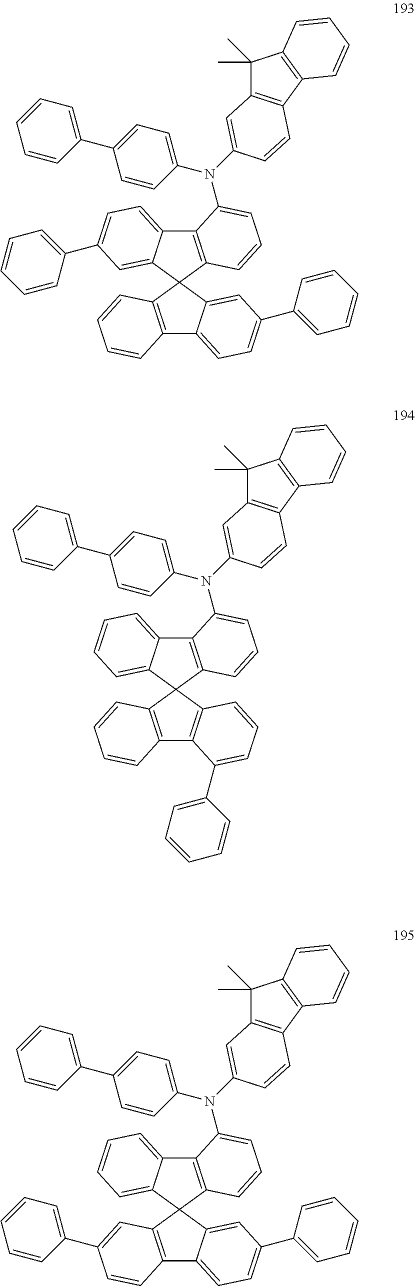 [SMILES: CC1(C)c2ccccc2-c2ccc(N(c3ccc(-c4ccccc4)cc3)c3cccc4c3-c3ccc(-c5ccccc5)cc3C43c4ccccc4-c4ccc(-c5ccccc5)cc43)cc21 ; CC1(C)c2ccccc2-c2ccc(N(c3ccc(-c4ccccc4)cc3)c3cccc4c3-c3ccccc3C43c4ccccc4-c4c(-c5ccccc5)cccc43)cc21 ; CC1(C)c2ccccc2-c2ccc(N(c3ccc(-c4ccccc4)cc3)c3cccc4c3-c3ccccc3C43c4cc(-c5ccccc5)ccc4-c4ccc(-c5ccccc5)cc43)cc21]

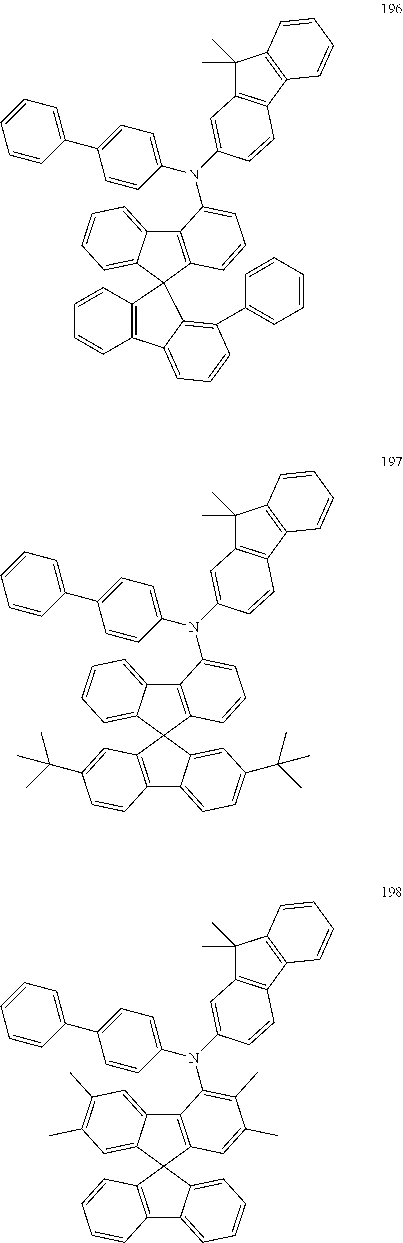 [SMILES: CC1(C)c2ccccc2-c2ccc(N(c3ccc(-c4ccccc4)cc3)c3cccc4c3-c3ccccc3C43c4ccccc4-c4cccc(-c5ccccc5)c43)cc21 ; CC(C)(C)c1ccc2c(c1)C1(c3cc(C(C)(C)C)ccc3-2)c2ccccc2-c2c(N(c3ccc(-c4ccccc4)cc3)c3ccc4c(c3)C(C)(C)c3ccccc3-4)cccc21 ; Cc1cc2c(cc1C)C1(c3ccccc3-c3ccccc31)c1cc(C)c(C)c(N(c3ccc(-c4ccccc4)cc3)c3ccc4c(c3)C(C)(C)c3ccccc3-4)c1-2]

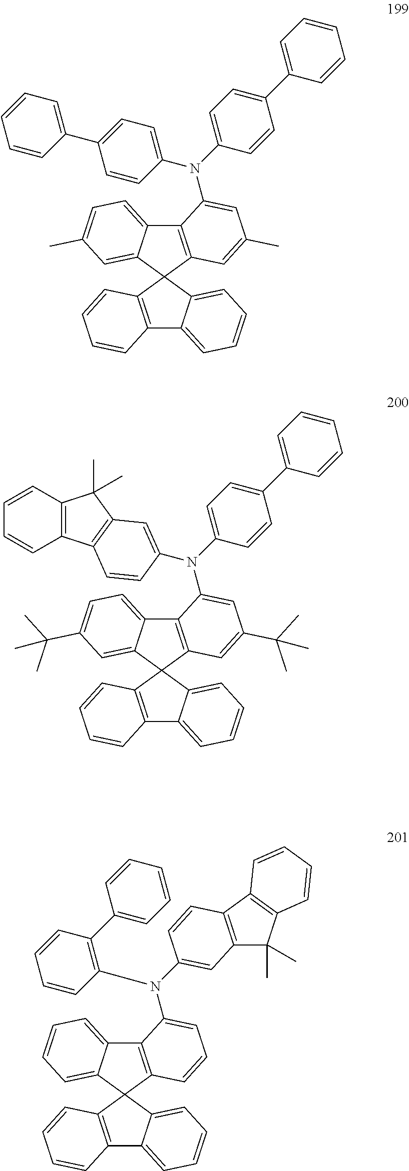 [SMILES: Cc1ccc2c(c1)C1(c3ccccc3-c3ccccc31)c1cc(C)cc(N(c3ccc(-c4ccccc4)cc3)c3ccc(-c4ccccc4)cc3)c1-2 ; CC(C)(C)c1ccc2c(c1)C1(c3ccccc3-c3ccccc31)c1cc(C(C)(C)C)cc(N(c3ccc(-c4ccccc4)cc3)c3ccc4c(c3)C(C)(C)c3ccccc3-4)c1-2 ; CC1(C)c2ccccc2-c2ccc(N(c3ccccc3-c3ccccc3)c3cccc4c3-c3ccccc3C43c4ccccc4-c4ccccc43)cc21]

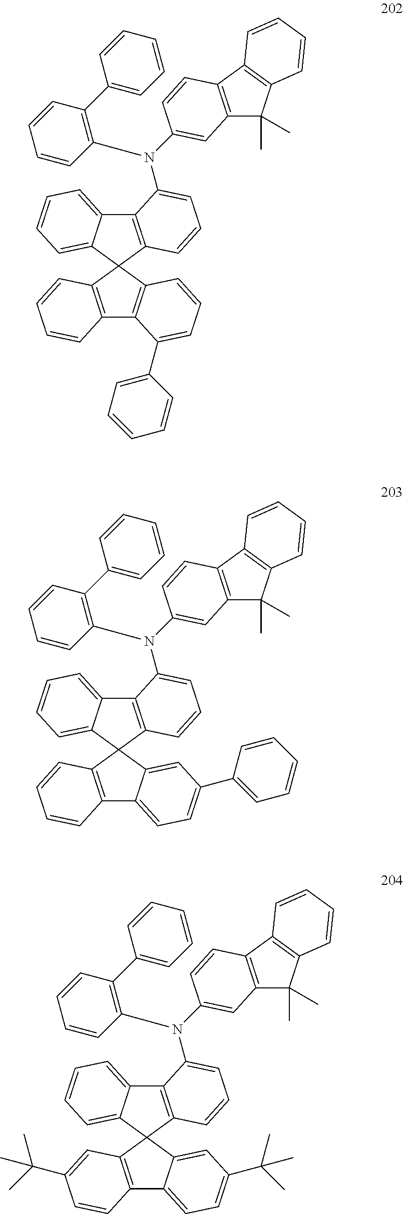 [SMILES: CC1(C)c2ccccc2-c2ccc(N(c3ccccc3-c3ccccc3)c3cccc4c3-c3ccccc3C43c4ccccc4-c4c(-c5ccccc5)cccc43)cc21 ; CC1(C)c2ccccc2-c2ccc(N(c3ccccc3-c3ccccc3)c3cccc4c3-c3ccccc3C43c4ccccc4-c4ccc(-c5ccccc5)cc43)cc21 ; CC(C)(C)c1ccc2c(c1)C1(c3cc(C(C)(C)C)ccc3-2)c2ccccc2-c2c(N(c3ccc4c(c3)C(C)(C)c3ccccc3-4)c3ccccc3-c3ccccc3)cccc21]

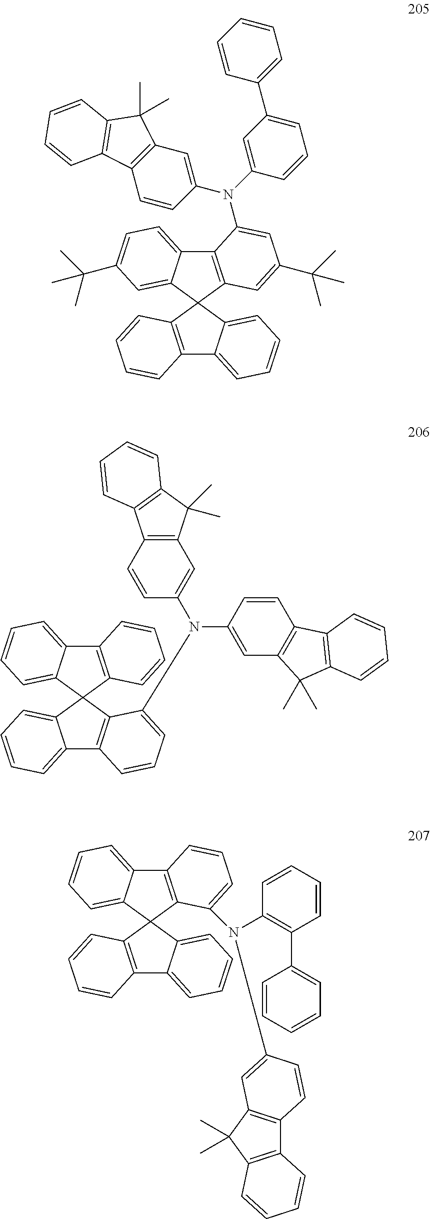 [SMILES: CC(C)(C)c1ccc2c(c1)C1(c3ccccc3-c3ccccc31)c1cc(C(C)(C)C)cc(N(c3cccc(-c4ccccc4)c3)c3ccc4c(c3)C(C)(C)c3ccccc3-4)c1-2 ; CC1(C)c2ccccc2-c2ccc(N(c3ccc4c(c3)C(C)(C)c3ccccc3-4)c3cccc4c3C3(c5ccccc5-c5ccccc53)c3ccccc3-4)cc21 ; CC1(C)c2ccccc2-c2ccc(N(c3ccccc3-c3ccccc3)c3cccc4c3C3(c5ccccc5-c5ccccc53)c3ccccc3-4)cc21]

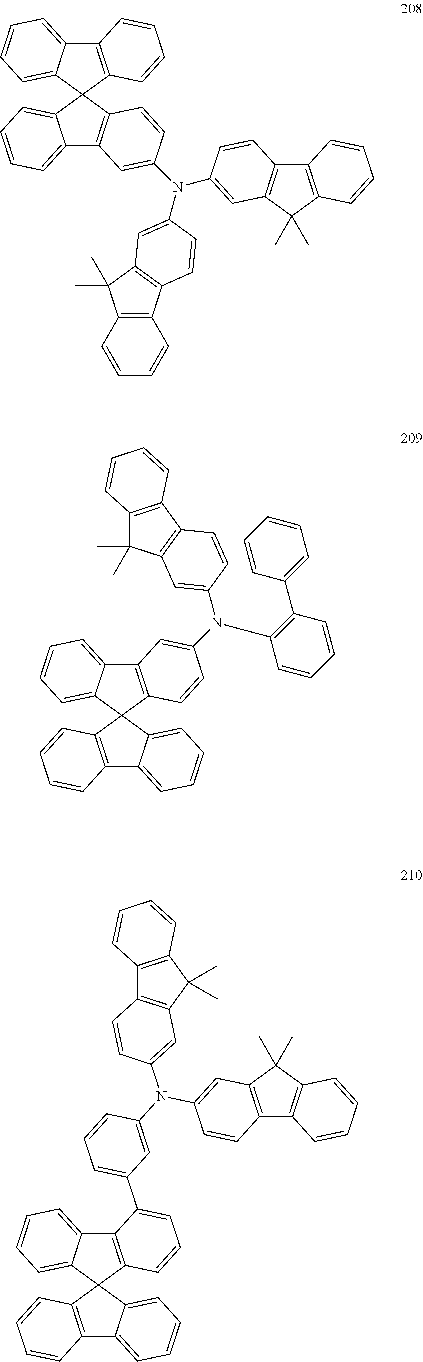 [SMILES: CC1(C)c2ccccc2-c2ccc(N(c3ccc4c(c3)-c3ccccc3C43c4ccccc4-c4ccccc43)c3ccc4c(c3)C(C)(C)c3ccccc3-4)cc21 ; CC1(C)c2ccccc2-c2ccc(N(c3ccc4c(c3)-c3ccccc3C43c4ccccc4-c4ccccc43)c3ccccc3-c3ccccc3)cc21 ; CC1(C)c2ccccc2-c2ccc(N(c3cccc(-c4cccc5c4-c4ccccc4C54c5ccccc5-c5ccccc54)c3)c3ccc4c(c3)C(C)(C)c3ccccc3-4)cc21]

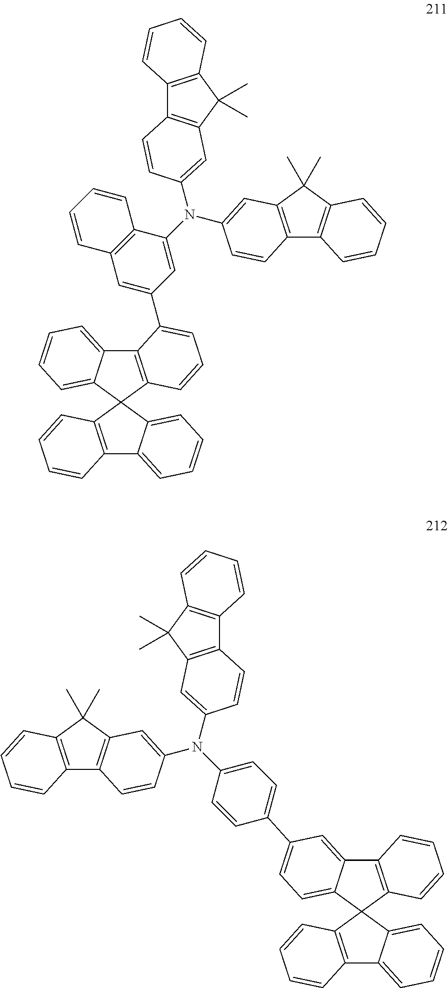 [SMILES: CC1(C)c2ccccc2-c2ccc(N(c3ccc4c(c3)C(C)(C)c3ccccc3-4)c3cc(-c4cccc5c4-c4ccccc4C54c5ccccc5-c5ccccc54)cc4ccccc34)cc21 ; CC1(C)c2ccccc2-c2ccc(N(c3ccc(-c4ccc5c(c4)-c4ccccc4C54c5ccccc5-c5ccccc54)cc3)c3ccc4c(c3)C(C)(C)c3ccccc3-4)cc21]

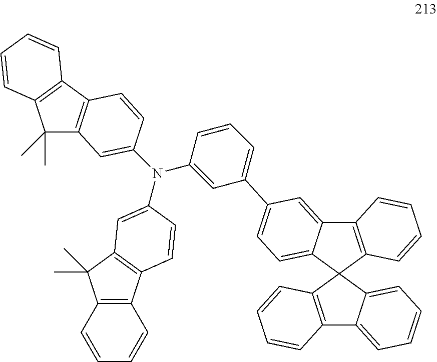 [SMILES: CC1(C)c2ccccc2-c2ccc(N(c3cccc(-c4ccc5c(c4)-c4ccccc4C54c5ccccc5-c5ccccc54)c3)c3ccc4c(c3)C(C)(C)c3ccccc3-4)cc21]

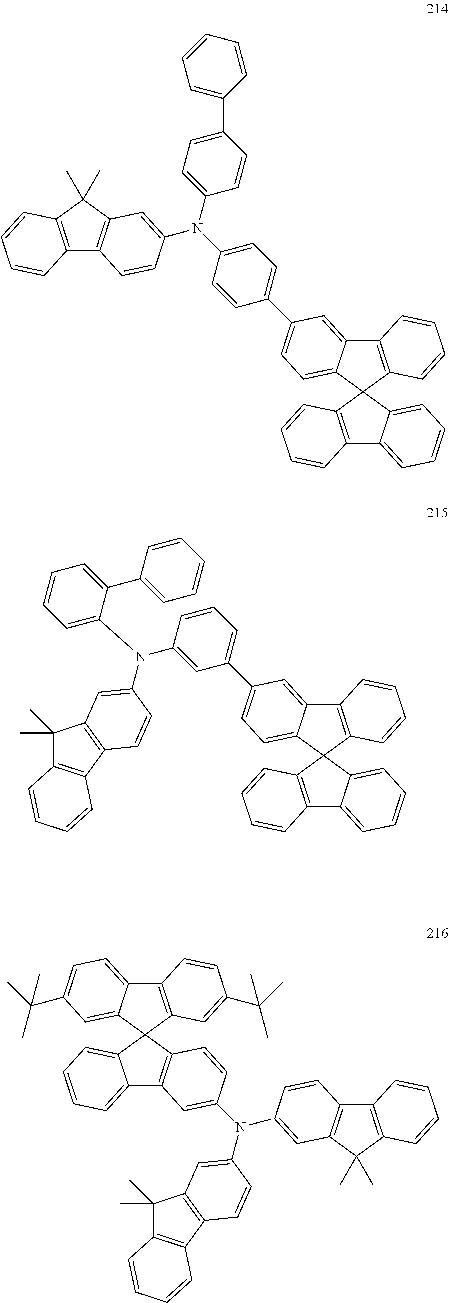

Processes for synthesis of the compounds of the formula (I) are known in the prior art, especially in the publications cited in the table below:

| Structure type | Publication |
|---|---|
| 4-Fluorenylamines | WO2007/072952; WO2019/168320 |
| 3-Fluorenylamines | WO2016/006710 |
| 4-Spirobifluorenylamines | KR20140045154A, WO2019/168320 |
| Spirobifluorenes with amino | WO2013/120577, WO2017/016632, |
| group in 1, 3 or 4 position | WO2017/102063, WO2017/102064 |
| Aminocarbazoles | WO2013/017192 |
| Spirobifluorenyldiamines | WO2016/078738, WO2017/061779 |
| 4-Spirobifluorenylamines with | WO2017/133829 |
| spacer group between | |
| spirobifluorenyl and amine | |

Formula (III) is preferred over formula (II) for the compound of the HTL2 layer.

In addition, T^{A} is preferably a single bond.

In addition, Z^{A1} is preferably CR^{A3}; where at least one CR^{A3} has a R^{A3}=

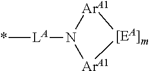

where the bond marked * is the bond to the carbon atom of this CR^{A3}group.

In a further preferred embodiment, 0, 1 or 2, more preferably 0 or 1 of the Z^{A1} groups, are N, and the remaining Z^{A1} groups are CR^{A3}.

Preferably, exactly one Z^{A1} group in formula (II) is CR^{A3} with R^{A3}=

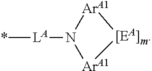

In addition, Z^{A2} is preferably CR^{A4}, where, in formula (III), Z^{A2} is C when the

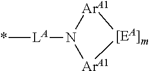

group is bonded thereto.

In a further preferred embodiment, 0, 1, 2 or 3, more preferably 0, 1 or 2, most preferably 0 or 1, of the Z^{A2} groups are N, and the remaining Z^{A2}groups are CR^{A4} or C in formula (III) when the

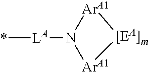

group is bonded thereto.

In a preferred embodiment, L^{A} is a single bond.

If L^{A} is selected from aromatic and heteroaromatic ring systems, L^{A} is preferably selected from the groups of the formulae Ar^{L}-1 to Ar^{L}-82, as listed above, where the dotted lines represent the bonds to the rest of the formula, and where the groups may bear one or more substituents R^{A5} other than H at the positions shown as being unsubstituted, and preferably bear H at the positions shown as being unsubstituted.

Preferably, index m is 0, i.e. the E^{A} group is absent, and the Ar¹ groups are not bonded to one another.

Ar^{A1} is preferably the same or different at each instance and is selected from groups of the formulae Ar¹-1 to Ar¹-270, as described above, where the dotted line represents the bond on the nitrogen atom, and where the groups may bear one or more substituents R^{A6} other than H at the positions shown as being unsubstituted, and preferably bear H at the positions shown as being unsubstituted. Particularly preferred among the groups of the formulae Ar¹-1 to Ar¹-270 specified above for Ar^{A1} are the groups of the formulae Ar¹-11 to Ar¹-7, Ar¹-48 to Ar¹-52, Ar¹-63 to Ar¹-84, Ar¹-107 to Ar¹-129, Ar¹-139 to Ar¹-158, Ar¹-172 to Ar¹-194, Ar¹-207 to Ar¹-218, and Ar¹-254 to Ar¹-261.

In a preferred embodiment, Ar^{A1} is not optionally substituted 4-spirobifluorenyl. In a particularly preferred embodiment, Ar^{A1} does not contain optionally substituted 4-spirobifluorenyl.

In an alternative preferred embodiment, at least one Ar^{A1} is selected from the following formulae:

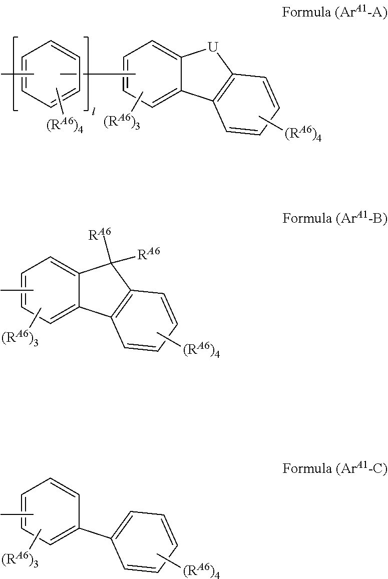

where i is 0, 1, 2, 3 or 4, U is O, S, or NR^{A6}, and the other groups that occur are as defined above.

Formula (Ar^{A1}-A) here preferably corresponds to the following formula (Ar^{A1}-A-1):

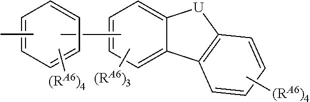

Formula (Ar^{A1}—B) here preferably corresponds to the following formula (Ar^{A1}—B-1):

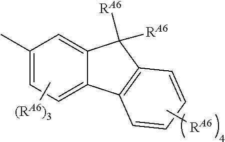

Formula (Ar^{A1}—C) here preferably corresponds to the following formula (Ar^{A1}—C-1):

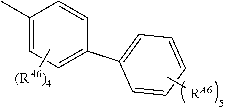

R^{A1} is preferably the same or different at each instance and is selected from H, D, F, CN, Si(R^{A8})₃, N(R^{A8})₂, straight-chain alkyl or alkoxy groups having 1 to 20 carbon atoms, branched or cyclic alkyl or alkoxy groups having 3 to 20 carbon atoms, aromatic ring systems having 6 to 40 aromatic ring atoms and heteroaromatic ring systems having 5 to 40 aromatic ring atoms; where the alkyl and alkoxy groups mentioned, the aromatic ring systems mentioned and the heteroaromatic ring systems mentioned are each substituted by R^{A8} radicals; and where one or more CH₂ groups in the alkyl or alkoxy groups mentioned may be replaced by —C≡C—, —R^{A8}C=CR^{A8}—, Si(R^{A8})₂, C=O, C=NR^{A8}, —NR^{A8}—, —O—, —S—, —C(═O)O— or —C(═O)NR^{A8}—. More preferably, R¹ is the same or different at each instance and is selected from straight-chain alkyl groups having 1 to 20 carbon atoms, from branched or cyclic alkyl groups having 3 to 20 carbon atoms, and from aromatic ring systems having 6 to 40 aromatic ring atoms; most preferably, R^{A1} is the same or different at each instance and is selected from methyl and phenyl.

R^{A3} is preferably the same or different at each instance and is selected from a group

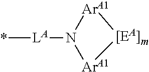

bonded via the bond marked * to the carbon atom of the Z^{A1} group, H, D, F, CN, Si(R^{A8})₃, straight-chain alkyl or alkoxy groups having 1 to 20 carbon atoms, branched or cyclic alkyl or alkoxy groups having 3 to 20 carbon atoms, aromatic ring systems having 6 to 40 aromatic ring atoms and heteroaromatic ring systems having 5 to 40 aromatic ring atoms; where the alkyl and alkoxy groups mentioned, the aromatic ring systems mentioned and the heteroaromatic ring systems mentioned are each substituted by R^{A8} radicals; and where one or more CH₂ groups in the alkyl or alkoxy groups mentioned may be replaced by —C≡C—, —R^{A8}C=CR^{A8}—, Si(R^{A8})₂, C=O, C=NR^{A8}, —NR^{A8}—, O—, —S—, —C(═O)O— or —C(═O)NR^{A8}—. More preferably, R^{A3} is the same or different at each instance and is selected from a group

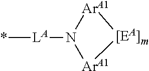

bonded via the bond marked * to the carbon atom of the Z^{A1} group, H, D, and aromatic ring systems which have 6 to 40 aromatic ring atoms and are each substituted by R^{A8} radicals. Most preferably, R^{A3} is the same or different at each instance and is selected from a group

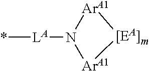

bonded via the bond marked * to the carbon atom of the Z^{A1} group, and H or D, especially H.

R^{A4} is preferably the same or different at each instance and is selected from H, D, F, CN, Si(R^{A8})₃, straight-chain alkyl or alkoxy groups having 1 to 20 carbon atoms, branched or cyclic alkyl or alkoxy groups having 3 to 20 carbon atoms, aromatic ring systems having 6 to 40 aromatic ring atoms and heteroaromatic ring systems having 5 to 40 aromatic ring atoms; where the alkyl and alkoxy groups mentioned, the aromatic ring systems mentioned and the heteroaromatic ring systems mentioned are each substituted by R^{A8} radicals; and where one or more CH₂ groups in the alkyl or alkoxy groups mentioned may be replaced by —C═C—, —R^{A8}C=CR^{A8}—, Si(R^{A8})₂, C=O, C=NR^{A8}, —NR^{A8}—, —O—, —S—, —C(═O)O— or —C(═O)NR^{A8}—. More preferably, R^{A4} is H or D, especially H.

R^{A5}, R^{A6} are preferably the same or different at each instance and are selected from H, D, F, CN, Si(R^{A8})₃, N(R^{A8})₂, straight-chain alkyl or alkoxy groups having 1 to 20 carbon atoms, branched or cyclic alkyl or alkoxy groups having 3 to 20 carbon atoms, aromatic ring systems having 6 to 40 aromatic ring atoms and heteroaromatic ring systems having 5 to 40 aromatic ring atoms; where the alkyl and alkoxy groups mentioned, the aromatic ring systems mentioned and the heteroaromatic ring systems mentioned are each substituted by R^{A8} radicals; and where one or more CH₂ groups in the alkyl or alkoxy groups mentioned may be replaced by —C═C—, —R^{A8}C=CR^{A8}—, Si(R^{A8})₂, C=O, C=NR^{A8}, —NR^{A8}—, —S—, —C(═O)O— or —C(═O)NR^{A8}—. More preferably, R^{A5}, R^{A6} is the same or different at each instance and is selected from H, D, straight-chain alkyl groups having 1 to 20 carbon atoms, branched or cyclic alkyl groups having 3 to 20 carbon atoms and aromatic ring systems having 6 to 40 aromatic ring atoms.

Preferably, R^{A8} is the same or different at each instance and is selected from H, D, F, CN, Si(R^{A9})₃, N(R^{A9})₂, straight-chain alkyl or alkoxy groups having 1 to 20 carbon atoms, branched or cyclic alkyl or alkoxy groups having 3 to 20 carbon atoms, aromatic ring systems having 6 to 40 aromatic ring atoms and heteroaromatic ring systems having 5 to 40 aromatic ring atoms; where the alkyl and alkoxy groups mentioned, the aromatic ring systems mentioned and the heteroaromatic ring systems mentioned are each substituted by R^{A9} radicals; and where one or more CH₂ groups in the alkyl or alkoxy groups mentioned may be replaced by —C═C—, —R^{A9}C=CR^{A9}—, Si(R^{A9})₂, C=O, C=NR^{A9}, —NR^{A9}—, —O—, —S—, —C(═O)O— or —C(═O)NR^{A9}—. More preferably, R^{A8} is the same or different at each instance and is selected from H, D, F, CN, straight-chain alkyl or alkoxy groups having 1 to 20 carbon atoms, branched or cyclic alkyl or alkoxy groups having 3 to 20 carbon atoms, aromatic ring systems having 6 to 40 aromatic ring atoms and heteroaromatic ring systems having 5 to 40 aromatic ring atoms; where said alkyl or alkoxy groups, said aromatic ring systems and said heteroaromatic ring systems are each substituted by R^{A9}radicals. Most preferably, R^{A8} is H or D, especially H.

Formula (II) preferably conforms to a formula (II-1)

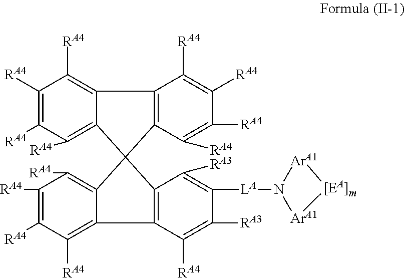

where the symbols and indices that occur are as defined above, and preferably correspond to their preferred embodiments.

In particular, it is preferable for formula (II-1) that
L^{A} is selected from a single bond and an aromatic ring system which has 6 to 40 aromatic ring atoms and is substituted by R^{A5} radicals
m is 0;
R^{A3} is the same or different at each instance and is selected from H, D, F, CN, Si(R^{A8})₃, straight-chain alkyl or alkoxy groups having 1 to 20 carbon atoms, branched or cyclic alkyl or alkoxy groups having 3 to 20 carbon atoms, aromatic ring systems having 6 to 40 aromatic ring atoms and heteroaromatic ring systems having 5 to 40 aromatic ring atoms; where the alkyl and alkoxy groups mentioned, the aromatic ring systems mentioned and the heteroaromatic ring systems mentioned are each substituted by R^{A8} radicals; and where one or more CH₂ groups in the alkyl or alkoxy groups mentioned may be replaced by —C≡C—, —R^{A8}C=CR^{A8}—, Si(R^{A8})₂, C=O, C=NR^{A8}, —NR^{A8}, —O—, —S—, —C(═O)O— or —C(═O)NR^{A8}—;
R^{A4} is the same or different at each instance and is selected from H, D, F, CN, Si(R^{A8})₃, straight-chain alkyl or alkoxy groups having 1 to 20 carbon atoms, branched or cyclic alkyl or alkoxy groups having 3 to 20 carbon atoms, aromatic ring systems having 6 to 40 aromatic ring atoms and heteroaromatic ring systems having 5 to 40 aromatic ring atoms; where the alkyl and alkoxy groups mentioned, the aromatic ring systems mentioned and the heteroaromatic ring systems mentioned are each substituted by R^{A8} radicals; and where one or more CH₂ groups in the alkyl or alkoxy groups mentioned may be replaced by —C≡C—, —R^{A8}C=CR^{A8}—, Si(R^{A8})₂, C=O, C=NR^{A8}, —NR^{A8}, —O—, —S—, —C(═O)O— or —C(═O)NR^{A8}—;
R^{A8} is the same or different at each instance and is selected from H, D, F, CN, straight-chain alkyl or alkoxy groups having 1 to 20 carbon atoms, branched or cyclic alkyl or alkoxy groups having 3 to 20 carbon atoms, aromatic ring systems having 6 to 40 aromatic ring atoms and heteroaromatic ring systems having 5 to 40 aromatic ring atoms; where said alkyl and alkoxy groups, said aromatic ring systems and said heteroaromatic ring systems are each substituted by R^{A9} radicals.

Again in particular, it is preferable for formula (II-1) that
L^{A} is selected from a single bond and aromatic ring system which has 6 to 40 aromatic ring atoms and is substituted by R^{A5} radicals;
m is 0;
RA³ is H or D;
RA⁴ is H or D.

Formula (III) preferably corresponds to a formula (III-1)

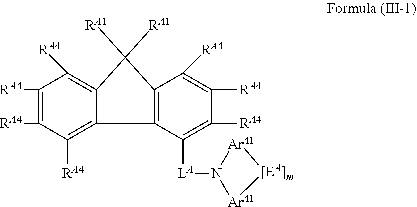

where the symbols and indices that occur are as defined above, and preferably correspond to their preferred embodiments.

In particular, it is preferable for formula (III-1) that
L^{A} is selected from a single bond and aromatic ring system which has 6 to 40 aromatic ring atoms and is substituted by R^{A5} radicals;
m is 0;
R^{A4} is the same or different at each instance and is selected from H, D, F, CN, Si(R^{A8})₃, straight-chain alkyl or alkoxy groups having 1 to 20 carbon atoms, branched or cyclic alkyl or alkoxy groups having 3 to 20 carbon atoms, aromatic ring systems having 6 to 40 aromatic ring atoms and heteroaromatic ring systems having 5 to 40 aromatic ring atoms; where the alkyl and alkoxy groups mentioned, the aromatic ring systems mentioned and the heteroaromatic ring systems mentioned are each substituted by R^{A8} radicals; and where one or more CH₂ groups in the alkyl or alkoxy groups mentioned may be replaced by —C≡C—, —R^{A8}C=CR^{A8}—, Si(R^{A8})₂, C=O, C=NR^{A8}, —NR^{A8}, —O—, —S—, —C(═O)O— or —C(═O)NR^{A8}—.
R^{A8} is the same or different at each instance and is selected from H, D, F, CN, straight-chain alkyl or alkoxy groups having 1 to 20 carbon atoms, branched or cyclic alkyl or alkoxy groups having 3 to 20 carbon atoms, aromatic ring systems having 6 to 40 aromatic ring atoms and heteroaromatic ring systems having 5 to 40 aromatic ring atoms; where said alkyl or alkoxy groups, said aromatic ring systems and said heteroaromatic ring systems are each substituted by R^{A9} radicals.

Again in particular, it is preferable for formula (Ill-1) that
L^{A} is selected from a single bond and aromatic ring system which has 6 to 40 aromatic ring atoms and is substituted by R^{A5} radicals;
m is 0;
RA⁴ is H or D.

Among the formulae (II-1) and (III-1), the formula (III-1) is particularly preferred.

The compound selected from compounds of the formulae (II) and (III) preferably has a HOMO of lower than −5.05 eV, more preferably of lower than −5.10 eV, even more preferably of lower than −5.15 eV, and most preferably of lower than −5.20 eV. When the compound of the formula (II) or (III) is arranged so as to adjoin a green-phosphorescing emitting layer on the anode side, it preferably has a HOMO of lower than −5.05 eV, more preferably of lower than −5.10 eV, most preferably of lower than −5.15 eV. When the compound of the formula (II) or (III) is arranged so as to adjoin a blue-fluorescing emitting layer on the anode side, it preferably has a HOMO of lower than −5.10 eV, more preferably of lower than −5.15 eV, most preferably of lower than −5.20 eV. The HOMO is determined here as specified in example 1 of the working examples of WO2021/028513.

Preferred compounds of the formulae (II) and (Ill) are depicted below:

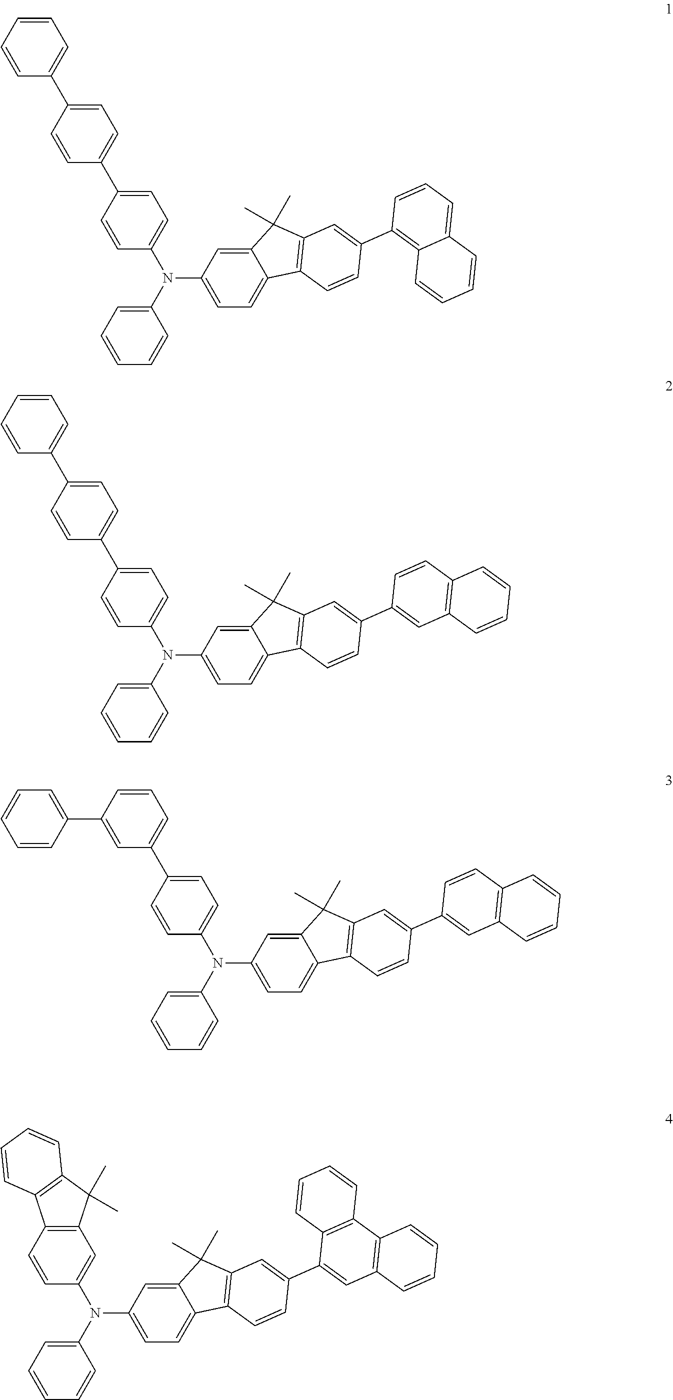 [SMILES: CC1(C)c2cc(-c3cccc4ccccc34)ccc2-c2ccc(N(c3ccccc3)c3ccc(-c4ccc(-c5ccccc5)cc4)cc3)cc21 ; CC1(C)c2cc(-c3ccc4ccccc4c3)ccc2-c2ccc(N(c3ccccc3)c3ccc(-c4ccc(-c5ccccc5)cc4)cc3)cc21 ; CC1(C)c2cc(-c3ccc4ccccc4c3)ccc2-c2ccc(N(c3ccccc3)c3ccc(-c4cccc(-c5ccccc5)c4)cc3)cc21 ; CC1(C)c2ccccc2-c2ccc(N(c3ccccc3)c3ccc4c(c3)C(C)(C)c3cc(-c5cc6ccccc6c6ccccc56)ccc3-4)cc21]

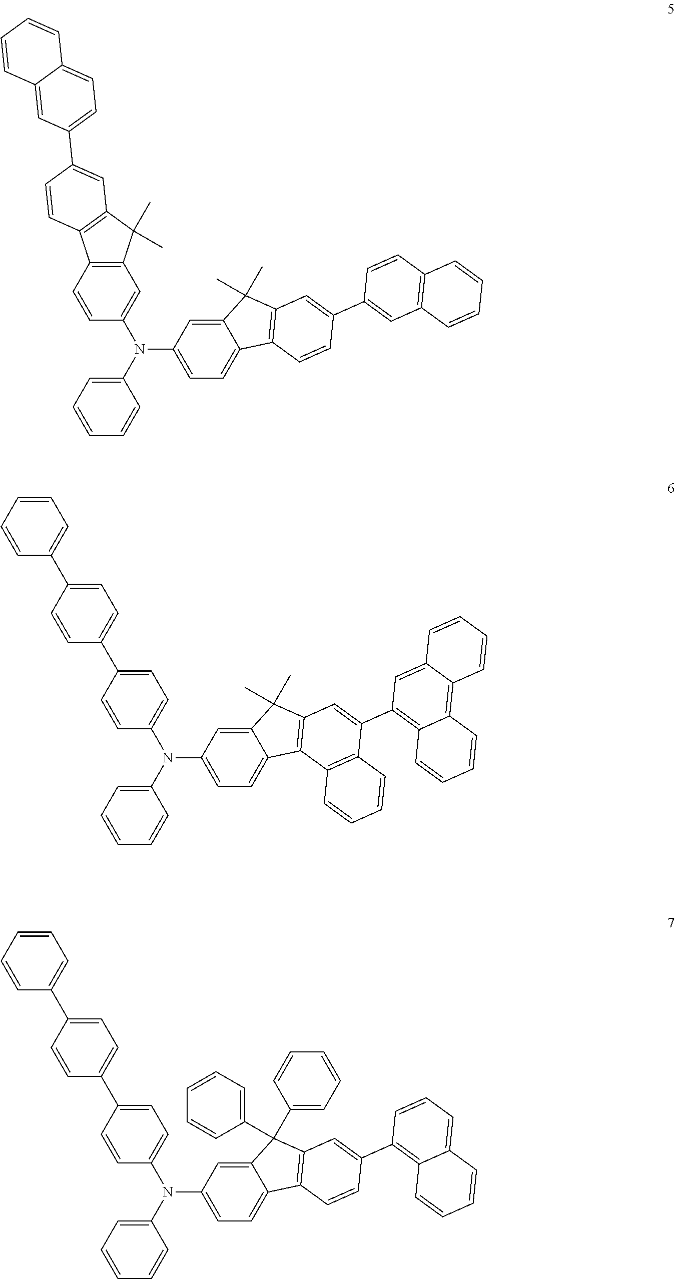 [SMILES: CC1(C)c2cc(-c3ccc4ccccc4c3)ccc2-c2ccc(N(c3ccccc3)c3ccc4c(c3)C(C)(C)c3cc(-c5ccc6ccccc6c5)ccc3-4)cc21 ; CC1(C)c2cc(N(c3ccccc3)c3ccc(-c4ccc(-c5ccccc5)cc4)cc3)ccc2-c2c1cc(-c1cc3ccccc3c3ccccc13)c1ccccc21 ; c1ccc(-c2ccc(-c3ccc(N(c4ccccc4)c4ccc5c(c4)C(c4ccccc4)(c4ccccc4)c4cc(-c6cccc7ccccc67)ccc4-5)cc3)cc2)cc1]

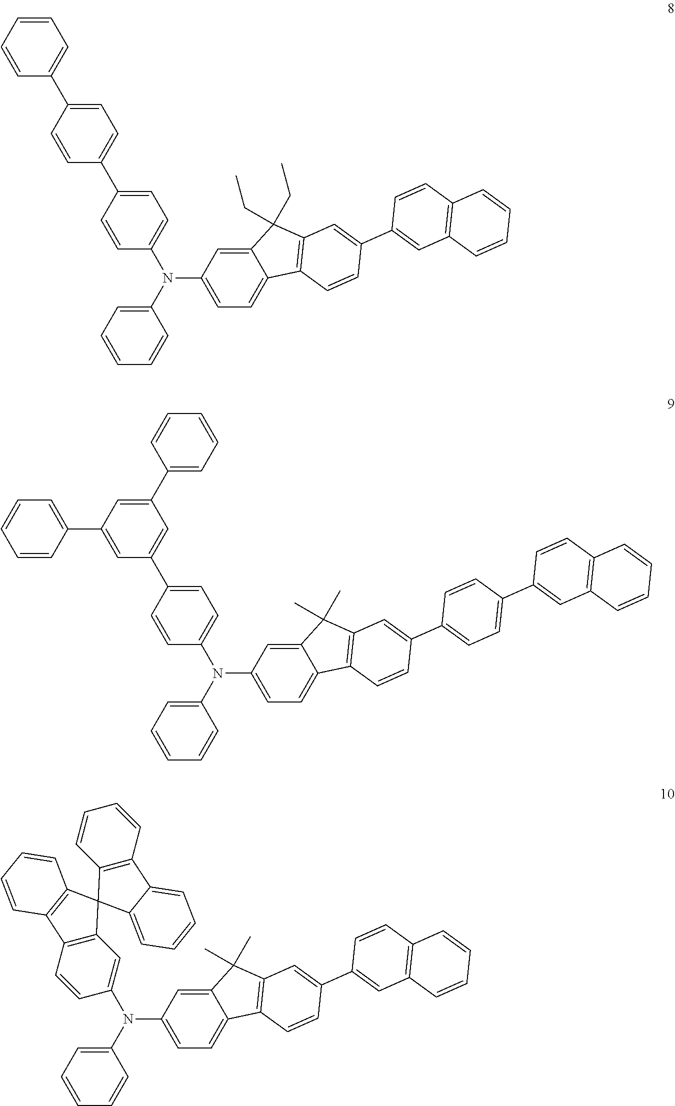 [SMILES: CCC1(CC)c2cc(-c3ccc4ccccc4c3)ccc2-c2ccc(N(c3ccccc3)c3ccc(-c4ccc(-c5ccccc5)cc4)cc3)cc21 ; CC1(C)c2cc(-c3ccc(-c4ccc5ccccc5c4)cc3)ccc2-c2ccc(N(c3ccccc3)c3ccc(-c4cc(-c5ccccc5)cc(-c5ccccc5)c4)cc3)cc21 ; CC1(C)c2cc(-c3ccc4ccccc4c3)ccc2-c2ccc(N(c3ccccc3)c3ccc4c(c3)C3(c5ccccc5-c5ccccc53)c3ccccc3-4)cc21]

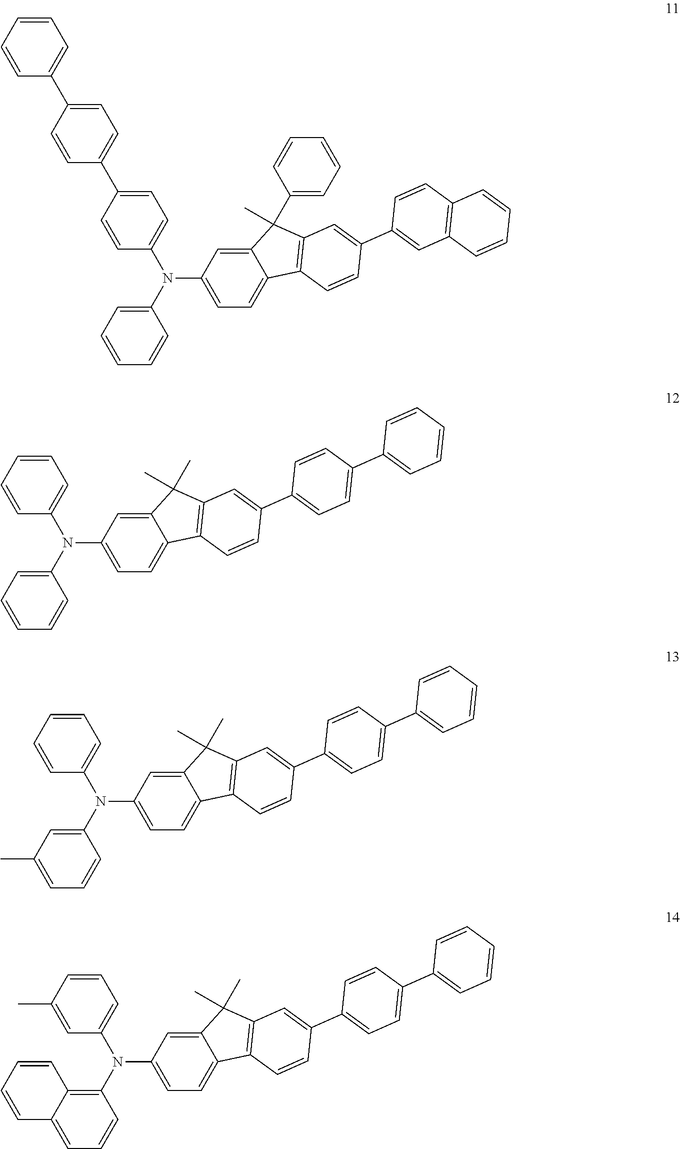 [SMILES: CC1(c2ccccc2)c2cc(-c3ccc4ccccc4c3)ccc2-c2ccc(N(c3ccccc3)c3ccc(-c4ccc(-c5ccccc5)cc4)cc3)cc21 ; CC1(C)c2cc(-c3ccc(-c4ccccc4)cc3)ccc2-c2ccc(N(c3ccccc3)c3ccccc3)cc21 ; Cc1cccc(N(c2ccccc2)c2ccc3c(c2)C(C)(C)c2cc(-c4ccc(-c5ccccc5)cc4)ccc2-3)c1 ; Cc1cccc(N(c2ccc3c(c2)C(C)(C)c2cc(-c4ccc(-c5ccccc5)cc4)ccc2-3)c2cccc3ccccc23)c1]

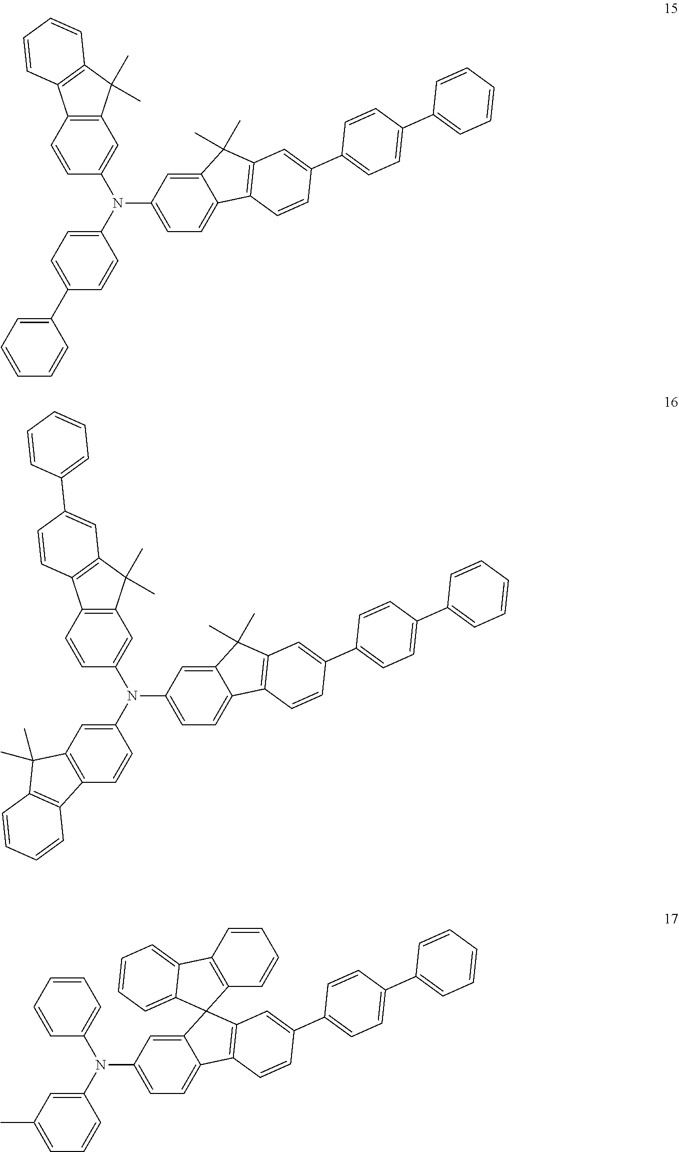

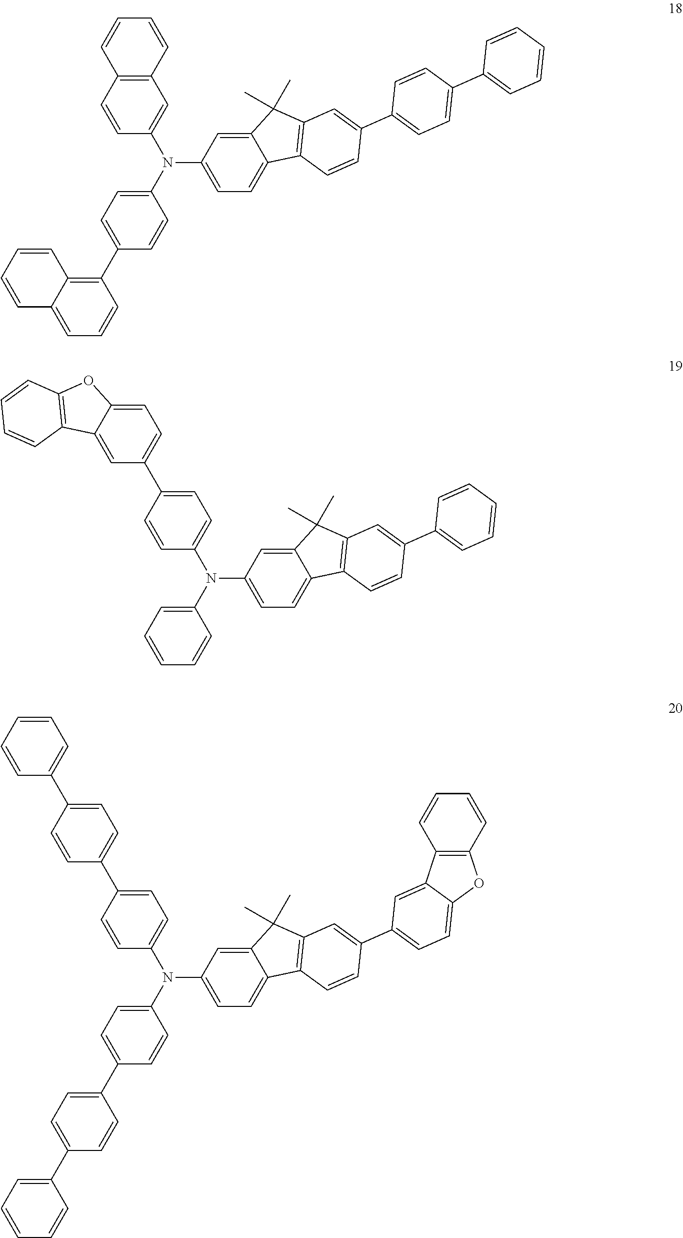

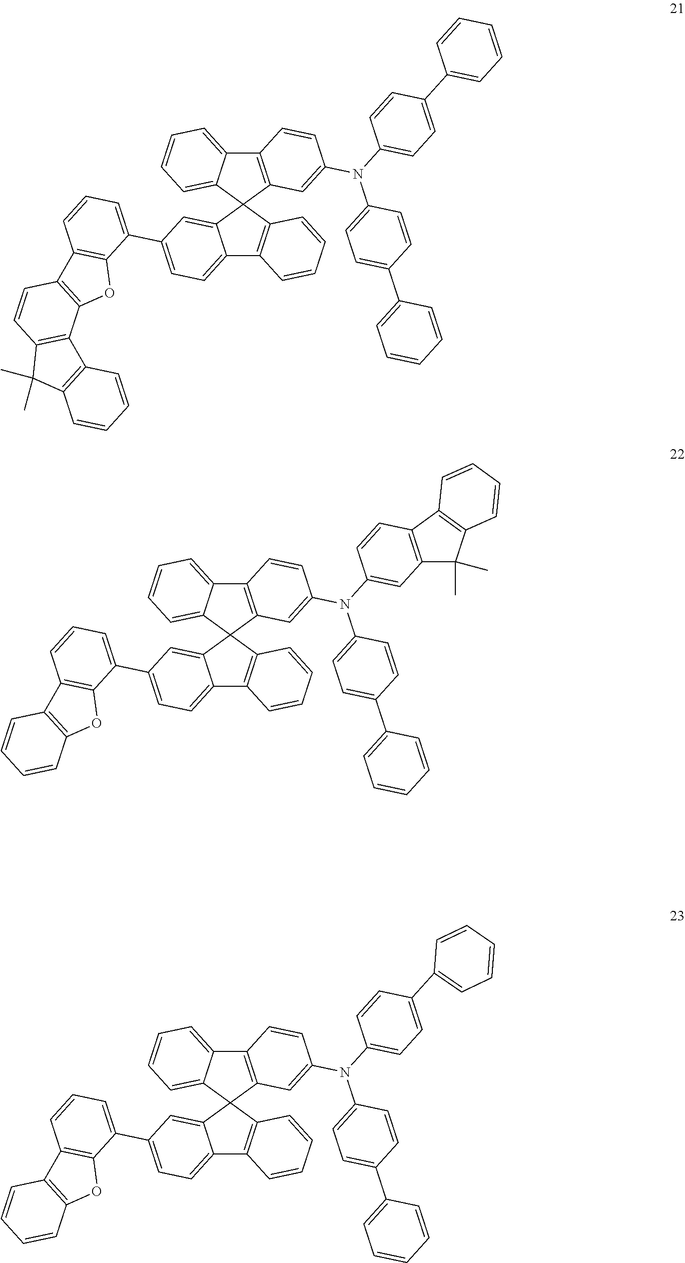 [SMILES: CC1(C)c2ccccc2-c2c1ccc1c2oc2c(-c3ccc4c(c3)C3(c5ccccc5-4)c4ccccc4-c4ccc(N(c5ccc(-c6ccccc6)cc5)c5ccc(-c6ccccc6)cc5)cc43)cccc21 ; CC1(C)c2ccccc2-c2ccc(N(c3ccc(-c4ccccc4)cc3)c3ccc4c(c3)C3(c5ccccc5-c5ccc(-c6cccc7c6oc6ccccc67)cc53)c3ccccc3-4)cc21 ; c1ccc(-c2ccc(N(c3ccc(-c4ccccc4)cc3)c3ccc4c(c3)C3(c5ccccc5-c5ccc(-c6cccc7c6oc6ccccc67)cc53)c3ccccc3-4)cc2)cc1]

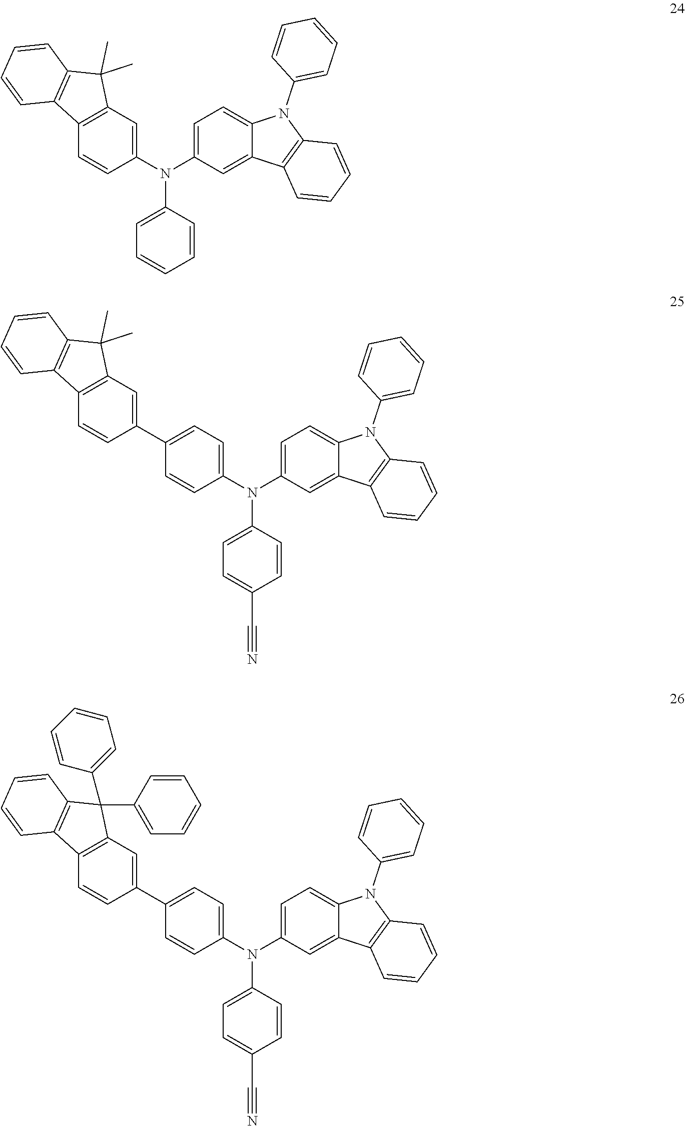 [SMILES: CC1(C)c2ccccc2-c2ccc(N(c3ccccc3)c3ccc4c(c3)c3ccccc3n4-c3ccccc3)cc21 ; CC1(C)c2ccccc2-c2ccc(-c3ccc(N(c4ccc(C#N)cc4)c4ccc5c(c4)c4ccccc4n5-c4ccccc4)cc3)cc21 ; N#Cc1ccc(N(c2ccc(-c3ccc4c(c3)C(c3ccccc3)(c3ccccc3)c3ccccc3-4)cc2)c2ccc3c(c2)c2ccccc2n3-c2ccccc2)cc1]

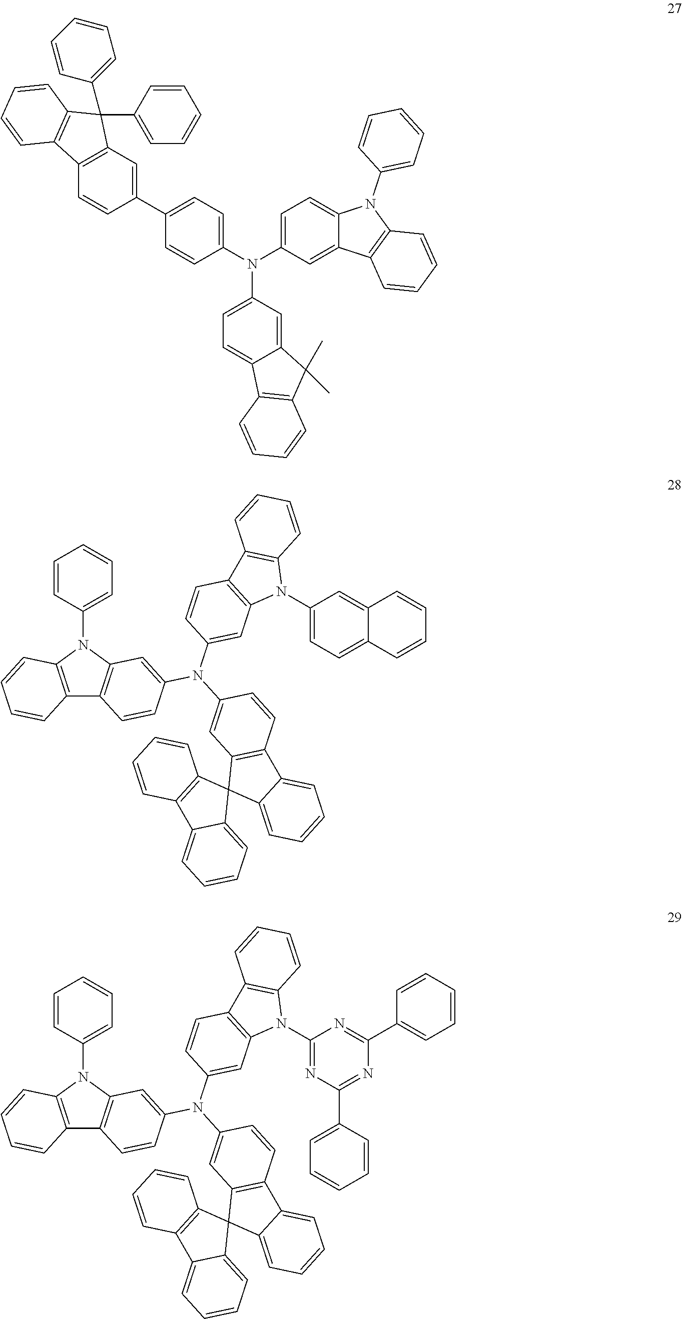

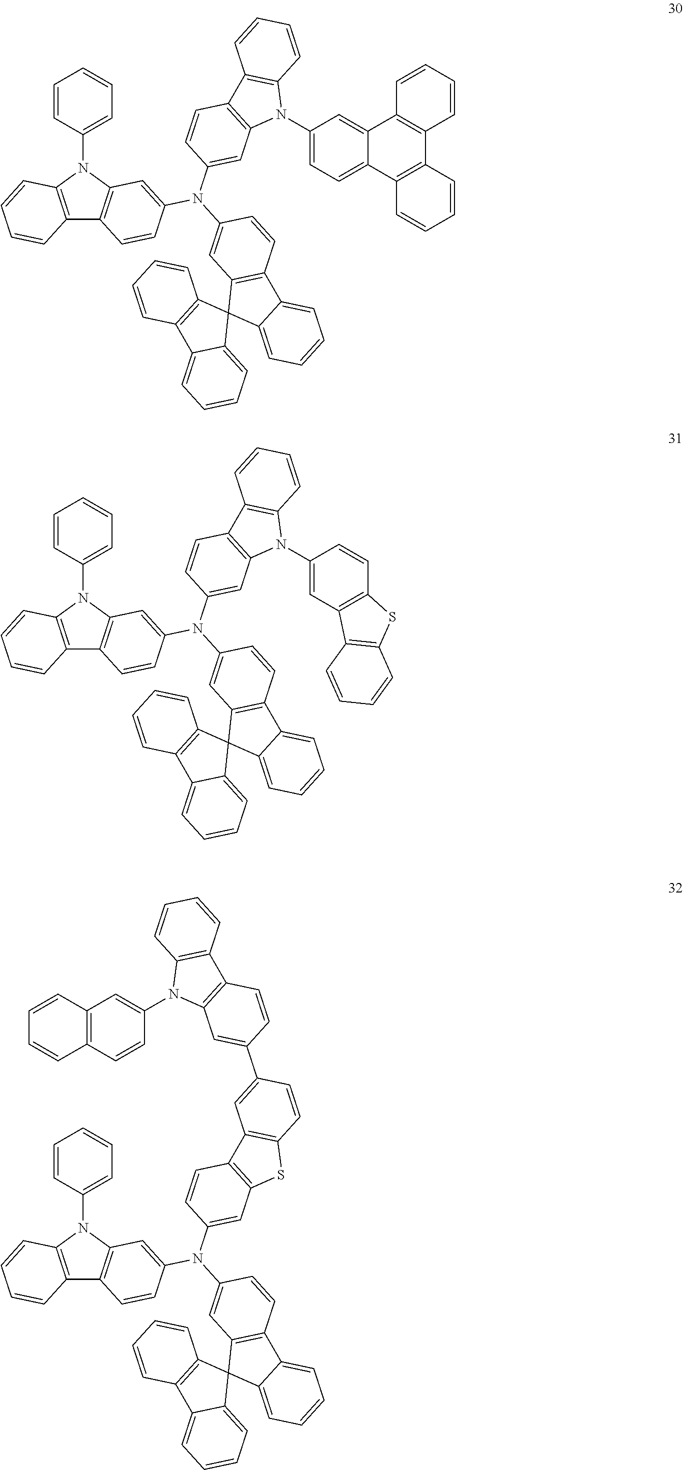 [SMILES: c1ccc(-n2c3ccccc3c3ccc(N(c4ccc5c(c4)C4(c6ccccc6-c6ccccc64)c4ccccc4-5)c4ccc5c6ccccc6n(-c6ccc7c8ccccc8c8ccccc8c7c6)c5c4)cc32)cc1 ; c1ccc(-n2c3ccccc3c3ccc(N(c4ccc5c(c4)C4(c6ccccc6-c6ccccc64)c4ccccc4-5)c4ccc5c6ccccc6n(-c6ccc7sc8ccccc8c7c6)c5c4)cc32)cc1 ; c1ccc(-n2c3ccccc3c3ccc(N(c4ccc5c(c4)C4(c6ccccc6-c6ccccc64)c4ccccc4-5)c4ccc5c(c4)sc4ccc(-c6ccc7c8ccccc8n(-c8ccc9ccccc9c8)c7c6)cc45)cc32)cc1]

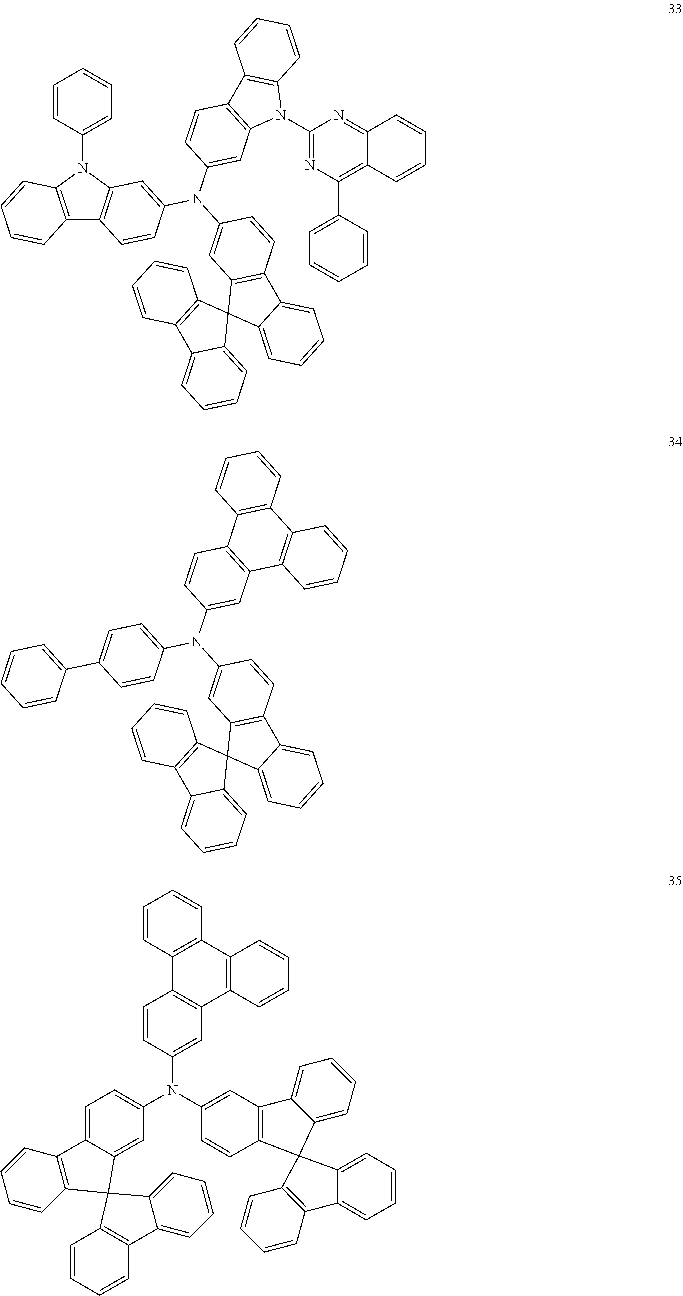 [SMILES: c1ccc(-c2nc(-n3c4ccccc4c4ccc(N(c5ccc6c(c5)C5(c7ccccc7-c7ccccc75)c5ccccc5-6)c5ccc6c7ccccc7n(-c7ccccc7)c6c5)cc43)nc3ccccc23)cc1 ; c1ccc(-c2ccc(N(c3ccc4c(c3)C3(c5ccccc5-c5ccccc53)c3ccccc3-4)c3ccc4c5ccccc5c5ccccc5c4c3)cc2)cc1 ; c1ccc2c(c1)-c1ccccc1C21c2ccccc2-c2cc(N(c3ccc4c(c3)C3(c5ccccc5-c5ccccc53)c3ccccc3-4)c3ccc4c5ccccc5c5ccccc5c4c3)ccc21]

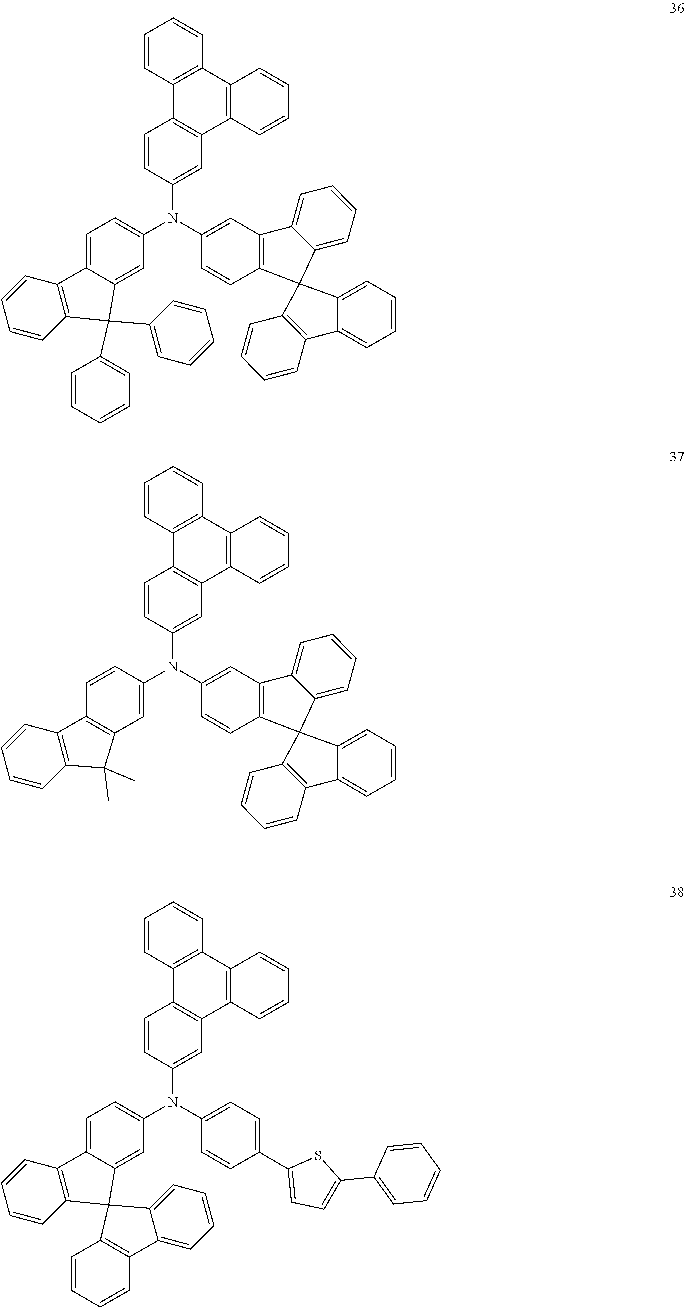 [SMILES: c1ccc(C2(c3ccccc3)c3ccccc3-c3ccc(N(c4ccc5c(c4)-c4ccccc4C54c5ccccc5-c5ccccc54)c4ccc5c6ccccc6c6ccccc6c5c4)cc32)cc1 ; CC1(C)c2ccccc2-c2ccc(N(c3ccc4c(c3)-c3ccccc3C43c4ccccc4-c4ccccc43)c3ccc4c5ccccc5c5ccccc5c4c3)cc21 ; c1ccc(-c2ccc(-c3ccc(N(c4ccc5c(c4)C4(c6ccccc6-c6ccccc64)c4ccccc4-5)c4ccc5c6ccccc6c6ccccc6c5c4)cc3)s2)cc1]

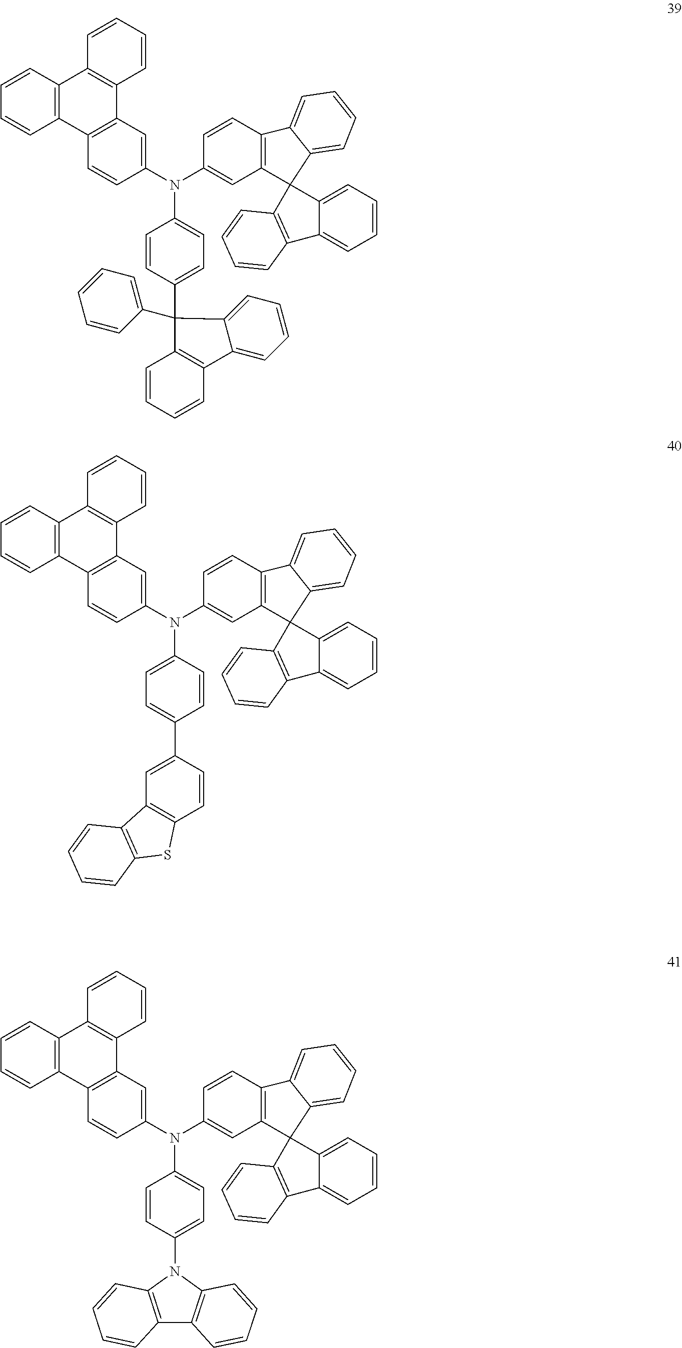 [SMILES: c1ccc(C2(c3ccc(N(c4ccc5c(c4)C4(c6ccccc6-c6ccccc64)c4ccccc4-5)c4ccc5c6ccccc6c6ccccc6c5c4)cc3)c3ccccc3-c3ccccc32)cc1 ; c1ccc2c(c1)-c1ccccc1C21c2ccccc2-c2ccc(N(c3ccc(-c4ccc5sc6ccccc6c5c4)cc3)c3ccc4c5ccccc5c5ccccc5c4c3)cc21 ; c1ccc2c(c1)-c1ccccc1C21c2ccccc2-c2ccc(N(c3ccc(-n4c5ccccc5c5ccccc54)cc3)c3ccc4c5ccccc5c5ccccc5c4c3)cc21]

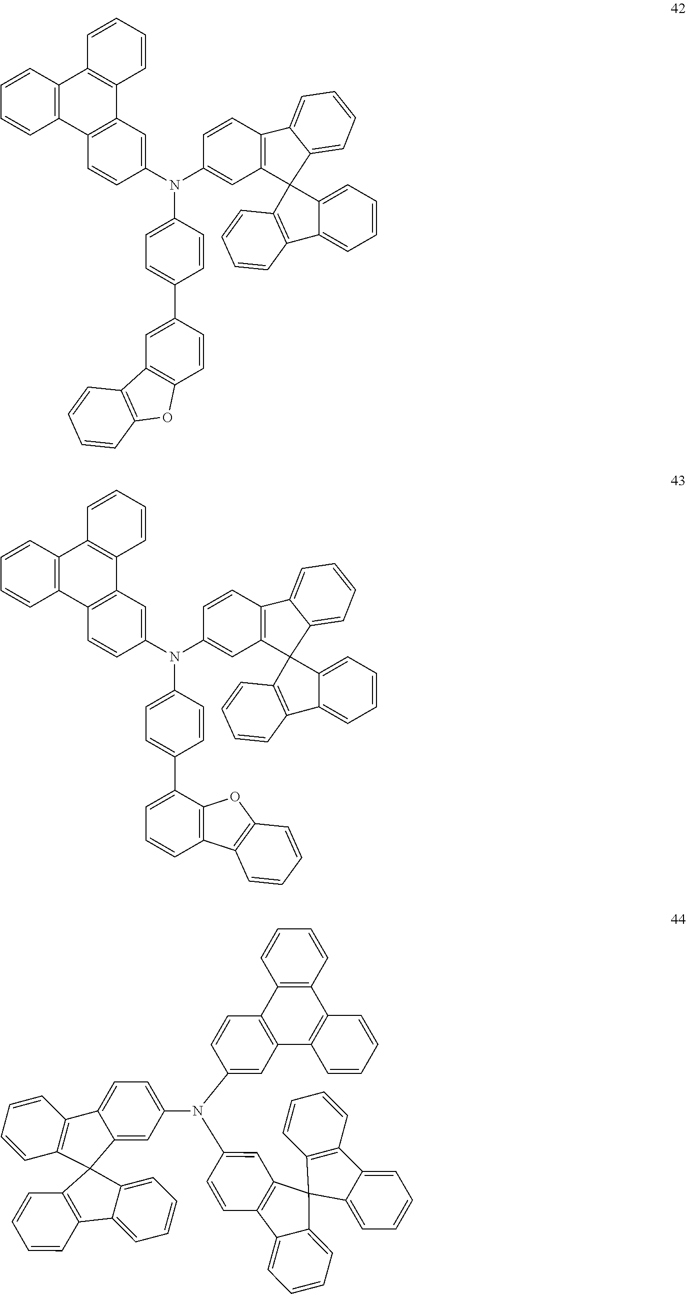

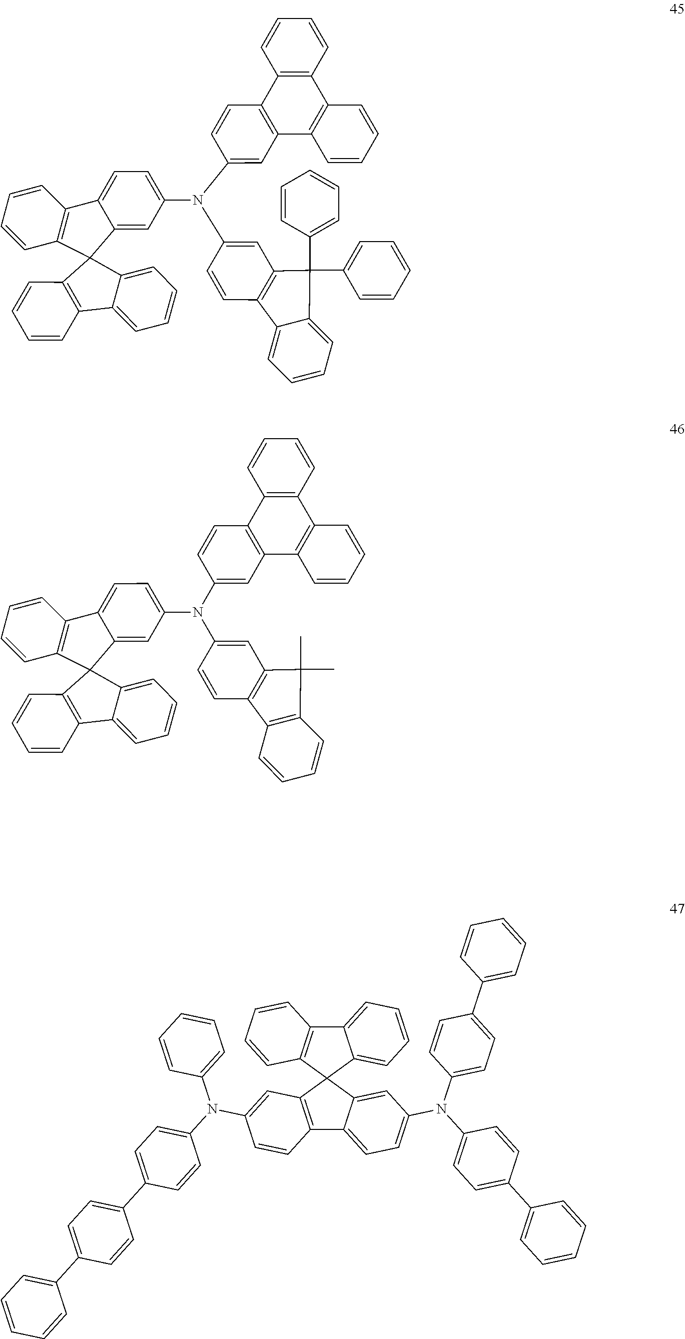 [SMILES: c1ccc(C2(c3ccccc3)c3ccccc3-c3ccc(N(c4ccc5c(c4)C4(c6ccccc6-c6ccccc64)c4ccccc4-5)c4ccc5c6ccccc6c6ccccc6c5c4)cc32)cc1 ; CC1(C)c2ccccc2-c2ccc(N(c3ccc4c(c3)C3(c5ccccc5-c5ccccc53)c3ccccc3-4)c3ccc4c5ccccc5c5ccccc5c4c3)cc21 ; c1ccc(-c2ccc(-c3ccc(N(c4ccccc4)c4ccc5c(c4)C4(c6ccccc6-c6ccccc64)c4cc(N(c6ccc(-c7ccccc7)cc6)c6ccc(-c7ccccc7)cc6)ccc4-5)cc3)cc2)cc1]

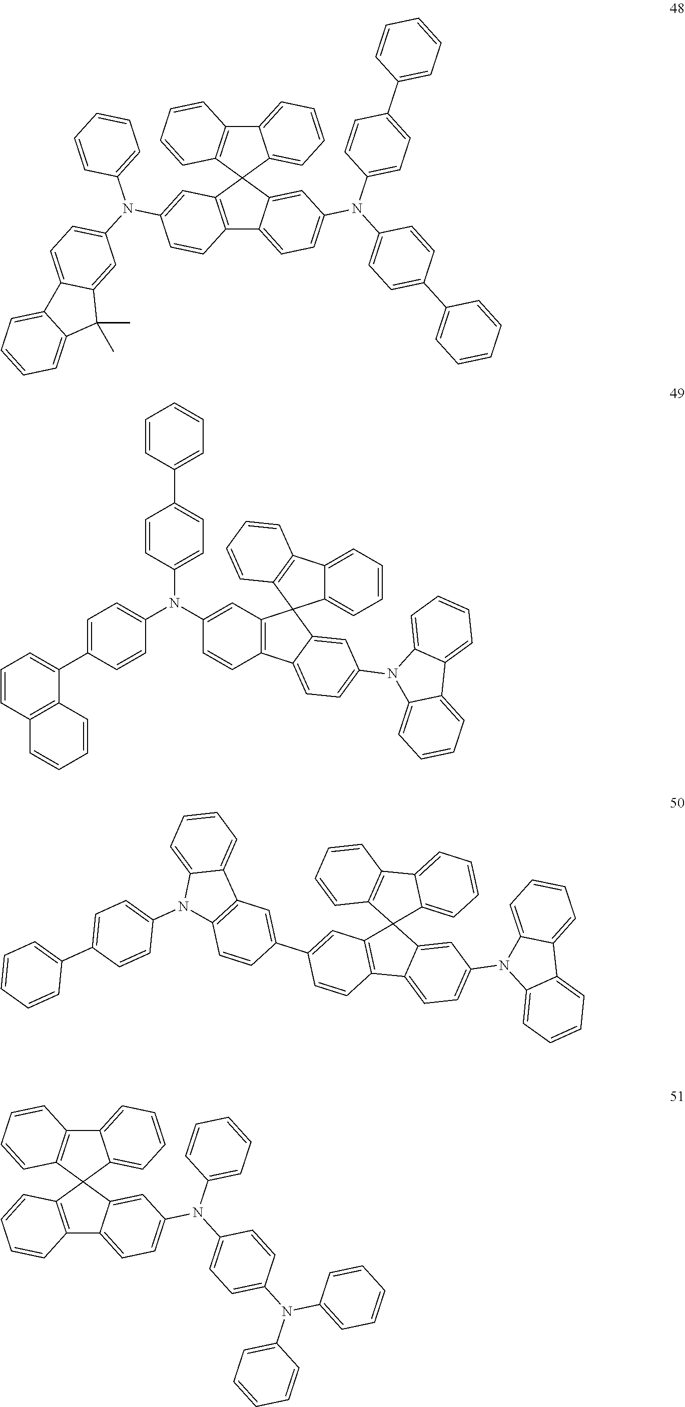 [SMILES: CC1(C)c2ccccc2-c2ccc(N(c3ccccc3)c3ccc4c(c3)C3(c5ccccc5-c5ccccc53)c3cc(N(c5ccc(-c6ccccc6)cc5)c5ccc(-c6ccccc6)cc5)ccc3-4)cc21 ; c1ccc(-c2ccc(N(c3ccc(-c4cccc5ccccc45)cc3)c3ccc4c(c3)C3(c5ccccc5-c5ccccc53)c3cc(-n5c6ccccc6c6ccccc65)ccc3-4)cc2)cc1 ; c1ccc(-c2ccc(-n3c4ccccc4c4cc(-c5ccc6c(c5)C5(c7ccccc7-c7ccccc75)c5cc(-n7c8ccccc8c8ccccc87)ccc5-6)ccc43)cc2)cc1 ; c1ccc(N(c2ccccc2)c2ccc(N(c3ccccc3)c3ccc4c(c3)C3(c5ccccc5-c5ccccc53)c3ccccc3-4)cc2)cc1]

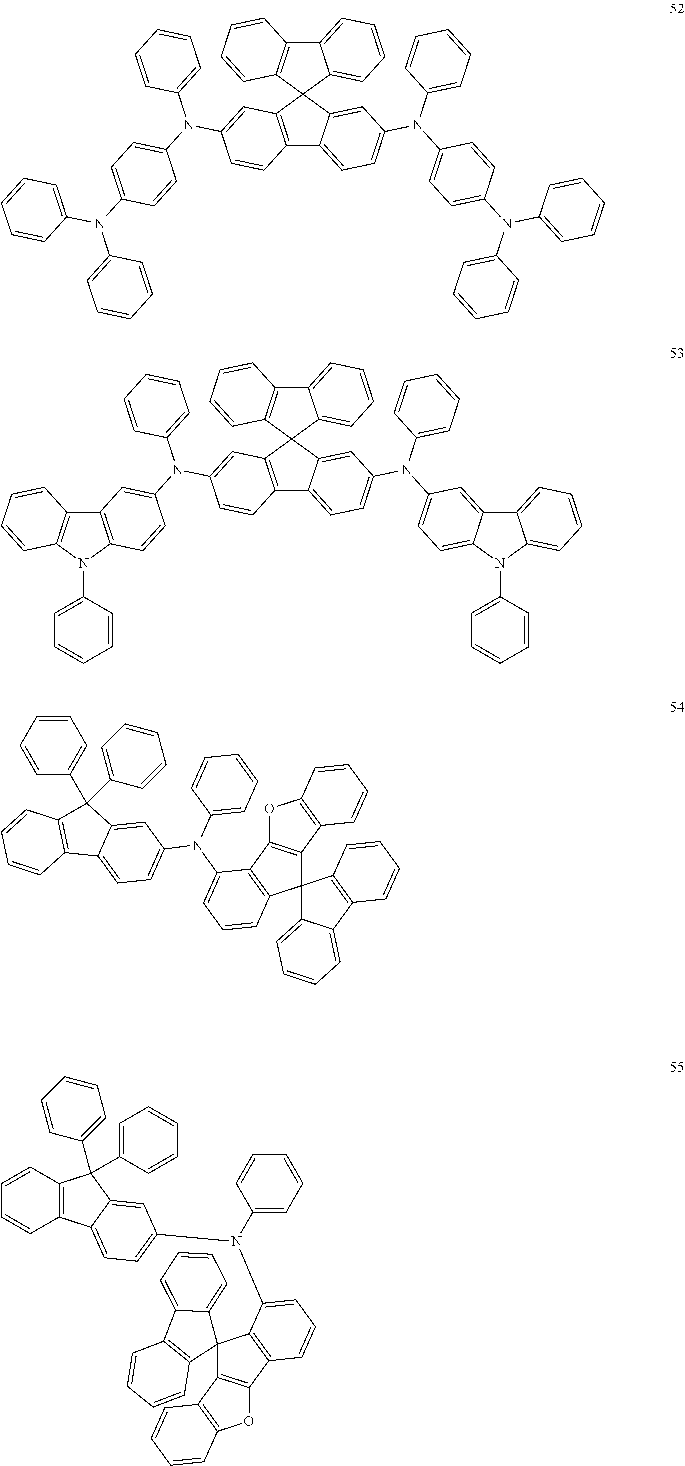 [SMILES: c1ccc(N(c2ccccc2)c2ccc(N(c3ccccc3)c3ccc4c(c3)C3(c5ccccc5-c5ccccc53)c3cc(N(c5ccccc5)c5ccc(N(c6ccccc6)c6ccccc6)cc5)ccc3-4)cc2)cc1 ; c1ccc(N(c2ccc3c(c2)C2(c4ccccc4-c4ccccc42)c2cc(N(c4ccccc4)c4ccc5c(c4)c4ccccc4n5-c4ccccc4)ccc2-3)c2ccc3c(c2)c2ccccc2n3-c2ccccc2)cc1 ; c1ccc(N(c2ccc3c(c2)C(c2ccccc2)(c2ccccc2)c2ccccc2-3)c2cccc3c2-c2oc4ccccc4c2C32c3ccccc3-c3ccccc32)cc1 ; c1ccc(N(c2ccc3c(c2)C(c2ccccc2)(c2ccccc2)c2ccccc2-3)c2cccc3c2C2(c4ccccc4-c4ccccc42)c2c-3oc3ccccc23)cc1]

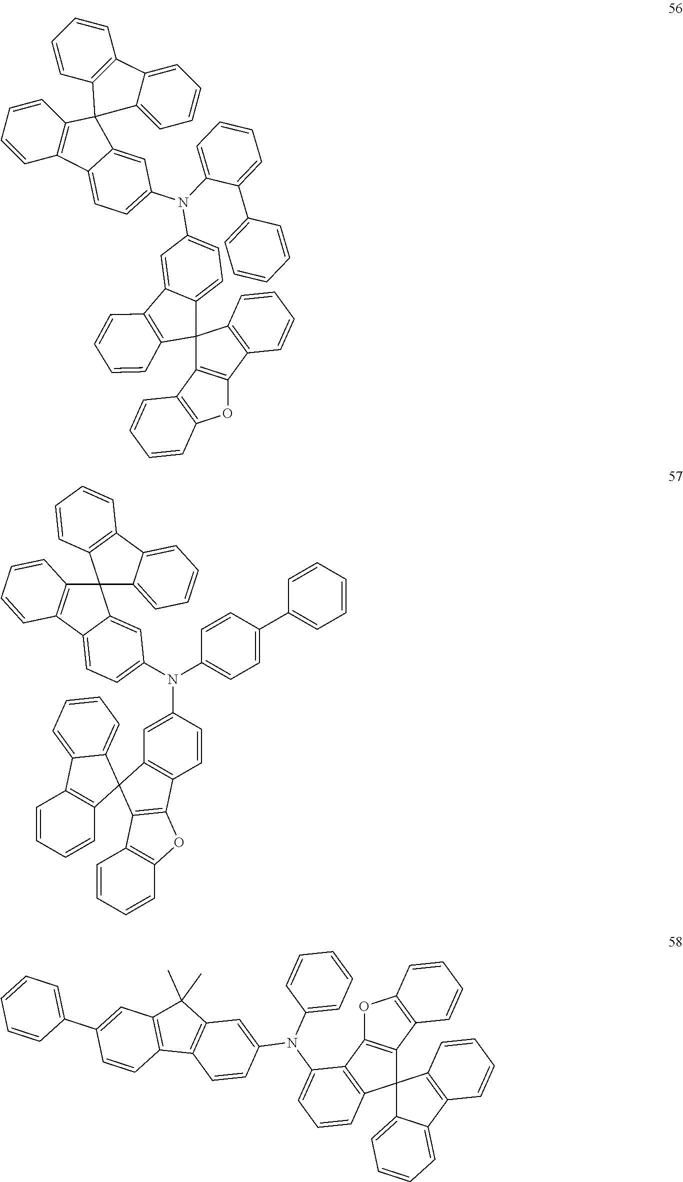 [SMILES: c1ccc(-c2ccccc2N(c2ccc3c(c2)-c2ccccc2C32c3ccccc3-c3oc4ccccc4c32)c2ccc3c(c2)C2(c4ccccc4-c4ccccc42)c2ccccc2-3)cc1 ; c1ccc(-c2ccc(N(c3ccc4c(c3)C3(c5ccccc5-c5ccccc53)c3ccccc3-4)c3ccc4c(c3)C3(c5ccccc5-c5ccccc53)c3c-4oc4ccccc34)cc2)cc1 ; CC1(C)c2cc(-c3ccccc3)ccc2-c2ccc(N(c3ccccc3)c3cccc4c3-c3oc5ccccc5c3C43c4ccccc4-c4ccccc43)cc21]

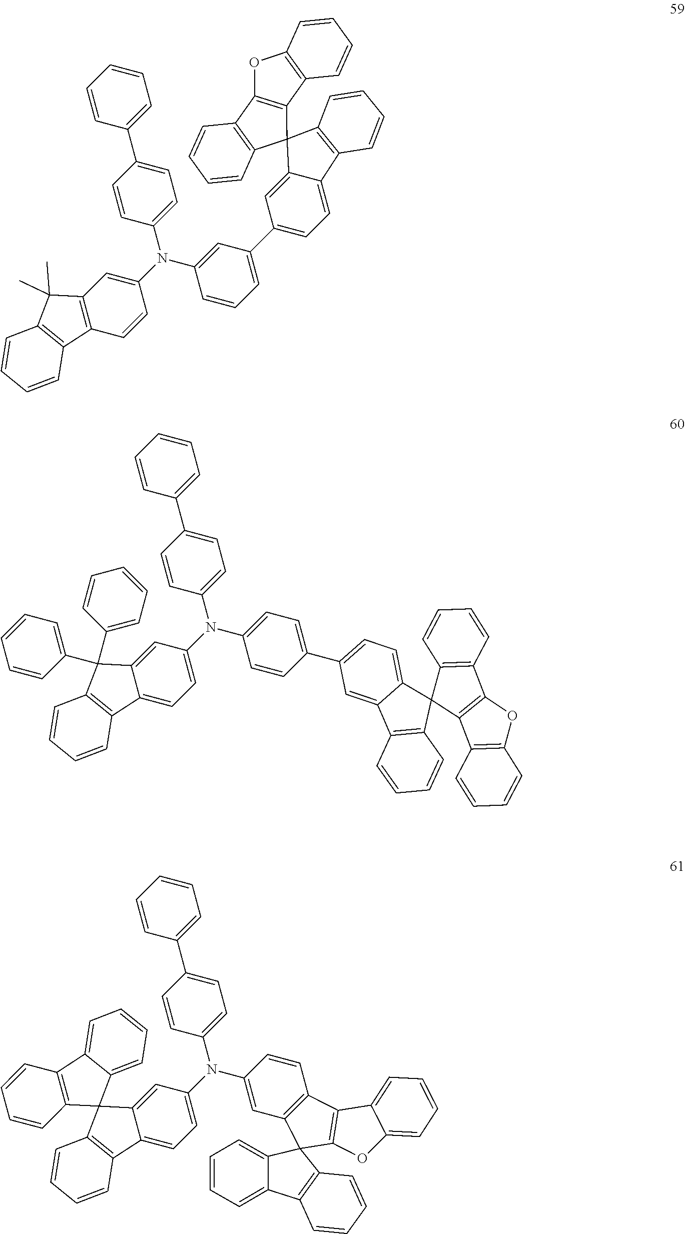 [SMILES: CC1(C)c2ccccc2-c2ccc(N(c3ccc(-c4ccccc4)cc3)c3cccc(-c4ccc5c(c4)C4(c6ccccc6-5)c5ccccc5-c5oc6ccccc6c54)c3)cc21 ; c1ccc(-c2ccc(N(c3ccc(-c4ccc5c(c4)-c4ccccc4C54c5ccccc5-c5oc6ccccc6c54)cc3)c3ccc4c(c3)C(c3ccccc3)(c3ccccc3)c3ccccc3-4)cc2)cc1 ; c1ccc(-c2ccc(N(c3ccc4c(c3)C3(c5ccccc5-c5ccccc53)c3ccccc3-4)c3ccc4c(c3)C3(c5ccccc5-c5ccccc53)c3oc5ccccc5c3-4)cc2)cc1]

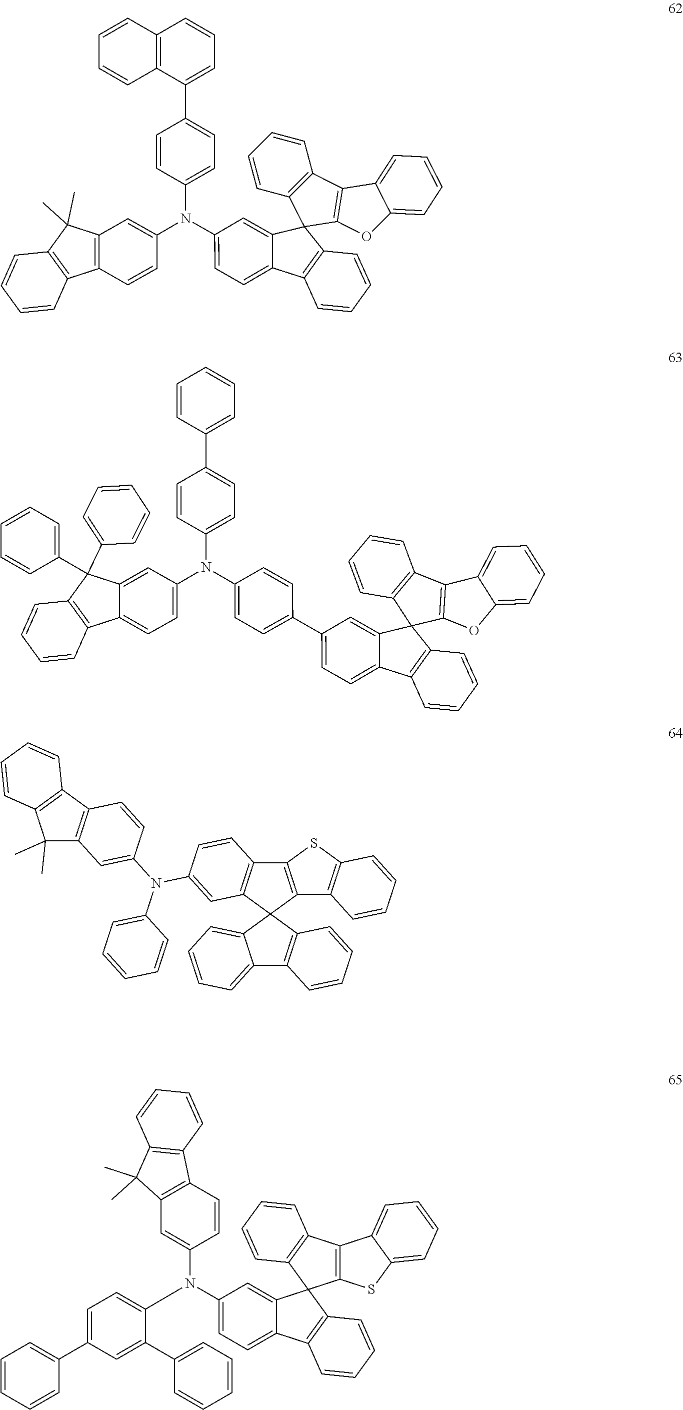 [SMILES: CC1(C)c2ccccc2-c2ccc(N(c3ccc(-c4cccc5ccccc45)cc3)c3ccc4c(c3)C3(c5ccccc5-4)c4ccccc4-c4c3oc3ccccc43)cc21 ; c1ccc(-c2ccc(N(c3ccc(-c4ccc5c(c4)C4(c6ccccc6-5)c5ccccc5-c5c4oc4ccccc54)cc3)c3ccc4c(c3)C(c3ccccc3)(c3ccccc3)c3ccccc3-4)cc2)cc1 ; CC1(C)c2ccccc2-c2ccc(N(c3ccccc3)c3ccc4c(c3)C3(c5ccccc5-c5ccccc53)c3c-4sc4ccccc34)cc21 ; CC1(C)c2ccccc2-c2ccc(N(c3ccc4c(c3)C3(c5ccccc5-4)c4ccccc4-c4c3sc3ccccc43)c3ccc(-c4ccccc4)cc3-c3ccccc3)cc21]

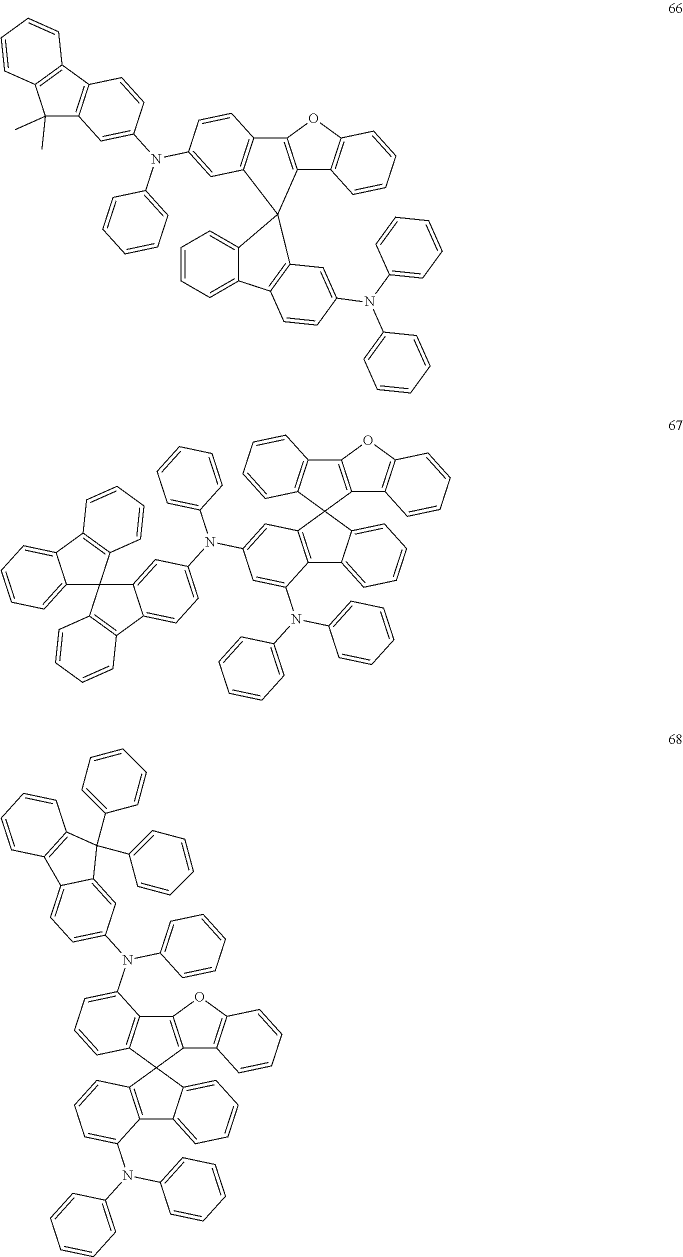 [SMILES: CC1(C)c2ccccc2-c2ccc(N(c3ccccc3)c3ccc4c(c3)C3(c5ccccc5-c5ccc(N(c6ccccc6)c6ccccc6)cc53)c3c-4oc4ccccc34)cc21 ; c1ccc(N(c2ccc3c(c2)C2(c4ccccc4-c4ccccc42)c2ccccc2-3)c2cc(N(c3ccccc3)c3ccccc3)c3c(c2)C2(c4ccccc4-c4oc5ccccc5c42)c2ccccc2-3)cc1 ; c1ccc(N(c2ccccc2)c2cccc3c2-c2ccccc2C32c3cccc(N(c4ccccc4)c4ccc5c(c4)C(c4ccccc4)(c4ccccc4)c4ccccc4-5)c3-c3oc4ccccc4c32)cc1]

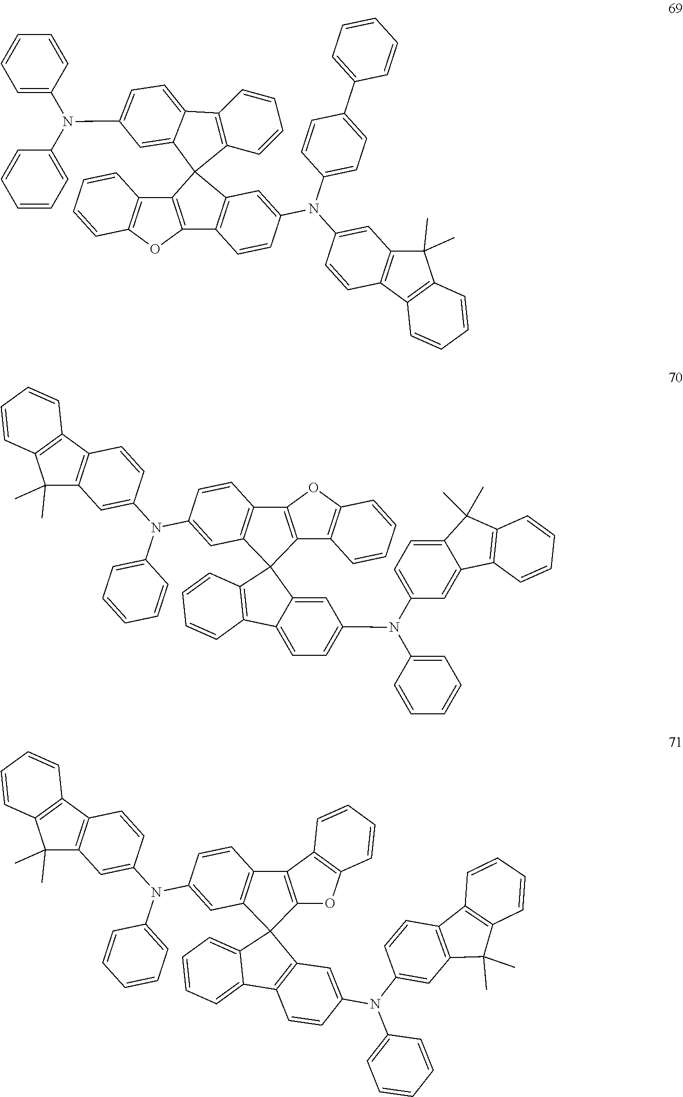 [SMILES: CC1(C)c2ccccc2-c2ccc(N(c3ccc(-c4ccccc4)cc3)c3ccc4c(c3)C3(c5ccccc5-c5ccc(N(c6ccccc6)c6ccccc6)cc53)c3c-4oc4ccccc34)cc21 ; CC1(C)c2ccccc2-c2cc(N(c3ccccc3)c3ccc4c(c3)C3(c5ccccc5-4)c4cc(N(c5ccccc5)c5ccc6c(c5)C(C)(C)c5ccccc5-6)ccc4-c4oc5ccccc5c43)ccc21 ; CC1(C)c2ccccc2-c2ccc(N(c3ccccc3)c3ccc4c(c3)C3(c5ccccc5-4)c4cc(N(c5ccccc5)c5ccc6c(c5)C(C)(C)c5ccccc5-6)ccc4-c4c3oc3ccccc43)cc21]

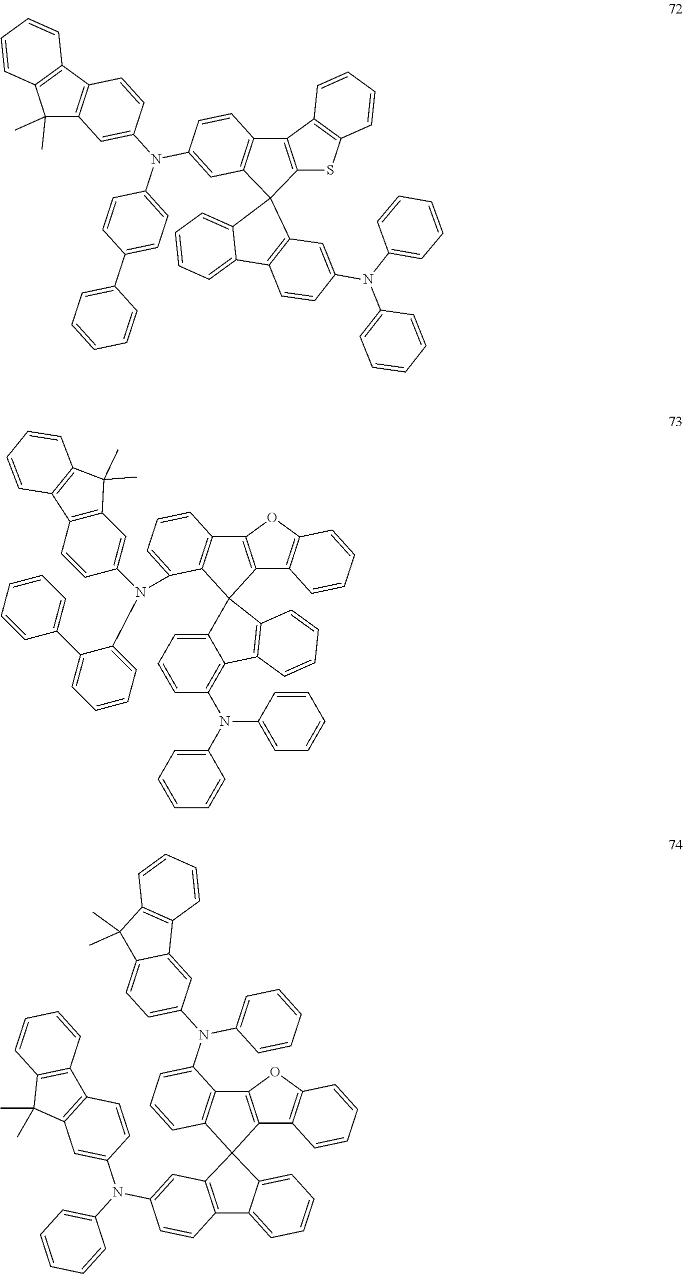 [SMILES: CC1(C)c2ccccc2-c2ccc(N(c3ccc(-c4ccccc4)cc3)c3ccc4c(c3)C3(c5ccccc5-c5ccc(N(c6ccccc6)c6ccccc6)cc53)c3sc5ccccc5c3-4)cc21 ; CC1(C)c2ccccc2-c2ccc(N(c3ccccc3-c3ccccc3)c3cccc4c3C3(c5ccccc5-c5c(N(c6ccccc6)c6ccccc6)cccc53)c3c-4oc4ccccc34)cc21 ; CC1(C)c2ccccc2-c2cc(N(c3ccccc3)c3cccc4c3-c3oc5ccccc5c3C43c4ccccc4-c4ccc(N(c5ccccc5)c5ccc6c(c5)C(C)(C)c5ccccc5-6)cc43)ccc21]

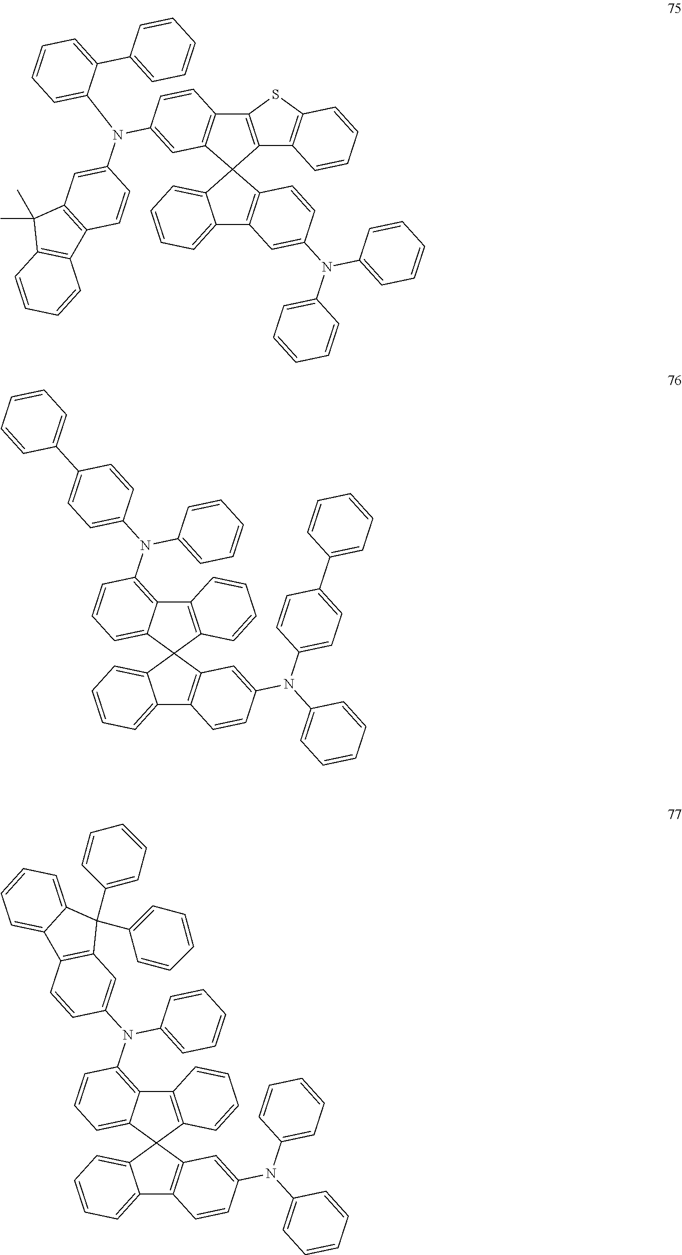 [SMILES: CC1(C)c2ccccc2-c2ccc(N(c3ccc4c(c3)C3(c5ccccc5-c5cc(N(c6ccccc6)c6ccccc6)ccc53)c3c-4sc4ccccc34)c3ccccc3-c3ccccc3)cc21 ; c1ccc(-c2ccc(N(c3ccccc3)c3ccc4c(c3)C3(c5ccccc5-4)c4ccccc4-c4c(N(c5ccccc5)c5ccc(-c6ccccc6)cc5)cccc43)cc2)cc1 ; c1ccc(N(c2ccccc2)c2ccc3c(c2)C2(c4ccccc4-3)c3ccccc3-c3c(N(c4ccccc4)c4ccc5c(c4)C(c4ccccc4)(c4ccccc4)c4ccccc4-5)cccc32)cc1]

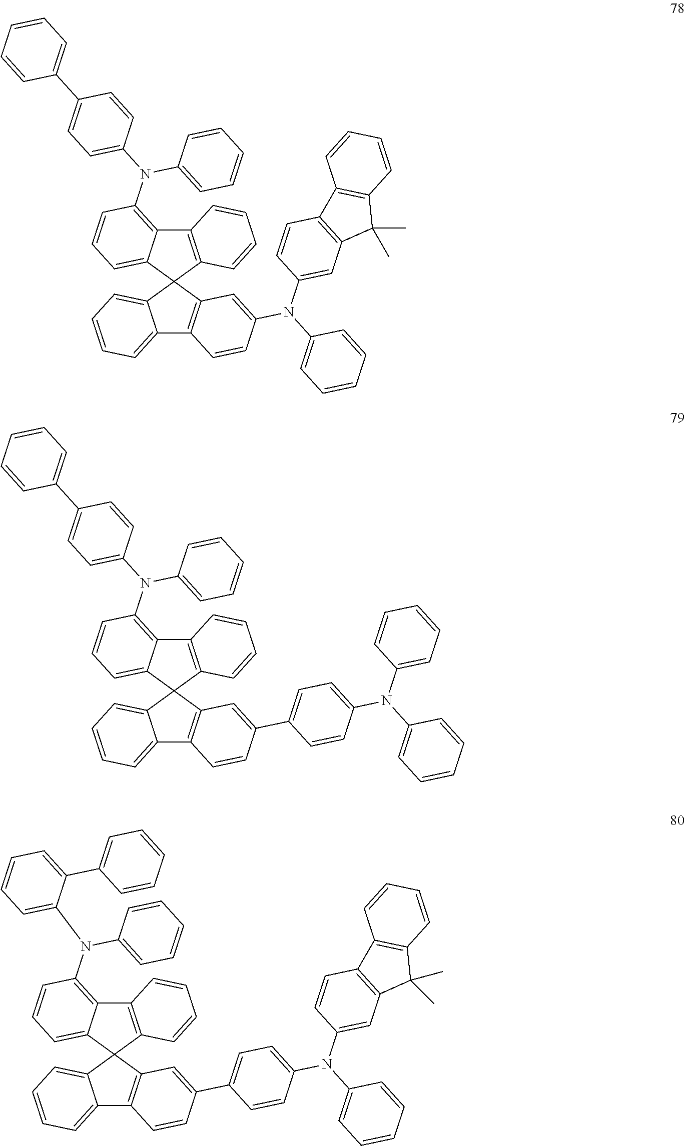 [SMILES: CC1(C)c2ccccc2-c2ccc(N(c3ccccc3)c3ccc4c(c3)C3(c5ccccc5-4)c4ccccc4-c4c(N(c5ccccc5)c5ccc(-c6ccccc6)cc5)cccc43)cc21 ; c1ccc(-c2ccc(N(c3ccccc3)c3cccc4c3-c3ccccc3C43c4ccccc4-c4ccc(-c5ccc(N(c6ccccc6)c6ccccc6)cc5)cc43)cc2)cc1 ; CC1(C)c2ccccc2-c2ccc(N(c3ccccc3)c3ccc(-c4ccc5c(c4)C4(c6ccccc6-5)c5ccccc5-c5c(N(c6ccccc6)c6ccccc6-c6ccccc6)cccc54)cc3)cc21]

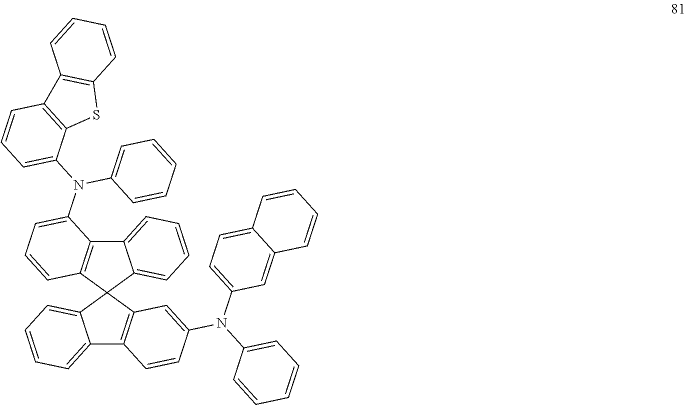 [SMILES: c1ccc(N(c2ccc3c(c2)C2(c4ccccc4-3)c3ccccc3-c3c(N(c4ccccc4)c4cccc5c4sc4ccccc45)cccc32)c2ccc3ccccc3c2)cc1]

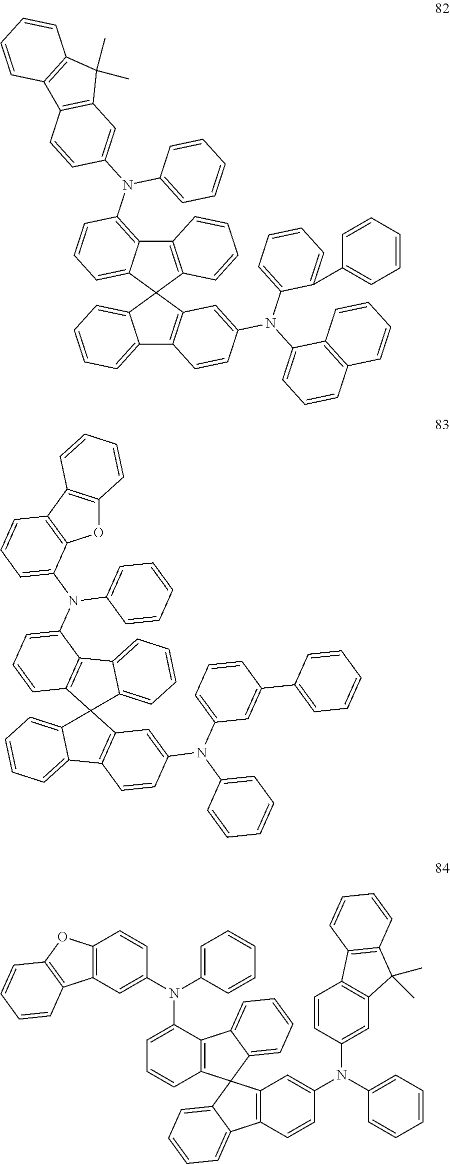 [SMILES: CC1(C)c2ccccc2-c2ccc(N(c3ccccc3)c3cccc4c3-c3ccccc3C43c4ccccc4-c4ccc(N(c5ccccc5-c5ccccc5)c5cccc6ccccc56)cc43)cc21 ; c1ccc(-c2cccc(N(c3ccccc3)c3ccc4c(c3)C3(c5ccccc5-4)c4ccccc4-c4c(N(c5ccccc5)c5cccc6c5oc5ccccc56)cccc43)c2)cc1 ; CC1(C)c2ccccc2-c2ccc(N(c3ccccc3)c3ccc4c(c3)C3(c5ccccc5-4)c4ccccc4-c4c(N(c5ccccc5)c5ccc6oc7ccccc7c6c5)cccc43)cc21]

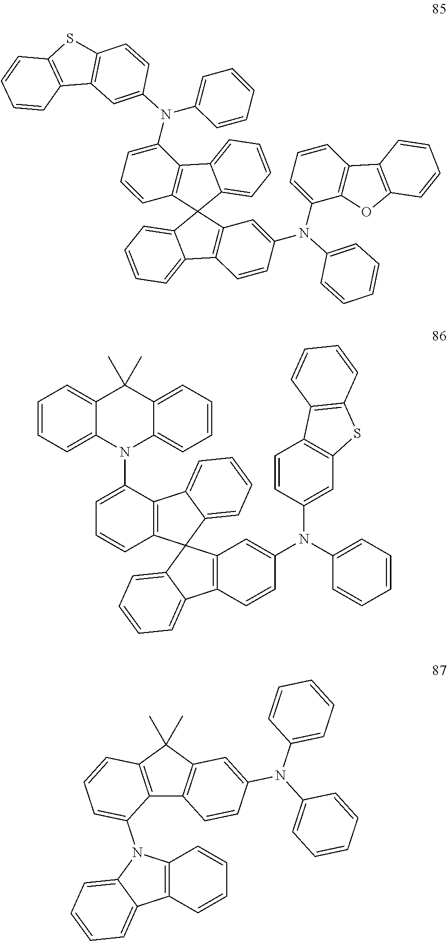

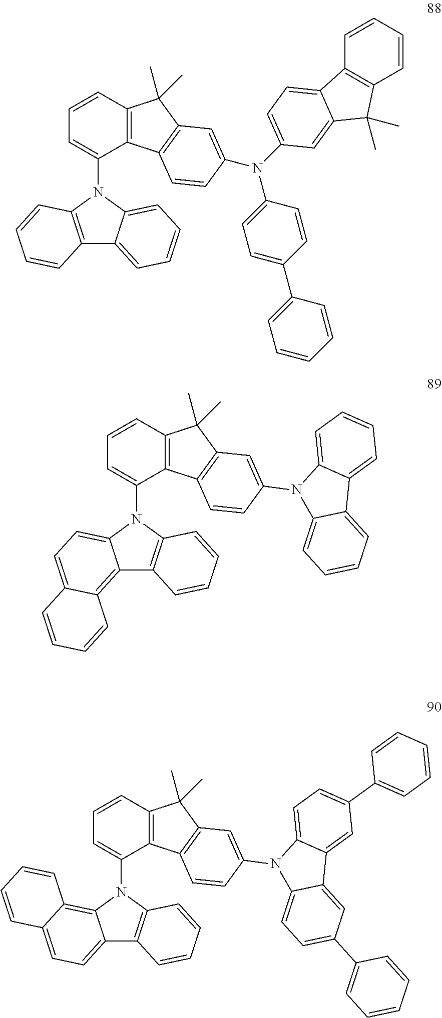 [SMILES: CC1(C)c2ccccc2-c2ccc(N(c3ccc(-c4ccccc4)cc3)c3ccc4c(c3)C(C)(C)c3cccc(-n5c6ccccc6c6ccccc65)c3-4)cc21 ; CC1(C)c2cc(-n3c4ccccc4c4ccccc43)ccc2-c2c(-n3c4ccccc4c4c5ccccc5ccc43)cccc21 ; CC1(C)c2cc(-n3c4ccc(-c5ccccc5)cc4c4cc(-c5ccccc5)ccc43)ccc2-c2c(-n3c4ccccc4c4ccc5ccccc5c43)cccc21]

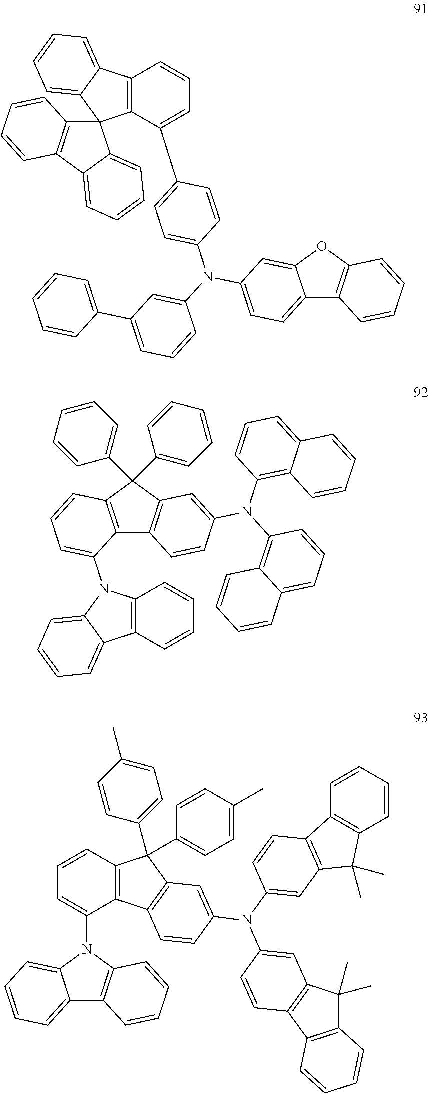

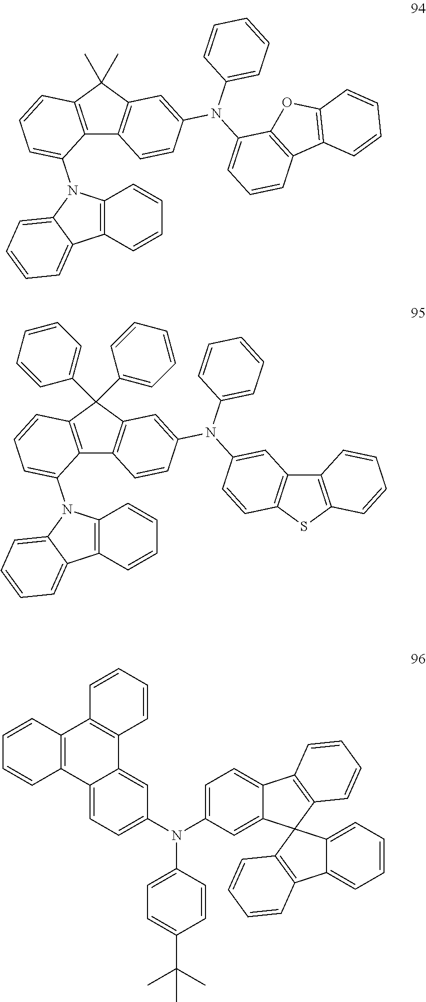 [SMILES: CC1(C)c2cc(N(c3ccccc3)c3cccc4c3oc3ccccc34)ccc2-c2c(-n3c4ccccc4c4ccccc43)cccc21 ; c1ccc(N(c2ccc3c(c2)C(c2ccccc2)(c2ccccc2)c2cccc(-n4c5ccccc5c5ccccc54)c2-3)c2ccc3sc4ccccc4c3c2)cc1 ; CC(C)(C)c1ccc(N(c2ccc3c(c2)C2(c4ccccc4-c4ccccc42)c2ccccc2-3)c2ccc3c4ccccc4c4ccccc4c3c2)cc1]

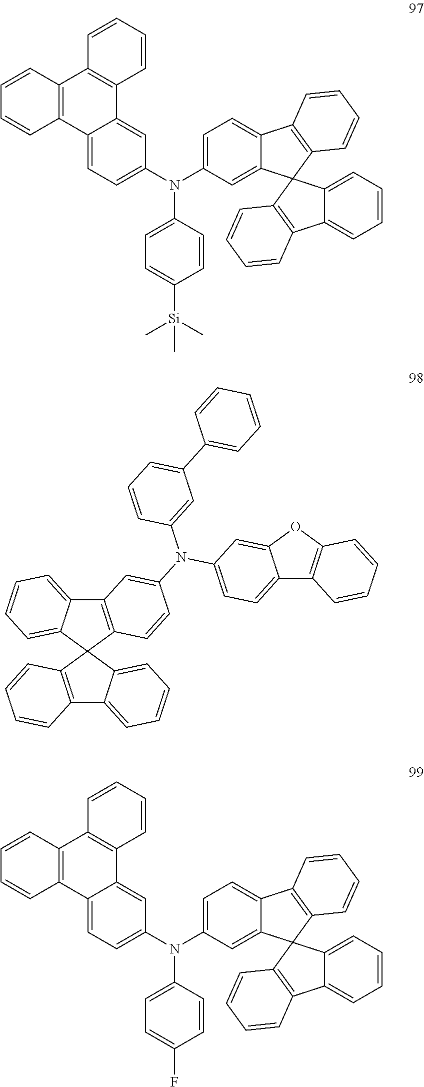 [SMILES: C[Si](C)(C)c1ccc(N(c2ccc3c(c2)C2(c4ccccc4-c4ccccc42)c2ccccc2-3)c2ccc3c4ccccc4c4ccccc4c3c2)cc1 ; c1ccc(-c2cccc(N(c3ccc4c(c3)-c3ccccc3C43c4ccccc4-c4ccccc43)c3ccc4c(c3)oc3ccccc34)c2)cc1 ; Fc1ccc(N(c2ccc3c(c2)C2(c4ccccc4-c4ccccc42)c2ccccc2-3)c2ccc3c4ccccc4c4ccccc4c3c2)cc1]

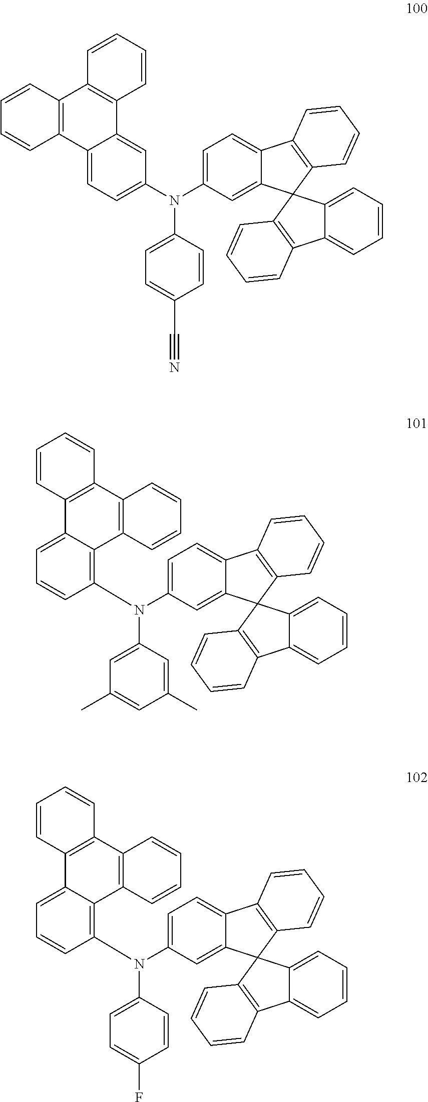 [SMILES: N#Cc1ccc(N(c2ccc3c(c2)C2(c4ccccc4-c4ccccc42)c2ccccc2-3)c2ccc3c4ccccc4c4ccccc4c3c2)cc1 ; Cc1cc(C)cc(N(c2ccc3c(c2)C2(c4ccccc4-c4ccccc42)c2ccccc2-3)c2cccc3c4ccccc4c4ccccc4c23)c1 ; Fc1ccc(N(c2ccc3c(c2)C2(c4ccccc4-c4ccccc42)c2ccccc2-3)c2cccc3c4ccccc4c4ccccc4c23)cc1]

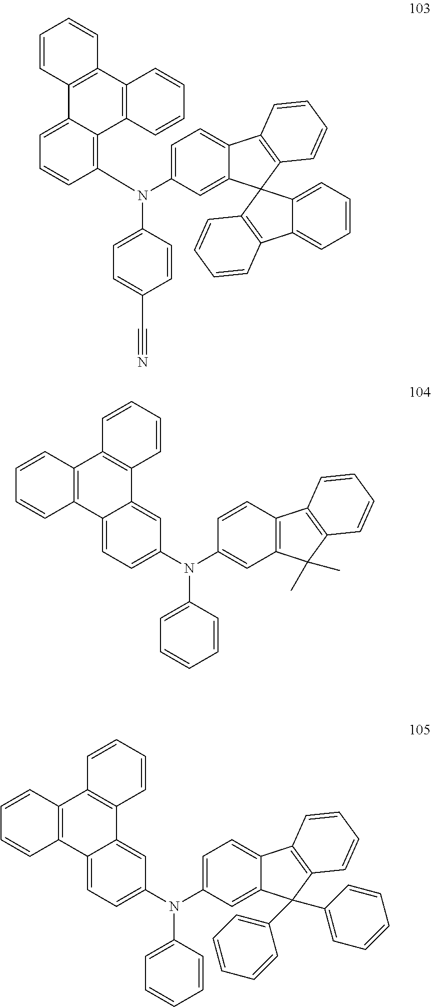

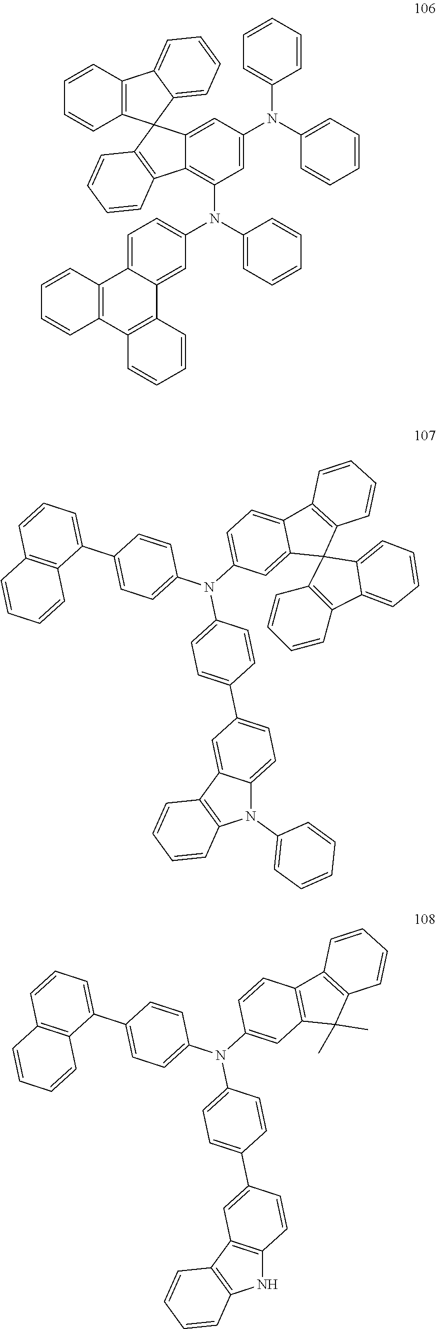 [SMILES: c1ccc(N(c2ccccc2)c2cc(N(c3ccccc3)c3ccc4c5ccccc5c5ccccc5c4c3)c3c(c2)C2(c4ccccc4-c4ccccc42)c2ccccc2-3)cc1 ; c1ccc(-n2c3ccccc3c3cc(-c4ccc(N(c5ccc(-c6cccc7ccccc67)cc5)c5ccc6c(c5)C5(c7ccccc7-c7ccccc75)c5ccccc5-6)cc4)ccc32)cc1 ; CC1(C)c2ccccc2-c2ccc(N(c3ccc(-c4ccc5[nH]c6ccccc6c5c4)cc3)c3ccc(-c4cccc5ccccc45)cc3)cc21]

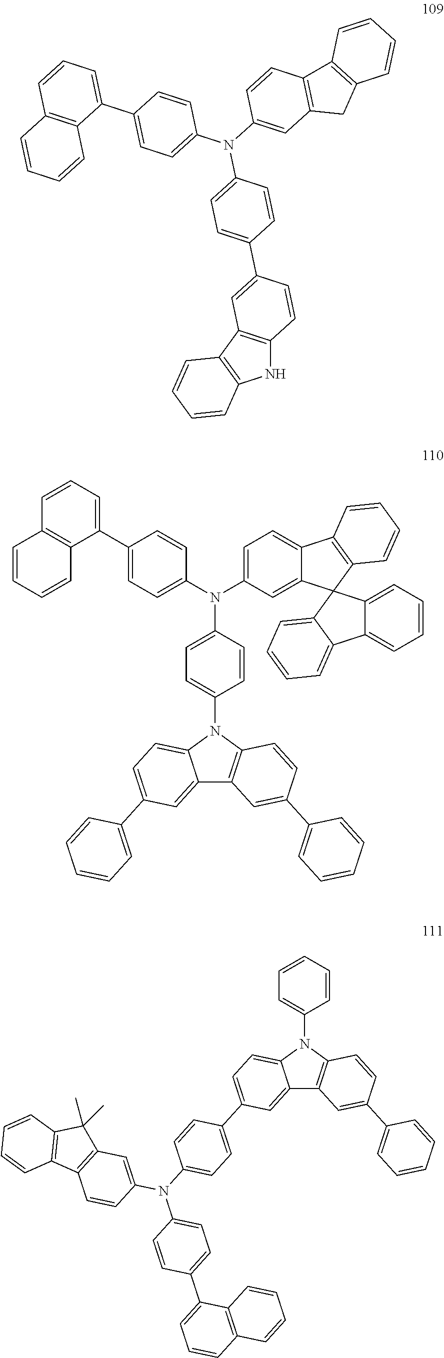 [SMILES: c1ccc2c(c1)Cc1cc(N(c3ccc(-c4ccc5[nH]c6ccccc6c5c4)cc3)c3ccc(-c4cccc5ccccc45)cc3)ccc1-2 ; c1ccc(-c2ccc3c(c2)c2cc(-c4ccccc4)ccc2n3-c2ccc(N(c3ccc(-c4cccc5ccccc45)cc3)c3ccc4c(c3)C3(c5ccccc5-c5ccccc53)c3ccccc3-4)cc2)cc1 ; CC1(C)c2ccccc2-c2ccc(N(c3ccc(-c4ccc5c(c4)c4cc(-c6ccccc6)ccc4n5-c4ccccc4)cc3)c3ccc(-c4cccc5ccccc45)cc3)cc21]

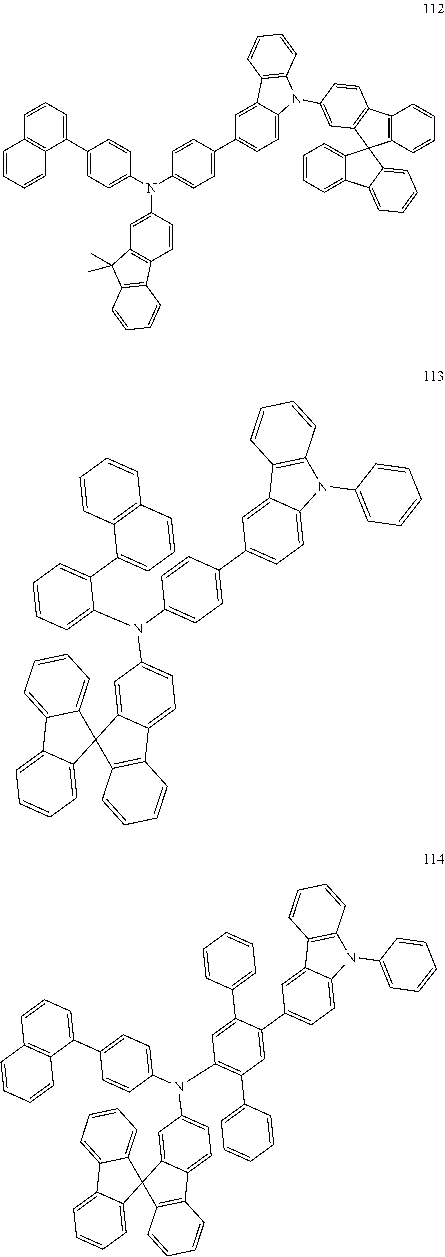 [SMILES: CC1(C)c2ccccc2-c2ccc(N(c3ccc(-c4ccc5c(c4)c4ccccc4n5-c4ccc5c(c4)C4(c6ccccc6-c6ccccc64)c4ccccc4-5)cc3)c3ccc(-c4cccc5ccccc45)cc3)cc21 ; c1ccc(-n2c3ccccc3c3cc(-c4ccc(N(c5ccc6c(c5)C5(c7ccccc7-c7ccccc75)c5ccccc5-6)c5ccccc5-c5cccc6ccccc56)cc4)ccc32)cc1 ; c1ccc(-c2cc(N(c3ccc(-c4cccc5ccccc45)cc3)c3ccc4c(c3)C3(c5ccccc5-c5ccccc53)c3ccccc3-4)c(-c3ccccc3)cc2-c2ccc3c(c2)c2ccccc2n3-c2ccccc2)cc1]

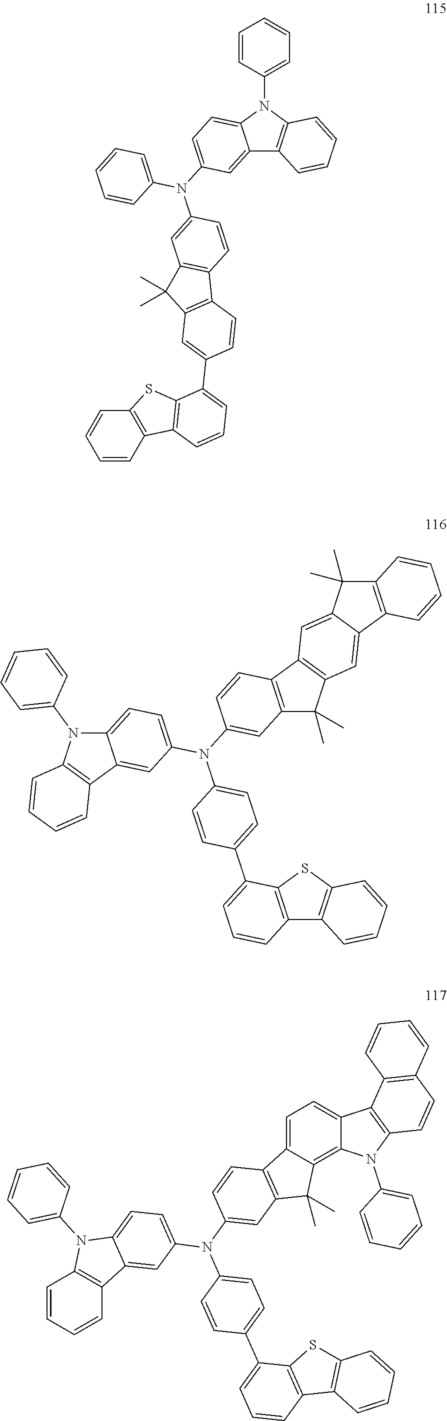 [SMILES: CC1(C)c2cc(-c3cccc4c3sc3ccccc34)ccc2-c2ccc(N(c3ccccc3)c3ccc4c(c3)c3ccccc3n4-c3ccccc3)cc21 ; CC1(C)c2ccccc2-c2cc3c(cc21)-c1ccc(N(c2ccc(-c4cccc5c4sc4ccccc45)cc2)c2ccc4c(c2)c2ccccc2n4-c2ccccc2)cc1C3(C)C ; CC1(C)c2cc(N(c3ccc(-c4cccc5c4sc4ccccc45)cc3)c3ccc4c(c3)c3ccccc3n4-c3ccccc3)ccc2-c2ccc3c4c5ccccc5ccc4n(-c4ccccc4)c3c21]

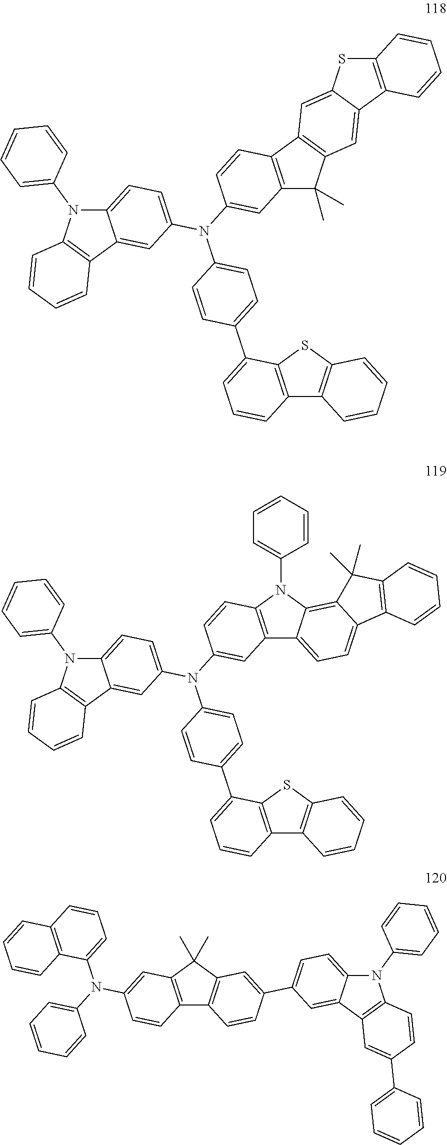 [SMILES: CC1(C)c2cc(N(c3ccc(-c4cccc5c4sc4ccccc45)cc3)c3ccc4c(c3)c3ccccc3n4-c3ccccc3)ccc2-c2cc3sc4ccccc4c3cc21 ; CC1(C)c2ccccc2-c2ccc3c4cc(N(c5ccc(-c6cccc7c6sc6ccccc67)cc5)c5ccc6c(c5)c5ccccc5n6-c5ccccc5)ccc4n(-c4ccccc4)c3c21 ; CC1(C)c2cc(-c3ccc4c(c3)c3cc(-c5ccccc5)ccc3n4-c3ccccc3)ccc2-c2ccc(N(c3ccccc3)c3cccc4ccccc34)cc21]

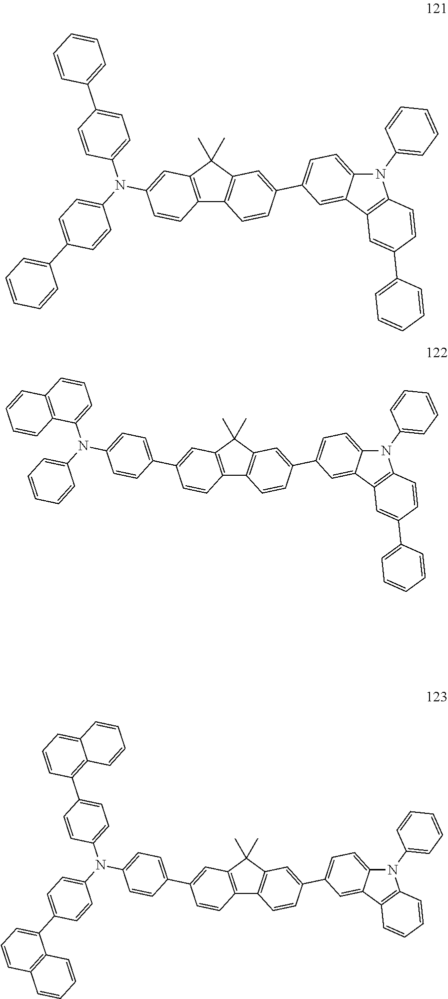 [SMILES: CC1(C)c2cc(-c3ccc4c(c3)c3cc(-c5ccccc5)ccc3n4-c3ccccc3)ccc2-c2ccc(N(c3ccc(-c4ccccc4)cc3)c3ccc(-c4ccccc4)cc3)cc21 ; CC1(C)c2cc(-c3ccc(N(c4ccccc4)c4cccc5ccccc45)cc3)ccc2-c2ccc(-c3ccc4c(c3)c3cc(-c5ccccc5)ccc3n4-c3ccccc3)cc21 ; CC1(C)c2cc(-c3ccc(N(c4ccc(-c5cccc6ccccc56)cc4)c4ccc(-c5cccc6ccccc56)cc4)cc3)ccc2-c2ccc(-c3ccc4c(c3)c3ccccc3n4-c3ccccc3)cc21]

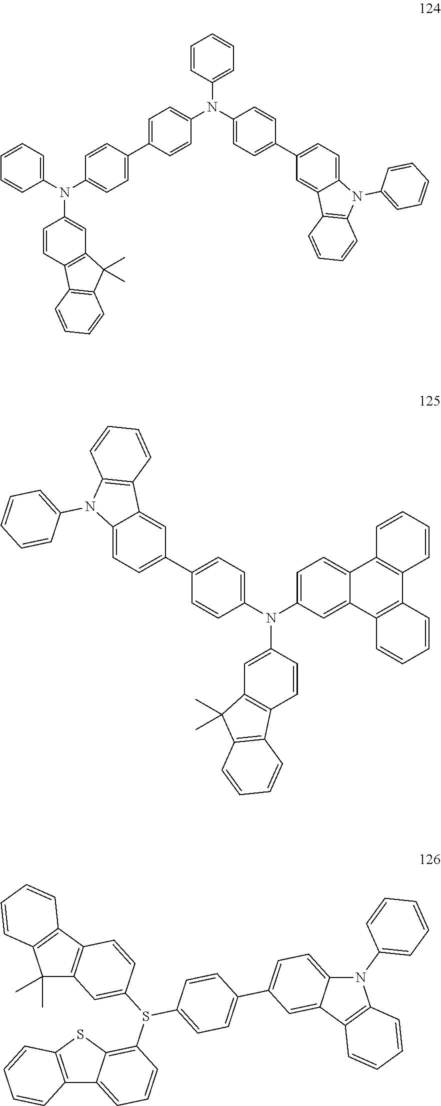

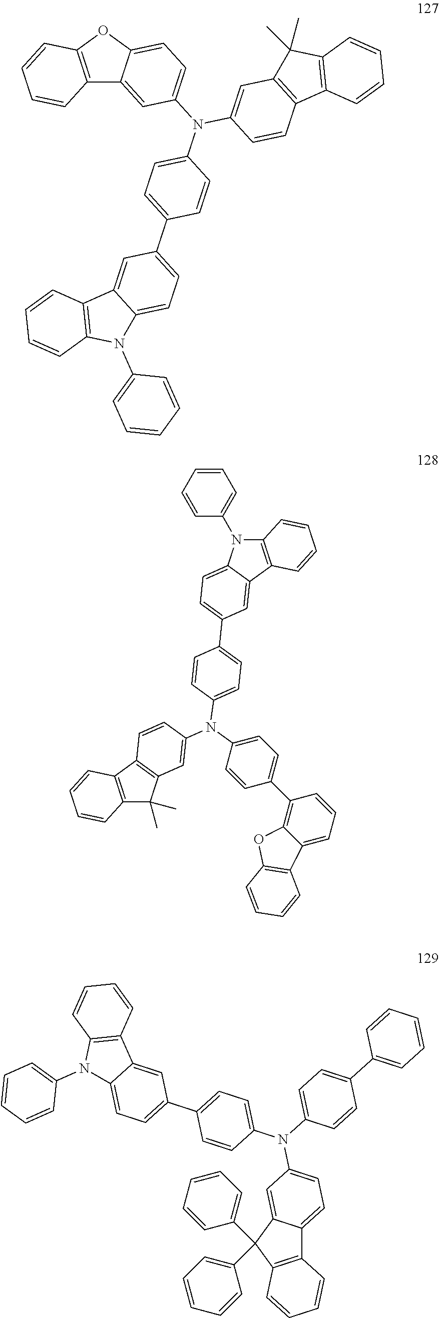 [SMILES: CC1(C)c2ccccc2-c2ccc(N(c3ccc(-c4ccc5c(c4)c4ccccc4n5-c4ccccc4)cc3)c3ccc4oc5ccccc5c4c3)cc21 ; CC1(C)c2ccccc2-c2ccc(N(c3ccc(-c4ccc5c(c4)c4ccccc4n5-c4ccccc4)cc3)c3ccc(-c4cccc5c4oc4ccccc45)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

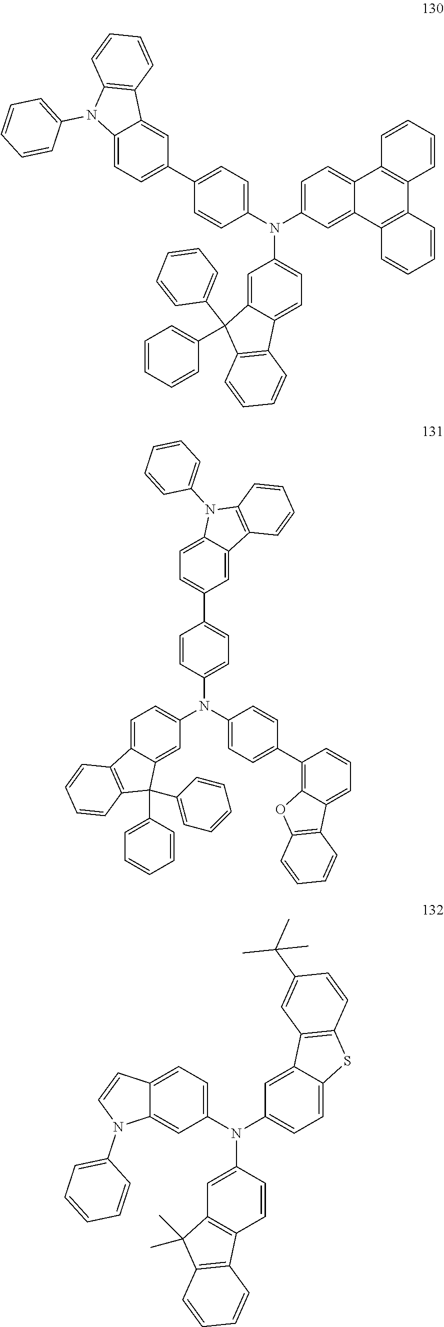

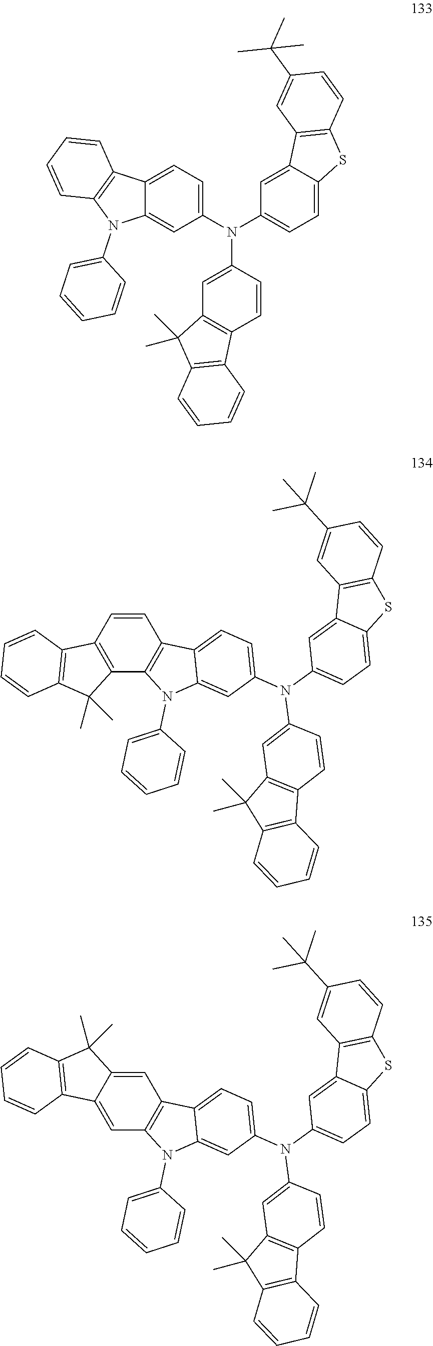 [SMILES: CC(C)(C)c1ccc2sc3ccc(N(c4ccc5c(c4)C(C)(C)c4ccccc4-5)c4ccc5c6ccccc6n(-c6ccccc6)c5c4)cc3c2c1 ; CC(C)(C)c1ccc2sc3ccc(N(c4ccc5c(c4)C(C)(C)c4ccccc4-5)c4ccc5c6ccc7c(c6n(-c6ccccc6)c5c4)C(C)(C)c4ccccc4-7)cc3c2c1 ; CC(C)(C)c1ccc2sc3ccc(N(c4ccc5c(c4)C(C)(C)c4ccccc4-5)c4ccc5c6cc7c(cc6n(-c6ccccc6)c5c4)-c4ccccc4C7(C)C)cc3c2c1]

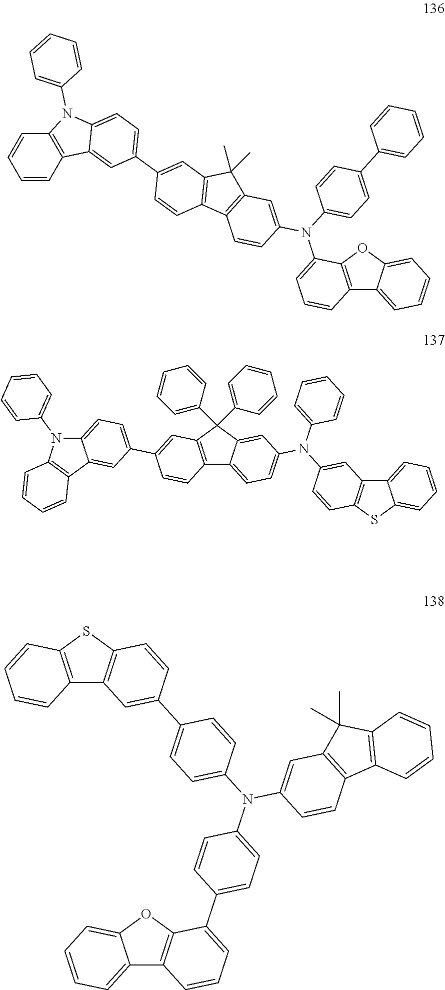 [SMILES: CC1(C)c2cc(-c3ccc4c(c3)c3ccccc3n4-c3ccccc3)ccc2-c2ccc(N(c3ccc(-c4ccccc4)cc3)c3cccc4c3oc3ccccc34)cc21 ; c1ccc(N(c2ccc3c(c2)C(c2ccccc2)(c2ccccc2)c2cc(-c4ccc5c(c4)c4ccccc4n5-c4ccccc4)ccc2-3)c2ccc3sc4ccccc4c3c2)cc1 ; CC1(C)c2ccccc2-c2ccc(N(c3ccc(-c4ccc5sc6ccccc6c5c4)cc3)c3ccc(-c4cccc5c4oc4ccccc45)cc3)cc21]

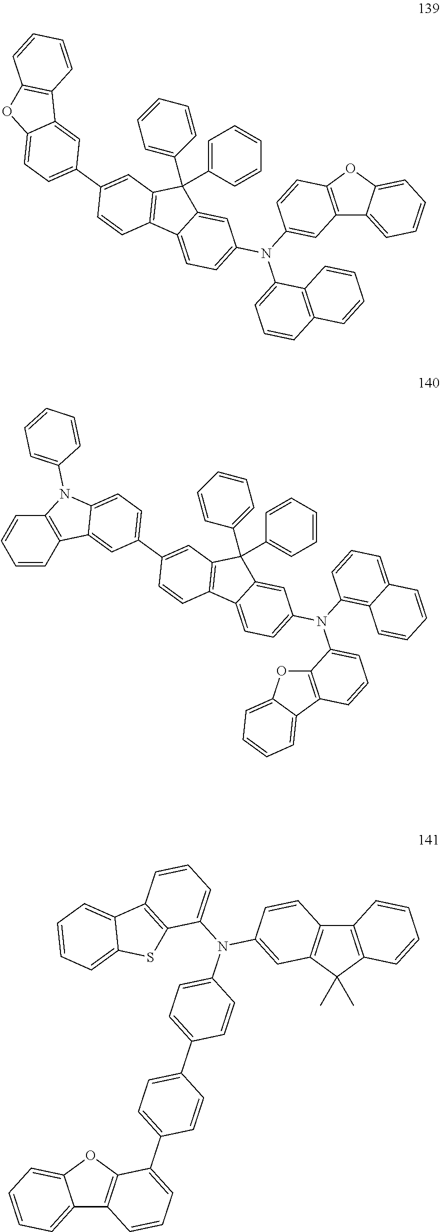 [SMILES: c1ccc(C2(c3ccccc3)c3cc(-c4ccc5oc6ccccc6c5c4)ccc3-c3ccc(N(c4ccc5oc6ccccc6c5c4)c4cccc5ccccc45)cc32)cc1 ; c1ccc(-n2c3ccccc3c3cc(-c4ccc5c(c4)C(c4ccccc4)(c4ccccc4)c4cc(N(c6cccc7ccccc67)c6cccc7c6oc6ccccc67)ccc4-5)ccc32)cc1 ; CC1(C)c2ccccc2-c2ccc(N(c3ccc(-c4ccc(-c5cccc6c5oc5ccccc56)cc4)cc3)c3cccc4c3sc3ccccc34)cc21]

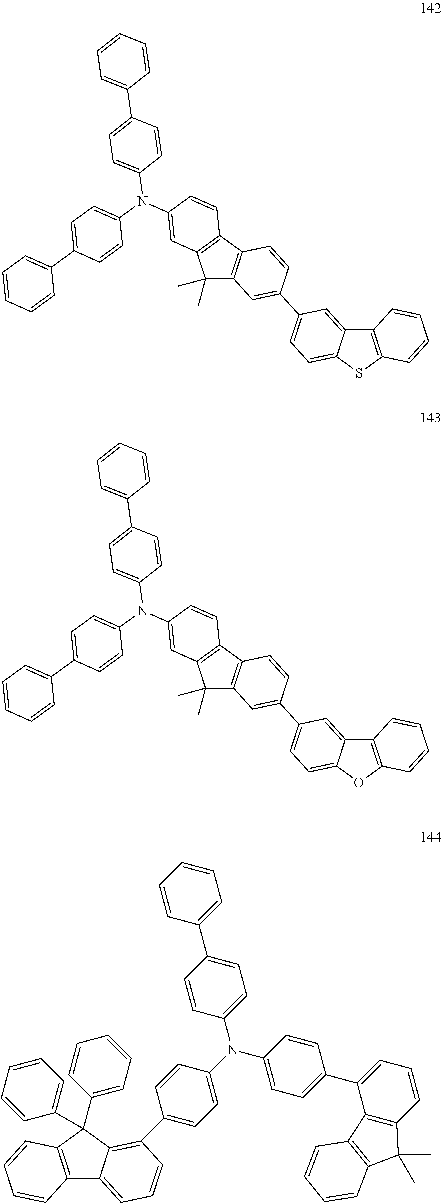 [SMILES: CC1(C)c2cc(-c3ccc4sc5ccccc5c4c3)ccc2-c2ccc(N(c3ccc(-c4ccccc4)cc3)c3ccc(-c4ccccc4)cc3)cc21 ; CC1(C)c2cc(-c3ccc4oc5ccccc5c4c3)ccc2-c2ccc(N(c3ccc(-c4ccccc4)cc3)c3ccc(-c4ccccc4)cc3)cc21 ; CC1(C)c2ccccc2-c2c(-c3ccc(N(c4ccc(-c5ccccc5)cc4)c4ccc(-c5cccc6c5C(c5ccccc5)(c5ccccc5)c5ccccc5-6)cc4)cc3)cccc21]

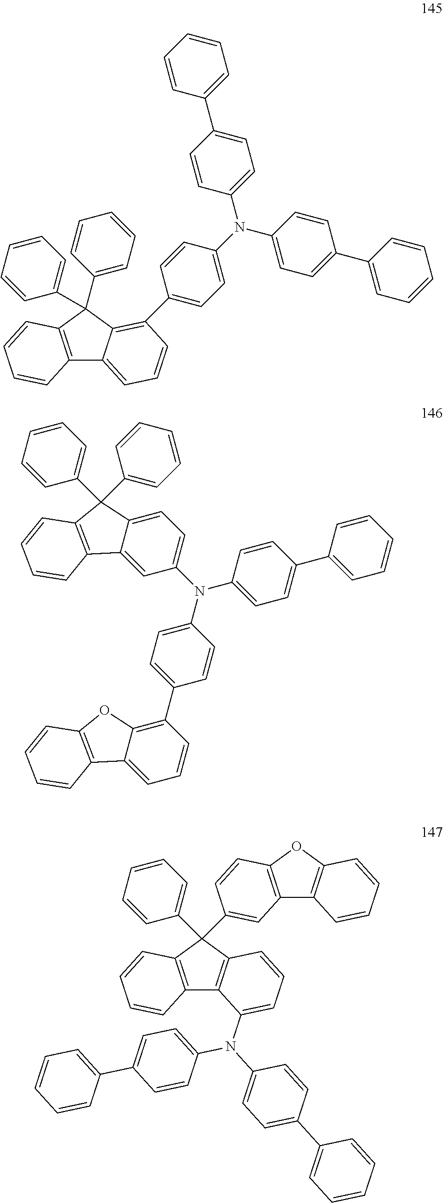

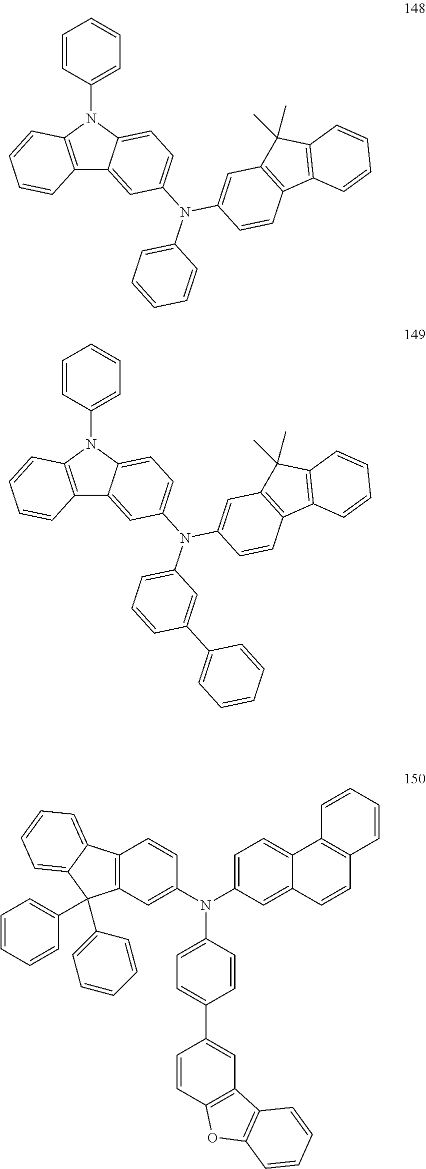 [SMILES: CC1(C)c2ccccc2-c2ccc(N(c3ccccc3)c3ccc4c(c3)c3ccccc3n4-c3ccccc3)cc21 ; CC1(C)c2ccccc2-c2ccc(N(c3cccc(-c4ccccc4)c3)c3ccc4c(c3)c3ccccc3n4-c3ccccc3)cc21 ; c1ccc(C2(c3ccccc3)c3ccccc3-c3ccc(N(c4ccc(-c5ccc6oc7ccccc7c6c5)cc4)c4ccc5c(ccc6ccccc65)c4)cc32)cc1]

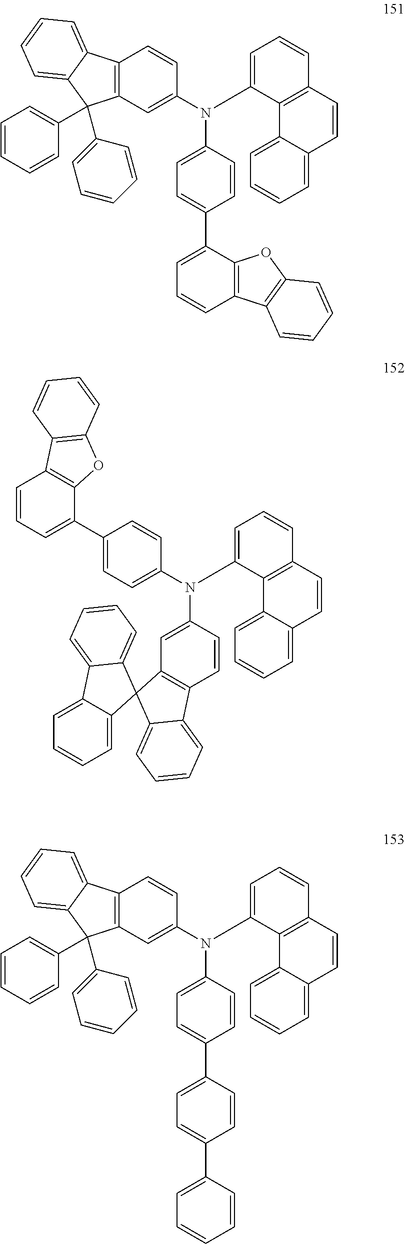 [SMILES: c1ccc(C2(c3ccccc3)c3ccccc3-c3ccc(N(c4ccc(-c5cccc6c5oc5ccccc56)cc4)c4cccc5ccc6ccccc6c45)cc32)cc1 ; c1ccc2c(c1)-c1ccccc1C21c2ccccc2-c2ccc(N(c3ccc(-c4cccc5c4oc4ccccc45)cc3)c3cccc4ccc5ccccc5c34)cc21 ; c1ccc(-c2ccc(-c3ccc(N(c4ccc5c(c4)C(c4ccccc4)(c4ccccc4)c4ccccc4-5)c4cccc5ccc6ccccc6c45)cc3)cc2)cc1]

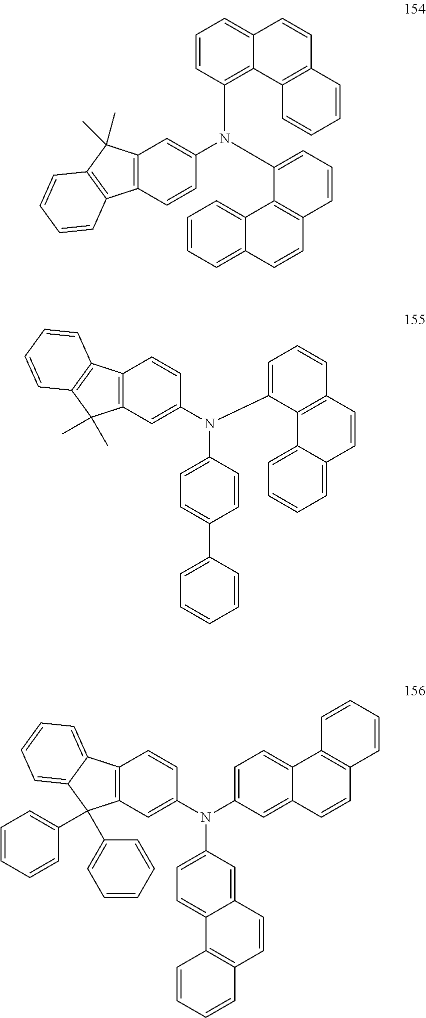 [SMILES: CC1(C)c2ccccc2-c2ccc(N(c3cccc4ccc5ccccc5c34)c3cccc4ccc5ccccc5c34)cc21 ; CC1(C)c2ccccc2-c2ccc(N(c3ccc(-c4ccccc4)cc3)c3cccc4ccc5ccccc5c34)cc21 ; c1ccc(C2(c3ccccc3)c3ccccc3-c3ccc(N(c4ccc5c(ccc6ccccc65)c4)c4ccc5c(ccc6ccccc65)c4)cc32)cc1]

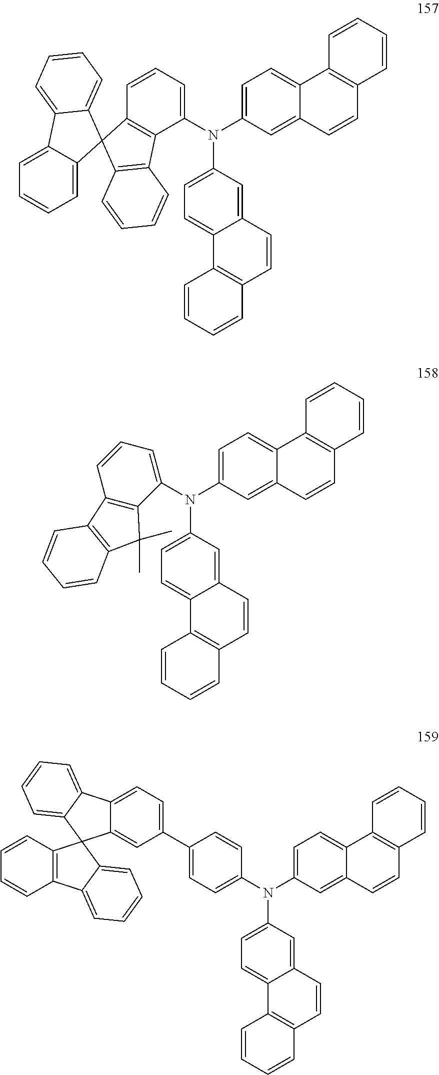 [SMILES: c1ccc2c(c1)-c1ccccc1C21c2ccccc2-c2c(N(c3ccc4c(ccc5ccccc54)c3)c3ccc4c(ccc5ccccc54)c3)cccc21 ; CC1(C)c2ccccc2-c2cccc(N(c3ccc4c(ccc5ccccc54)c3)c3ccc4c(ccc5ccccc54)c3)c21 ; c1ccc2c(c1)-c1ccccc1C21c2ccccc2-c2ccc(-c3ccc(N(c4ccc5c(ccc6ccccc65)c4)c4ccc5c(ccc6ccccc65)c4)cc3)cc21]

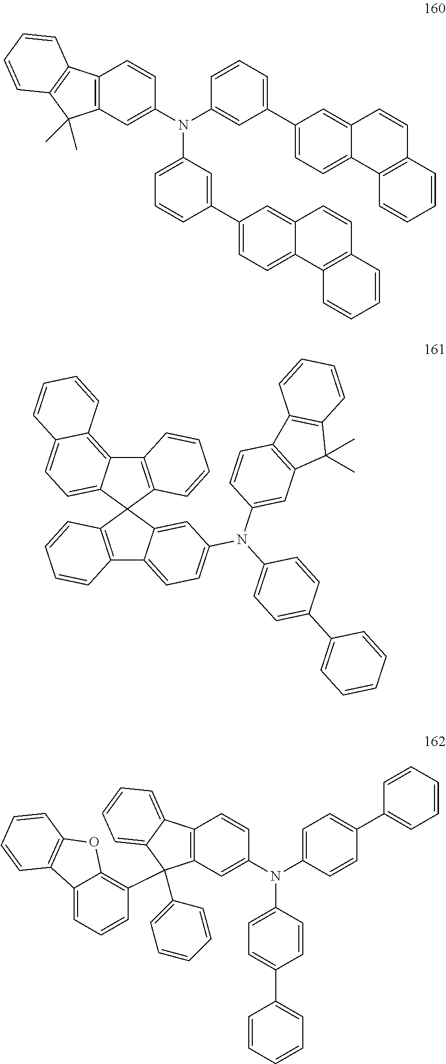 [SMILES: CC1(C)c2ccccc2-c2ccc(N(c3cccc(-c4ccc5c(ccc6ccccc65)c4)c3)c3cccc(-c4ccc5c(ccc6ccccc65)c4)c3)cc21 ; CC1(C)c2ccccc2-c2ccc(N(c3ccc(-c4ccccc4)cc3)c3ccc4c(c3)C3(c5ccccc5-4)c4ccccc4-c4c3ccc3ccccc43)cc21 ; c1ccc(-c2ccc(N(c3ccc(-c4ccccc4)cc3)c3ccc4c(c3)C(c3ccccc3)(c3cccc5c3oc3ccccc35)c3ccccc3-4)cc2)cc1]

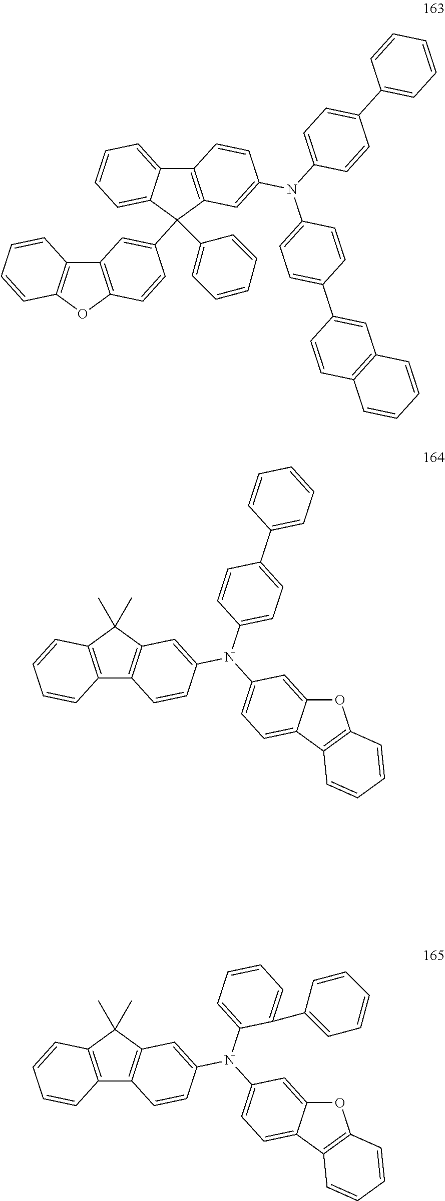 [SMILES: c1ccc(-c2ccc(N(c3ccc(-c4ccc5ccccc5c4)cc3)c3ccc4c(c3)C(c3ccccc3)(c3ccc5oc6ccccc6c5c3)c3ccccc3-4)cc2)cc1 ; CC1(C)c2ccccc2-c2ccc(N(c3ccc(-c4ccccc4)cc3)c3ccc4c(c3)oc3ccccc34)cc21 ; CC1(C)c2ccccc2-c2ccc(N(c3ccc4c(c3)oc3ccccc34)c3ccccc3-c3ccccc3)cc21]

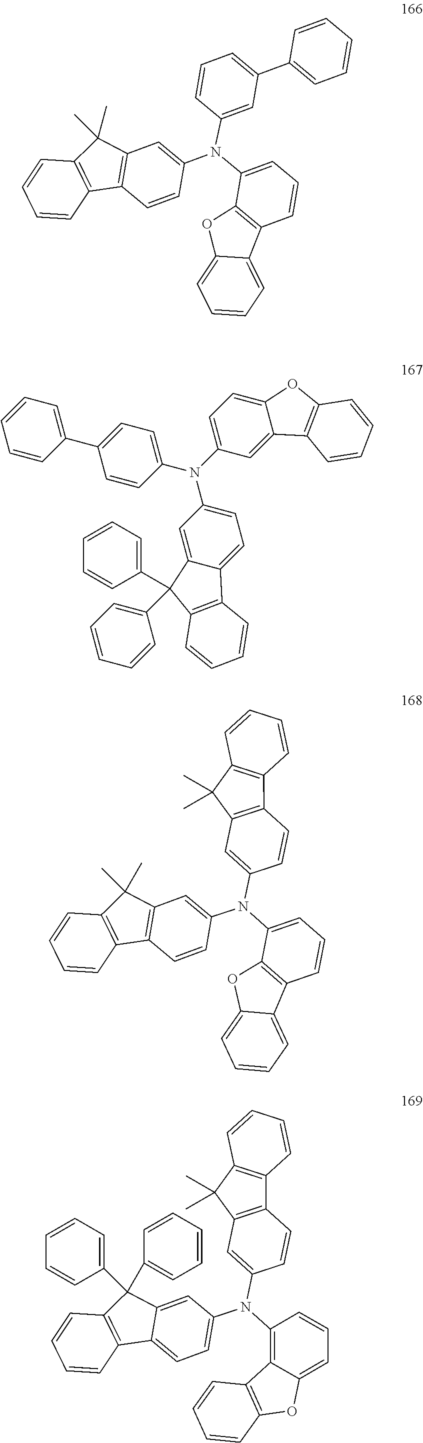

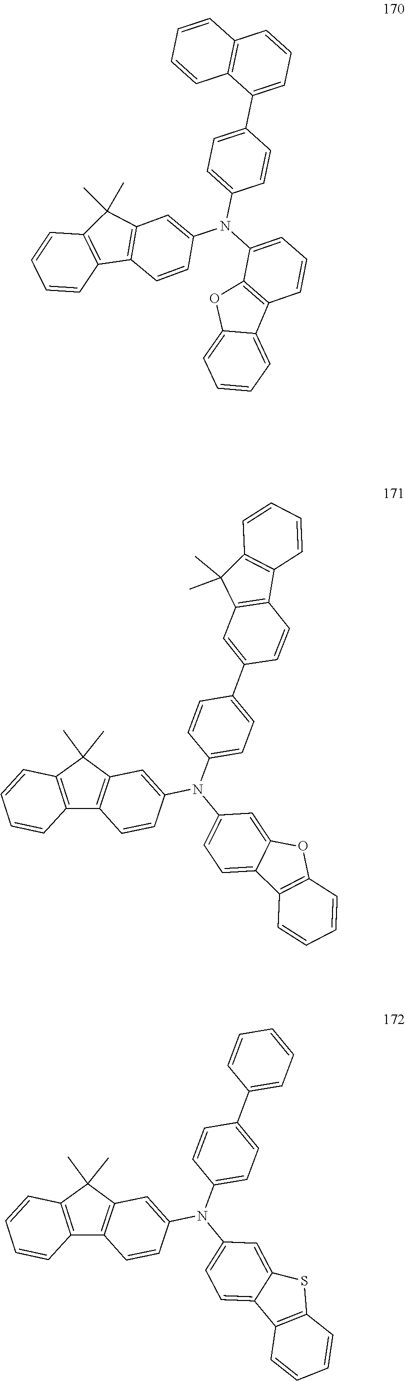 [SMILES: CC1(C)c2ccccc2-c2ccc(N(c3ccc(-c4cccc5ccccc45)cc3)c3cccc4c3oc3ccccc34)cc21 ; CC1(C)c2ccccc2-c2ccc(-c3ccc(N(c4ccc5c(c4)C(C)(C)c4ccccc4-5)c4ccc5c(c4)oc4ccccc45)cc3)cc21 ; CC1(C)c2ccccc2-c2ccc(N(c3ccc(-c4ccccc4)cc3)c3ccc4c(c3)sc3ccccc34)cc21]

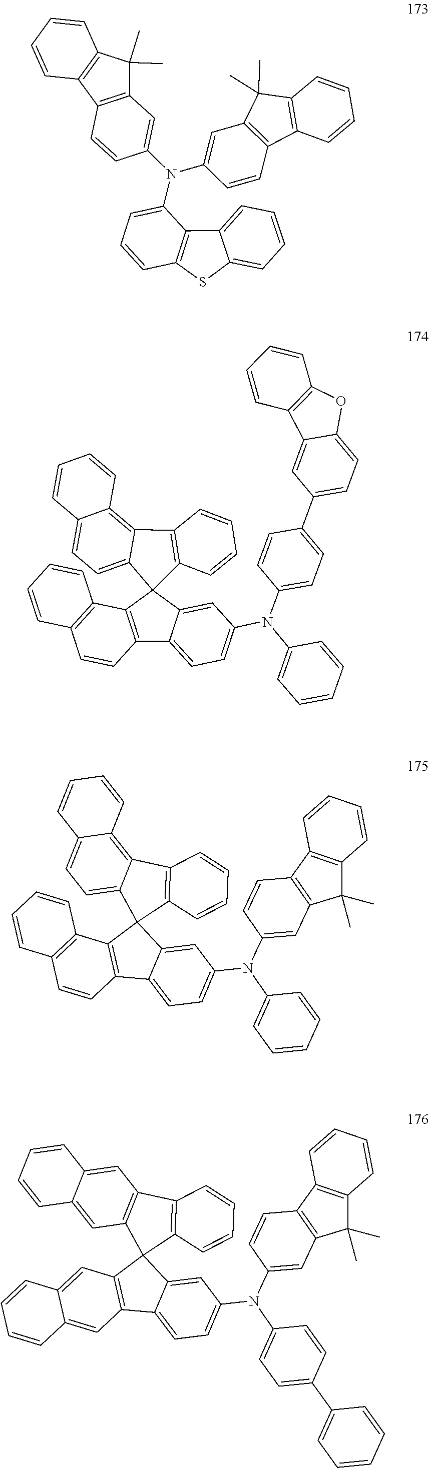 [SMILES: CC1(C)c2ccccc2-c2ccc(N(c3ccc4c(c3)C(C)(C)c3ccccc3-4)c3cccc4sc5ccccc5c34)cc21 ; c1ccc(N(c2ccc(-c3ccc4oc5ccccc5c4c3)cc2)c2ccc3c(c2)C2(c4ccccc4-c4c2ccc2ccccc42)c2c-3ccc3ccccc23)cc1 ; CC1(C)c2ccccc2-c2ccc(N(c3ccccc3)c3ccc4c(c3)C3(c5ccccc5-c5c3ccc3ccccc53)c3c-4ccc4ccccc34)cc21 ; CC1(C)c2ccccc2-c2ccc(N(c3ccc(-c4ccccc4)cc3)c3ccc4c(c3)C3(c5ccccc5-c5cc6ccccc6cc53)c3cc5ccccc5cc3-4)cc21]

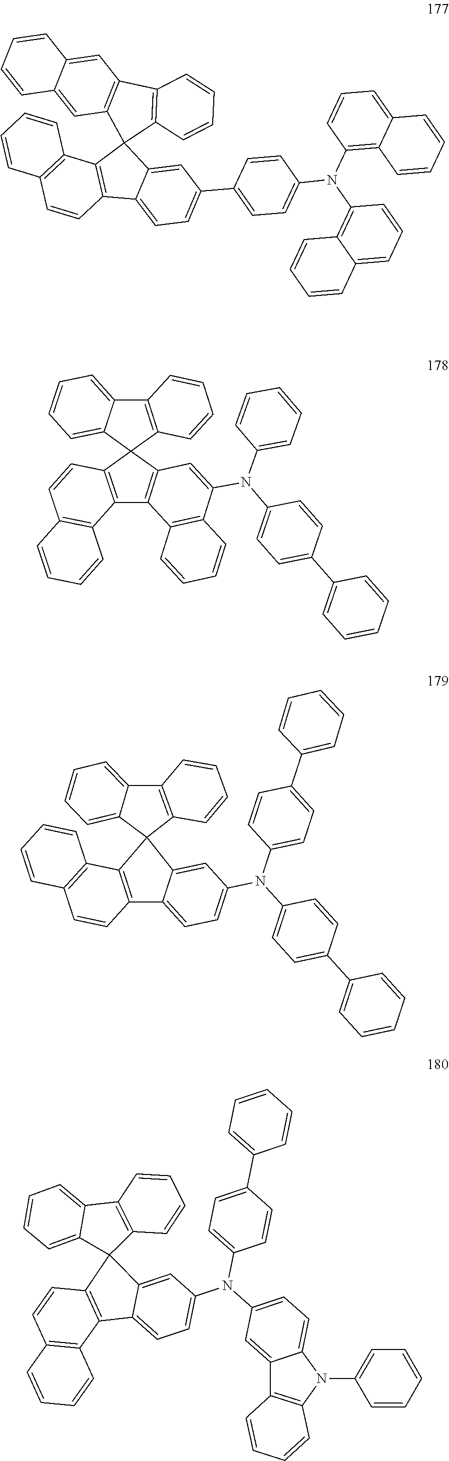 [SMILES: c1ccc2c(c1)-c1cc3ccccc3cc1C21c2cc(-c3ccc(N(c4cccc5ccccc45)c4cccc5ccccc45)cc3)ccc2-c2ccc3ccccc3c21 ; c1ccc(-c2ccc(N(c3ccccc3)c3cc4c(c5ccccc35)-c3c(ccc5ccccc35)C43c4ccccc4-c4ccccc43)cc2)cc1 ; c1ccc(-c2ccc(N(c3ccc(-c4ccccc4)cc3)c3ccc4c(c3)C3(c5ccccc5-c5ccccc53)c3c-4ccc4ccccc34)cc2)cc1 ; c1ccc(-c2ccc(N(c3ccc4c(c3)C3(c5ccccc5-c5ccccc53)c3ccc5ccccc5c3-4)c3ccc4c(c3)c3ccccc3n4-c3ccccc3)cc2)cc1]

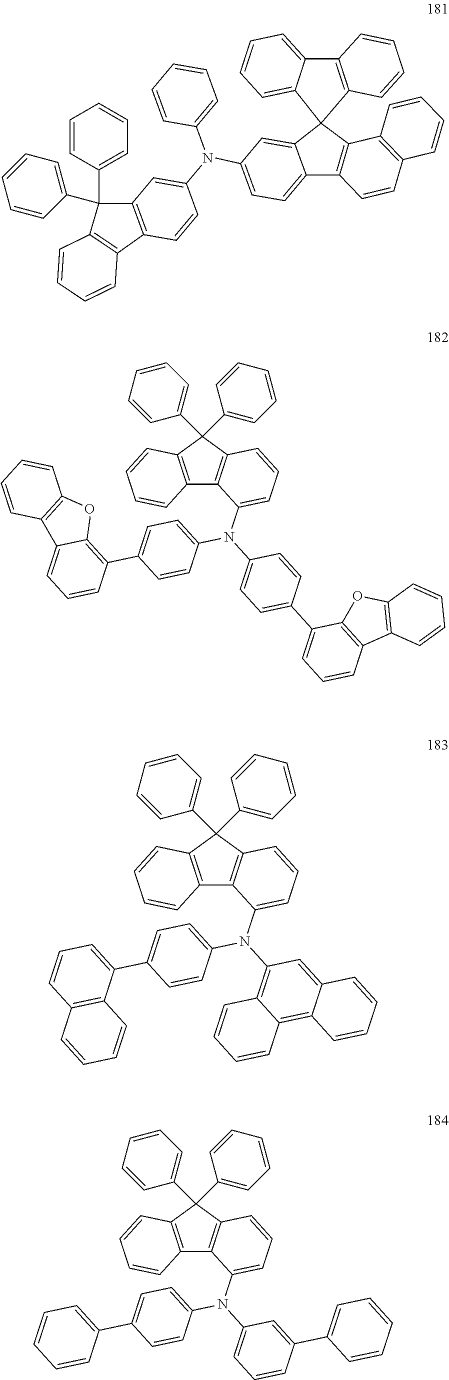 [SMILES: c1ccc(N(c2ccc3c(c2)C(c2ccccc2)(c2ccccc2)c2ccccc2-3)c2ccc3c(c2)C2(c4ccccc4-c4ccccc42)c2c-3ccc3ccccc23)cc1 ; c1ccc(C2(c3ccccc3)c3ccccc3-c3c(N(c4ccc(-c5cccc6c5oc5ccccc56)cc4)c4ccc(-c5cccc6c5oc5ccccc56)cc4)cccc32)cc1 ; c1ccc(C2(c3ccccc3)c3ccccc3-c3c(N(c4ccc(-c5cccc6ccccc56)cc4)c4cc5ccccc5c5ccccc45)cccc32)cc1 ; c1ccc(-c2ccc(N(c3cccc(-c4ccccc4)c3)c3cccc4c3-c3ccccc3C4(c3ccccc3)c3ccccc3)cc2)cc1]

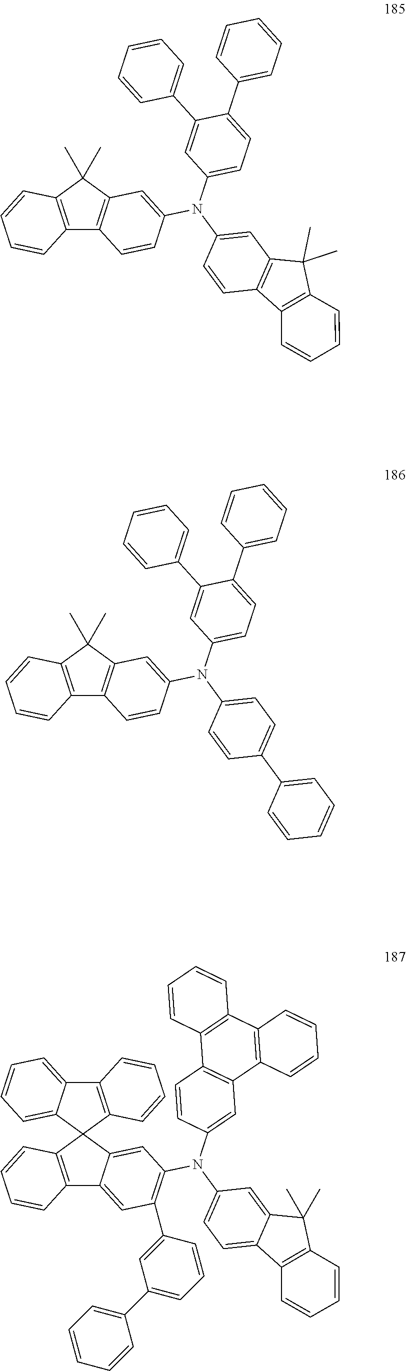 [SMILES: CC1(C)c2ccccc2-c2ccc(N(c3ccc(-c4ccccc4)c(-c4ccccc4)c3)c3ccc4c(c3)C(C)(C)c3ccccc3-4)cc21 ; CC1(C)c2ccccc2-c2ccc(N(c3ccc(-c4ccccc4)cc3)c3ccc(-c4ccccc4)c(-c4ccccc4)c3)cc21 ; CC1(C)c2ccccc2-c2ccc(N(c3ccc4c5ccccc5c5ccccc5c4c3)c3cc4c(cc3-c3cccc(-c5ccccc5)c3)-c3ccccc3C43c4ccccc4-c4ccccc43)cc21]

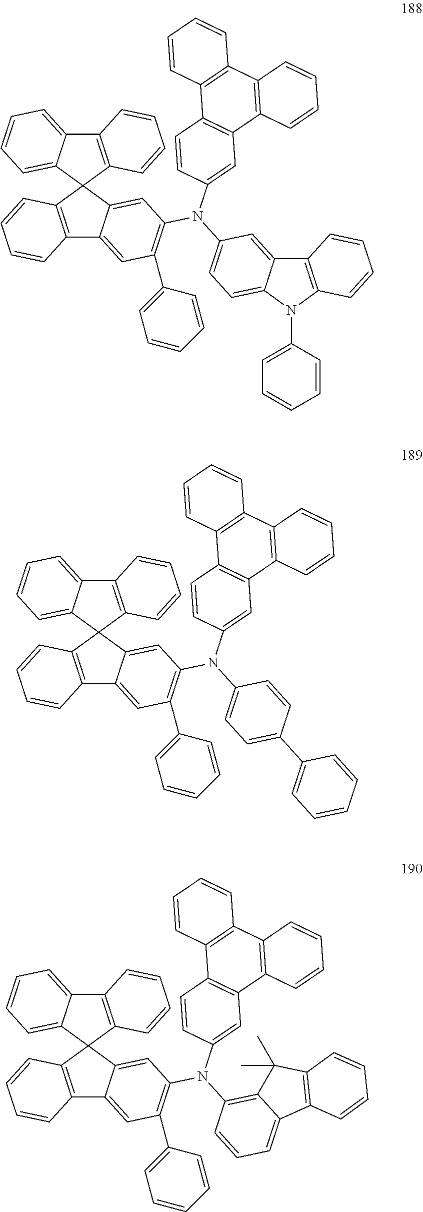 [SMILES: c1ccc(-c2cc3c(cc2N(c2ccc4c5ccccc5c5ccccc5c4c2)c2ccc4c(c2)c2ccccc2n4-c2ccccc2)C2(c4ccccc4-c4ccccc42)c2ccccc2-3)cc1 ; c1ccc(-c2ccc(N(c3ccc4c5ccccc5c5ccccc5c4c3)c3cc4c(cc3-c3ccccc3)-c3ccccc3C43c4ccccc4-c4ccccc43)cc2)cc1 ; CC1(C)c2ccccc2-c2cccc(N(c3ccc4c5ccccc5c5ccccc5c4c3)c3cc4c(cc3-c3ccccc3)-c3ccccc3C43c4ccccc4-c4ccccc43)c21]

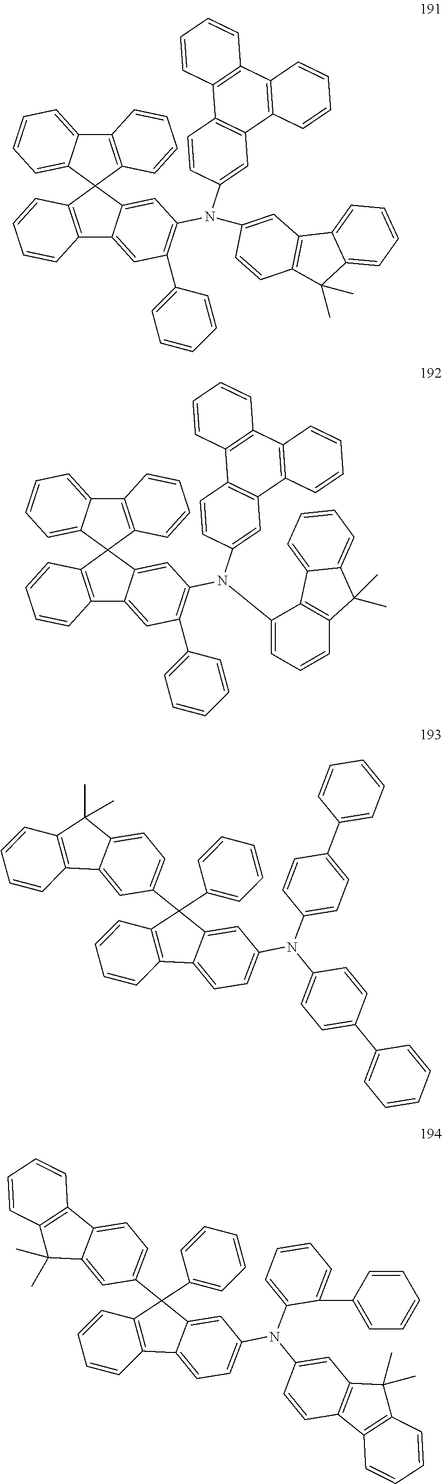

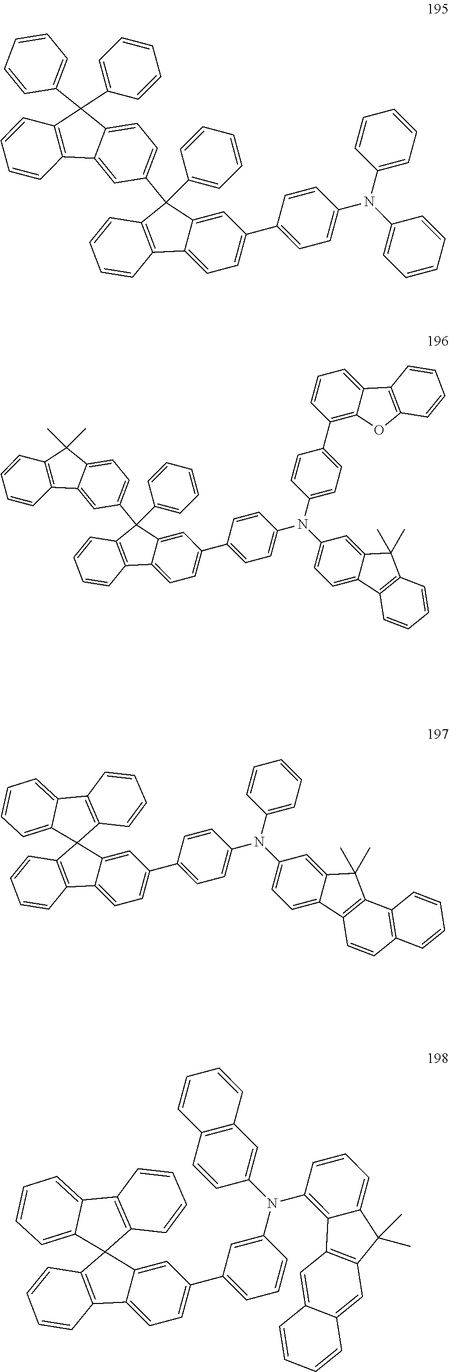 [SMILES: c1ccc(N(c2ccccc2)c2ccc(-c3ccc4c(c3)C(c3ccccc3)(c3ccc5c(c3)-c3ccccc3C5(c3ccccc3)c3ccccc3)c3ccccc3-4)cc2)cc1 ; CC1(C)c2ccccc2-c2cc(C3(c4ccccc4)c4ccccc4-c4ccc(-c5ccc(N(c6ccc(-c7cccc8c7oc7ccccc78)cc6)c6ccc7c(c6)C(C)(C)c6ccccc6-7)cc5)cc43)ccc21 ; CC1(C)c2cc(N(c3ccccc3)c3ccc(-c4ccc5c(c4)C4(c6ccccc6-c6ccccc64)c4ccccc4-5)cc3)ccc2-c2ccc3ccccc3c21 ; CC1(C)c2cc3ccccc3cc2-c2c(N(c3cccc(-c4ccc5c(c4)C4(c6ccccc6-c6ccccc64)c4ccccc4-5)c3)c3ccc4ccccc4c3)cccc21]

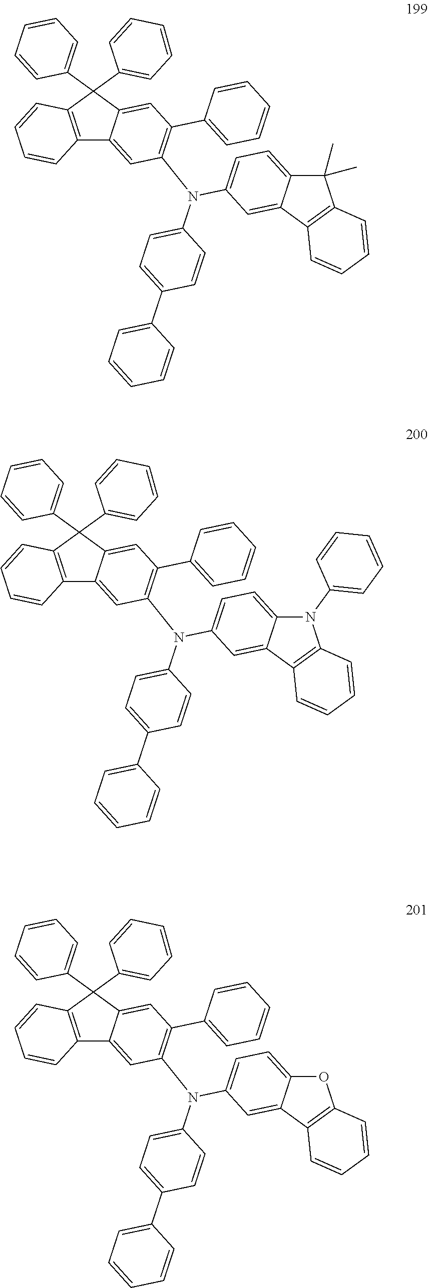 [SMILES: CC1(C)c2ccccc2-c2cc(N(c3ccc(-c4ccccc4)cc3)c3cc4c(cc3-c3ccccc3)C(c3ccccc3)(c3ccccc3)c3ccccc3-4)ccc21 ; c1ccc(-c2ccc(N(c3ccc4c(c3)c3ccccc3n4-c3ccccc3)c3cc4c(cc3-c3ccccc3)C(c3ccccc3)(c3ccccc3)c3ccccc3-4)cc2)cc1 ; c1ccc(-c2ccc(N(c3ccc4oc5ccccc5c4c3)c3cc4c(cc3-c3ccccc3)C(c3ccccc3)(c3ccccc3)c3ccccc3-4)cc2)cc1]

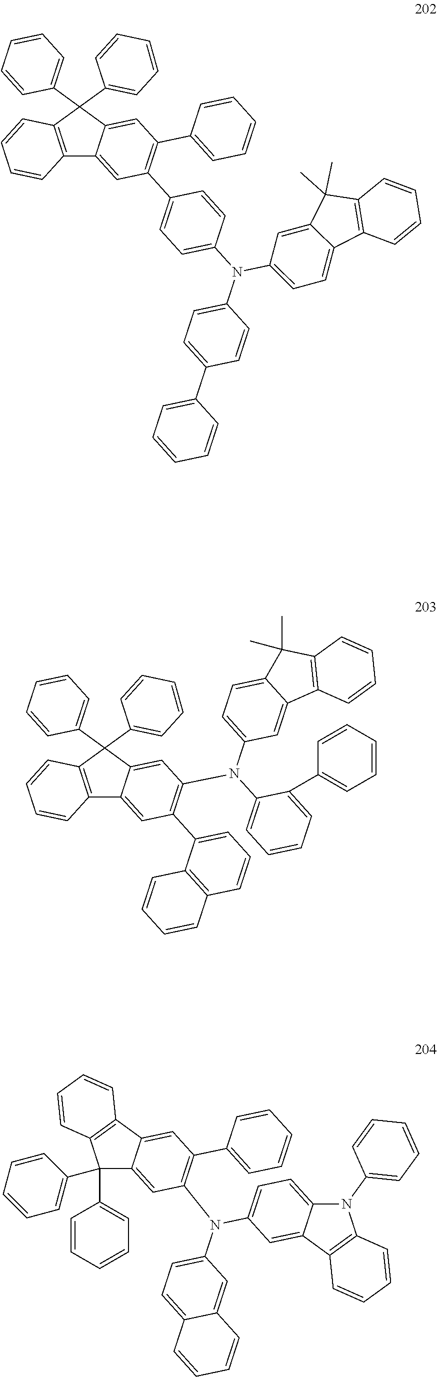 [SMILES: CC1(C)c2ccccc2-c2ccc(N(c3ccc(-c4ccccc4)cc3)c3ccc(-c4cc5c(cc4-c4ccccc4)C(c4ccccc4)(c4ccccc4)c4ccccc4-5)cc3)cc21 ; CC1(C)c2ccccc2-c2cc(N(c3ccccc3-c3ccccc3)c3cc4c(cc3-c3cccc5ccccc35)-c3ccccc3C4(c3ccccc3)c3ccccc3)ccc21 ; c1ccc(-c2cc3c(cc2N(c2ccc4ccccc4c2)c2ccc4c(c2)c2ccccc2n4-c2ccccc2)C(c2ccccc2)(c2ccccc2)c2ccccc2-3)cc1]

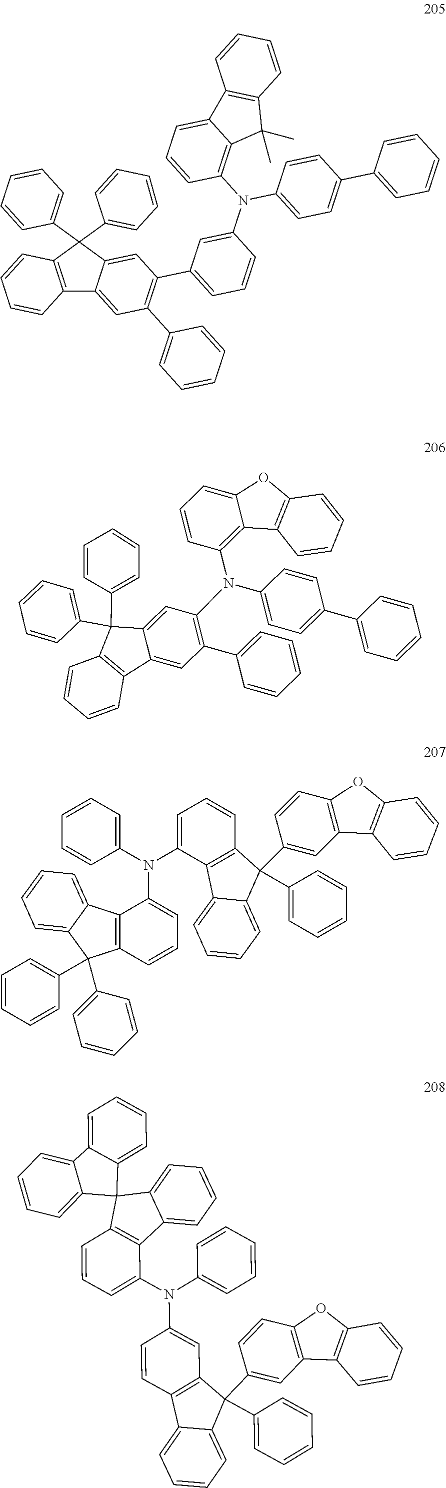

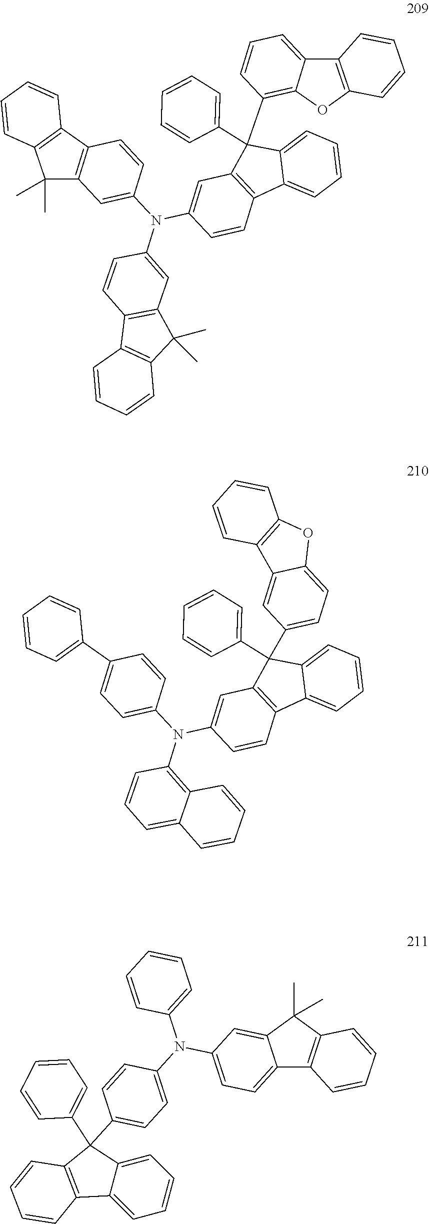 [SMILES: CC1(C)c2ccccc2-c2ccc(N(c3ccc4c(c3)C(C)(C)c3ccccc3-4)c3ccc4c(c3)C(c3ccccc3)(c3cccc5c3oc3ccccc35)c3ccccc3-4)cc21 ; c1ccc(-c2ccc(N(c3ccc4c(c3)C(c3ccccc3)(c3ccc5oc6ccccc6c5c3)c3ccccc3-4)c3cccc4ccccc34)cc2)cc1 ; CC1(C)c2ccccc2-c2ccc(N(c3ccccc3)c3ccc(C4(c5ccccc5)c5ccccc5-c5ccccc54)cc3)cc21]

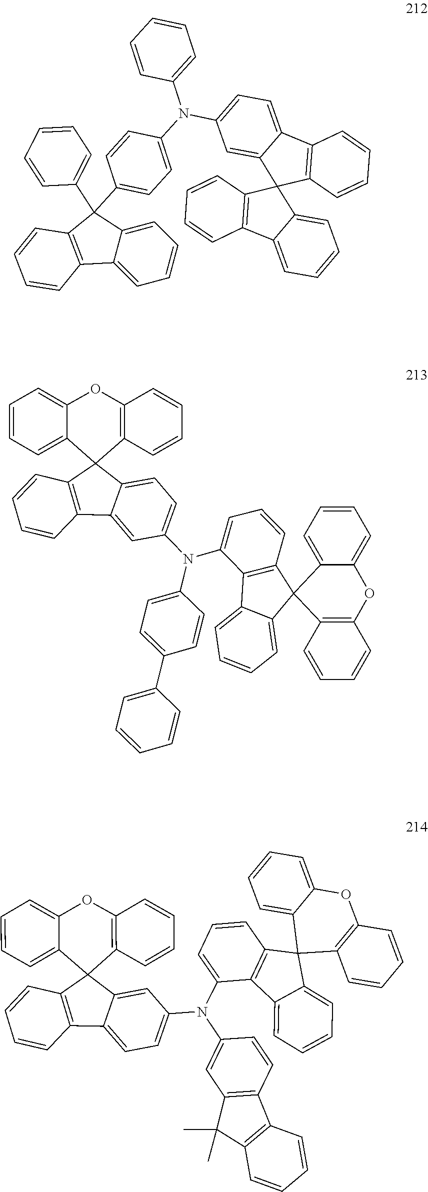 [SMILES: c1ccc(N(c2ccc(C3(c4ccccc4)c4ccccc4-c4ccccc43)cc2)c2ccc3c(c2)C2(c4ccccc4-c4ccccc42)c2ccccc2-3)cc1 ; c1ccc(-c2ccc(N(c3ccc4c(c3)-c3ccccc3C43c4ccccc4Oc4ccccc43)c3cccc4c3-c3ccccc3C43c4ccccc4Oc4ccccc43)cc2)cc1 ; CC1(C)c2ccccc2-c2ccc(N(c3ccc4c(c3)C3(c5ccccc5Oc5ccccc53)c3ccccc3-4)c3cccc4c3-c3ccccc3C43c4ccccc4Oc4ccccc43)cc21]

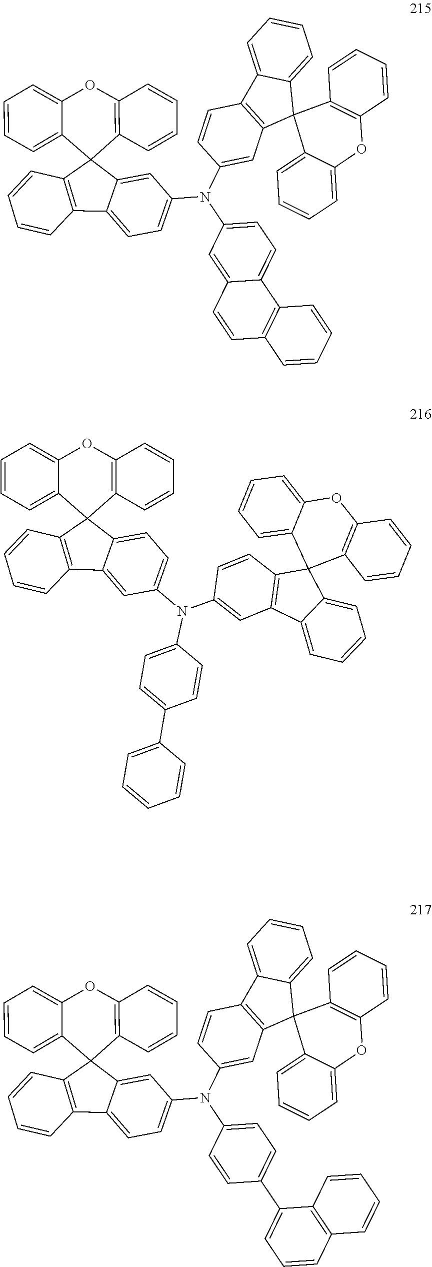 [SMILES: c1ccc2c(c1)Oc1ccccc1C21c2ccccc2-c2ccc(N(c3ccc4c(c3)C3(c5ccccc5Oc5ccccc53)c3ccccc3-4)c3ccc4c(ccc5ccccc54)c3)cc21 ; c1ccc(-c2ccc(N(c3ccc4c(c3)-c3ccccc3C43c4ccccc4Oc4ccccc43)c3ccc4c(c3)-c3ccccc3C43c4ccccc4Oc4ccccc43)cc2)cc1 ; c1ccc2c(c1)Oc1ccccc1C21c2ccccc2-c2ccc(N(c3ccc(-c4cccc5ccccc45)cc3)c3ccc4c(c3)C3(c5ccccc5Oc5ccccc53)c3ccccc3-4)cc21]

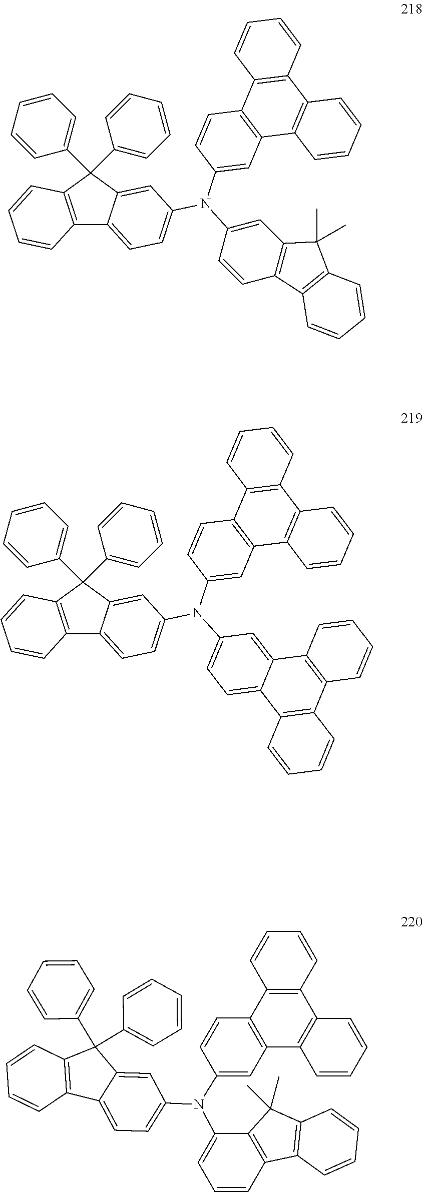 [SMILES: CC1(C)c2ccccc2-c2ccc(N(c3ccc4c(c3)C(c3ccccc3)(c3ccccc3)c3ccccc3-4)c3ccc4c5ccccc5c5ccccc5c4c3)cc21 ; c1ccc(C2(c3ccccc3)c3ccccc3-c3ccc(N(c4ccc5c6ccccc6c6ccccc6c5c4)c4ccc5c6ccccc6c6ccccc6c5c4)cc32)cc1 ; CC1(C)c2ccccc2-c2cccc(N(c3ccc4c(c3)C(c3ccccc3)(c3ccccc3)c3ccccc3-4)c3ccc4c5ccccc5c5ccccc5c4c3)c21]

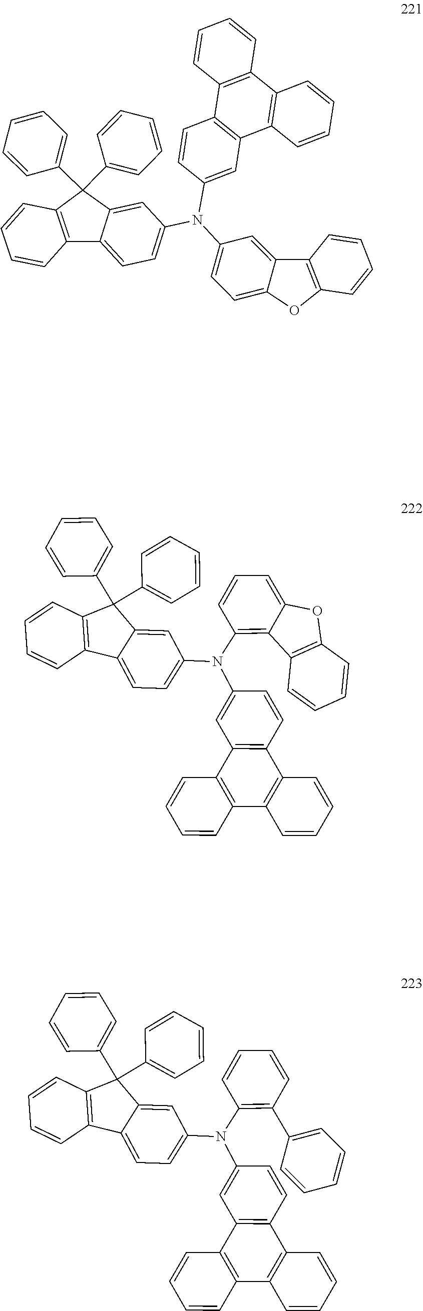 [SMILES: c1ccc(C2(c3ccccc3)c3ccccc3-c3ccc(N(c4ccc5oc6ccccc6c5c4)c4ccc5c6ccccc6c6ccccc6c5c4)cc32)cc1 ; c1ccc(C2(c3ccccc3)c3ccccc3-c3ccc(N(c4ccc5c6ccccc6c6ccccc6c5c4)c4cccc5oc6ccccc6c45)cc32)cc1 ; c1ccc(-c2ccccc2N(c2ccc3c(c2)C(c2ccccc2)(c2ccccc2)c2ccccc2-3)c2ccc3c4ccccc4c4ccccc4c3c2)cc1]

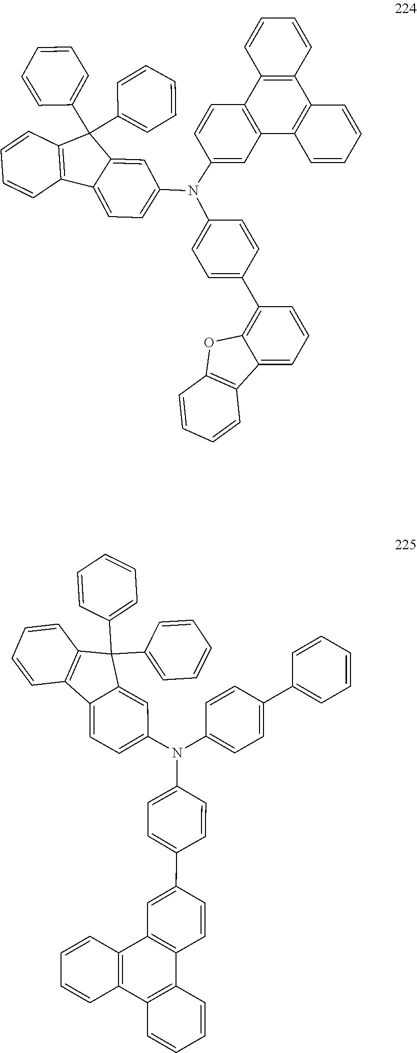 [SMILES: c1ccc(C2(c3ccccc3)c3ccccc3-c3ccc(N(c4ccc(-c5cccc6c5oc5ccccc56)cc4)c4ccc5c6ccccc6c6ccccc6c5c4)cc32)cc1 ; c1ccc(-c2ccc(N(c3ccc(-c4ccc5c6ccccc6c6ccccc6c5c4)cc3)c3ccc4c(c3)C(c3ccccc3)(c3ccccc3)c3ccccc3-4)cc2)cc1]

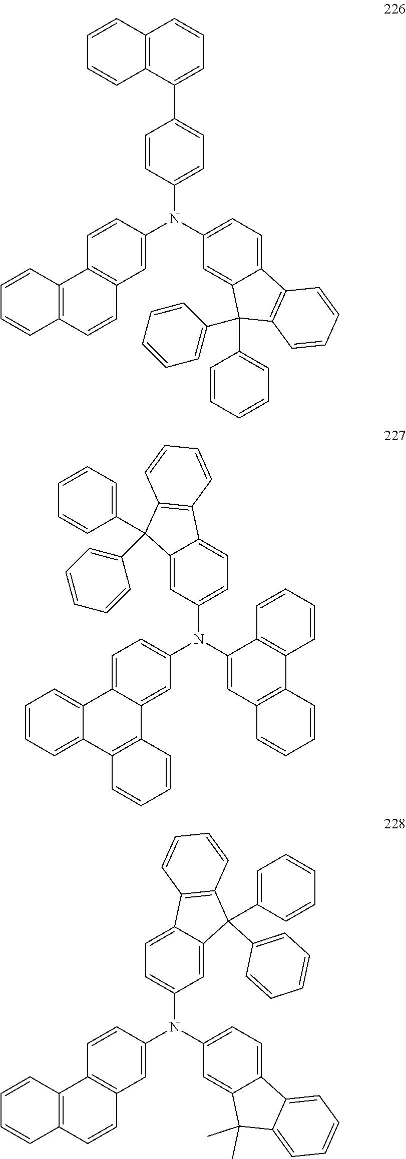

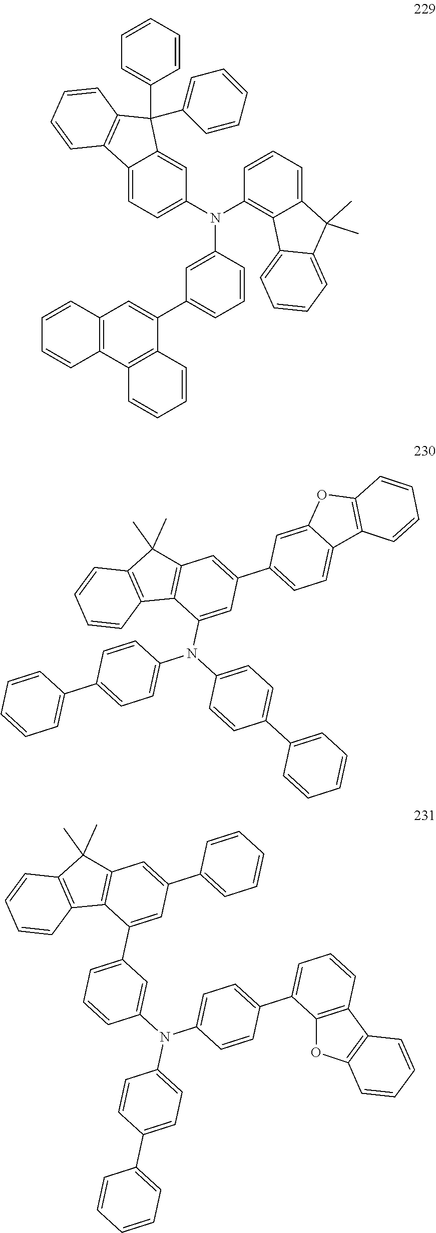 [SMILES: CC1(C)c2ccccc2-c2c(N(c3cccc(-c4cc5ccccc5c5ccccc45)c3)c3ccc4c(c3)C(c3ccccc3)(c3ccccc3)c3ccccc3-4)cccc21 ; CC1(C)c2ccccc2-c2c(N(c3ccc(-c4ccccc4)cc3)c3ccc(-c4ccccc4)cc3)cc(-c3ccc4c(c3)oc3ccccc34)cc21 ; CC1(C)c2ccccc2-c2c(-c3cccc(N(c4ccc(-c5ccccc5)cc4)c4ccc(-c5cccc6c5oc5ccccc56)cc4)c3)cc(-c3ccccc3)cc21]

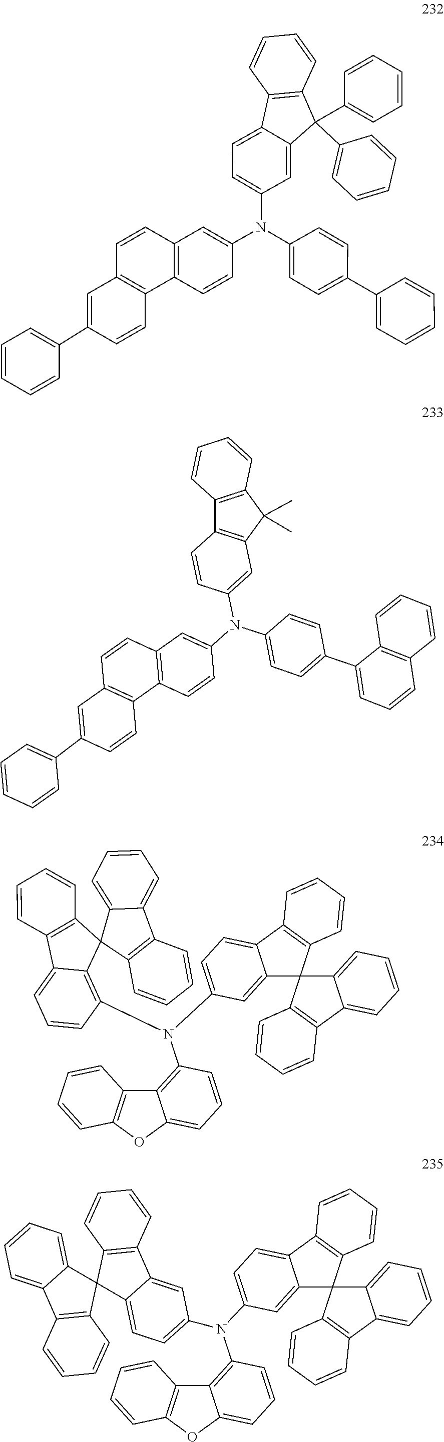 [SMILES: c1ccc(-c2ccc(N(c3ccc4c(c3)C(c3ccccc3)(c3ccccc3)c3ccccc3-4)c3ccc4c(ccc5cc(-c6ccccc6)ccc54)c3)cc2)cc1 ; CC1(C)c2ccccc2-c2ccc(N(c3ccc(-c4cccc5ccccc45)cc3)c3ccc4c(ccc5cc(-c6ccccc6)ccc54)c3)cc21 ; c1ccc2c(c1)-c1ccccc1C21c2ccccc2-c2ccc(N(c3cccc4c3C3(c5ccccc5-c5ccccc53)c3ccccc3-4)c3cccc4oc5ccccc5c34)cc21 ; c1ccc2c(c1)-c1ccccc1C21c2ccccc2-c2cc(N(c3ccc4c(c3)C3(c5ccccc5-c5ccccc53)c3ccccc3-4)c3cccc4oc5ccccc5c34)ccc21]

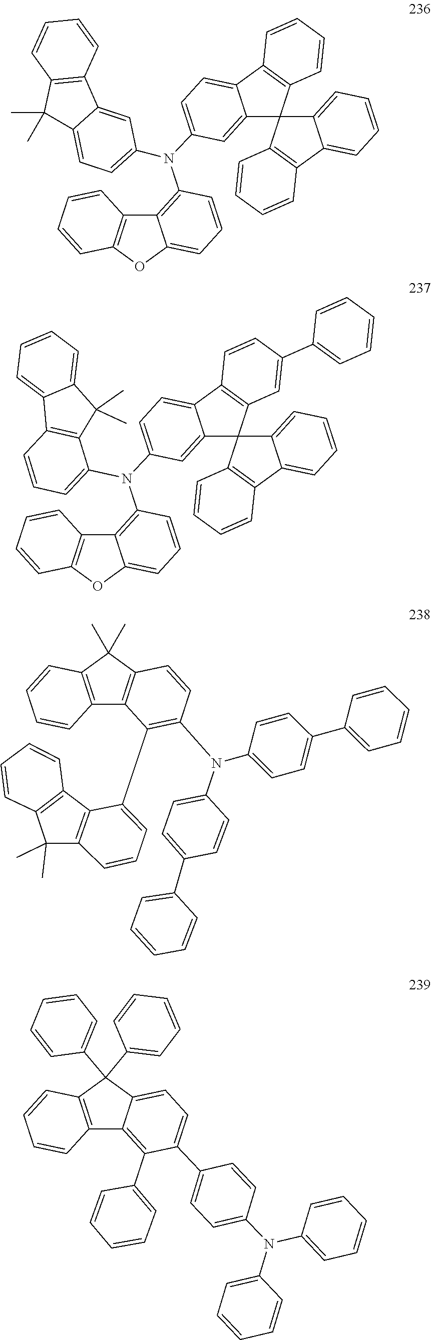

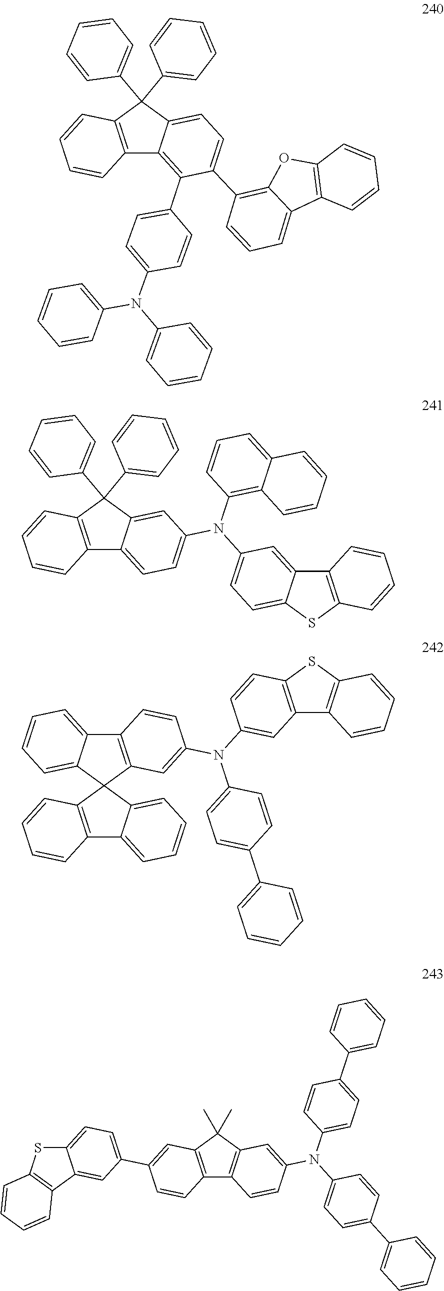

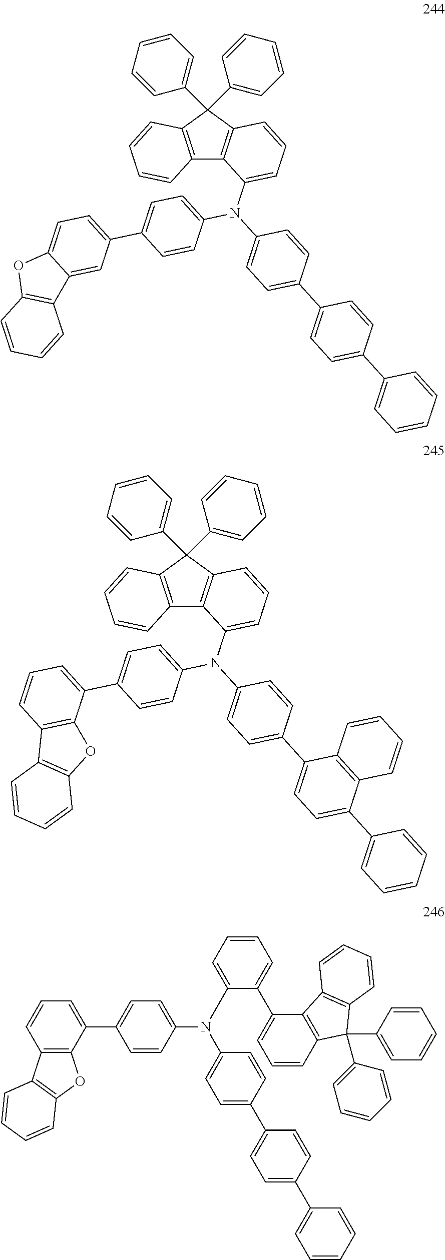 [SMILES: c1ccc(-c2ccc(-c3ccc(N(c4ccc(-c5ccc6oc7ccccc7c6c5)cc4)c4cccc5c4-c4ccccc4C5(c4ccccc4)c4ccccc4)cc3)cc2)cc1 ; c1ccc(-c2ccc(-c3ccc(N(c4ccc(-c5cccc6c5oc5ccccc56)cc4)c4cccc5c4-c4ccccc4C5(c4ccccc4)c4ccccc4)cc3)c3ccccc23)cc1 ; c1ccc(-c2ccc(-c3ccc(N(c4ccc(-c5cccc6c5oc5ccccc56)cc4)c4ccccc4-c4cccc5c4-c4ccccc4C5(c4ccccc4)c4ccccc4)cc3)cc2)cc1]

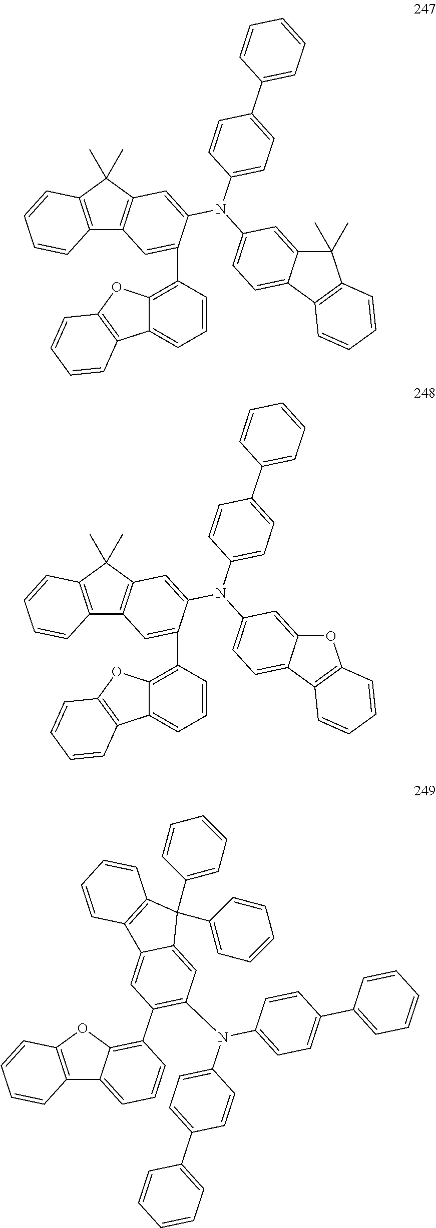 [SMILES: CC1(C)c2ccccc2-c2ccc(N(c3ccc(-c4ccccc4)cc3)c3cc4c(cc3-c3cccc5c3oc3ccccc35)-c3ccccc3C4(C)C)cc21 ; CC1(C)c2ccccc2-c2cc(-c3cccc4c3oc3ccccc34)c(N(c3ccc(-c4ccccc4)cc3)c3ccc4c(c3)oc3ccccc34)cc21 ; c1ccc(-c2ccc(N(c3ccc(-c4ccccc4)cc3)c3cc4c(cc3-c3cccc5c3oc3ccccc35)-c3ccccc3C4(c3ccccc3)c3ccccc3)cc2)cc1]

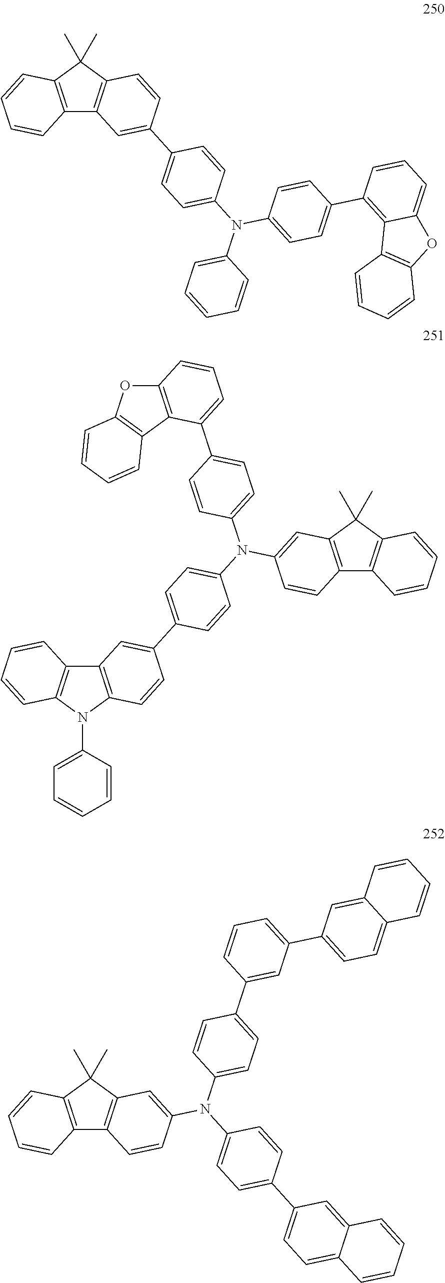 [SMILES: CC1(C)c2ccccc2-c2cc(-c3ccc(N(c4ccccc4)c4ccc(-c5cccc6oc7ccccc7c56)cc4)cc3)ccc21 ; CC1(C)c2ccccc2-c2ccc(N(c3ccc(-c4ccc5c(c4)c4ccccc4n5-c4ccccc4)cc3)c3ccc(-c4cccc5oc6ccccc6c45)cc3)cc21 ; CC1(C)c2ccccc2-c2ccc(N(c3ccc(-c4cccc(-c5ccc6ccccc6c5)c4)cc3)c3ccc(-c4ccc5ccccc5c4)cc3)cc21]

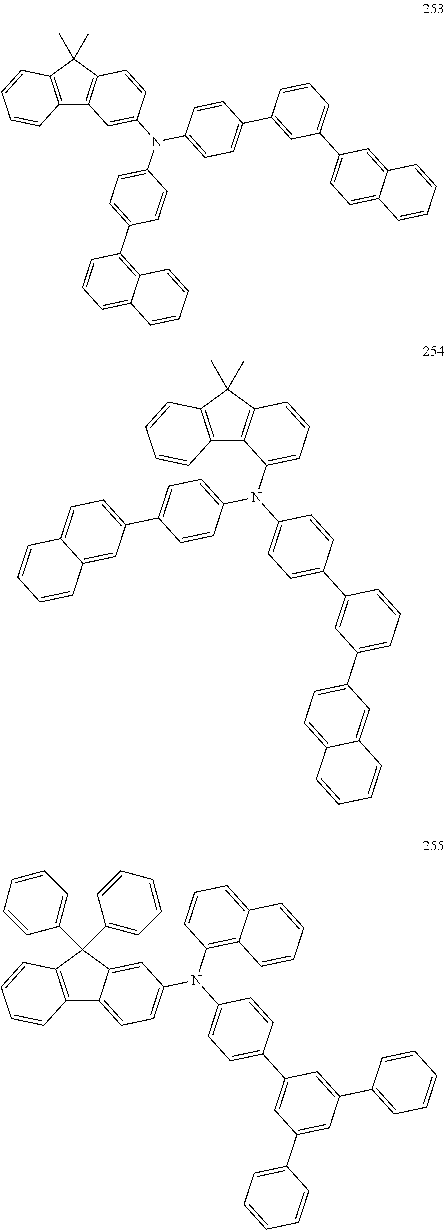 [SMILES: CC1(C)c2ccccc2-c2cc(N(c3ccc(-c4cccc(-c5ccc6ccccc6c5)c4)cc3)c3ccc(-c4cccc5ccccc45)cc3)ccc21 ; CC1(C)c2ccccc2-c2c(N(c3ccc(-c4cccc(-c5ccc6ccccc6c5)c4)cc3)c3ccc(-c4ccc5ccccc5c4)cc3)cccc21 ; c1ccc(-c2cc(-c3ccccc3)cc(-c3ccc(N(c4ccc5c(c4)C(c4ccccc4)(c4ccccc4)c4ccccc4-5)c4cccc5ccccc45)cc3)c2)cc1]

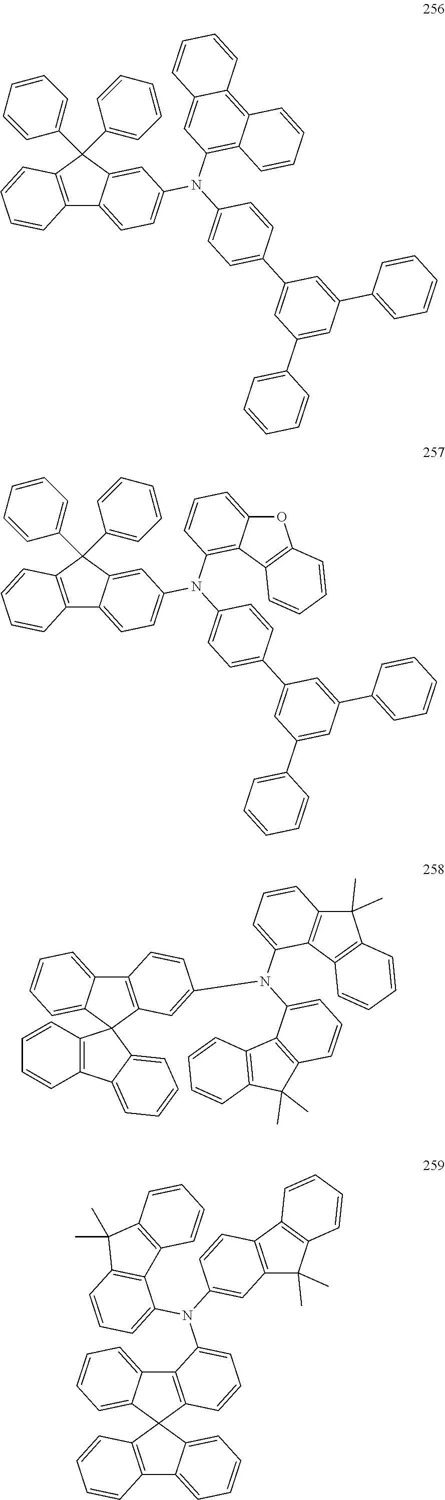 [SMILES: c1ccc(-c2cc(-c3ccccc3)cc(-c3ccc(N(c4ccc5c(c4)C(c4ccccc4)(c4ccccc4)c4ccccc4-5)c4cc5ccccc5c5ccccc45)cc3)c2)cc1 ; c1ccc(-c2cc(-c3ccccc3)cc(-c3ccc(N(c4ccc5c(c4)C(c4ccccc4)(c4ccccc4)c4ccccc4-5)c4cccc5oc6ccccc6c45)cc3)c2)cc1 ; CC1(C)c2ccccc2-c2c(N(c3ccc4c(c3)C3(c5ccccc5-c5ccccc53)c3ccccc3-4)c3cccc4c3-c3ccccc3C4(C)C)cccc21 ; CC1(C)c2ccccc2-c2ccc(N(c3cccc4c3-c3ccccc3C4(C)C)c3cccc4c3-c3ccccc3C43c4ccccc4-c4ccccc43)cc21]

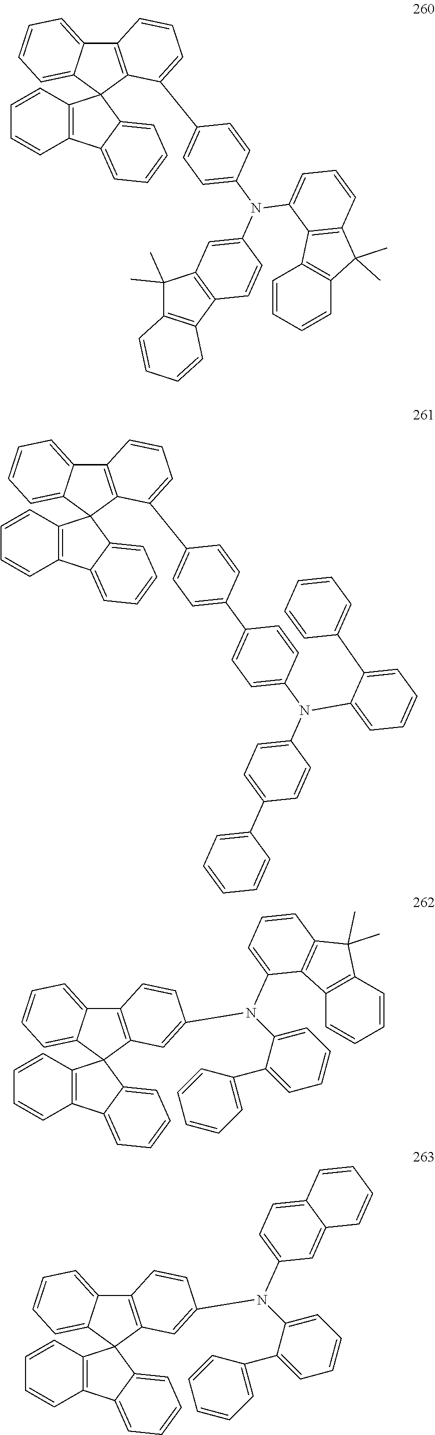

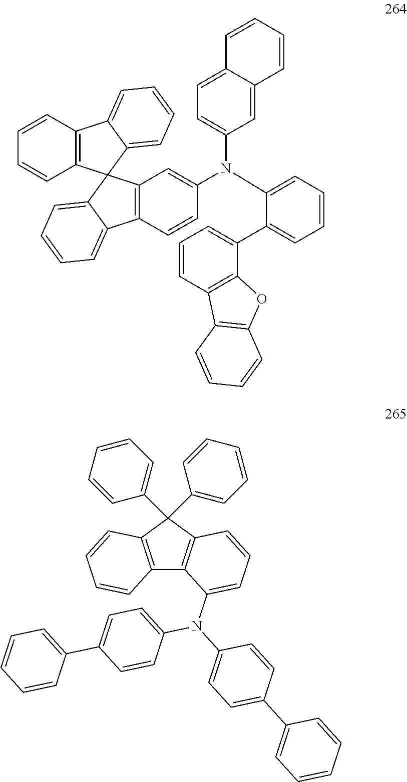 [SMILES: c1ccc(N(c2ccc3c(c2)C2(c4ccccc4-c4ccccc42)c2ccccc2-3)c2ccc3ccccc3c2)c(-c2cccc3c2oc2ccccc23)c1 ; c1ccc(-c2ccc(N(c3ccc(-c4ccccc4)cc3)c3cccc4c3-c3ccccc3C4(c3ccccc3)c3ccccc3)cc2)cc1]

Processes for synthesis of the compounds of the formulae (II) and (III) are known in the prior art, especially in the publications cited in the table below:

| Structure type | Publication |
|---|---|
| 2-Fluorenylamines | WO2013/118846 |
| 2-Spirobifluoreneamines with | WO2016/199784 |
| triphenylene | |
| 2,4′-Spirobifluorenyldiamines | WO2017/061779 |
| Aminocarbazoles | WO2012/043531 |
| Phenanthreneamines | WO2017/022729 |
| 9,9′-Diphenylfluorenyl-2-amines | US2020/106017 |
| 4-Fluorenylamines with | WO2019/168320 |
| substituents | |
| 4-Fluorenylamines with spacer | WO2019/216411 |
| group between amine and | |
| fluorenyl group | |
| Spirobifluorenes with amino group | WO2013/120577, WO2017/016632, |
| in 1, 3 or 4 position | WO2017/102063, WO2017/102064 |
| 2-Spirobifluorenylamines | WO2012/034627 |
| 1-Spirobifluorenylamines | WO2017/144150, WO2019/002190 |

The electronic device is preferably selected from the group consisting of organic integrated circuits (OICs), organic field-effect transistors (OFETs), organic thin-film transistors (OTFTs), organic light-emitting transistors (OLETs), organic solar cells (OSCs), organic optical detectors, organic photoreceptors, organic field-quench devices (OFQDs), organic light-emitting electrochemical cells (OLECs), organic laser diodes (O-lasers) and organic electroluminescent devices (OLEDs). More preferably, the electronic device is an organic electroluminescent device.

Layers HTL1 and HTL2 are hole-transporting layers. Hole-transporting layers are understood here to mean all layers disposed between anode and emitting layer, preferably hole injection layers, hole transport layers, and electron blocker layers. A hole injection layer is understood here to mean a layer that directly adjoins the anode. A hole transport layer is understood here to mean a layer which is between the anode and emitting layer but does not directly adjoin the anode, and preferably does not directly adjoin the emitting layer either. An electron blocker layer is understood here to mean a layer which is between the anode and emitting layer and directly adjoins the emitting layer. An electron blocker layer preferably has a high-energy LUMO and hence prevents electrons from exiting from the emitting layer.

Layer HTL1 is preferably a hole transport layer. Layer HTL1 preferably has a thickness of 50 to 150 nm, more preferably of 70 to 120 nm. Layer HTL1 preferably directly adjoins layer HTL2 on the anode side. In an alternative preferred embodiment, there are one or more hole-transporting layers between layer HTL1 and layer HTL2. Layer HTL1 preferably contains essentially exclusively a compound of the formula (I).

Layer HTL2 is preferably an electron blocker layer. Layer HTL2 preferably has a thickness of 5 to 50 nm, more preferably of 15 to 35 nm. If layer HTL2 is a layer directly adjoining a green-phosphorescing emitting layer, it preferably has a thickness of 10 to 50 nm. If layer HTL2 is a layer directly adjoining a blue-fluorescing emitting layer, it preferably has a thickness of 5 to 30 nm. Layer HTL2 preferably contains essentially exclusively a compound selected from compounds of the formula (II) or (Ill).

Preferred cathodes of the electronic device are metals having a low work function, metal alloys or multilayer structures composed of various metals, for example alkaline earth metals, alkali metals, main group metals or lanthanoids (e.g. Ca, Ba, Mg, Al, In, Mg, Yb, Sm, etc.). Additionally suitable are alloys composed of an alkali metal or alkaline earth metal and silver, for example an alloy composed of magnesium and silver. In the case of multilayer structures, in addition to the metals mentioned, it is also possible to use further metals having a relatively high work function, for example Ag or Al, in which case combinations of the metals such as Ca/Ag, Mg/Ag or Ba/Ag, for example, are generally used. It may also be preferable to introduce a thin interlayer of a material having a high dielectric constant between a metallic cathode and the organic semiconductor. Examples of useful materials for this purpose are alkali metal or alkaline earth metal fluorides, but also the corresponding oxides or carbonates (e.g. LiF, Li₂O, BaF₂, MgO, NaF, CsF, Cs₂CO₃, etc.). It is also possible to use lithium quinolinate (LiQ) for this purpose. The layer thickness of this layer is preferably between 0.5 and 5 nm.

Preferred anodes are materials having a high work function. Preferably, the anode has a work function of greater than 4.5 eV versus vacuum. Firstly, metals having a high redox potential are suitable for this purpose, for example Ag, Pt or Au. Secondly, metal/metal oxide electrodes (e.g. Al/Ni/NiOₓ, Al/PtOₓ) may also be preferred. For some applications, at least one of the electrodes has to be transparent or partly transparent in order to enable either the irradiation of the organic material (organic solar cell) or the emission of light (OLED, O-LASER). Preferred anode materials here are conductive mixed metal oxides. Particular preference is given to indium tin oxide (ITO) or indium zinc oxide (IZO). Preference is further given to conductive doped organic materials, especially conductive doped polymers. In addition, the anode may also consist of two or more layers, for example of an inner layer of ITO and an outer layer of a metal oxide, preferably tungsten oxide, molybdenum oxide or vanadium oxide.

The emitting layer of the electronic device may be a phosphorescent emitting layer, or it may be a fluorescent emitting layer. A phosphorescent emitting layer preferably contains at least one matrix material and at least one phosphorescent emitter. A fluorescent emitting layer preferably contains at least one matrix material and at least one fluorescent emitter.

In a preferred embodiment of the invention, the emitting layer of the electronic device is a blue-fluorescing emitting layer or a green-phosphorescing layer. Correspondingly, the emitting layer of the electronic device in the first case contains a blue-fluorescing emitter compound, and in the second case contains a green-phosphorescing emitter compound.

When the emitting layer of the electronic device is a blue-fluorescing emitting layer, it is especially preferable that layer HTL-2 contains a compound of the formula (III), more preferably a compound of the formula (III-1).

When the emitting layer of the electronic device is a green-phosphorescing layer, it is especially preferable that layer HTL-2 contains a compound of the formula (II), more preferably a compound of the formula (II-1).

Most preferably, the emitting layer of the electronic device is a blue-fluorescing emitting layer, and layer HTL2 contains a compound of the formula (III-1).

The electronic device preferably contains a single emitting layer. In this case, the emitting layer is preferably selected from blue-fluorescing emitting layers and green-phosphorescing emitting layers, more preferably from blue-fluorescing emitting layers.

In a preferred embodiment, the electronic device is part of an arrangement consisting of three or more, preferably three, electronic devices, of which one device contains a blue-emitting layer, one device a green-emitting layer, and one device a red-emitting layer (called an RGB side-by-side arrangement). The electronic device according to the application is the blue-emitting device in the arrangement and/or the green-emitting device in the arrangement. Preferably, both the blue-emitting device and the green-emitting device in the arrangement are each devices according to the application. The electronic devices in the arrangement are preferably arranged alongside one another.

In a preferred embodiment, the arrangement contains a device according to the application containing a layer HTL1, a layer HTL2 and a blue-fluorescing emitting layer. Layer HTL2 here preferably contains a compound of a formula (III), more preferably a compound of a formula (III-1).

In a preferred embodiment, the arrangement contains a device according to the application containing a layer HTL1, a layer HTL2 and a green-phosphorescing emitting layer. Layer HTL2 here preferably contains a compound of a formula (II), more preferably a compound of a formula (II-1).

In a particularly preferred embodiment, the arrangement contains a first device according to the application containing a layer HTL1, a layer HTL2 and a blue-fluorescing emitting layer, and a second device according to the application containing a layer HTL1, a layer HTL2 and a green-phosphorescing emitting layer. There is preferably a third electronic device in the arrangement that contains a red-emitting layer, preferably a red-phosphorescing layer. Layer HTL2 in the second device according to the application preferably contains a compound of a formula (II), more preferably a compound of a formula (II-1). Layer HTL2 in the first device according to the application preferably contains a compound of a formula (III), more preferably a compound of a formula (III-1). Preferably, layer HTL1 is identical, especially containing the same material, in the first and second devices according to the application in the arrangement, and preferably also in the third electronic device of the arrangement. Further preferably, layer HTL2 contains the same material in the first and second devices according to the application in the arrangement, and preferably also in the third electronic device of the arrangement; more preferably, layer HTL2 is identical in the first and second devices according to the application in the arrangement. Further preferably, the second device according to the application in the arrangement contains a layer between layer HTL1 and layer HTL2, which preferably contains a compound selected from compounds of the formulae (II) and (III).

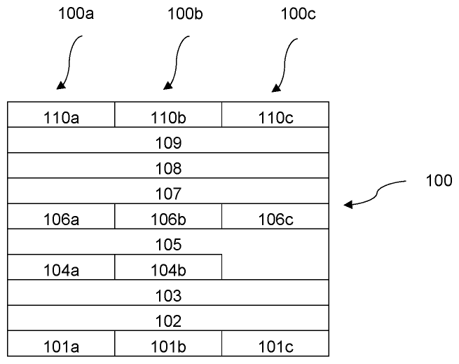

A particularly preferred example of such an arrangement 100 containing three electronic devices, two of which are electronic devices according to the application, is shown in FIG. 1. In this FIGURE, 100c is an electronic device, preferably the abovementioned first device according to the application, 100b is an electronic device, preferably the abovementioned second device according to the application, and 100c is a red-emitting electronic device. Layer 101a is the anode of the red-emitting electronic device, layer 101b is the anode of the second device according to the application, and layer 101c is the anode of the first device according to the application, layer 102 is a hole injection layer in the form of a common layer, layer 103 is layer HTL1, designed as a common layer, layer 104a is the prime layer of the right-emitting electronic device, layer 104b is the prime layer of the green-emitting electronic device and preferably a layer according to the definition of layer HTL2, layer 105 is a common layer and preferably a layer according to the definition of layer HTL2, layer 106a is a red-emitting layer, layer 106b is a green-emitting layer, layer 106c is a blue light-emitting layer, layer 107 is a hole blocker layer, designed as a common layer, layer 108 is an electron transport layer, designed as a common layer, layer 109 is an electron injection layer, designed as a common layer, layer 110a is the cathode of the red-emitting electronic device, layer 110b is the cathode of the second device according to the application, and layer 110c is the cathode of the first device according to the application. Layer 103 preferably contains a compound of the formula (I). Layers 104b and 105 preferably contain a compound selected from compounds of the formulae (II) and (Ill). More preferably, layer 104b contains a compound of the formula (II), and layer 105 contains a compound of the formula (III). What is meant by a “common layer” in the above details is that the layer contains the same material in all three layers of the arrangement. This preferably means that the layer is identical in all three devices in the arrangement, i.e. extends as one layer across all three devices in the arrangement.

The electronic devices of the arrangement shown in FIG. 1 may contain additional layers not shown in the FIGURE.

In an alternative, likewise preferred embodiment, the electronic device contains multiple emitting layers arranged in succession, each having different emission maxima between 380 nm and 750 nm. In other words, different emitting compounds used in each of the multiple emitting layers fluoresce or phosphoresce and emit blue, green, yellow, orange or red light. In a preferred embodiment, the electronic device contains three emitting layers in succession in a stack, of which one in each case exhibits blue emission, one green emission, and one orange or red, preferably red, emission. Preferably, in this case, the blue-emitting layer is a fluorescent layer, and the green-emitting layer is a phosphorescent layer, and the red-emitting layer is a phosphorescent layer.

An emitting layer of the electronic device may also contain systems comprising a plurality of matrix materials (mixed matrix systems) and/or a plurality of emitting compounds. When the electronic device contains a phosphorescent emitting layer, it is preferable that this layer contains two or more, preferably exactly two, different matrix materials.

Mixed matrix systems preferably comprise two or three different matrix materials, more preferably two different matrix materials. Preferably, in this case, one of the two materials is a material having hole-transporting properties and the other material is a material having electron-transporting properties. It is further preferable when one of the materials is selected from compounds having a large energy differential between HOMO and LUMO (wide-bandgap materials). The two different matrix materials may be present in a ratio of 1:50 to 1:1, preferably 1:20 to 1:1, more preferably 1:10 to 1:1 and most preferably 1:4 to 1:1. The desired electron-transporting and hole-transporting properties of the mixed matrix components may, however, also be combined mainly or entirely in a single mixed matrix component, in which case the further mixed matrix component(s) fulfil(s) other functions.

Preference is given to using the following material classes in emitting layers of the electronic device:

### Phosphorescent Emitters:

The term “phosphorescent emitters” typically encompasses compounds where the emission of light is effected through a spin-forbidden transition, for example a transition from an excited triplet state or a state having a higher spin quantum number, for example a quintet state.

Suitable phosphorescent emitters are especially compounds which, when suitably excited, emit light, preferably in the visible region, and also contain at least one atom of atomic number greater than 20, preferably greater than 38, and less than 84, more preferably greater than 56 and less than 80. Preference is given to using, as phosphorescent emitters, compounds containing copper, molybdenum, tungsten, rhenium, ruthenium, osmium, rhodium, iridium, palladium, platinum, silver, gold or europium, especially compounds containing iridium, platinum or copper.

In the context of the present invention, all luminescent iridium, platinum or copper complexes are considered to be phosphorescent compounds.

In general, all phosphorescent complexes as used for phosphorescent OLEDs according to the prior art and as known to those skilled in the art in the field of organic electroluminescent devices are suitable for use in the devices according to the application.

### Fluorescent Emitters:

Preferred fluorescent emitting compounds are selected from the class of the arylamines. An arylamine or an aromatic amine in the context of this invention is understood to mean a compound containing three substituted or unsubstituted aromatic or heteroaromatic ring systems bonded directly to the nitrogen. Preferably, at least one of these aromatic or heteroaromatic ring systems is a fused ring system, more preferably having at least 14 aromatic ring atoms. Preferred examples of these are aromatic anthraceneamines, aromatic anthracenediamines, aromatic pyreneamines, aromatic pyrenediamines, aromatic chryseneamines or aromatic chrysenediamines. An aromatic anthraceneamine is understood to mean a compound in which a diarylamino group is bonded directly to an anthracene group, preferably in the 9 position. An aromatic anthracenediamine is understood to mean a compound in which two diarylamino groups are bonded directly to an anthracene group, preferably in the 9,10 positions. Aromatic pyreneamines, pyrenediamines, chryseneamines and chrysenediamines are defined analogously, where the diarylamino groups are bonded to the pyrene preferably in the 1 position or 1,6 positions. Further preferred emitting compounds are indenofluoreneamines or -diamines, benzoindenofluoreneamines or -diamines, and dibenzoindenofluoreneamines or -diamines, and indenofluorene derivatives having fused aryl groups. Likewise preferred are pyrenearylamines. Likewise preferred are benzoindenofluoreneamines, benzofluoreneamines, extended benzoindenofluorenes, phenoxazines, and fluorene derivatives joined to furan units or to thiophene units.

### Matrix Materials for Fluorescent Emitters:

Preferred matrix materials for fluorescent emitters are selected from the classes of the oligoarylenes (e.g. 2,2′,7,7′-tetraphenylspirobifluorene), especially the oligoarylenes containing fused aromatic groups, the oligoarylenevinylenes, the polypodal metal complexes, the hole-conducting compounds, the electron-conducting compounds, especially ketones, phosphine oxides and sulfoxides; the atropisomers, the boronic acid derivatives or the benzanthracenes. Particularly preferred matrix materials are selected from the classes of the oligoarylenes comprising naphthalene, anthracene, benzanthracene and/or pyrene or atropisomers of these compounds, the oligoarylenevinylenes, the ketones, the phosphine oxides and the sulfoxides. Very particularly preferred matrix materials are selected from the classes of the oligoarylenes comprising anthracene, benzanthracene, benzophenanthrene and/or pyrene or atropisomers of these compounds. An oligoarylene in the context of this invention shall be understood to mean a compound in which at least three aryl or arylene groups are bonded to one another.

### Matrix Materials for Phosphorescent Emitters:

Preferred matrix materials for phosphorescent emitters are aromatic ketones, aromatic phosphine oxides or aromatic sulfoxides or sulfones, triarylamines, carbazole derivatives, e.g. CBP (N,N-biscarbazolylbiphenyl), indolocarbazole derivatives, indenocarbazole derivatives, azacarbazole derivatives, bipolar matrix materials, silanes, azaboroles or boronic esters, triazine derivatives, zinc complexes, diazasilole or tetraazasilole derivatives, diazaphosphole derivatives, bridged carbazole derivatives, triphenylene derivatives, or lactams.

Apart from cathode, anode, emitting layer, layer HTL1 and layer HTL2, the electronic device may comprise further layers. These are selected, for example, from in each case one or more hole injection layers, hole transport layers, hole blocker layers, electron transport layers, electron injection layers, electron blocker layers, exciton blocker layers, interlayers, charge generation layers and/or organic or inorganic p/n junctions. However, it should be pointed out that not every one of these layers need necessarily be present and the choice of layers always depends on the compounds used and especially also on whether the device is a fluorescent or phosphorescent electroluminescent device.

The sequence of layers in the electronic device is preferably as follows:
anode
hole injection layer, preferably p-doped
HTL1
optionally further hole transport layer or hole transport layers
HTL2
emitting layer
optionally hole blocker layer
electron transport layer
electron injection layer
cathode.

It is not obligatory for all the layers mentioned to be present, and/or further layers may additionally be present.

In a preferred embodiment, the electronic device contains a layer disposed between the anode and layer HTL1 and preferably directly adjoining the anode, and more preferably additionally directly adjoining layer HTL1. This layer is preferably a hole injection layer. It preferably conforms to one of the following embodiments: a) it contains a triarylamine and at least one p-dopant; or b) it contains a single electron-deficient material (electron acceptor). In a preferred embodiment of embodiment b), the electron-deficient material is a hexaazatriphenylene derivative as described in US 2007/0092755. It is further preferable that the layer contains, as the main component or sole component, a compound having a 4-substituted spirobifluorene group and an amino group, especially a compound having a spirobifluorene group 4-substituted by an amino group or an amino group bonded via an aromatic system. In a preferred embodiment, the main component is doped by a p-dopant. It is further preferable that the layer disposed between the anode and layer HTL1 contains a compound of formula (I) as defined above. Especially preferably, this layer directly adjoins the anode and layer HTL1.

p-Dopants according to the present application are organic electron acceptor compounds. p-Dopants used are preferably those organic electron acceptor compounds capable of oxidizing one or more of the other compounds in the p-doped layer.

Particularly preferred as p-dopants are quinodimethane compounds, azaindenofluorenediones, azaphenalenes, azatriphenylenes, I₂, metal halides, preferably transition metal halides, metal oxides, preferably metal oxides comprising at least one transition metal or a metal from main group 3, and transition metal complexes, preferably complexes of Cu, Co, Ni, Pd and Pt with ligands containing at least one oxygen atom as binding site. Preference is further given to transition metal oxides as dopants, preferably oxides of rhenium, molybdenum and tungsten, more preferably Re₂O₇, MoO₃, WO₃ and ReO₃. Still further preference is given to complexes of bismuth in the (Ill) oxidation state, more particularly bismuth(Ill) complexes with electron-deficient ligands, more particularly carboxylate ligands.

The p-dopants are preferably in substantially homogeneous distribution in the p-doped layers. This can be achieved, for example, by co-evaporation of the p-dopant and the hole transport material matrix. The p-dopant is preferably present in a proportion of 1% to 10% in the p-doped layer.

Preferred p-dopants are especially the compounds shown in WO2021/104749 on pages 99-100 as (D-1) to (D-14).

In a preferred embodiment, the electronic device may have one or more further hole transport layers in addition to layer HTL1. These may be present between the anode and layer HTL1, or between layer HTL1 and layer HTL2. More preferably, the one or more further hole transport layers of the electronic device are present between layer HTL1 and layer HTL2.

Compounds that are preferably used in further hole-transporting layers of the device according to the application are indenofluoreneamine derivatives, amine derivatives, hexaazatriphenylene derivatives, amine derivatives with fused aromatic systems, monobenzoindenofluoreneamines, dibenzoindenofluoreneamines, spirobifluoreneamines, fluoreneamines, spirodibenzopyranamines, dihydroacridine derivatives, spirodibenzofurans and spirodibenzothiophenes, phenanthrenediarylamines, spirotribenzotropolones, spirobifluorenes having meta-phenyldiamine groups, spirobisacridines, xanthenediarylamines, and 9,10-dihydroanthracene spiro compounds having diarylamino groups.

The electronic device preferably contains at least one electron transport layer. In addition, the electronic device preferably contains at least one electron injection layer. The electron injection layer preferably directly adjoins the cathode. In a preferred embodiment, the electron transport layer contains a triazine derivative and lithium quinolinate. In a preferred embodiment, the electron injection layer contains a triazine derivative and lithium quinolinate. In a particularly preferred embodiment, the electron transport layer and/or the electron injection layer, most preferably the electron transport layer and the electron injection layer, contain a triazine derivative and lithium quinolinate (LiQ).

In a preferred embodiment, the electronic device contains at least one hole blocker layer. This preferably has hole-blocking and electron-transporting properties, and directly adjoins this emitting layer on the cathode side in a device containing a single emitting layer. In a device comprising multiple emitting layers that are arranged in succession, the hole blocker layer directly adjoins those of the multiple emitting layers that are closest to the cathode on the cathode side.

Suitable electron-transporting materials are, for example, the compounds disclosed in Y. Shirota et al., Chem. Rev. 2007, 107(4), 953-1010, or other materials used in these layers according to the prior art.

Materials used for the electron transport layer may be any materials that are used as electron transport materials in the electron transport layer according to the prior art. Especially suitable are aluminium complexes, for example Alq₃, zirconium complexes, for example Zrq₄, lithium complexes, for example Liq, benzimidazole derivatives, triazine derivatives, pyrimidine derivatives, pyridine derivatives, pyrazine derivatives, quinoxaline derivatives, quinoline derivatives, oxadiazole derivatives, aromatic ketones, lactams, boranes, diazaphosphole derivatives and phosphine oxide derivatives.

In a preferred embodiment, the electronic device is characterized in that one or more layers are applied by a sublimation process. In this case, the materials are applied by vapour deposition in vacuum sublimation systems at an initial pressure of less than 10⁻⁵ mbar, preferably less than 10⁻⁶ mbar. In this case, however, it is also possible that the initial pressure is even lower, for example less than 10⁻⁷ mbar.

Preference is likewise given to an electronic device, characterized in that one or more layers are coated by the OVPD (organic vapour phase deposition) method or with the aid of a carrier gas sublimation. In this case, the materials are applied at a pressure between 10⁻⁵ mbar and 1 bar. A special case of this method is the OVJP (organic vapour jet printing) method, in which the materials are applied directly by a nozzle and thus structured (for example M. S. Arnold et al., Appl. Phys. Lett. 2008, 92, 053301).

Preference is additionally given to an electronic device, characterized in that one or more layers are produced from solution, for example by spin-coating, or by any printing method, for example screen printing, flexographic printing, nozzle printing or offset printing, but more preferably LITI (light-induced thermal imaging, thermal transfer printing) or inkjet printing.

It is further preferable that an electronic device according to the application is produced by applying one or more layers from solution and one or more layers by a sublimation method.

After application of the layers, according to the use, the device is structured, contact-connected and finally sealed, in order to rule out damaging effects of water and air.

The electronic device may be used in displays, as light source in lighting applications, and as light source in medical and/or cosmetic applications.

It is preferable in the context of the present application that two or more preferred embodiments are present in combination with one another in the device according to the application. It is especially preferable in the context of the present application that the compound of the formula (I) of layer HTL1 corresponds to one of its above-specified preferred embodiments, and that, in combination therewith, the compound of one of the formulae (II) and (III) of layer HTL2 corresponds to one of the above-specified preferred embodiments thereof.

### EXAMPLES

### Production of the OLEDs

In the examples which follow, the data for various OLEDs are presented. Glass plates which have been coated with structured ITO (indium tin oxide) in a thickness of 50 nm form the substrates to which the OLEDs are applied. The OLEDs basically have the following layer structure: substrate/hole injection layer (HIL)/hole transport layer (HTL)/electron blocker layer (EBL)/emission layer (EML)/electron transport layer (ETL)/electron injection layer (EIL) and finally a cathode. The cathode is formed by an aluminium layer of thickness 100 nm. The exact structure of the OLEDs can be found in tables 2 and 2a. The results are shown in tables 3 and 3a. The materials required for production of the OLEDs are shown in table 1.

All materials are applied by thermal vapour deposition in a vacuum chamber. In this case, the emission layer always consists of at least one matrix material (host material) and an emitting dopant (emitter) which is added to the matrix material(s) in a particular proportion by volume by co-evaporation. Details given in such a form as H1:SEB1 (95%:5%) mean here that the material H1 is present in the layer in a proportion by volume of 95% and SEB1 in a proportion of 5%. Analogously, it is also possible for other layers to consist of a mixture of two materials, as is the case in the present examples for the HIL and the ETL.

The OLEDs are characterized in a standard manner. For this purpose, the electroluminescence spectra, the current efficiency (measured in cd/A), the power efficiency (measured in Im/W) and the external quantum efficiency (EQE, measured in percent) as a function of luminance, calculated from current-voltage-luminance characteristics (IUL characteristics) assuming Lambertian emission characteristics, and the lifetime are determined. Electroluminescence spectra are determined at a luminance of 1000 cd/m², and these are used to calculate the CIE 1931 x and y colour coordinates. The parameter U @10 mA/cm² in tables 3 and 3a refers to the voltage which is required for a current density of 10 mA/cm². EQE @ 10 mA/cm² refers to the external quantum efficiency which is attained at 10 mA/cm². The lifetime LT80 @60 mA/cm² or 80 mA/cm² defines the time after which the luminance falls to a proportion of 80% in the course of operation with the same current density.

### Technical Advantages of the OLEDs According to the Invention, Compared to OLEDs According to the Prior Art

The material combinations according to the invention are notable for the use of materials of the general formula (I) in the hole transport layer in combination with materials of the general formula (II) and formula (III) in the electron blocker layer.

The examples in table 2 show that inventive OLEDs E1-E9 that contain a compound of the general formula (I), especially a 4-spirobifluoreneamine, in the hole transport layer, and a compound of the general formula (III), especially a 4-fluorenylamine, in the electron blocker layer have distinct improvements in properties compared to OLEDs according to the prior art V1-V9.

These OLEDs V1-V9 each have a 4-spirobifluoreneamine in the hole transport layer (HTMV1, HTMV2, HTMV3), and a 4-spirobifluoreneamine in the electron blocker layer (HTMV4, HTMV5, HTMV6).

These OLEDs E1-E9 each have a 4-spirobifluoreneamine in the hole transport layer which is selected from the same compounds as in examples V1-V9 (HTMV1, HTMV2, HTMV3), and, by contrast with the OLEDs V1-V9, they have a 4-fluorenylamine in the electron blocker layer (HTM6, HTM7, HTM8).

The specific comparison of the three-membered groups of examples V1 to V3 and E1 to E2 shows that the devices according to the invention have improved lifetime and efficiency compared to the comparative devices that differ from the devices according to the invention merely by the presence of a 4-spirobifluorenyl compound rather than a 4-fluorenyl compound (Table 3).

The same applies to the comparison of the three-membered groups of examples V4-V6 and E4-E6, and the three-membered groups of examples V7-V9 and E7-E9. The sole difference therein between devices according to the invention and comparative devices is the presence of a 4-spirobifluorenyl compound rather than a 4-fluorenyl compound in the comparative devices. Unlike in the three-membered groups V1 to V3 and E1 to E3, a different 4-spirobifluorenyl compound is used here in the hole transport layer (HTMV2 and HTMV3 rather than HTMV1). This underlines that the effect shown is essentially independent of the choice of the specific 4-spirobifluorenyl compound in the hole transport layer.

Examples E10 to E13 show further OLEDs according to the invention (device construction in Table 2a and data in Table 3a). These OLEDs also show very good device properties.

CIE coordinates in all cases are x=0.14 and y=0.15-0.17 for the blue-emitting OLEDs.

The above-discussed devices have been emphasized merely by way of example. Similar effects can also be observed in the case of other devices not discussed explicitly, as apparent from the tables containing the device data.

TABLE 1
Structures of the materials used

| | |
|---|---|
| 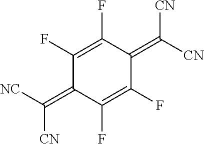 [SMILES: N#CC(C#N)=c1c(F)c(F)c(=C(C#N)C#N)c(F)c1F] | F4TCNQ |
| 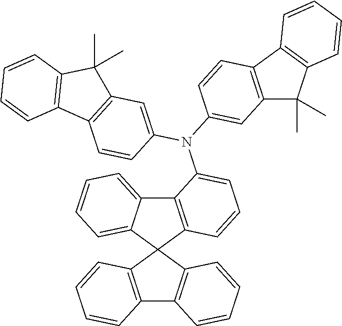 [SMILES: CC1(C)c2ccccc2-c2ccc(N(c3ccc4c(c3)C(C)(C)c3ccccc3-4)c3cccc4c3-c3ccccc3C43c4ccccc4-c4ccccc43)cc21] | HTMV1 |
| 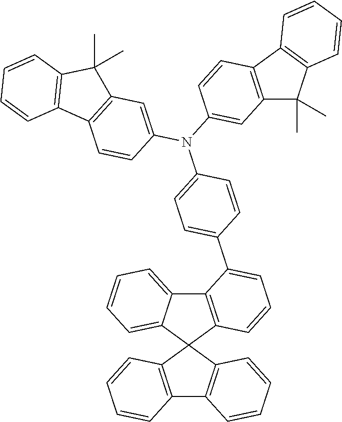 [SMILES: CC1(C)c2ccccc2-c2ccc(N(c3ccc(-c4cccc5c4-c4ccccc4C54c5ccccc5-c5ccccc54)cc3)c3ccc4c(c3)C(C)(C)c3ccccc3-4)cc21] | HTMV2 |
| 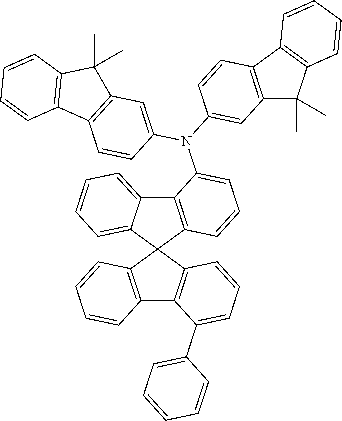 [SMILES: CC1(C)c2ccccc2-c2ccc(N(c3ccc4c(c3)C(C)(C)c3ccccc3-4)c3cccc4c3-c3ccccc3C43c4ccccc4-c4c(-c5ccccc5)cccc43)cc21] | HTMV3 |
| 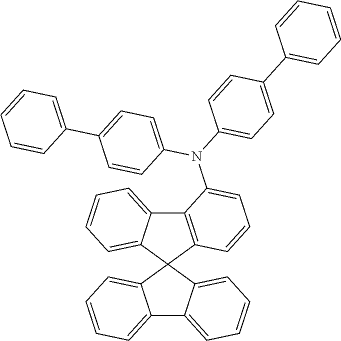 [SMILES: c1ccc(-c2ccc(N(c3ccc(-c4ccccc4)cc3)c3cccc4c3-c3ccccc3C43c4ccccc4-c4ccccc43)cc2)cc1] | HTMV4 |
| 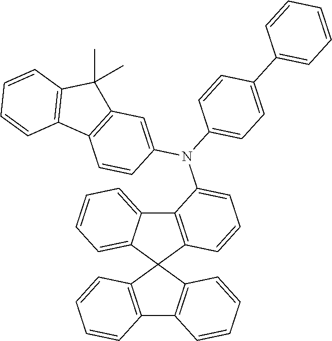 [SMILES: CC1(C)c2ccccc2-c2ccc(N(c3ccc(-c4ccccc4)cc3)c3cccc4c3-c3ccccc3C43c4ccccc4-c4ccccc43)cc21] | HTMV5 |
| 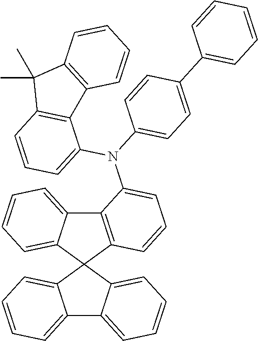 [SMILES: CC1(C)c2ccccc2-c2c(N(c3ccc(-c4ccccc4)cc3)c3cccc4c3-c3ccccc3C43c4ccccc4-c4ccccc43)cccc21] | HTMV6 |
| 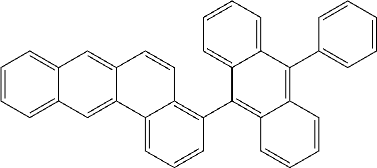 [SMILES: c1ccc(-c2c3ccccc3c(-c3cccc4c3ccc3cc5ccccc5cc34)c3ccccc23)cc1] | H1 |
| 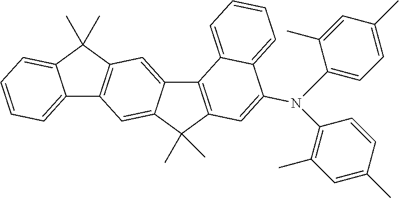 [SMILES: Cc1ccc(N(c2ccc(C)cc2C)c2cc3c(c4ccccc24)-c2cc4c(cc2C3(C)C)-c2ccccc2C4(C)C)c(C)c1] | SEB |
| 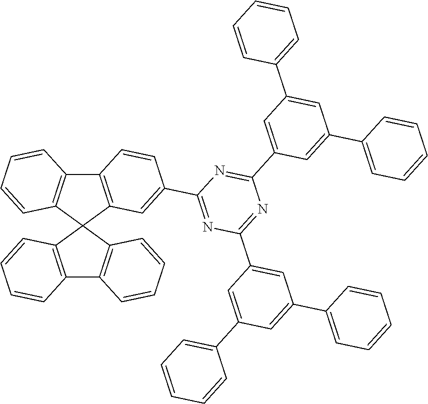 [SMILES: c1ccc(-c2cc(-c3ccccc3)cc(-c3nc(-c4cc(-c5ccccc5)cc(-c5ccccc5)c4)nc(-c4ccc5c(c4)C4(c6ccccc6-c6ccccc64)c4ccccc4-5)n3)c2)cc1] | ETM |
| 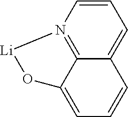 | LiQ |
| 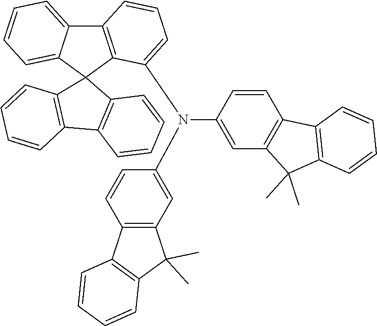 [SMILES: CC1(C)c2ccccc2-c2ccc(N(c3ccc4c(c3)C(C)(C)c3ccccc3-4)c3cccc4c3C3(c5ccccc5-c5ccccc53)c3ccccc3-4)cc21] | HTM1 |
| 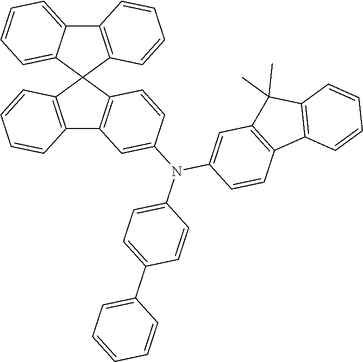 [SMILES: CC1(C)c2ccccc2-c2ccc(N(c3ccc(-c4ccccc4)cc3)c3ccc4c(c3)-c3ccccc3C43c4ccccc4-c4ccccc43)cc21] | HTM2 |
| 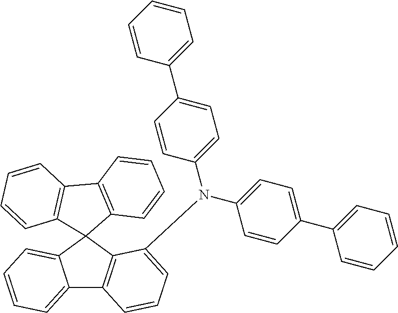 [SMILES: c1ccc(-c2ccc(N(c3ccc(-c4ccccc4)cc3)c3cccc4c3C3(c5ccccc5-c5ccccc53)c3ccccc3-4)cc2)cc1] | HTM3 |
| 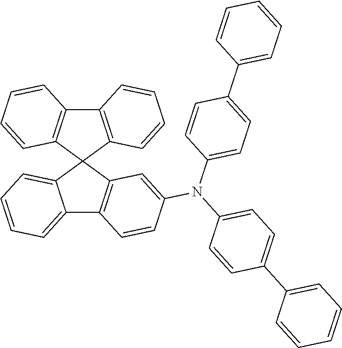 [SMILES: c1ccc(-c2ccc(N(c3ccc(-c4ccccc4)cc3)c3ccc4c(c3)C3(c5ccccc5-c5ccccc53)c3ccccc3-4)cc2)cc1] | HTM4 |
| 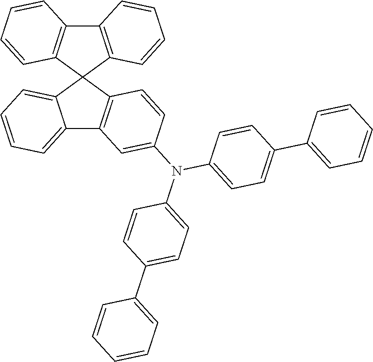 [SMILES: c1ccc(-c2ccc(N(c3ccc(-c4ccccc4)cc3)c3ccc4c(c3)-c3ccccc3C43c4ccccc4-c4ccccc43)cc2)cc1] | HTM5 |
| 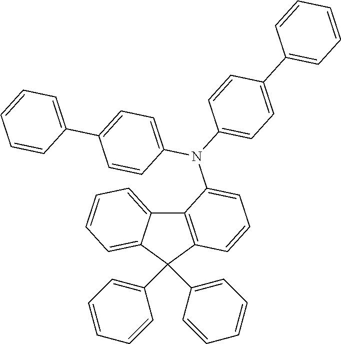 [SMILES: c1ccc(-c2ccc(N(c3ccc(-c4ccccc4)cc3)c3cccc4c3-c3ccccc3C4(c3ccccc3)c3ccccc3)cc2)cc1] | HTM6 |
| 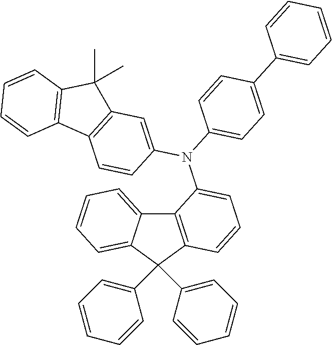 [SMILES: CC1(C)c2ccccc2-c2ccc(N(c3ccc(-c4ccccc4)cc3)c3cccc4c3-c3ccccc3C4(c3ccccc3)c3ccccc3)cc21] | HTM7 |
| 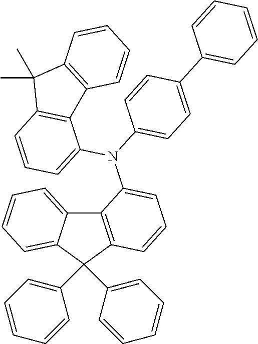 [SMILES: CC1(C)c2ccccc2-c2c(N(c3ccc(-c4ccccc4)cc3)c3cccc4c3-c3ccccc3C4(c3ccccc3)c3ccccc3)cccc21] | HTM8 |

TABLE 2
Structure of the OLEDs

| | Ex. | | | | | |
|---|---|---|---|---|---|---|
| | HIL | HTL | EBL | EML | ETL | EIL |
| | Thick- | Thick- | Thick- | Thick- | Thick- | Thick- |
| | ness/ | ness/ | ness/ | ness/ | ness/ | ness/ |
| | nm | nm | nm | nm | nm | nm |
| V1 | HTMV1: | HTMV1 | HTMV4 | H1: | ETM: | LiQ |
| | F4TCNQ(5%) | 180 nm | 10 nm | SEB(5%) | LiQ(50%) | 1 nm |
| | 20 nm | | | 20 nm | 30 nm | |
| V2 | HTMV1: | HTMV1 | HTMV5 | H1: | ETM: | LIQ |
| | F4TCNQ(5%) | 180 nm | 10 nm | SEB(5%) | LiQ(50%) | 1 nm |
| | 20 nm | | | 20 nm | 30 nm | |
| V3 | HTMV1: | HTMV1 | HTMV6 | H1: | ETM: | LiQ |
| | F4TCNQ(5%) | 180 nm | 10 nm | SEB(5%) | LiQ(50%) | 1 nm |
| | 20 nm | | | 20 nm | 30 nm | |
| V4 | HTMV2: | HTMV2 | HTMV4 | H1: | ETM: | LiQ |
| | F4TCNQ(5%) | 180 nm | 10 nm | SEB(5%) | LiQ(50%) | 1 nm |
| | 20 nm | | | 20 nm | 30 nm | |
| V5 | HTMV2: | HTMV2 | HTMV5 | H1: | ETM: | LiQ |
| | F4TCNQ(5%) | 180 nm | 10 nm | SEB(5%) | LiQ(50%) | 1 nm |
| | 20 nm | | | 20 nm | 30 nm | |
| V6 | HTMV2: | HTMV2 | HTMV6 | H1: | ETM: | LiQ |
| | F4TCNQ(5%) | 180 nm | 10 nm | SEB(5%) | LiQ(50%) | 1 nm |
| | 20 nm | | | 20 nm | 30 nm | |
| V7 | HTMV3: | HTMV3 | HTMV4 | H1: | ETM: | LIQ |
| | F4TCNQ(5%) | 180 nm | 10 nm | SEB(5%) | LiQ(50%) | 1 nm |
| | 20 nm | | | 20 nm | 30 nm | |
| V8 | HTMV3: | HTMV3 | HTMV5 | H1: | ETM: | LiQ |
| | F4TCNQ(5%) | 180 nm | 10 nm | SEB(5%) | LiQ(50%) | 1 nm |
| | 20 nm | | | 20 nm | 30 nm | |
| V9 | HTMV3: | HTMV3 | HTMV6 | H1: | ETM: | LiQ |
| | F4TCNQ(5%) | 180 nm | 10 nm | SEB(5%) | LiQ(50%) | 1 nm |
| | 20 nm | | | 20 nm | 30 nm | |
| E1 | HTMV1: | HTMV1 | HTM6 | H1: | ETM: | LIQ |
| | F4TCNQ(5%) | 180 nm | 10 nm | SEB(5%) | LiQ(50%) | 1 nm |
| | 20 nm | | | 20 nm | 30 nm | |
| E2 | HTMV1: | HTMV1 | HTM7 | H1: | ETM: | LIQ |
| | F4TCNQ(5%) | 180 nm | 10 nm | SEB(5%) | LiQ(50%) | 1 nm |
| | 20 nm | | | 20 nm | 30 nm | |
| E3 | HTMV1: | HTMV1 | HTM8 | H1: | ETM: | LIQ |
| | F4TCNQ(5%) | 180 nm | 10 nm | SEB(5%) | LiQ(50%) | 1 nm |
| | 20 nm | | | 20 nm | 30 nm | |
| E4 | HTMV2: | HTMV2 | HTM6 | H1: | ETM: | LiQ |
| | F4TCNQ(5%) | 180 nm | 10 nm | SEB(5%) | LiQ(50%) | 1 nm |
| | 20 nm | | | 20 nm | 30 nm | |
| E5 | HTMV2: | HTMV2 | HTM7 | H1: | ETM: | LIQ |
| | F4TCNQ(5%) | 180 nm | 10 nm | SEB(5%) | LiQ(50%) | 1 nm |
| | 20 nm | | | 20 nm | 30 nm | |
| E6 | HTMV2: | HTMV2 | HTM8 | H1: | ETM: | LiQ |
| | F4TCNQ(5%) | 180 nm | 10 nm | SEB(5%) | LiQ(50%) | 1 nm |
| | 20 nm | | | 20 nm | 30 nm | |
| E7 | HTMV3: | HTMV3 | HTM6 | H1: | ETM: | LiQ |
| | F4TCNQ(5%) | 180 nm | 10 nm | SEB(5%) | LiQ(50%) | 1 nm |
| | 20 nm | | | 20 nm | 30 nm | |
| E8 | HTMV3: | HTMV3 | HTM7 | H1: | ETM: | LiQ |
| | F4TCNQ(5%) | 180 nm | 10 nm | SEB(5%) | LiQ(50%) | 1 nm |
| | 20 nm | | | 20 nm | 30 nm | |
| E9 | HTMV3: | HTMV3 | HTM8 | H1: | ETM: | LiQ |
| | F4TCNQ(5%) | 180 nm | 10 nm | SEB(5%) | LiQ(50%) | 1 nm |
| | 20 nm | | | 20 nm | 30 nm | |

TABLE 3
Data of the OLEDs

| | U @ | EQE | LT80 |
|---|---|---|---|
| | 10 mA/cm² | @ 10 mA/cm² | @ 60 mA/cm² |
| Ex. | V | % | [h] |
| V1 | 4.1 | 9.1% | 230 |
| V2 | 4.0 | 8.9% | 260 |
| V3 | 4.1 | 9.3% | 210 |
| V4 | 4.2 | 8.9% | 260 |
| V5 | 4.2 | 8.7% | 260 |
| V6 | 4.3 | 9.0% | 230 |
| V7 | 4.3 | 8.7% | 240 |
| V8 | 4.1 | 8.6% | 250 |
| V9 | 4.3 | 8.9% | 210 |
| E1 | 4.0 | 9.5% | 240 |
| E2 | 3.9 | 9.3% | 250 |
| E3 | 4.1 | 9.6% | 230 |
| E4 | 4.2 | 9.8% | 270 |
| E5 | 4.0 | 9.5% | 260 |
| E6 | 4.1 | 9.7% | 240 |
| E7 | 4.2 | 9.6% | 260 |
| E8 | 4.1 | 9.5% | 280 |
| E9 | 4.1 | 9.9% | 250 |

TABLE 2a
Structure of the OLEDs

| | Ex. | | | | | |
|---|---|---|---|---|---|---|
| | HIL | HTL | EBL | EML | ETL | EIL |
| | Thick- | Thick- | Thick- | Thick- | Thick- | Thick- |
| | ness/ | ness/ | ness/ | ness/ | ness/ | ness/ |
| | nm | nm | nm | nm | nm | nm |
| E10 | HTM1: | HTM1 | HTM3 | H1:S | ETM: | LiQ |
| | F4TCNQ(5%) | 180 nm | 10 nm | EB(5%) | LiQ(50%) | 1 nm |
| | 20 nm | | | 20 nm | 30 nm | |
| E11 | HTM1: | HTM1 | HTM4 | H1: | ETM: | LiQ |
| | F4TCNQ(5%) | 180 nm | 10 nm | SEB(5%) | LiQ(50%) | 1 nm |
| | 20 nm | | | 20 nm | 30 nm | |
| E12 | HTMV1: | HTMV1 | HTM5 | H1: | ETM: | LiQ |
| | F4TCNQ(5%) | 180 nm | 10 nm | SEB(5%) | LiQ(50%) | 1 nm |
| | 20 nm | | | 20 nm | 30 nm | |
| E13 | HTM2: | HTM2 | HTM7 | H1: | ETM: | LiQ |
| | F4TCNQ(5%) | 180 nm | 10 nm | SEB(5%) | LiQ(50%) | 1 nm |
| | 20 nm | | | 20 nm | 30 nm | |

TABLE 3a
Data of the OLEDs

| | U @ | EQE | LT80 |
|---|---|---|---|
| | 10 mA/cm² | @ 10 mA/cm² | @ 60 mA/cm² |
| Ex | V | % | [h] |
| E10 | 4.0 | 9.5% | 340 |
| E11 | 3.9 | 9.2% | 390 |
| E12 | 3.9 | 9.5% | 290 |
| E13 | 3.9 | 9.3% | 250 |

1.-20. (canceled)

21. An electronic device comprising an anode,
a cathode,
an emitting layer disposed between anode and cathode,
an undoped layer HTL1 which is disposed between anode and emitting layer and contains a compound of a formula (I) 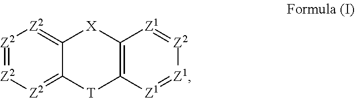
for which:
X is selected from C(R¹)₂ and a group 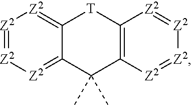
where the dotted lines represent the bonds of the group to the rest of the formula (I);
T is the same or different at each instance and is selected from single bond, O, S, NR², and C(R²)₂;
Z¹ is the same or different at each instance and is CR³ or N; where at least one Z¹ group is CR³ with 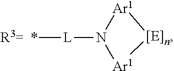
where the bond marked * is the bond to the carbon atom of this CR³ group; Z² is CR⁴ or N;
L is selected from single bond, aromatic ring systems which have 6 to 40 aromatic ring atoms and are substituted by R⁵ radicals and heteroaromatic ring systems which have 5 to 40 aromatic ring atoms and are substituted by R⁵ radicals;
Ar¹ is the same or different at each instance and is selected from aromatic ring systems which have 6 to 40 aromatic ring atoms and are substituted by R radicals, and heteroaromatic ring systems which have 5 to 40 aromatic ring atoms and are substituted by R⁶ radicals;
E is selected from single bond, C(R⁷)₂, —C(R⁷)₂—C(R⁷)₂—, —CR⁷=CR⁷—, Si(R⁷)₂, S, S=O, SO₂ and NR⁷;
R¹ is the same or different at each instance and is selected from H, D, F, Cl, Br, I, C(═O)R, CN, Si(R⁸)₃, N(R⁸)₂, P(═O)(R⁸)₂, OR⁸, S(═O)R⁸, S(═O)₂R⁸, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two R¹ radicals may be joined to one another to form a cycloalkyl ring; where the alkyl, alkoxy, alkenyl and alkynyl groups mentioned and the aromatic ring systems and heteroaromatic ring systems mentioned are each substituted by R⁸ radicals; and where one or more CH₂ groups in the alkyl, alkoxy, alkenyl and alkynyl groups mentioned may be replaced by —R⁸C=CR⁸—, —C═C—, Si(R⁸)₂, C=O, C=NR⁸, —C(═O)O—, —C(═O)NR⁸—, NR⁸, P(═O)(R⁸), —O—, —S—, SO or SO₂;
R² is the same or different at each instance and is selected from H, D, F, Cl, Br, I, C(═O)R⁸, CN, Si(R⁸)₃, N(R⁸)₂, P(═O)(R⁸)₂, OR⁸, S(═O)R⁸, S(═O)₂R⁸, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two R² radicals may be joined to one another and may form a ring; where the alkyl, alkoxy, alkenyl and alkynyl groups mentioned and the aromatic ring systems and heteroaromatic ring systems mentioned are each substituted by R⁸ radicals; and where one or more CH₂ groups in the alkyl, alkoxy, alkenyl and alkynyl groups mentioned may be replaced by —R⁸C=CR⁸—, —C≡C—, Si(R⁸)₂, C=O, C=NR⁸, —C(═O)O—, —C(═O)NR⁸—, NR⁸, P(═O)(R⁸), —O—, —S—, SO or SO₂;
R³ is the same or different at each instance and is selected from a group 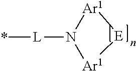
bonded via the bond marked * to the carbon atom of the Z¹ group,
H, D, F, Cl, Br, I, C(═O)R⁸, CN, Si(R⁸)₃, N(R⁸)₂, P(═O)(R⁸)₂, OR⁸, S(═O)R⁸, S(═O)₂R⁸, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R³ radicals may be joined to one another and may form a ring; where the alkyl, alkoxy, alkenyl and alkynyl groups mentioned and the aromatic ring systems and heteroaromatic ring systems mentioned are each substituted by R⁸ radicals; and where one or more CH₂ groups in the alkyl, alkoxy, alkenyl and alkynyl groups mentioned may be replaced by —R⁸C=CR⁸—, —C≡C—, Si(R)₂, C═O, C=NR⁸, —C(═O)O—, —C(═O)NR⁸—, NR⁸, P(═O)(R⁸), —O—, —S—, SO or SO₂;
R⁴ is the same or different at each instance and is selected from a group 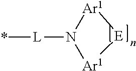
bonded via the bond marked * to the carbon atom of the Z² group,
H, D, F, Cl, Br, I, C(═O)R⁸, CN, Si(R⁸)₃, N(R⁸)₂, P(═O)(R⁸)₂, OR⁸, S(═O)R⁸, S(═O)₂R⁸, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R⁴ radicals may be joined to one another and may form a ring; where the alkyl, alkoxy, alkenyl and alkynyl groups mentioned and the aromatic ring systems and heteroaromatic ring systems mentioned are each substituted by R radicals; and where one or more CH₂ groups in the alkyl, alkoxy, alkenyl and alkynyl groups mentioned may be replaced by —R⁸C=CR⁸—, —C≡C—, Si(R⁸)₂, C═O, C=NR⁸, —C(═O)O—, —C(═O)NR⁸, NR⁸, P(═O)(R⁸), —O—, —S—, SO or SO₂;
R⁵ is the same or different at each instance and is selected from H, D, F, Cl, Br, I, C(═O)R⁸, CN, Si(R⁸)₃, N(R⁸), P(═O)(R⁸)₂, OR⁸, S(═O)R⁸, S(═O)₂R⁸, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R radicals may be joined to one another and may form a ring; where the alkyl, alkoxy, alkenyl and alkynyl groups mentioned and the aromatic ring systems and heteroaromatic ring systems mentioned are each substituted by R⁸ radicals; and where one or more CH₂ groups in the alkyl, alkoxy, alkenyl and alkynyl groups mentioned may be replaced by —R⁸C=CR⁸—, —C≡C—, Si(R⁸)₂, C=O, C=NR⁸, —C(═O)O—C(═O)NR⁸—, NR⁸, P(═O)(R⁸), —O—, —S—, SO or SO₂;
R⁶ is the same or different at each instance and is selected from H, D, F, Cl, Br, I, C(═O)R⁸, CN, Si(R⁸)₃, N(R⁸)₂, P(═O)(R⁸)₂, OR⁸, S(═O)R⁸, S(═O)₂R⁸, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R⁶ radicals may be joined to one another and may form a ring; where the alkyl, alkoxy, alkenyl and alkynyl groups mentioned and the aromatic ring systems and heteroaromatic ring systems mentioned are each substituted by R⁸ radicals; and where one or more CH₂ groups in the alkyl, alkoxy, alkenyl and alkynyl groups mentioned may be replaced by —R⁸C=CR⁸—, —C═C—, Si(R⁸)₂, C=O, C=NR⁸, —C(═O)O—, —C(═O)NR⁸—, NR⁹, P(═O)(R⁸), —O—, —S—, SO or SO₂;
R⁷ is the same or different at each instance and is selected from H, D, F, Cl, Br, I, C(═O)R⁸, CN, Si(R⁸)₃, N(R⁸)₂, P(═O)(R⁸)₂, OR, S(O)R⁸, S(═O)₂R⁸, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R⁷ radicals may be joined to one another and may form a ring; where the alkyl, alkoxy, alkenyl and alkynyl groups mentioned and the aromatic ring systems and heteroaromatic ring systems mentioned are each substituted by R⁸ radicals; and where One or more CH₂ groups in the alkyl, alkoxy, alkenyl and alkynyl groups mentioned may be replaced by —R⁸C=CR⁸—, —C≡C—, Si(R⁸)₂, C=O, C=NR⁸, —C(═O)O—, —C(═O)NR⁸—, NR, P(═O)(R⁸), —O—, —S—, SO or SO₂;
R⁸ is the same or different at each instance and is selected from H, D, F, Cl, Br, I, C(O)R⁹, CN, Si(R⁹)₃, N(R⁹)₂, P(═O)(R⁹)₂, OR⁹, S(═O)R⁹, S(═O)₂R⁹, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R radicals may be joined to one another and may form a ring; where the alkyl, alkoxy, alkenyl and alkynyl groups mentioned and the aromatic ring systems and heteroaromatic ring systems mentioned are each substituted by R⁹ radicals; and where one or more CH₂ groups in the alkyl, alkoxy, alkenyl and alkynyl groups mentioned may be replaced by —R⁹C=CR⁹—, —C≡C—, Si(R⁹)₂, C=O, C=NR⁹, —C(═O)O—, —C(═O)NR⁹—, NR⁹, P(═O)(R⁹), —O—, —S—, SO or SO₂;
R⁹ is the same or different at each instance and is selected from H, D, F, Ci, Br, I, CN, alkyl or alkoxy groups having 1 to 20 carbon atoms, alkenyl or alkynyl groups having 2 to 20 carbon atoms, aromatic ring systems having 6 to 40 aromatic ring atoms and heteroaromatic ring systems having 5 to 40 aromatic ring atoms; where two or more R⁹ radicals may be joined to one another and may form a ring; and where the alkyl, alkoxy, alkenyl and alkynyl groups, aromatic ring systems and heteroaromatic ring systems mentioned may be substituted by one or more radicals selected from F and CN;
n is 0 or 1, where, when n=0, the E group is absent, and the two Ar¹ groups are not bonded to one another:
and
a layer HTL2 which is disposed between the anode and emitting layer and directly adjoining the emitting layer, and which contains a compound of the formula (I) or (III) 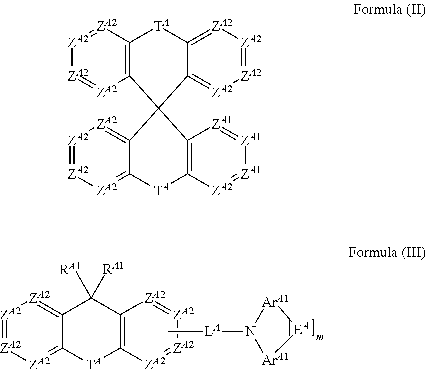
for which:
T^{A} is the same or different at each instance and is selected from single bond, O, S, NR^{A2}, and C(RA²)₂
Z^{A1} is the same or different at each instance and is CR^{A3} or N; where at least one Z group in formula (II) is CR^{A3} with 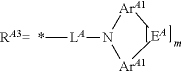
where the bond marked * is the bond to the carbon atom of this CR^{A3} group;
Z^{A2} is the same or different at each instance and is CR^{A4} or N, or is C in formula (III) when the 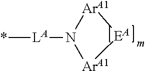
group is bonded thereto;
L^{A} is selected from single bond, aromatic ring systems which have 6 to 40 aromatic ring atoms and are substituted by R^{A5} radicals and heteroaromatic ring systems which have 5 to 40 aromatic ring atoms and are substituted by R^{A5} radicals;
Ar^{A1} is the same or different at each instance and is selected from aromatic ring systems which have 6 to 40 aromatic ring atoms and are substituted by R^{A6} radicals, and heteroaromatic ring systems which have 5 to 40 aromatic ring atoms and are substituted by R^{A6} radicals;
E^{A} is selected from single bond, C(R^{A7})₂, —C(R^{A7})₂—C(R^{A7})₂—, —CR^{A7}=CR^{A7}—, Si(R^{A7})₂, O, S, S=O, SO₂ and NR^{A7};
R^{A1} is the same or different at each instance and is selected from H, D, F, Cl, Br, I, C(═O)R^{A8}, CN, Si(R^{A8})₃, N(R^{A8})₂, P(═O)(R^{A8})₂, OR^{A8}, S(═O)R^{A8}, S(═O)₂R^{A8}, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two R^{A1} radicals may be joined to one another to form a cycloalkyl ring; where the alkyl, alkoxy, alkenyl and alkynyl groups mentioned and the aromatic ring systems and heteroaromatic ring systems mentioned are each substituted by R^{A8} radicals; and where one or more CH₂ groups in the alkyl, alkoxy, alkenyl and alkynyl groups mentioned may be replaced by —R^{A8}C=CR^{A8}, —C≡C—, Si(R^{A8})₂, C=O, C=NR^{A8}, —C(═O)O—, —C(═O)NR^{A8}—, NR^{A8}, P(═O)(R^{A8}), —O—, —S—, SO or SO₂;
R^{A2} is the same or different at each instance and is selected from H, D, F, Cl, Br, I, C(═O)R^{A8}, CN, Si(R^{A8})₃, N(R^{A8})₂, P(═O)(R^{A8})₂, OR^{A8}, S(═O)R^{A8}, S(═O)₂R^{A8}, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R^{A2} radicals may be joined to one another and may form a ring; where the alkyl, alkoxy, alkenyl and alkynyl groups mentioned and the aromatic ring systems and heteroaromatic ring systems mentioned are each substituted by R^{A8} radicals; and where one or more CH₂ groups in the alkyl, alkoxy, alkenyl and alkynyl groups mentioned may be replaced by —R^{A8}C=CR^{A8}—, —C≡C—, Si(R^{A8})₂, C═O, C=NR^{A8}, —C(═O)O—, —C(═O)NR^{A8}—, NR^{A8}, P(═O)(R^{A8}), —O—, —S—, SO or SO₂;
R^{A3} is the same or different at each instance and is selected from a group 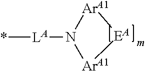
bonded via the bond marked * to the carbon atom of the Z^{A1} group,
H, D, F, Cl, Br, I, C(═O)R^{A8}, CN, Si(R^{A8})₃, N(R^{A8})₂, P(═O)(R^{A8})₂, OR^{A8}, S(═O)R^{A8}, S(═O)₂R^{A8}, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R^{A3} radicals may be joined to one another and may form a ring; where the alkyl, alkoxy, alkenyl and alkynyl groups mentioned and the aromatic ring systems and heteroaromatic ring systems mentioned are each substituted by R^{A8} radicals; and where one or more CH₂ groups in the alkyl, alkoxy, alkenyl and alkynyl groups mentioned may be replaced by —R^{A8}C=CR^{A8}—, —C=C—, Si(R^{A8})₂, C=O, C=NR^{A8}, —C(═O)O—, —C(═O)NR^{A8}—, NR^{A8}, P(═O)(R^{A8}), —O—, —S—, SO or SO₂;
R^{A4} is the same or different at each instance and is selected from H, D, F, Ci, Br, I, C(═O)R^{A8}, CN, Si(R^{A8})₃, N(R^{A8})₂, P(═O)(R^{A8})₂, OR^{A8}, S(═O)R^{A8}, S(═O)₂R^{A8}, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R^{A4} radicals may be joined to one another and may form a ring; where the alkyl, alkoxy, alkenyl and alkynyl groups mentioned and the aromatic ring systems and heteroaromatic ring systems mentioned are each substituted by R^{A8} radicals; and where one or more CH₂ groups in the alkyl, alkoxy, alkenyl and alkynyl groups mentioned may be replaced by —R^{A8}C=CR^{A8}—, —C≡C—, Si(R^{A8})₂, C═O, C=NR^{A8}, —C(═O)O—, —C(═O)NR^{A8}—, NR^{A8}, P(═O)(R^{A8}), —O—, —S—, SO or SO₂,
R^{A5} is the same or different at each instance and is selected from H, D, F, Cl, Br, I, C(═O)R^{A8}, CN, Si(R^{A8})₃, N(R^{A8})₂, P(═O)(R^{A8})₂, OR^{A8}, S(═O)R^{A8}, S(═O)₂R^{A8}, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R^{A5} radicals may be joined to one another and may form a ring; where the alkyl, alkoxy, alkenyl and alkynyl groups mentioned and the aromatic ring systems and heteroaromatic ring systems mentioned are each substituted by R^{A8} radicals; and where one or more CH₂ groups in the alkyl, alkoxy, alkenyl and alkynyl groups mentioned may be replaced by —R^{A8}C=CR^{A8}—, —C≡C—, Si(R^{A8})₂, C═O, C=NR^{A8}, —C(=(O)O—, —C(O)NR^{A8}—, NR^{A8}, P(═O)(R^{A8}), —O—, —S—, SO or SO₂;
R^{A6} is the same or different at each instance and is selected from H, D, F, Cl, Br, I, C(═O)R^{A8}, CN, Si(R^{A8})₃, N(R^{A8})₂ P(═O)(R^{A8})₂, OR^{A8}, S(═O)RA⁸, S(═O)₂R^{A8}, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R^{A6} radicals may be joined to one another and may form a ring; where the alkyl, alkoxy, alkenyl and alkynyl groups mentioned and the aromatic ring systems and heteroaromatic ring systems mentioned are each substituted by R^{A5} radicals; and where one or more CH₂ groups in the alkyl, alkoxy, alkenyl and alkynyl groups mentioned may be replaced by —R^{A8}C=C^{A8}—, —C≡C—, Si(R^{A8})₂, C=O, C=NR^{A8}, —C(═O)O—, —C(═O)NR^{A8}—, NR^{A8}, P(═O)(R^{A8}), —O—, —S—, SO or SO₂;
R^{A7} is the same or different at each instance and is selected from H, D, F, Cl, Br, I, C(═O)R^{A8}, CN, Si(R^{A8})₃, N(R^{A8})₂, P(═O)(R^{A8})₂, OR^{A8}, S(═O)R^{A8}, S(═O)₂R^{A8}, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more RA radicals may be joined to one another and may form a ring; where the alkyl, alkoxy, alkenyl and alkynyl groups mentioned and the aromatic ring systems and heteroaromatic ring systems mentioned are each substituted by R^{A8} radicals; and where one or more CH₂ groups in the alkyl, alkoxy, alkenyl and alkynyl groups mentioned may be replaced by —R^{A8}C=CR^{A8}—, —C≡C—, Si(R^{A8})₂, C═O, C=NR^{A8}, —C(═O)O—, —C(═O)NR^{A8}—, NR^{A8}—, P(═O)(R^{A8}), —O—, —S—, SO or SO₂;
R^{A} is the same or different at each instance and is selected from H, D, F, Cl, Br, I, C(═O)R^{A9}, CN, Si(R^{A9})₃, N(R^{A9})₂, P(═O)(R^{A9})₂, OR^{A9}, S(═O)R^{A9}, S(═O)₂R^{A9}, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R^{A8} radicals may be joined to one another and may form a ring; where the alkyl, alkoxy, alkenyl and alkynyl groups mentioned and the aromatic ring systems and heteroaromatic ring systems mentioned are each substituted by R^{A9} radicals; and where one or more CH₂ groups in the alkyl, alkoxy, alkenyl and alkynyl groups mentioned may be replaced by —R^{A9}C=CR^{A9}—, —C≡C—, Si(R^{a9})₂, C═O, C=NR^{A9}, —C(═O)O—, —C(═O)NR^{A9}—, NR^{A9}, P(═O)(R^{A8}), —O—, —S—, SO or SO₂;
R^{A9} is the same or different at each instance and is selected from H, D, F, Cl, Br, I, CN, alkyl or alkoxy groups having 1 to 20 carbon atoms, alkenyl or alkynyl groups having 2 to 20 carbon atoms, aromatic ring systems having 6 to 40 aromatic ring atoms and heteroaromatic ring systems having 5 to 40 aromatic ring atoms; where two or more R^{A9} radicals may be joined to one another and may form a ring; and where the alkyl, alkoxy, alkenyl and alkynyl groups, aromatic ring systems and heteroaromatic ring systems mentioned may be substituted by one or more radicals selected from F and CN;
m is 0 or 1, where, when m=0, the E^{A} group is absent, and the two Ar^{A1} groups are not bonded to one another.

22. The device according to claim 21, characterized in that, in formula (I), X is selected from a group 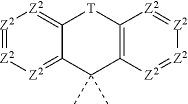
where the dotted lines represent the bonds of the group to the rest of the formula (I).

23. The device according to claim 21, characterized in that at least one Ar¹ is the same or different at each instance and are selected from the formulae 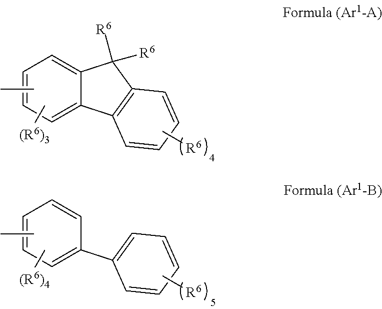
where the groups that occur are as defined in claim 21.

24. The device according to claim 21, characterized in that R³ is the same or different at each instance and is selected from a group 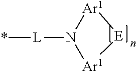
bonded via the bond marked * to the carbon atom of the Z¹ group, and H.

25. The device according to claim 21, characterized in that n is 0.

26. The device according to claim 21, characterized in that formula (I) corresponds to the formula (I-1) 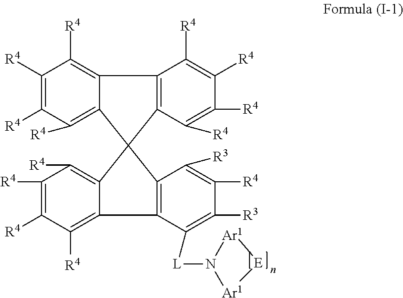
where the variables that occur are as defined in claim 21.

27. The device according to claim 21, characterized in that the R³ group that corresponds to the following group: 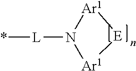
contains at least one Ar¹ group selected from fluorenyl, spirobifluorenyl and carbazolyl, each substituted by R⁶ radicals.

28. The device according to claim 21, characterized in that the layer HTL2 contains a compound of the formula (III) where T^{A} is a single bond.

29. The device according to claim 21, characterized in that m is 0.

30. The device according to claim 21, characterized in that at least one Ar^{A1} group is selected from the following formulae: 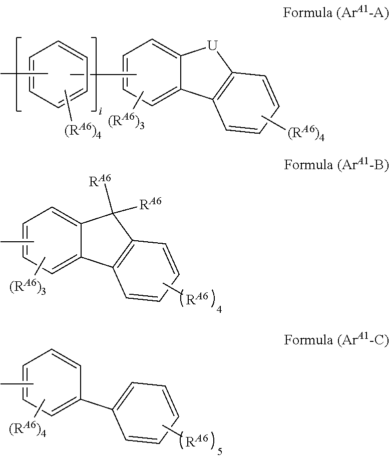
where i is 0, 1, 2, 3 or 4, U is O, S, or NR^{A6}, and the other groups that occur are as defined in claim 21.

31. The device according to claim 21, characterized in that R^{A3} is the same or different at each instance and is selected from a group 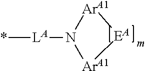
bonded via the bond marked * to the carbon atom of the Z^{A1} group, and H.

32. The device according to claim 21, characterized in that formula (III) corresponds to a formula (III-1) 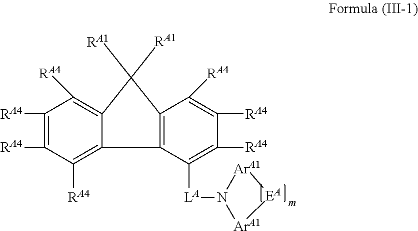
where the symbols that occur are as defined in claim 21.

33. The device according to claim 21, characterized in that the compound of the formula (II) or (III) has a HOMO of higher than −5.25 eV.

34. The device according to claim 21, characterized in that the compound of the formula (II) or (III) has a HOMO of lower than −5.05 eV.

35. The device according to claim 21, characterized in that it includes a hole injection layer which is disposed between the anode and layer HTL1 and contains a compound of the formula (I) and a p-dopant.

36. The device according to claim 21, characterized in that it has at least one layer selected from electron transport layers and electron injection layers containing a triazine derivative and lithium quinolinate (LiQ).

37. The device according to claim 21, characterized in that the emitting layer of the device is a blue-fluorescing emitting layer, and layer HTL2 contains a compound of formula (III).

38. The device according to claim 21, characterized in that the emitting layer of the device is a green-phosphorescing emitting layer, and layer HTL2 contains a compound of formula (II).

39. An arrangement comprising
two electronic devices as claimed in claim 21, wherein a first of the two devices contains a blue-fluorescing emitting layer and a layer HTL2 containing a compound of the formula (III), and a second of the two devices contains a green-phosphorescing emitting layer and a layer HTL2 containing a compound of the formula (II) and
a third electronic device containing a red-phosphorescing emitting layer.

40. A process for producing a device according to claim 21, characterized in that one or more layers of the device are applied by a sublimation method.
